(19) United States
(12) Patent Application Publication
(10) Pub. No.: US 2023/0232714 A1
(43) Pub. Date: Jul. 20, 2023

(54) LIGHT EMITTING ELEMENT AND POLYCYCLIC COMPOUND FOR THE SAME

(71) Applicant: Samsung Display Co., Ltd., Yongin-si (KR)

(72) Inventors: YESEUL LEE, Hwaseong-si (KR); JANG YEOL BAEK, Yongin-si (KR); HEECHOON AHN, Seoul (KR); HYOYOUNG LEE, Suwon-si (KR); SEOWON CHO, Asan-si (KR)

(21) Appl. No.: 17/976,568

(22) Filed: Oct. 28, 2022

(30) Foreign Application Priority Data
Jan. 20, 2022 (KR) 10-2022-0008782

(51) Int. Cl. H01L 51/00; C07F 5/02; C07F 7/08; H01L 51/50

(52) U.S. Cl. CPC H01L 51/0072; C07F 5/027; H01L 51/0094; C07F 7/0812; H01L 51/0073; H01L 51/0074; H01L 51/0067; H01L 51/5024; C07B 2200/05

(57) ABSTRACT

A light emitting element that includes a first electrode, a second electrode facing the first electrode, and an emission layer between the first electrode and the second electrode is provided. The emission layer includes a polycyclic compound represented by Formula 1. The light emitting element has a reduced driving voltage and an increased efficiency.

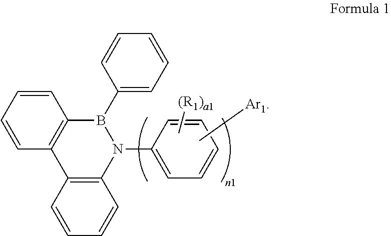

### CROSS-REFERENCE TO RELATED APPLICATION

This application claims priority to and the benefit of Korean Patent Application No. 10-2022-0008782, filed on Jan. 20, 2022, the entire content of which is hereby incorporated by reference.

### BACKGROUND

### 1. Field

Aspects of one or more embodiments of the present disclosure relate to a light emitting element and a polycyclic compound utilized therein.

### 2. Description of the Related Art

As image display devices, organic electroluminescence display devices and/or the like have recently been actively developed. The organic electroluminescence display devices and/or the like are display devices including self-luminescent light emitting elements in which holes and electrons injected from a first electrode and a second electrode recombine in an emission layer, and thus a luminescent material in the emission layer emits light to accomplish display (e.g., to display an image).

For application of light emitting elements to display devices, there is a demand or desired for reduced driving voltage, high efficiency and long lifespan, and development of materials, for light emitting elements, capable of stably attaining such characteristics is being continuously required (sought).

### SUMMARY

An aspect of one or more embodiments of the present disclosure is directed toward a light emitting element having reduced driving voltage and increased efficiency.

An aspect of one or more embodiments of the present disclosure is also directed toward a polycyclic compound as a material for a light emitting element which has reduced driving voltage and high efficiency characteristics.

Additional aspects will be set forth in part in the description which follows and, in part, will be apparent from the description, or may be learned by practice of the presented embodiments of the disclosure.

An embodiment of the present disclosure provides a light emitting element including a first electrode, a second electrode facing the first electrode, and an emission layer between the first electrode and the second electrode and containing a polycyclic compound represented by Formula 1.

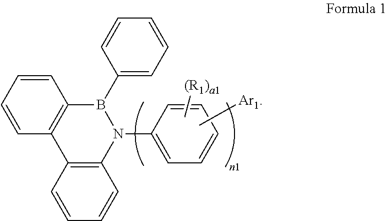

In Formula 1, n1 may be an integer from 0 to 3, Ar₁ may be a substituted or unsubstituted carbazole group, a substituted or unsubstituted pyridine group, a substituted or unsubstituted pyrimidine group, or a substituted or unsubstituted triazine group, when Ar₁ is an unsubstituted carbazole group, n1 is an integer from 1 to 3, when n1 is 1 and Ar₁ is an unsubstituted carbazole group, Ar₁ is bonded in meta position with respect to N, a1 is an integer from 0 to 4, and R₁ is a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted hydrocarbon ring group having 6 to 60 ring-forming carbon atoms, a substituted or unsubstituted aryl group having 6 to 60 ring-forming carbon atoms, or a substituted or unsubstituted heterocyclic group having 2 to 60 ring-forming carbon atoms.

In Formula 1, Ar₁ may be represented by Formula 2-1 or Formula 2-2.

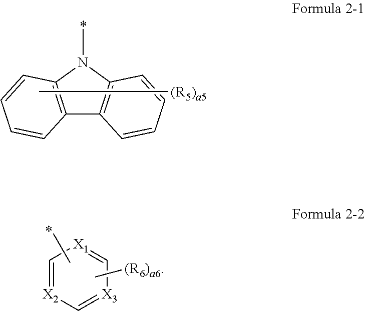

In Formula 2-1, a5 may be an integer from 0 to 8, and R₅ may be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms; and in Formula 2-2, a6 may be an integer from 0 to 2, at least one of X₁ to X₃ may be N and each of the reminder of X₁ to X₃ may independently be CR₇, and R₆ and R₇ may each independently be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms.

In Formulas 2-1 and 2-2, R₅ and R₆ may each independently be represented by any one selected from among RN-1 to RN-5.

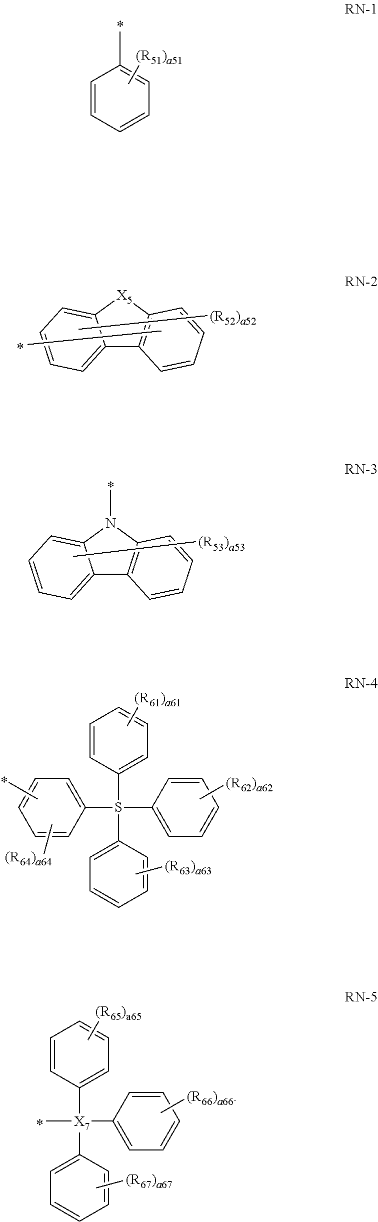

In RN-2, a52 may be an integer from 0 to 7, and X₅ may be CR₅₄R₅₅, SiR₅₆R₅₇, NR₅₈, O, or S; in RN-3, a53 may be an integer from 0 to 8; in RN-4, a64 may be an integer from 0 to 4, and X₆ may be C or Si; in RN-5, X₇ may be C or Si; and in RN-1 to RN-5, a51, a61 to a63, and a65 to a67 may each independently be an integer from 0 to 5, and R₅₁ to R₅₈, and R₆₁ to R₆₇ may each independently be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms.

Formula 1 may be represented by any one selected from among Formulas 1-1 to 1-5.

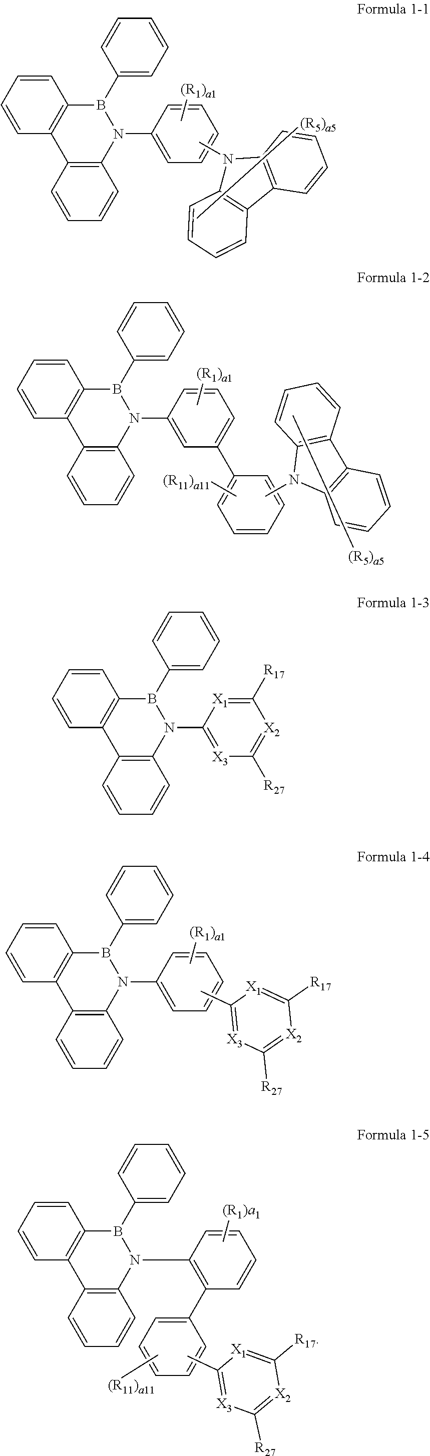

In Formulas 1-1 and 1-2, a5 may be an integer from 0 to 8, and R₅ may be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms; in Formulas 1-2 and 1-5, a11 may be an integer from 0 to 4, and R₁₁ may be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted hydrocarbon ring group having 6 to 60 ring-forming carbon atoms, a substituted or unsubstituted aryl group having 6 to 60 ring-forming carbon atoms, or a substituted or unsubstituted heterocyclic group having 2 to 60 ring-forming carbon atoms; in Formulas 1-3 to 1-5, at least one of X₁ to X₃ may be N and each of the reminder of X₁ to X₃ is independently CR₇, and R₇, R₁₇, and R₂₇ may each independently be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms; and in Formulas 1-1 to 1-5, a1 and R₁ are the same as defined in Formula 1.

Formula 1 may be represented by any one selected from among Formulas 1-A1 to 1-A4.

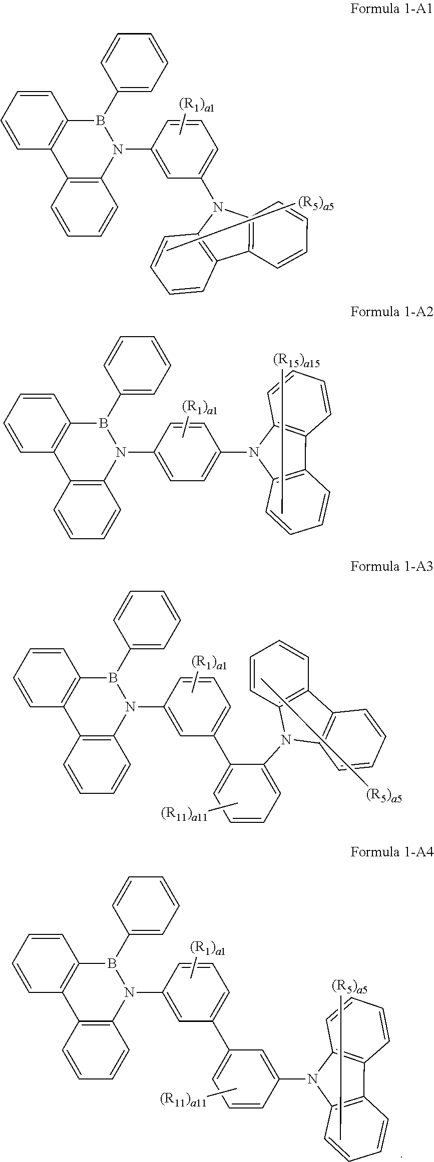

In Formula 1-A2, a15 may be an integer from 1 to 8, and R₁₅ may be a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms; in Formulas 1-A3 and 1-A4, a11 may be an integer from 0 to 4, and R₁₁ may be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted hydrocarbon ring group having 6 to 60 ring-forming carbon atoms, a substituted or unsubstituted aryl group having 6 to 60 ring-forming carbon atoms, or a substituted or unsubstituted heterocyclic group having 2 to 60 ring-forming carbon atoms; in Formulas 1-A1, 1-A3 and 1-A4, a5 may be an integer from 0 to 8, and R₅ may be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms; and in Formulas 1-A1 to 1-A4, a1 and R₁ are the same as defined in Formula 1.

Formula 1 may be represented by any one selected from among Formulas 1-B1 to 1-B65.

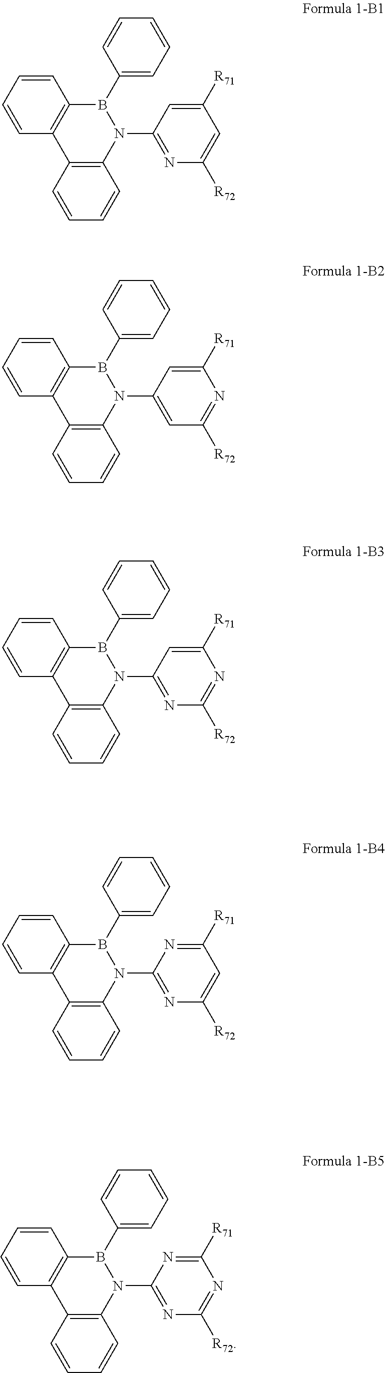

In Formulas 1-B1 to 1-B5, R₇₁ and R₇₂ may each independently be a substituted or unsubstituted aryl group having 6 to 60 ring-forming carbon atoms, or a substituted or unsubstituted heteroaryl group having 2 to 60 ring-forming carbon atoms.

Formula 1 may be represented by any one selected from among Formulas 1-C1 to 1-C6.

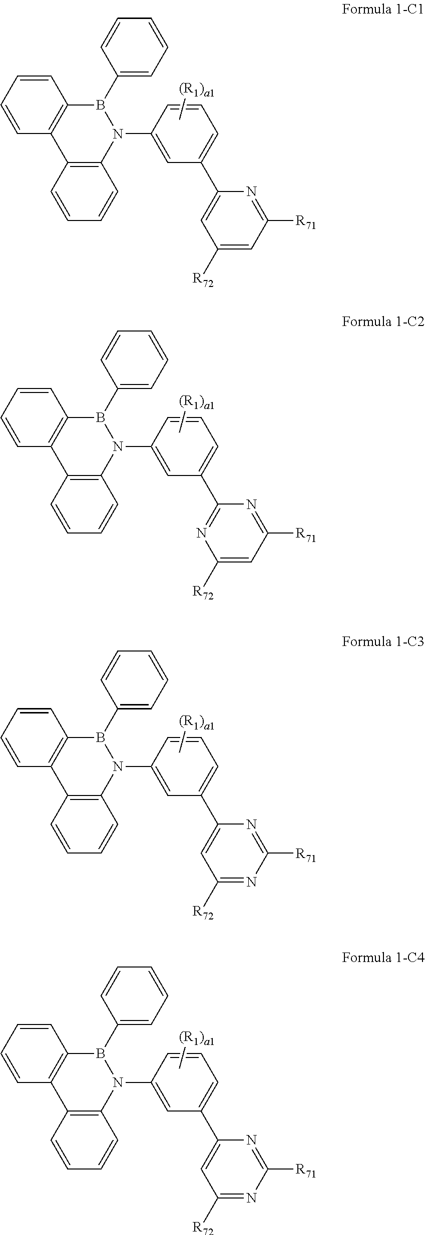

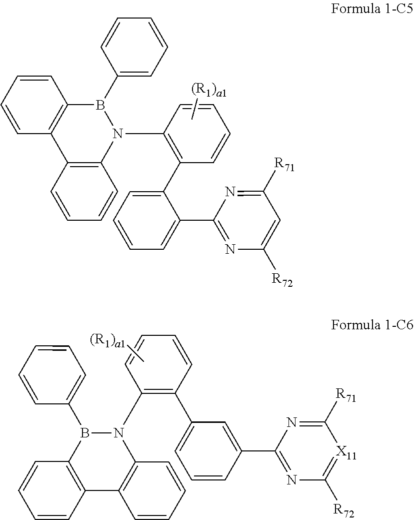

In Formula 1-C6, X₁₁ may be CH or N; and in Formulas 1-C1 to 1-C6, R₇₁ and R₇₂ may each independently be a substituted or unsubstituted aryl group having 6 to 60 ring-forming carbon atoms, or a substituted or unsubstituted heteroaryl group having 2 to 60 ring-forming carbon atoms, and a1 and R₁ are the same as defined in Formula 1.

In Formula 1, R₁ may be represented by any one selected from among R1-1 to R1-5.

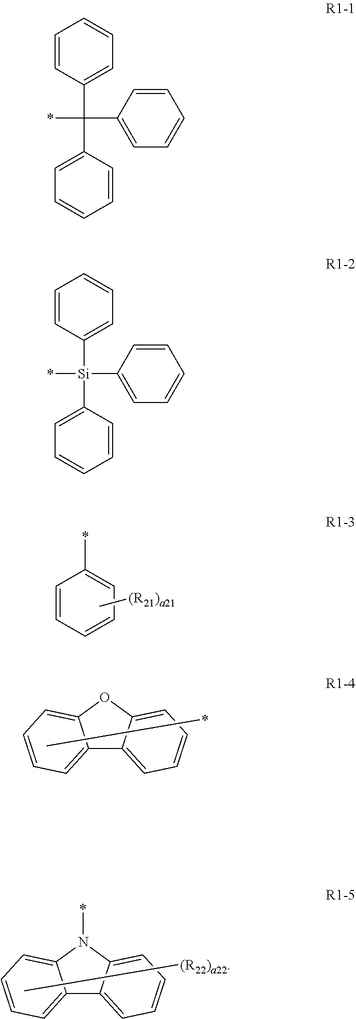

In RN-3, a21 may be an integer from 0 to 5, and R₂₁ may be a hydrogen atom, a deuterium atom, a substituted or unsubstituted silyl group, or a substituted or unsubstituted carbazole group; in RN-5, a22 may be an integer from 0 to 8, and R₂₂ is a hydrogen atom, a deuterium atom, or a substituted or unsubstituted carbazole group.

The emission layer may include a dopant and a host, and the host may contain the polycyclic compound.

The emission layer may be a layer of phosphorescence, or a layer of thermally activated delayed fluorescence.

In an embodiment of the present disclosure, provided is a polycyclic compound represented by Formula 1.

In Formula 1, at least one of R₁ or Ar₁ may include a deuterium atom or a substituent containing a deuterium atom.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a plan view showing a display device according to an embodiment;

FIG. 2 is a cross-sectional view showing a portion corresponding to line I-I′ of FIG. 1;

FIG. 3 is a cross-sectional view schematically showing a light emitting element according to an embodiment;

FIG. 4 is a cross-sectional view schematically showing a light emitting element according to an embodiment;

FIG. 5 is a cross-sectional view schematically showing a light emitting element according to an embodiment;

FIG. 6 is a cross-sectional view schematically showing a light emitting element according to an embodiment;

FIG. 7 is a cross-sectional view showing a display device according to an embodiment;

FIG. 8 is a cross-sectional view showing a display device according to an embodiment;

FIG. 9 is a cross-sectional view showing a display device according to an embodiment; and

FIG. 10 is a cross-sectional view showing a display device according to an embodiment.

### DETAILED DESCRIPTION

The present disclosure may be modified in many alternate forms, and thus specific embodiments will be exemplified in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

In the present description, when an element (or a region, a layer, a portion, etc.) is referred to as being “on,” “connected to,” or “coupled to” another element, it refers to that the element may be directly disposed on/connected to/coupled to the other element, or that a third element may be disposed therebetween.

Like reference numerals refer to like elements. In some embodiments, in the drawings, the thickness, the ratio, and the dimensions of elements may be exaggerated for an effective description of technical contents. The term “and/or,” includes all combinations of one or more of which associated configurations may define.

It will be understood that, although the terms first, second, etc. may be utilized herein to describe one or more suitable elements, these elements should not be limited by these terms. These terms are only utilized to distinguish one element from another element. For example, a first element may be referred to as a second element, and similarly, a second element may be referred to as a first element without departing from the teachings of the present disclosure. The singular forms are intended to include the plural forms as well, unless the context clearly indicates otherwise.

Also, terms of “below”, “on lower side”, “above”, “on upper side”, and/or the like may be utilized to describe the relationships of the components illustrated in the drawings. The terms are utilized as a relative concept and are described with reference to the direction indicated in the drawings.

It should be understood that the terms “comprise”, “include” or “have” are intended to specify the presence of stated features, integers, steps, operations, elements, components, or combinations thereof in the disclosure, but do not preclude the presence or addition of one or more other features, integers, steps, operations, elements, components, or combinations thereof. As used herein, the singular forms “a”, “an” and “the” are intended to include the plural forms as well, unless the context clearly indicates otherwise.

Unless otherwise defined, all terms (including technical and scientific terms) utilized herein have the same meaning as commonly understood by one of ordinary skill in the art to which the present disclosure pertains. It is also to be understood that terms defined in commonly utilized dictionaries should be interpreted as having meanings consistent with the meanings in the context of the related art, and are expressly defined herein unless they are interpreted in an ideal or overly formal sense.

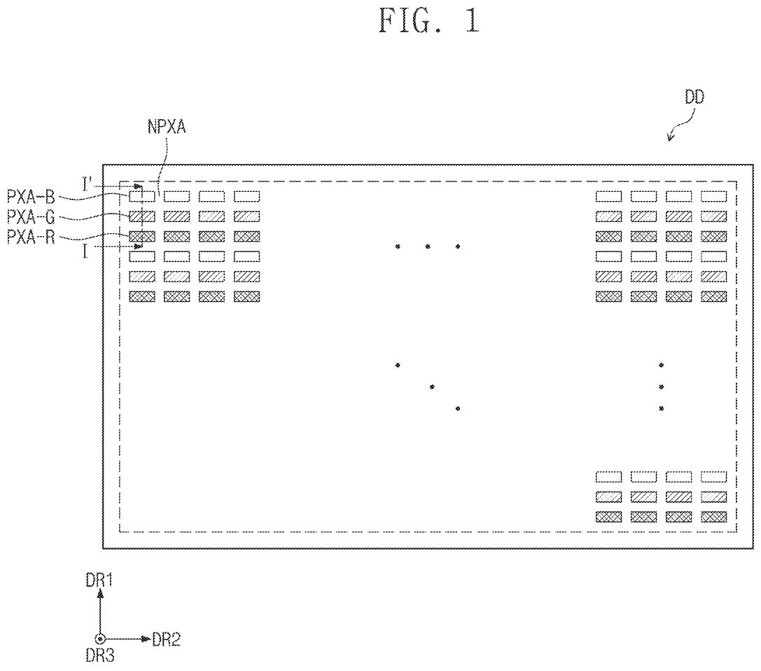

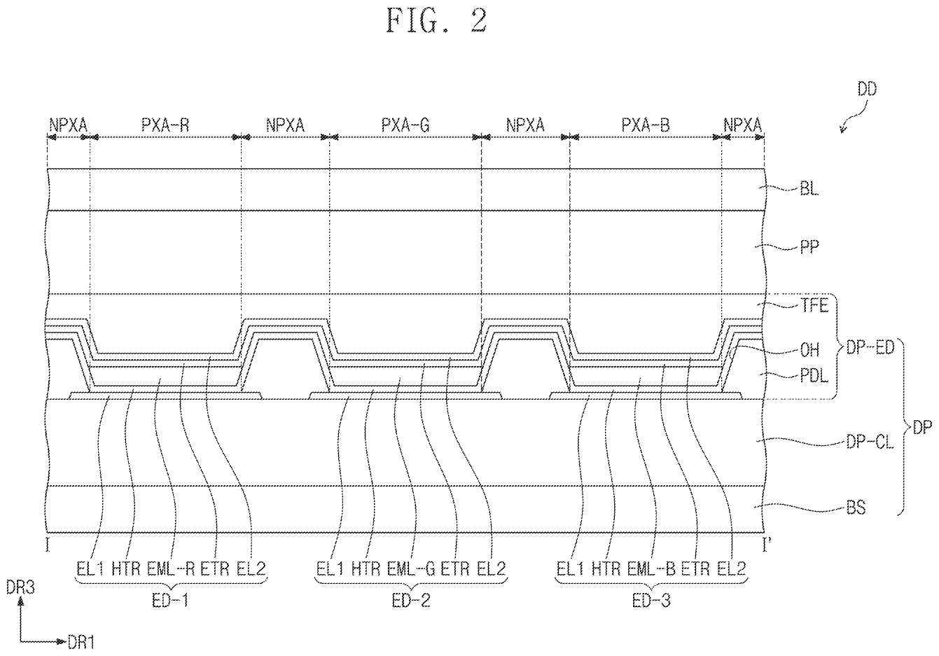

Hereinafter, embodiments of the present disclosure will be described with reference to the accompanying drawings. FIG. 1 is a plan view showing an embodiment of a display device DD. FIG. 2 is a cross-sectional view of a display device DD of an embodiment. FIG. 2 is a cross-sectional view showing a portion corresponding to line I-I′ of FIG. 1.

The display device DD may include a display panel DP and an optical layer PP on the display panel DP. The display panel DP may include light emitting elements ED-1, ED-2, and ED-3. The display device DD may include a plurality of light emitting elements ED-1, ED-2, and ED-3. The optical layer PP may be on the display panel DP to control reflected light in the display panel DP due to external light. The optical layer PP may include, for example, a polarizing layer or a color filter layer. The optical layer PP may not be provided in the display device DD of an embodiment.

A base substrate BL may be on the optical layer PP. The base substrate BL may be a member providing a base surface on which the optical layer PP is disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, the base substrate BL may not be provided.

The display device DD according to an embodiment may further include a filling layer. The filling layer may be between a display element layer DP-ED and the base substrate BL. The filling layer may be an organic material layer. The filling layer may include at least one selected from among an acrylic resin, a silicone-based resin, and an epoxy-based resin.

The display panel DP may include a base layer BS, a circuit layer DP-CL provided on the base layer BS, and a display element layer DP-ED. The display element layer DP-ED may include pixel defining films PDL, a plurality of light emitting elements ED-1, ED-2, and ED-3 disposed between the pixel defining films PDL, and an encapsulation layer TFE on the plurality of light emitting elements ED-1, ED-2, and ED-3.

The base layer BS may be a member providing a base surface in which the display element layer DP-ED is disposed. The base layer BS may be a glass substrate, a metal substrate, a plastic substrate, etc. However, the embodiment of the present disclosure is not limited thereto, and the base layer BS may be an inorganic layer, an organic layer, or a composite material layer.

In an embodiment, the circuit layer DP-CL may be disposed on the base layer BS, and the circuit layer DP-CL may include a plurality of transistors. The transistors may each include a control electrode, an input electrode, and an output electrode. For example, the circuit layer DP-CL may include a switching transistor and a driving transistor for driving the plurality of light emitting elements ED-1, ED-2 and ED-3 of the display element layer DP-ED.

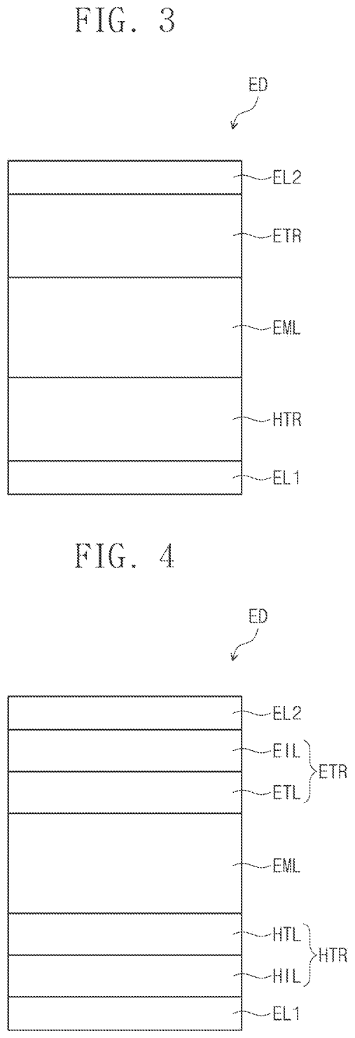

The light emitting elements ED-1, ED-2, and ED-3 may each have a structure of a light emitting element ED of an embodiment of FIGS. 3 to 6, which will be described in more detail. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment in which the emission layers EML-R, EML-G, and EML-B of the light emitting elements ED-1, ED-2, and ED-3 are disposed in openings OH defined in the pixel defining films PDL, and the hole transport region HTR, the electron transport region ETR, and the second electrode EL2 are provided as a common layer throughout the light emitting elements ED-1, ED-2, and ED-3. However, the embodiment of the present disclosure is not limited thereto, and in an embodiment, the hole transport region HTR and the electron transport region ETR may be provided to be patterned inside the openings OH defined in the pixel defining films PDL. For example, in an embodiment, the hole transport region HTR, the emission layers EML-R, EML-G, and EML-B, and the electron transport region ETR, etc. of the light emitting elements ED-1, ED-2, and ED-3 may be patterned and provided through an inkjet printing method.

The encapsulation layer TFE may cover the light emitting elements ED-1, ED-2 and ED-3. The encapsulation layer TFE may seal the display element layer DP-ED. The encapsulation layer TFE may be a thin film encapsulation layer. The encapsulation layer TFE may be a single layer or a laminated layer of a plurality of layers. The encapsulation layer may include at least one insulating layer. The encapsulation layer TFE according to an embodiment may include at least one inorganic film (hereinafter, an encapsulation inorganic film). In some embodiments, the encapsulation layer TFE may include at least one organic film (hereinafter, an encapsulation organic film) and at least one encapsulation inorganic film.

The encapsulation inorganic film may protect (or reduce) the display element layer DP-ED from moisture/oxygen, and the encapsulation organic film may protect (or reduce) the display element layer DP-ED from foreign substances such as dust particles. The encapsulation inorganic film may include silicon nitride, silicon oxy nitride, silicon oxide, titanium oxide, aluminum oxide, etc., but is not limited thereto. The encapsulation organic layer may include an acrylic compound, an epoxy-based compound, etc. The encapsulation organic layer may include a photopolymerizable organic material, and is not limited thereto.

The encapsulation layer TFE may be on the second electrode EL2, and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region emitting light generated from a corresponding one of the light emitting elements ED-1, ED-2, and ED-3. The light emitting regions PXA-R, PXA-G, and PXA-B may be spaced apart from (separated from) each other when viewed on a plane (e.g., in a plan view).

The light emitting regions PXA-R, PXA-G, and PXA-B may each be a region separated by the pixel defining films PDL. The non-light emitting regions NPXA may be regions between neighboring light emitting regions PXA-R, PXA-G, and PXA-B, and may correspond to the pixel defining films PDL. In the present disclosure, the light emitting regions PXA-R, PXA-G, and PXA-B may each correspond to a pixel. The pixel defining films PDL may separate the light emitting elements ED-1, ED-2 and ED-3. The emission layers EML-R, EML-G, and EML-B of the light emitting elements ED-1, ED-2 and ED-3 may be disposed and separated in the openings OH defined by the pixel defining films PDL.

The light emitting regions PXA-R, PXA-G, and PXA-B may be divided into a plurality of groups according to the color of light generated from the light emitting elements ED-1, ED-2, and ED-3. In the display device DD of an embodiment shown in FIGS. 1 and 2, three light emitting regions PXA-R, PXA-G, and PXA-B which emit red light, green light, and blue light, are illustrated as an example. For example, the display device DD of an embodiment may include a red light emitting region PXA-R, a green light emitting region PXA-G, and a blue light emitting region PXA-B, which are distinct from one another.

In the display device DD according to an embodiment, the plurality of light emitting elements ED-1, ED-2, and ED-3 may emit light having different wavelength ranges. For example, in an embodiment, the display device DD may include a first light emitting element ED-1 emitting red light, a second light emitting element ED-2 emitting green light, and a third light emitting element ED-3 emitting blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, the embodiment of the present disclosure is not limited thereto, and the first to third light emitting elements ED-1, ED-2 and ED-3 may emit light in substantially (e.g., may each emit) the same wavelength range or emit light in one or more different wavelength ranges. For example, the first to third light emitting elements ED-1, ED-2, and ED-3 may all emit blue light.

The light emitting regions PXA-R, PXA-G, and PXA-B in the display device DD according to an embodiment may be arranged in the form of a stripe. Referring to FIG. 1, a plurality of red light emitting regions PXA-R may be arranged with each other along a second direction axis DR2, a plurality of green light emitting regions PXA-G may be arranged with each other along the second direction axis DR2, and a plurality of blue light emitting regions PXA-B may each be arranged with each other along a second direction axis DR2. In some embodiments, the red light emitting region PXA-R, the green light emitting region PXA-G, and the blue light emitting region PXA-B may be alternately arranged in turn along a first direction axis DR1. (DR3 is a third direction which is normal or perpendicular to the plane defined by the first direction DR1 and the second direction DR2).

FIGS. 1 and 2 illustrate that the light emitting regions PXA-R, PXA-G, and PXA-B are all similar in size, but the embodiment of the present disclosure is not limited thereto, and the light emitting regions PXA-R, PXA-G and PXA-B may be different in size from each other according to wavelength range of emitted light. The areas of the light emitting regions PXA-R, PXA-G, and PXA-B may refer to areas when viewed on a plane defined by the first direction axis DR1 and the second direction axis DR2 (e.g., when viewed in a plan view).

The arrangement of the light emitting regions PXA-R, PXA-G, and PXA-B is not limited to what is shown in FIG. 1, and the order in which the red light emitting region PXA-R, the green light emitting region PXA-G, and the blue light emitting region PXA-B are arranged with one or more suitable combinations according to display quality characteristics required for the display device DD. For example, the arrangement form of the light emitting regions PXA-R, PXA-G, and PXA-B may be a PENTILE® configuration (for example, an RGBG matrix, an RGBG structure, or RGBG matrix structure) or a Diamond Pixel™ configuration (e.g., a display (e.g., an OLED display) containing red, blue, and green (RGB) light emitting regions arranged in the shape of diamonds. PENTILE® is a duly registered trademark of Samsung Display Co., Ltd. Diamond Pixel™ is a trademark of Samsung Display Co., Ltd.

In some embodiments, areas of each of the light emitting regions PXA-R, PXA-G, and PXA-B may be different in size from one another. For example, in an embodiment, the green light emitting region PXA-G may be smaller than the blue light emitting region PXA-B in size, but the embodiment of the present disclosure is not limited thereto.

Hereinafter, FIGS. 3 to 6 are cross-sectional views schematically showing a light emitting element according to an embodiment. The light emitting element ED according to an embodiment may include a first electrode EU, a hole transport region HTR, an emission layer EML, an electron transport region ETR, and a second electrode EL2.

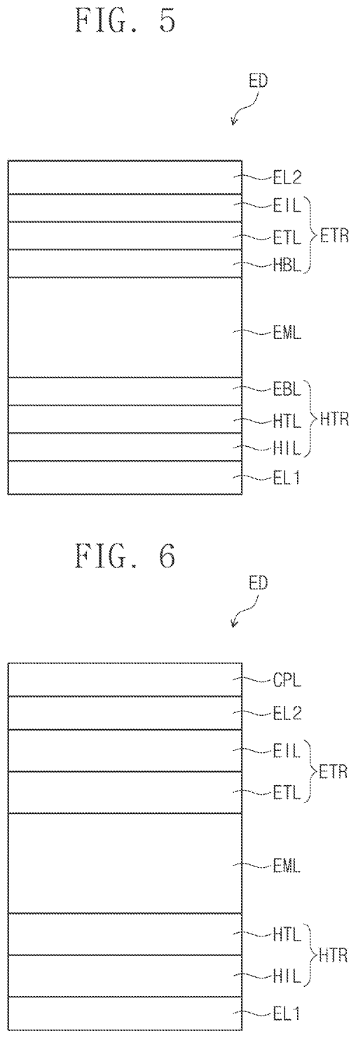

FIG. 4 shows, compared with FIG. 3, a cross-sectional view of a light emitting element ED of an embodiment in which the hole transport region HTR includes a hole injection layer HIL and a hole transport layer HTL, and the electron transport region ETR includes an electron injection layer EIL and an electron transport layer ETL. In some embodiments, FIG. 5 shows, compared with FIG. 3, a cross-sectional view of a light emitting element ED of an embodiment in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. FIG. 6 shows, compared with FIG. 4, a cross-sectional view of a light emitting element ED of an embodiment, in which a capping layer CPL on the second electrode EL2 is provided.

The light emitting element ED according to an embodiment may include a polycyclic compound according to an embodiment. For example, the emission layer EML may include a polycyclic compound according to an embodiment. The polycyclic compound according to an embodiment may include a fused ring of three rings, which contains B and N as ring-forming atoms, and at least one of a carbazole group, a pyridine group, a pyrimidine group or a triazine group is directly or indirectly bonded to the fused ring of three rings. The carbazole group, the pyridine group, the pyrimidine group, and the triazine group may be directly or indirectly bonded to N, which is a ring-forming atom, in the fused ring of three rings. The carbazole group, the pyridine group, the pyrimidine group, and the triazine group may each be substituted or unsubstituted.

In the present disclosure, the term “substituted or unsubstituted” may indicate that one is substituted or unsubstituted with at least one substituent selected from the group including (e.g., consisting of) a deuterium atom, a halogen atom, a cyano group, a nitro group, an amine group, a silyl group, oxy group, thio group, sulfinyl group, sulfonyl group, carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified above may be substituted or unsubstituted. For example, a biphenyl group may be interpreted as an aryl group or as a phenyl group substituted with a phenyl group.

In the present disclosure, the term “linked to an adjacent group to form a ring” may indicate that one is linked to an adjacent group to form a substituted or unsubstituted hydrocarbon ring, or a substituted or unsubstituted heterocycle. The hydrocarbon ring includes an aliphatic hydrocarbon ring and/or an aromatic hydrocarbon ring. The heterocycle includes an aliphatic heterocycle and/or an aromatic heterocycle. The hydrocarbon ring and the heterocycle may be monocyclic or polycyclic. In some embodiments, the rings formed by being linked to each other may be connected to another ring to form a spiro structure.

In the present disclosure, the term “an adjacent group” may refer to a substituent substituted for an atom which is directly connected to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as mutually “adjacent groups” and two ethyl groups in 1,1-diethylcyclopentane may be interpreted as mutually “adjacent groups”.

In some embodiments, two methyl groups in 4,5-dimethylphenanthrene may be interpreted as mutually “adjacent groups”.

In the present disclosure, examples of a halogen atom may include a fluorine atom, a chlorine atom, a bromine atom, and/or an iodine atom.

In the present disclosure, an alkyl group may be a linear, branched or cyclic type or kind. The number of carbon atoms in the alkyl group may be 1 to 60, 1 to 50, 1 to 30, 1 to 20, 1 to 10 or 1 to 6. Examples of the alkyl group may include a methyl group, an ethyl group, an n-propyl group, an isopropyl group, an n-butyl group, a s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but are not limited thereto.

In the present disclosure, an alkenyl group refers to a hydrocarbon group including at least one carbon double bond in the middle or end of an alkyl group having 2 or more carbon atoms. The alkenyl group may be linear, branched or cyclic. The cyclic alkenyl group may include a cycloalkenyl group. The number of carbon atoms is not limited, but may be 2 to 60, 2 to 30, 2 to 20 or 2 to 10. Examples of the alkenyl group include a vinyl group, a 1-butenyl group, a 1-pentenyl group, a 1,3-butadienyl aryl group, a styrenyl group, a styryl vinyl group, etc., but are not limited thereto.

In the present disclosure, a hydrocarbon ring group refers to any functional group or substituent derived from an aliphatic hydrocarbon ring. The hydrocarbon ring group may be a monocyclic hydrocarbon ring group or a polycyclic hydrocarbon ring group. The hydrocarbon ring group may be a saturated hydrocarbon ring group. The number of ring-forming carbon atoms in the hydrocarbon ring group may be 5 to 60, 6 to 60, 5 to 30, 5 to 20, or 5 to 10.

In the present disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but are not limited thereto.

In the present disclosure, a heterocyclic group refers to any functional groups or substituents derived from a ring containing at least one of B, O, N, P, Si, or S as a hetero atom. When the heterocyclic group contains two or more hetero atoms, the two or more hetero atoms may be the same as or different from each other. The number of ring-forming carbon atoms in the heterocyclic group may be 2 to 60, 2 to 30, 2 to 20, or 2 to 10. The heterocyclic group may include an aliphatic heterocyclic group and/or an aromatic heterocyclic group. The aliphatic heterocyclic group may contain a single bond and/or multiple bonds (e.g., double bonds and/or triple bonds). The aliphatic heterocyclic group and the aromatic heterocyclic group may be monocyclic or polycyclic. Examples of the aliphatic heterocyclic group include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but are not limited to thereto. The aromatic heterocyclic group may be a heteroaryl group.

In the present disclosure, a heteroaryl group may include at least one of B, O, N, P, Si, or S as a hetero atom. When the heteroaryl group contains two or more hetero atoms, the two or more hetero atoms may be the same as or different from each other. The heteroaryl group may be a monocyclic heteroaryl group or a polycyclic heteroaryl group. The number of ring-forming carbon atoms in the heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but are not limited thereto.

In the present disclosure, a silyl group includes an alkyl silyl group and/or an aryl silyl group. The alkyl group in the alkyl silyl group is the same as the examples of the alkyl group described above, and the aryl group in the aryl silyl group is the same as the examples of the aryl group described above. Examples of the silyl group include a trimethylsilyl group, a triethylsilyl group, a t-butyldimethylsilyl group, an ethyldimethylsilyl group, a propyldimethylsilyl group, a triphenylsilyl group, a diphenylsilyl group, a phenylsilyl group, etc., but are not limited thereto.

In the present disclosure, a thio group may include an alkyl thio group and/or an aryl thio group. The thio group may refer to a sulfur atom that is bonded to an alkyl group or an aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but are not limited to thereto.

In the present disclosure, an oxy group may indicate refer to an oxygen atom that is bonded to an alkyl group or aryl group as defined above. The oxy group may include an alkoxy group and an aryl oxy group. The alkoxy group may be linear, branched or cyclic. The number of carbon atoms in the alkoxy group is not limited, but may be, for example, 1 to 20, or 1 to 10. Examples of the oxy group include methoxy, ethoxy, n-propoxy, isopropoxy, butoxy, pentyloxy, hexyloxy, octyloxy, nonyloxy, decyloxy, benzyloxy, etc., but are not limited thereto.

In the present disclosure, the number of carbon atoms in an amine group is not, but may be 1 to 30. The amine group may include an alkyl amine group and/or an aryl amine group. Examples of the amine group include a methylamine group, a dimethylamine group, a phenylamine group, a diphenylamine group, a naphthylamine group, a 9-methyl-anthracenylamine group, a triphenylamine group, etc., but are not limited thereto.

In the present disclosure, the above description of the aryl group may be applied to an arylene group, except that the arylene group is a divalent group. The above description of the heteroaryl group may be applied to a heteroarylene group, except that the heteroarylene group is a divalent group.

In the present disclosure, a direct linkage may refer to a single bond. In the present disclosure,

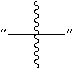

and “—*” refer to positions to be linked.

A polycyclic compound according to an embodiment may be represented by Formula 1. A light emitting element ED according to an embodiment may include the polycyclic compound represented by Formula 1.

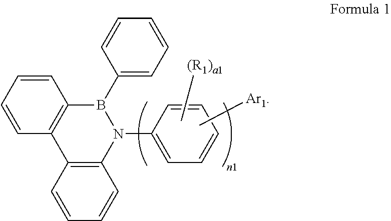

In Formula 1, n1 may be an integer from 0 to 3. When n1 is 0, Ar₁ may be directly bonded to N, which is a ring-forming atom of a fused ring of three rings. When n1 is an integer from 1 to 3, Ar₁ may be indirectly bonded to N through a phenyl group including R₁. When n1 is 2 or 3, a plurality of phenyl groups including R₁ are provided, and the plurality of phenyl groups may be the same as or different from each other. When n1 is 2 or 3, the phenyl groups including R₁ may each independently be substituted or unsubstituted. When n1 is 2, Ar₁ may be bonded to a substituted or unsubstituted biphenyl group. When n1 is 3, Ar₁ may be bonded to a substituted or unsubstituted terphenyl group.

Ar₁ may be a substituted or unsubstituted carbazole group, a substituted or unsubstituted pyridine group, a substituted or unsubstituted pyrimidine group, or a substituted or unsubstituted triazine group. For example, when Ar₁ is a substituted or unsubstituted carbazole group and N, which is a ring-forming atom of the carbazole group, is a bonding position, n1 may be an integer from 1 to 3.

When n1 is 1 and Ar₁ is an unsubstituted carbazole group, Ar₁ may be bonded in meta position with respect to N. When n1 is 1 and Ar₁ is an unsubstituted carbazole group, Ar₁ may not be bonded in para position with respect to N. In Formula Z1, Cₘ indicates the meta position with respect to N and Cₚ indicates the para position with respect to N.

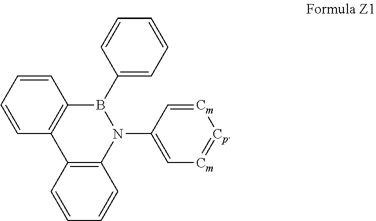

In Formula 1, a1 may be an integer from 0 to 4. When a1 is an integer of 2 or greater, a plurality of R₁s may all be the same or at least one may be different from the others.

R₁ may be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted hydrocarbon ring group having 6 to 60 ring-forming carbon atoms, a substituted or unsubstituted aryl group having 6 to 60 ring-forming carbon atoms, or a substituted or unsubstituted heterocyclic group having 2 to 60 ring-forming carbon atoms. For example, R₁ may be a hydrogen atom, a deuterium atom, a substituted methyl group, a substituted silyl group, a substituted or unsubstituted phenyl group, an unsubstituted dibenzofuran group, or a substituted or unsubstituted carbazole group.

R₁ may be a hydrogen atom, a deuterium atom, or one represented by any one selected from among R1-1 to R1-5. R1-1 indicates a methyl group substituted with a phenyl group, and for example indicates a triphenylmethyl group. R1-2 indicates a silyl group substituted with a phenyl group, and for example indicates a triphenylsilyl group. R1-3 indicates a substituted or unsubstituted phenyl group, and R1-4 indicates an unsubstituted dibenzofuran group. R1-5 indicates a substituted or unsubstituted carbazole group, and indicates a position where N, which is a ring-forming atom of the carbazole group, is bonded.

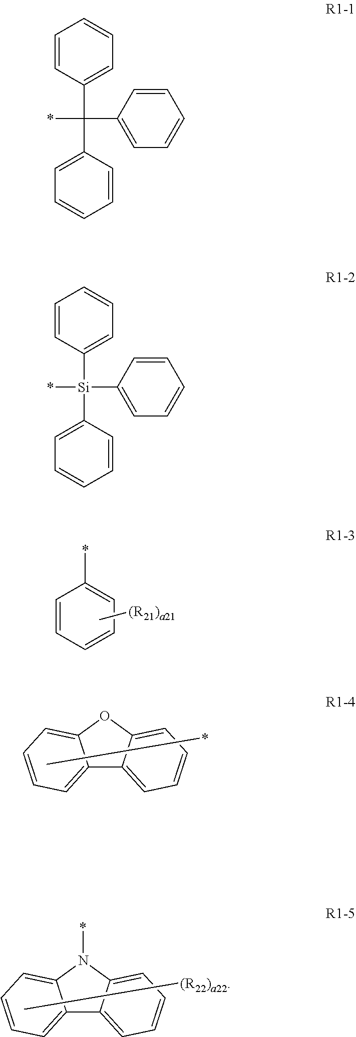

In R1-3, a21 may be an integer from 0 to 5. When a21 is an integer of 2 or greater, a plurality of R₂₁s may all be the same or at least one may be different from the others. R₂₁ may be a hydrogen atom, a deuterium atom, a substituted or unsubstituted silyl group, or a substituted or unsubstituted carbazole group.

In R1-5, a22 may be an integer from 0 to 8. When a22 is an integer of 2 or greater, a plurality of R₂₂s may all be the same or at least one may be different from the others. R₂₂ may be a hydrogen atom, a deuterium atom, or a substituted or unsubstituted carbazole group.

For example, R1-3 may be represented by any one selected among R1-31 to R1-33. R1-31 indicates an unsubstituted phenyl group, R1-32 indicates a phenyl group substituted with a carbazole group, and R1-33 indicates a phenyl group substituted with a silyl group.

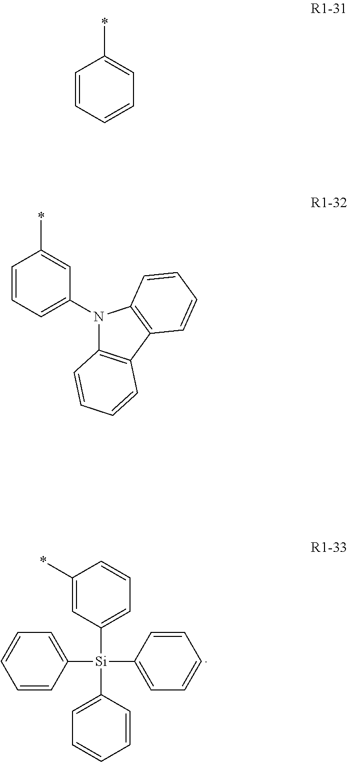 [SMILES: *c1ccccc1 ; *c1cccc(-n2c3ccccc3c3ccccc32)c1 ; *c1cccc([Si](c2ccccc2)(c2ccccc2)c2ccccc2)c1]

A polycyclic compound according to an embodiment may include at least one deuterium atom or a substituent substituted with a deuterium atom. For example, at least one of R₁ or Ar₁ may include a deuterium atom or a substituent containing a deuterium atom. For example, a1 may be an integer of 2 or greater, and a plurality of R₁s may be deuterium atoms. Ar₁ may be a substituted carbazole group, and at least one hydrogen atom selected from among hydrogen atoms bonded to a ring-forming carbon atom of the carbazole group may be substituted with a deuterium atom. In some embodiments, Ar₁ may be a substituted carbazole group, and a substituent other than a hydrogen atom bonded to the carbazole group may be substituted with a deuterium atom. However, this is merely an example, and the embodiment of the present disclosure is not limited thereto.

The polycyclic compound according to an embodiment may include at least one of a triphenylmethyl group or a triphenylsilyl group. For example, in Formula 1, R₁ may be a triphenylmethyl group or a triphenylsilyl group. In some embodiments, R₁ in Formula 1 may include a substituent substituted with at least one of a triphenylmethyl group or a triphenylsilyl group. In Formula 1, Ar₁ may include at least one of a triphenylmethyl group or a triphenylsilyl group as a substituent, or a substituent substituted with at least one of a triphenylmethyl group or a triphenylsilyl group. However, this is merely an example, and the embodiment of the present disclosure is not limited thereto.

According to an embodiment, in Formula 1, Ar₁ may be represented by Formula 2-1 or Formula 2-2. Formula 2-1 indicates a substituted or unsubstituted carbazole group.

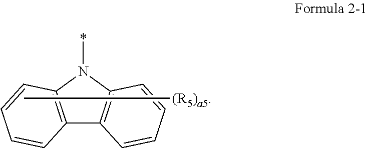

In Formula 2-1, a5 may be an integer from 0 to 8. When a5 is an integer of 2 or greater, a plurality of R₅s may all be the same or at least one may be different from the others.

R₅ may be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms. For example, R₅ may be a substituted methyl group, a substituted silyl group, a substituted or unsubstituted phenyl group, a substituted or unsubstituted carbazole group, a substituted or unsubstituted dibenzofuran group, or a substituted or unsubstituted dibenzothiophene group. However, this is merely an example, and the embodiment of the present disclosure is not limited thereto.

When Ar₁ is represented by Formula 2-1, n1 in Formula 1 may be an integer from 1 to 3. For example, Ar₁ may be a substituted or unsubstituted carbazole group, and N, which is a ring-forming atom of the carbazole group, may be indirectly bonded to N, which is a ring-forming atom of a fused ring of three rings through at least one phenyl group.

In Formula 1, when n1 is 1, Ar₁ is represented by Formula 2-1, and a5 is 0 in Formula 2-1, Formula 2-1 may be bonded in meta position with respect to N of Formula 1. In Formula 1, when n1 is 1, Ar₁ is represented by Formula 2-1, and a5 is 0 in Formula 2-1, Formula 2-1 is not bonded in para position with respect to N of Formula 1.

In Formula 1, when n1 is 1, Ar₁ is represented by Formula 2-1, and R₅ is a hydrogen atom in Formula 2-1, Formula 2-1 may be bonded in meta position with respect to N of Formula 1. In Formula 1, when n1 is 1, Ar₁ is represented by Formula 2-1, and R₅ is a hydrogen atom in Formula 2-1, Formula 2-1 is not bonded in para position with respect to N of Formula 1.

Formula 2-2 indicates a hexagonal ring including N as a ring-forming atom. For example, Formula 2-2 indicates a substituted or unsubstituted pyridine group, a substituted or unsubstituted pyrimidine group, and/or a substituted or unsubstituted triazine group.

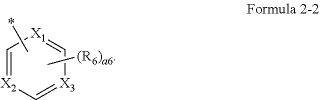

In Formula 2-2, a6 may be an integer from 0 to 2. When a6 is 2, two R₆s may be the same as or different from each other.

At least one of X₁ to X₃ may be N, and each of the reminder of X₁ to X₃ may independently be CR₇. When any one selected from among X₁ to X₃ is N, Formula 2-2 may be a substituted or unsubstituted pyridine group. When any two of X₁ to X₃ are N, Formula 2-2 may be a substituted or unsubstituted pyrimidine group. When all of X₁ to X₃ are N, Formula 2-2 may be a substituted or unsubstituted triazine group.

In Formula 2-2, R₆ and R₇ may each independently be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms. For example, R₇ may be a hydrogen atom.

When Ar₁ is represented by Formula 2-2, n1 in Formula 1 may be an integer from 0 to 3. For example, when Ar₁ is a substituted or unsubstituted pyridine group, a substituted or unsubstituted pyrimidine group, or a substituted or unsubstituted triazine group, Ar₁ may be directly bonded to N, which is a ring-forming atom of a fused ring of three rings, or indirectly bonded through a phenyl group.

In Formulas 2-1 and 2-2, R₅ and R₆ may each independently be represented by any one selected from among RN-1 to RN-5. RN-1 to RN-5 indicate each substituent of a substituted carbazole group, a substituted pyridine group, a substituted pyrimidine group, and/or a substituted triazine group.

RN-1 indicates a substituted or unsubstituted phenyl group. RN-2 indicates a substituted or unsubstituted heteroaryl group, and the heteroaryl group may have 12 or 13 ring-forming carbon atoms. RN-3 indicates a substituted or unsubstituted carbazole group. RN-4 indicates a substituted phenyl group, and the substituent of the phenyl group is a substituted or unsubstituted triphenylmethyl group or a substituted or unsubstituted triphenylsilyl group. RN-5 indicates a substituted or unsubstituted triphenylmethyl group or a substituted or unsubstituted triphenylsilyl group.

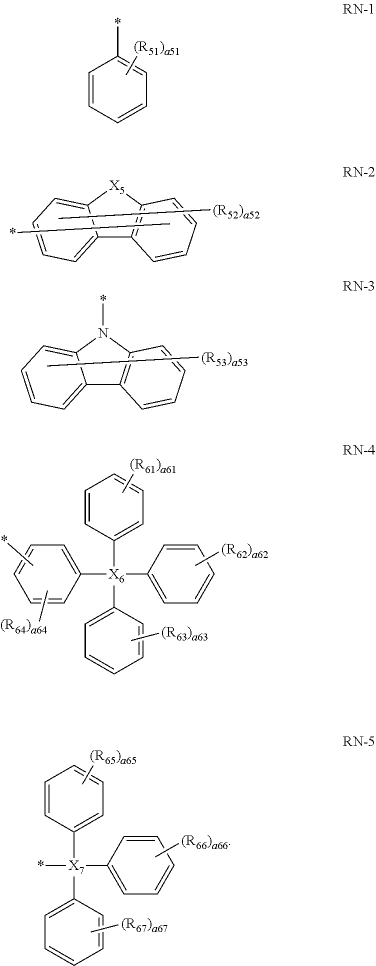

In RN-2, a52 may be an integer from 0 to 7. When a52 is an integer of 2 or greater, a plurality of R₅₂s may all be the same or at least one may be different from the others.

In RN-2, X₅ may be CR₅₄R₅₅, SiR₅₆R₅₇, NR₅₈, O, or S. When X₅ is CR₅₄R₅₅, RN-2 may be a substituted or unsubstituted fluorenyl group. When X₅ is SiR₅₆R₅₇, RN-2 may be a substituted or unsubstituted dibenzosilole group. When X₅ is NR₅₈, RN-2 may be a substituted or unsubstituted carbazole group. When X₅ is O, RN-2 may be a substituted or unsubstituted dibenzofuran group. When X₅ is S, RN-2 may be a substituted or unsubstituted dibenzothiophene group.

In RN-3, a53 may be an integer from 0 to 8. When a53 is an integer of 2 or greater, a plurality of R₅₃s may all be the same or at least one may be different from the others.

In RN-4, a64 may be an integer from 0 to 4. When a64 is an integer of 2 or greater, a plurality of R₆₄s may all be the same or at least one may be different from the others. X₆ may be C or Si. When X₆ is C, RN-4 may be a phenyl group substituted with a triphenylmethyl group, and the triphenylmethyl group may be substituted or unsubstituted. When X₆ is Si, RN-4 may be a phenyl group substituted with a triphenylsilyl group, and the triphenylsilyl group may be substituted or unsubstituted.

In RN-5, X₇ may be C or Si. When X₇ is C, RN-5 may be a substituted or unsubstituted triphenylmethyl group. When X₇ is Si, RN-5 may be a substituted or unsubstituted triphenylsilyl group.

In RN-1 to RN-5, a51, a61 to a63, and a65 to a67 may each independently be an integer from 0 to 5. When a51 is an integer of 2 or greater, a plurality of R₅₁s may all be the same or at least one may be different from the others. When a61 is an integer of 2 or greater, a plurality of R₆₁s may all be the same or at least one may be different from the others. When a62 is an integer of 2 or greater, a plurality of R₆₂s may all be the same or at least one may be different from the others. When a63 is an integer of 2 or greater, a plurality of R₆₃s may all be the same or at least one may be different from the others. When a65 is an integer of 2 or greater, a plurality of R₆₅s may all be the same or at least one may be different from the others. When a66 is an integer of 2 or greater, a plurality of R₆₆s may all be the same or at least one may be different from the others. When a67 is an integer of 2 or greater, a plurality of R₆₇s may all be the same or at least one may be different from the others.

In RN-1 to RN-5, R₅₁ to R₅₈ and R₆₁ to R₆₇ may each independently be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms.

For example, RN-1 may be represented by any one selected from among RN-11 to RN-18. RN-11 indicates an unsubstituted phenyl group, and RN-12 to RN-18 indicate a phenyl group substituted with a carbazole group, a dibenzofuran group, a cyano group, a phenyl group, a deuterium atom, and/or the like.

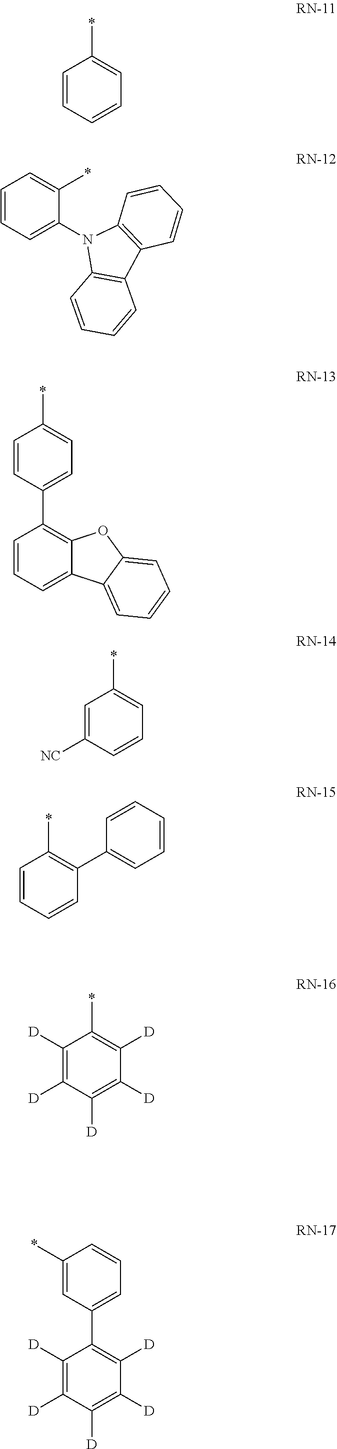

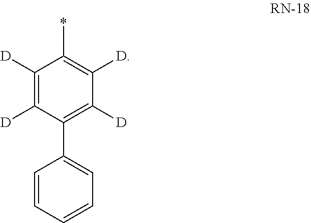

For example, RN-2 may be represented by any one selected from among RN-21 to RN-24. RN-21 and RN-22 indicate a substituted carbazole group, and RN-23 indicates an unsubstituted dibenzofuran group. RN-24 indicates an unsubstituted dibenzothiophene group.

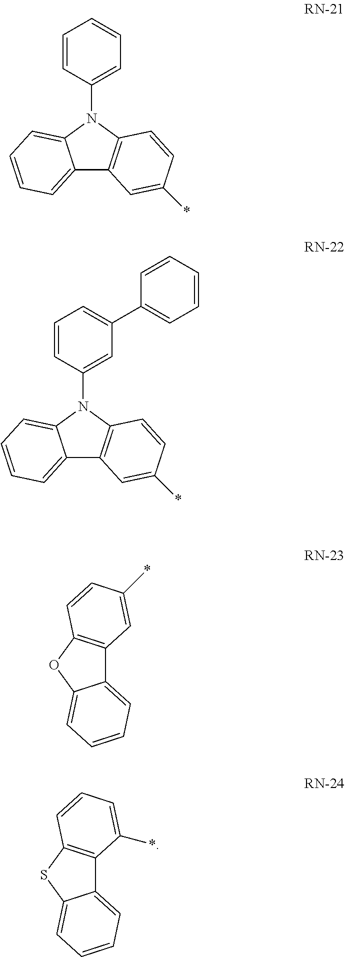

For example, RN-3 may be represented by any one selected from among RN-31 to RN-39. RN-31 indicates an unsubstituted carbazole group. RN-32 to RN-39 indicate a carbazole group substituted with a phenyl group, a cyano group, a deuterium atom, a triphenylsilyl group, and/or the like.

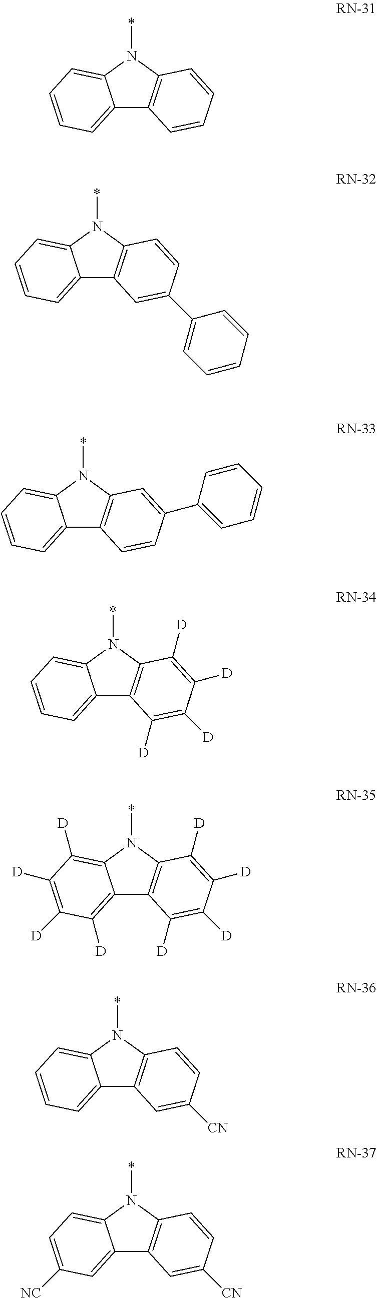

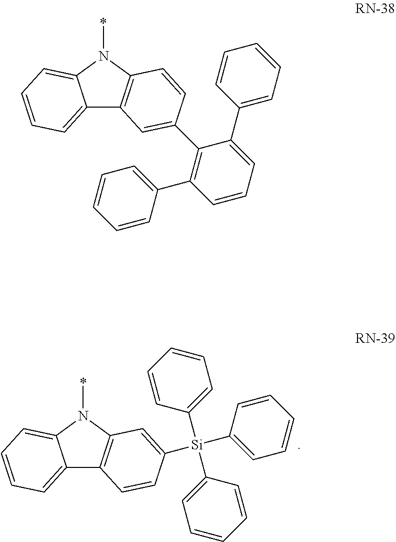 [SMILES: *n1c2ccccc2c2cc(-c3c(-c4ccccc4)cccc3-c3ccccc3)ccc21 ; *n1c2ccccc2c2ccc([Si](c3ccccc3)(c3ccccc3)c3ccccc3)cc21]

For example, RN-4 may be represented by any one selected from among RN-41 to RN-48. RN-41 shows an embodiment in which four phenyl groups are unsubstituted phenyl groups. RN-42 to RN-48 indicate a phenyl group substituted with at least one phenyl group among four phenyl groups, and the substituent of the substituted phenyl group indicates a deuterium atom, a silyl group, a phenyl group, and/or the like.

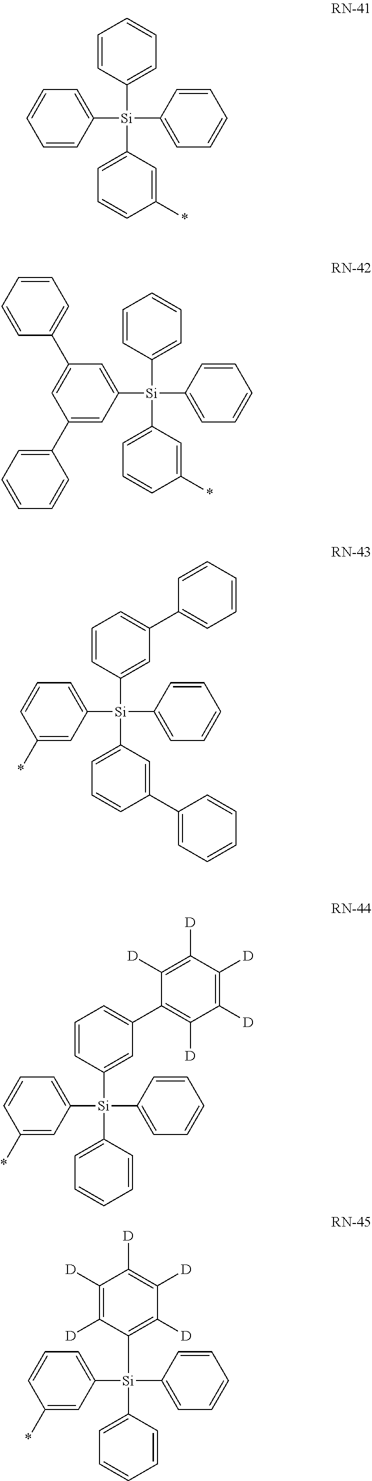

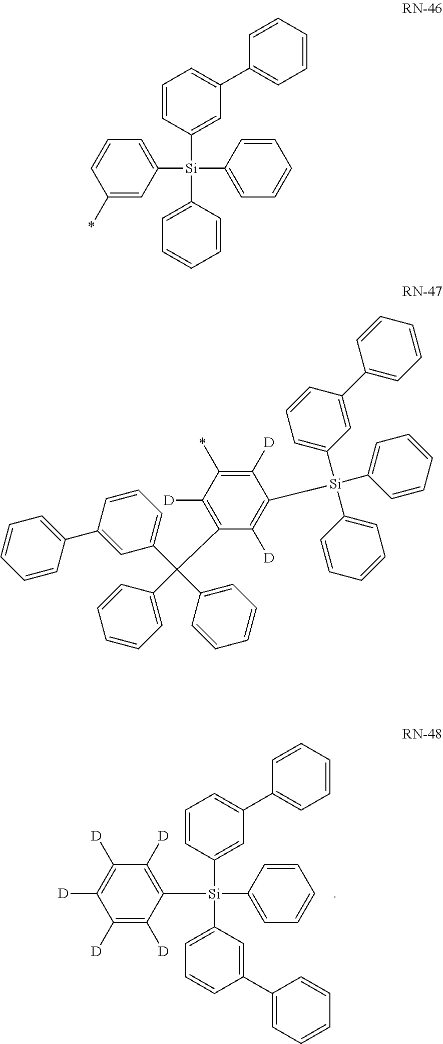 [SMILES: *c1cccc([Si](c2ccccc2)(c2ccccc2)c2cccc(-c3ccccc3)c2)c1 ; *c1c([2H])c(C(c2ccccc2)(c2ccccc2)c2cccc(-c3ccccc3)c2)c([2H])c([Si](c2ccccc2)(c2ccccc2)c2cccc(-c3ccccc3)c2)c1[2H] ; [2H]c1c([2H])c([2H])c([Si](c2ccccc2)(c2cccc(-c3ccccc3)c2)c2cccc(-c3ccccc3)c2)c([2H])c1[2H]]

For example, RN-5 may be represented by any one selected from among RN-51 to RN-53. RN-51 and RN-53 indicate a substituted or unsubstituted triphenylsilyl group, and RN-52 indicates an unsubstituted triphenylmethyl group.

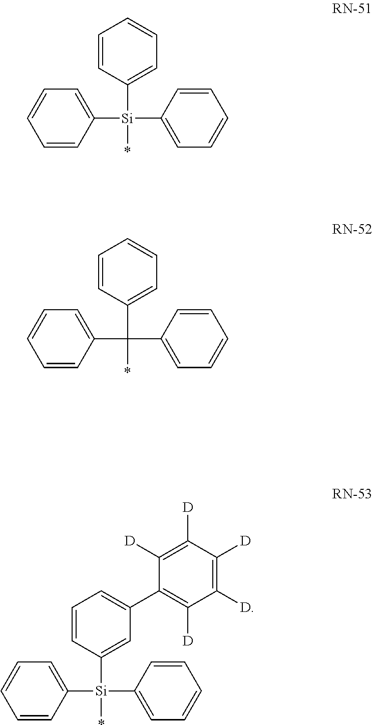

In an embodiment, Formula 1 may be represented by any one selected from among Formulas 1-1 to 1-5. Formulas 1-1 and 1-2 show an embodiment in which Ar₁ of Formula 1 is represented by Formula 2-1. In some embodiments, Formula 1-1 shows an embodiment in which n1 of Formula 1 is 1, and Formula 1-2 shows an embodiment in which n1 of Formula 1 is 2.

Formulas 1-3 to 1-5 show an embodiment in which Ar₁ of Formula 1 is represented by Formula 2-2. In some embodiments, Formula 1-3 shows an embodiment in which n1 of Formula 1 is 0, Formula 1-4 shows an embodiment in which n1 of Formula 1 is 1, and Formula 1-5 shows an embodiment in which n1 of Formula 1 is 2.

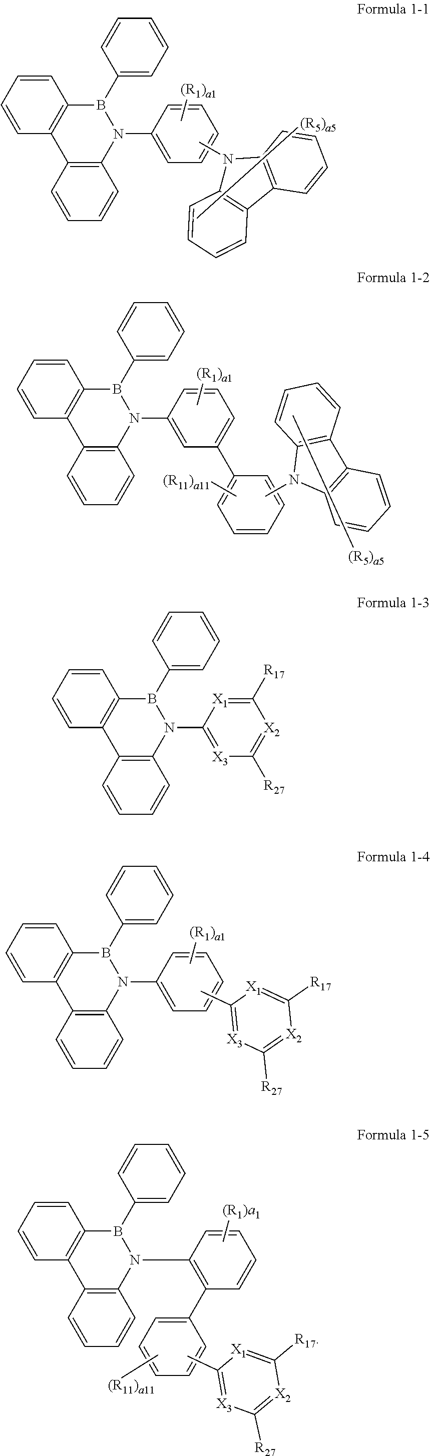

In Formulas 1-1 to 1-5, the same descriptions as in Formula 1 may be applied to a1 and R₁. In Formulas 1-1 and 1-2, a5 may be an integer from 0 to 8. R₅ may be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms. In Formulas 1-1 to 1-2, the same descriptions as in Formula 2-1 may be applied to a5 and R₅.

In Formula 1-1, when a5 is 0 or R₅ is a hydrogen atom, a carbazole group including a5 and R₅ may be bonded in meta position with respect to N. In Formula 1-1, when a5 is 0 or R₅ is a hydrogen atom, a carbazole group including a5 and R₅ may not be bonded in para position with respect to N. For example, when the carbazole group including a5 and R₅ in Formula 1-1 is an unsubstituted carbazole group, the carbazole group may be bonded in meta position with respect to N, but not be bonded in para position with respect to N.

In Formulas 1-2 and 1-5, a11 may be an integer from 0 to 4. When a11 is an integer of 2 or greater, a plurality of R₁₁s may all be the same or at least one may be different from the others. R₁₁ may be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted hydrocarbon ring group having 6 to 60 ring-forming carbon atoms, a substituted or unsubstituted aryl group having 6 to 60 ring-forming carbon atoms, or a substituted or unsubstituted heterocyclic group having 2 to 60 ring-forming carbon atoms.

In Formulas 1-3 to 1-5, at least one selected from among X₁ to X₃ may be N, and each of the remainder of X₁ to X₃ may be independently CR₇. R₇, R₁₇, and R₂₇ may each independently be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms; and in Formulas 1-3 to 1-5, the same descriptions as in Formula 2-2 may be applied to X₁ to X₃. In some embodiments, in Formulas 1-3 to 1-5, R₁₇ and R₂₇ correspond to R₆ of Formula 2-2, and the same descriptions as for R₆ of Formula 2-2 may be applied to R₁₇ and R₂₇.

In an embodiment, Formula 1 may be represented by any one selected from among Formulas 1-A1 to 1-A4. Formulas 1-A1 to 1-A4 show embodiments in which Ar₁ of Formula 1 is represented by Formula 2-1.

Formulas 1-A1 and 1-A2 show embodiments in which n1 of Formula 1 is 1, and Formulas 1-A1 and 1-A2 have different bonding positions of Formula 2-1 in regard to Formula 1. Formulas 1-A3 and 1-A4 show embodiments in which n1 of Formula 1 is 2, and Formulas 1-A3 and 1-A4 have different bonding positions of Formula 2-1 in regard to Formula 1.

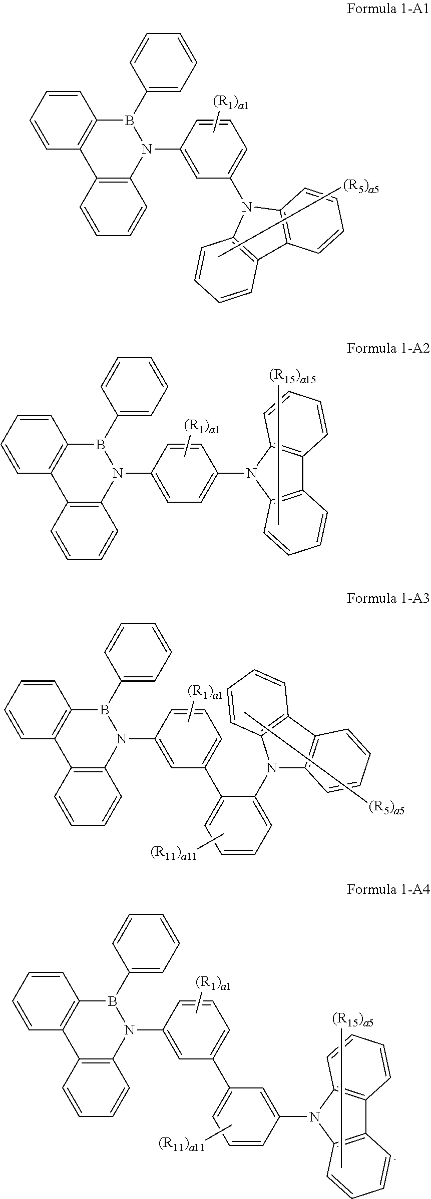

In Formulas 1-A1 to 1 A4, the same descriptions as in Formula 1 may be applied to a1 and R₁.

In Formula 1-A2, a15 may be an integer from 1 to 8. R₁₅ may be a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms. In Formula 1-A2, a carbazole group including a15 and R₁₅ may be a substituted carbazole group. For example, in Formula 1-A2, a15 may be 1, and R₁₅ may be represented by RN-31.

In Formulas 1-A3 and 1-A4, a11 may be an integer from 0 to 4. When a11 is an integer of 2 or greater, a plurality of R₁₁s may all be the same or at least one may be different from the others. R₁₁ may be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted hydrocarbon ring group having 6 to 60 ring-forming carbon atoms, a substituted or unsubstituted aryl group having 6 to 60 ring-forming carbon atoms, or a substituted or unsubstituted heterocyclic group having 2 to 60 ring-forming carbon atoms. For example, R₁₁ may be a hydrogen atom, a deuterium atom, or a substituted or unsubstituted phenyl group.

In Formulas 1-A1, 1-A3, and 1-A4, a5 may be an integer from 0 to 8. R₅ may be a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms. In Formulas 1-A1, 1-A3, and 1-A4, the same descriptions as in Formula 2-1 may be applied to a5 and R₅.

For example, in Formula 1-A3, a5 may be 1, and R₅ may be represented by RN-31 or RN-51. In Formula 1-A4, a5 may be 1 or 2, and R₅ may be represented by RN-11, RN-31, or RN-35. However, this is merely an example, and the embodiment of the present disclosure is not limited thereto.

In an embodiment, Formula 1 may be represented by any one selected from among Formulas 1-B1 to 1-B5. Formulas 1-B1 to 1-B5 show embodiments in which n1 of Formula 1 is 0, Ar₁ is represented by Formula 2-2. Formulas 1-B1 and 1-B2 show embodiments in which Ar₁ is represented by a pyridine group, and Formulas 1-B1 and 1-B2 have different positions of N, which is a ring-forming atom of the pyridine group.

Formulas 1-B3 and 1-B4 show embodiments in which Ar₁ is represented by a pyrimidine group, and Formulas 1-B3 and 1-B4 have different positions of N, which is a ring-forming atom of the pyrimidine group. Formula 1-B5 shows a case in which Ar₁ is represented by a triazine group.

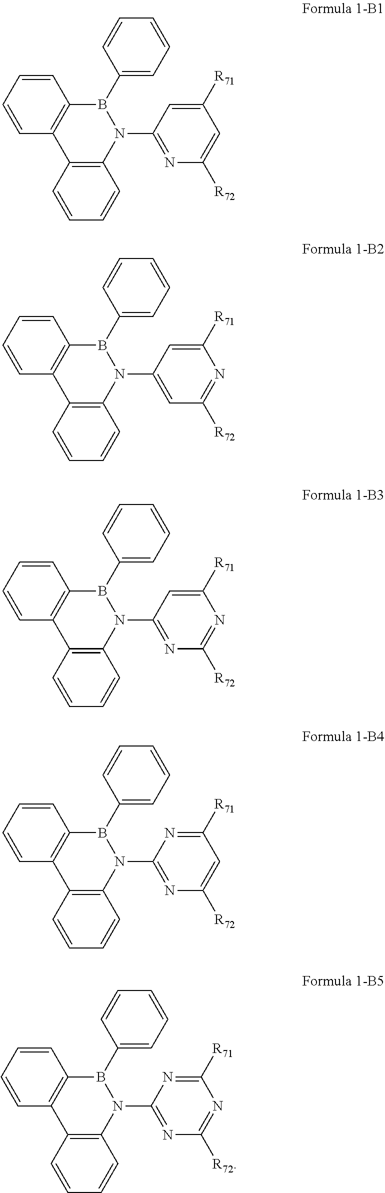

In Formulas 1-B1 to 1-B5, R₇₁ and R₇₂ may each independently be a substituted or unsubstituted aryl group having 6 to 60 ring-forming carbon atoms, or a substituted or unsubstituted heteroaryl group having 2 to 60 ring-forming carbon atoms. For example, R₇₁ and R₇₂ may each independently be represented by any one selected from among RN-1 to RN-4.

In an embodiment, Formula 1 may be represented by any one selected from among Formulas 1-C1 to 1-C6. Formulas 1-C1 to 1-C6 show embodiments in which Ar₁ of Formula 1 is represented by Formula 2-2.

Formulas 1-C1 to 1-C4 show embodiments in which n1 of Formula 1 is 1. Formula 1-C1 shows an embodiment in which Ar₁ of Formula 1 is a pyridine group, Formulas 1-C2 and 1-C3 shows embodiments in which Ar₁ of Formula 1 is a pyrimidine group, and Formula 1-C4 shows an embodiment in which Ar₁ of Formula 1 is a triazine group. In Formulas 1-C2 and 1-C3, the positions of N, which is a ring-forming atom of the pyridine group, are different.

Formulas 1-05 and 1-C6 show embodiments in which n1 of Formula 1 is 2. Formula 1-C5 shows an embodiment in which Ar₁ of Formula 1 is a pyrimidine group, and Formula 1-C6 shows an embodiment in which Ar₁ of Formula 1 is a pyrimidine group or a triazine group.

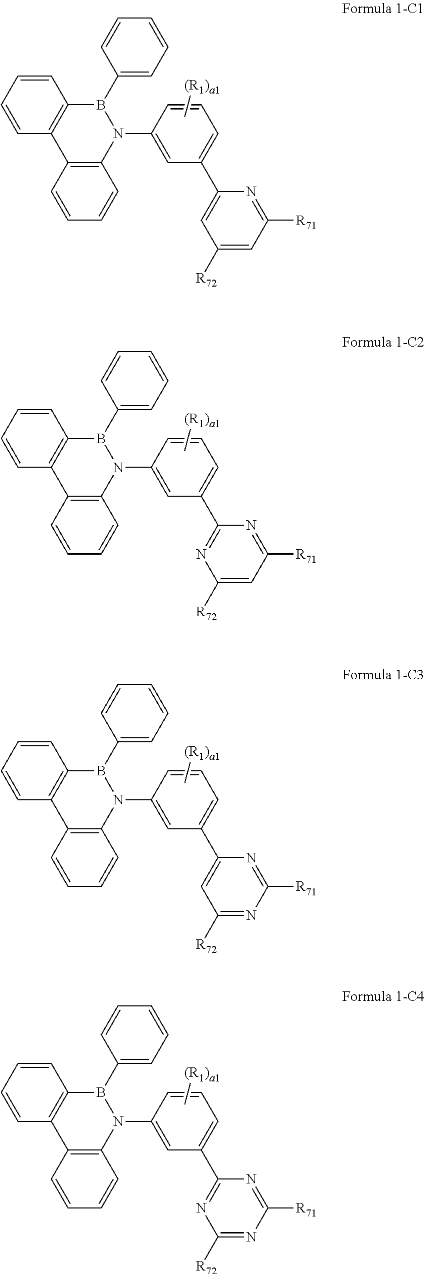

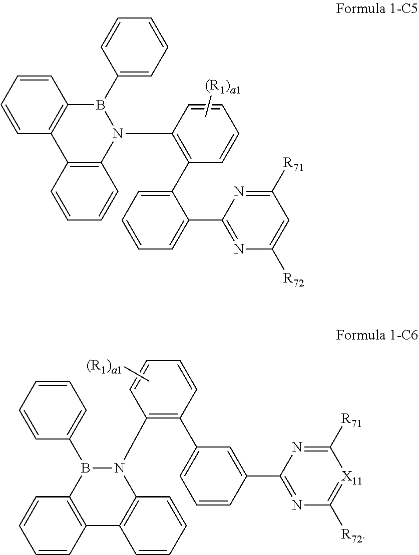

In Formula 1-C6, X₁₁ may be CH or N. In Formula 1-C6, when X₁₁ is CH, a cyclic group including X₁₁ as a ring-forming atom may be a pyrimidine group. In Formula 1-C6, when X₁₁ is N, a cyclic group including X₁₁ as a ring-forming atom may be a triazine group.

In Formulas 1-C1 to 1-C6, the same descriptions as in Formula 1 may be applied to a1 and R₁. In Formulas 1-C1 to 1-C6, R₇₁ and R₇₂ may each independently be a substituted or unsubstituted aryl group having 6 to 60 ring-forming carbon atoms, or a substituted or unsubstituted heteroaryl group having 2 to 60 ring-forming carbon atoms. For example, R₇₁ and R₇₂ may each independently be represented by any one selected from among RN-1 to RN-4

Formula 1 may be represented by any one selected from among Formulas 1-D1 to 1-D5.

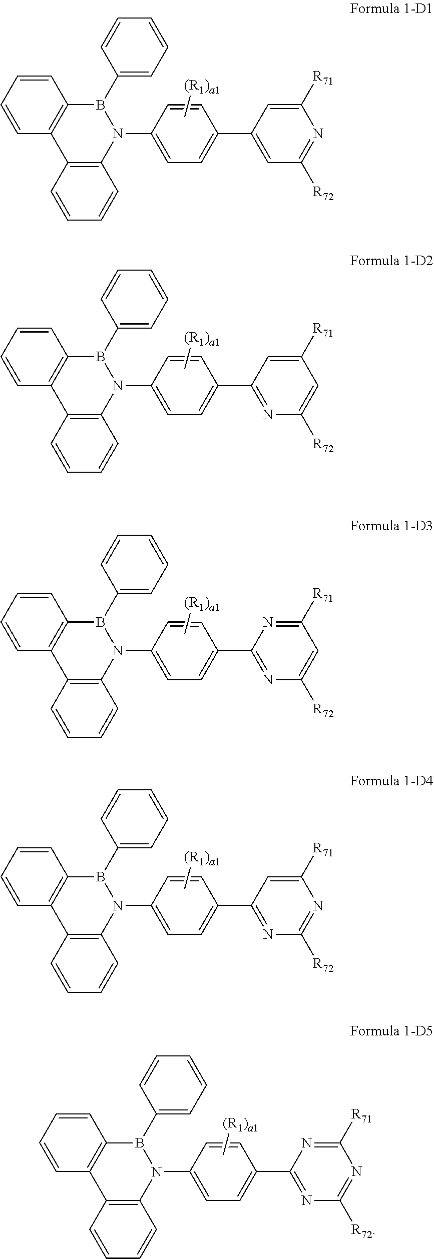

In Formulas 1-D1 to 1-D5, the same descriptions as in Formula 1 may be applied to a1 and R₁. The same descriptions as in Formulas 1-C1 to 1-C6 may be applied to R₇₁ and R₇₂.

A polycyclic compound according to an embodiment may be represented by any one selected from among compounds of Compound Group 1. A light emitting element ED according to an embodiment may include at least one of (e.g., selected from among) the compounds of Compound Group 1. In Compound Group 1, D is a deuterium atom.

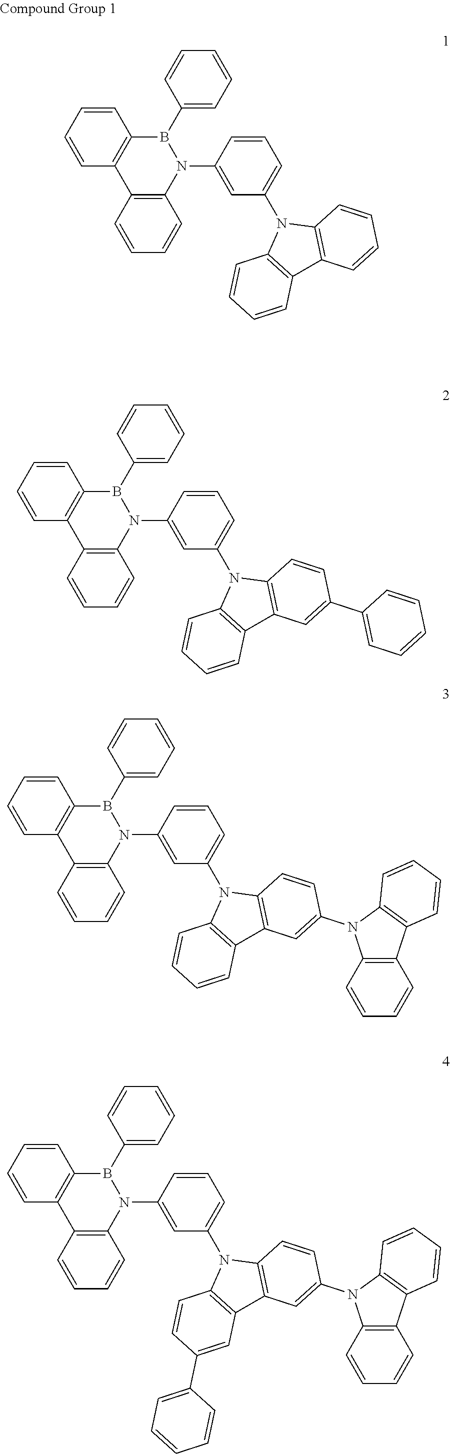 [SMILES: c1ccc(B2c3ccccc3-c3ccccc3N2c2cccc(-n3c4ccccc4c4ccccc43)c2)cc1 ; c1ccc(B2c3ccccc3-c3ccccc3N2c2cccc(-n3c4ccccc4c4cc(-c5ccccc5)ccc43)c2)cc1 ; c1ccc(B2c3ccccc3-c3ccccc3N2c2cccc(-n3c4ccccc4c4cc(-n5c6ccccc6c6ccccc65)ccc43)c2)cc1 ; c1ccc(B2c3ccccc3-c3ccccc3N2c2cccc(-n3c4ccc(-c5ccccc5)cc4c4cc(-n5c6ccccc6c6ccccc65)ccc43)c2)cc1]

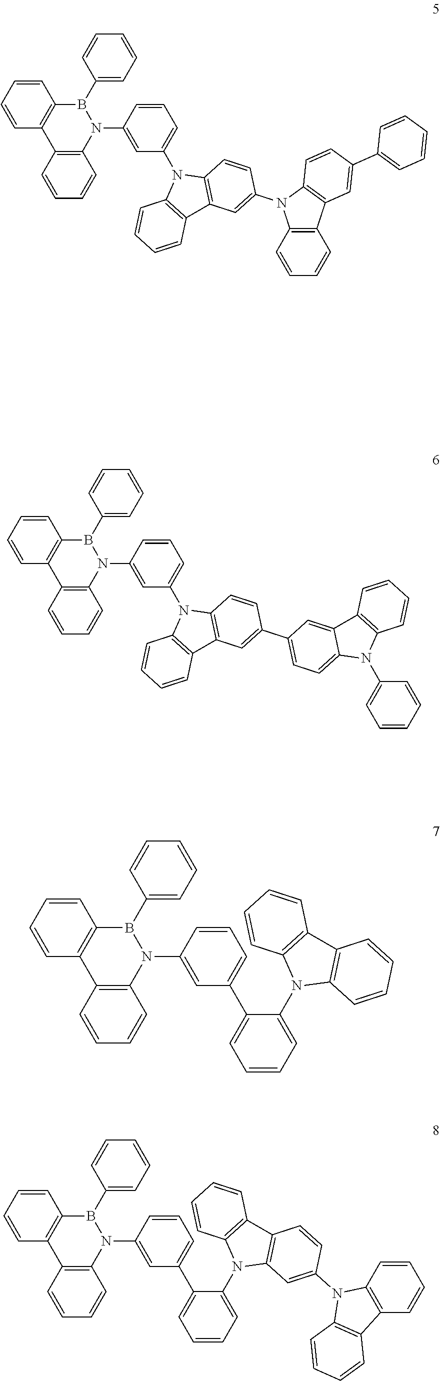 [SMILES: c1ccc(B2c3ccccc3-c3ccccc3N2c2cccc(-n3c4ccccc4c4cc(-n5c6ccccc6c6cc(-c7ccccc7)ccc65)ccc43)c2)cc1 ; c1ccc(B2c3ccccc3-c3ccccc3N2c2cccc(-n3c4ccccc4c4cc(-c5ccc6c(c5)c5ccccc5n6-c5ccccc5)ccc43)c2)cc1 ; c1ccc(B2c3ccccc3-c3ccccc3N2c2cccc(-c3ccccc3-n3c4ccccc4c4ccccc43)c2)cc1 ; c1ccc(B2c3ccccc3-c3ccccc3N2c2cccc(-c3ccccc3-n3c4ccccc4c4ccc(-n5c6ccccc6c6ccccc65)cc43)c2)cc1]

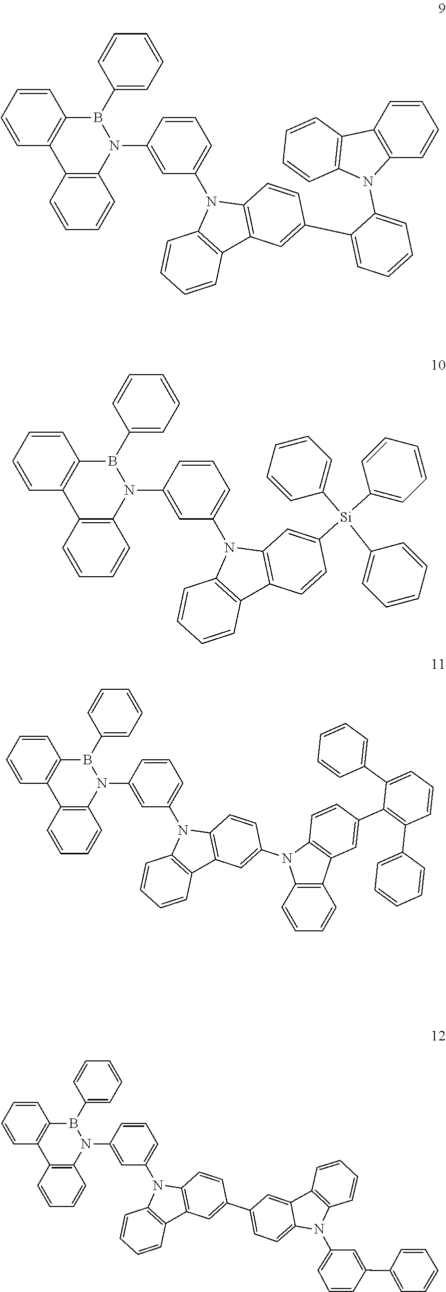 [SMILES: c1ccc(B2c3ccccc3-c3ccccc3N2c2cccc(-n3c4ccccc4c4cc(-c5ccccc5-n5c6ccccc6c6ccccc65)ccc43)c2)cc1 ; c1ccc(B2c3ccccc3-c3ccccc3N2c2cccc(-n3c4ccccc4c4ccc([Si](c5ccccc5)(c5ccccc5)c5ccccc5)cc43)c2)cc1 ; c1ccc(B2c3ccccc3-c3ccccc3N2c2cccc(-n3c4ccccc4c4cc(-n5c6ccccc6c6cc(-c7c(-c8ccccc8)cccc7-c7ccccc7)ccc65)ccc43)c2)cc1 ; c1ccc(B2c3ccccc3-c3ccccc3N2c2cccc(-n3c4ccccc4c4cc(-c5ccc6c(c5)c5ccccc5n6-c5cccc(-c6ccccc6)c5)ccc43)c2)cc1]

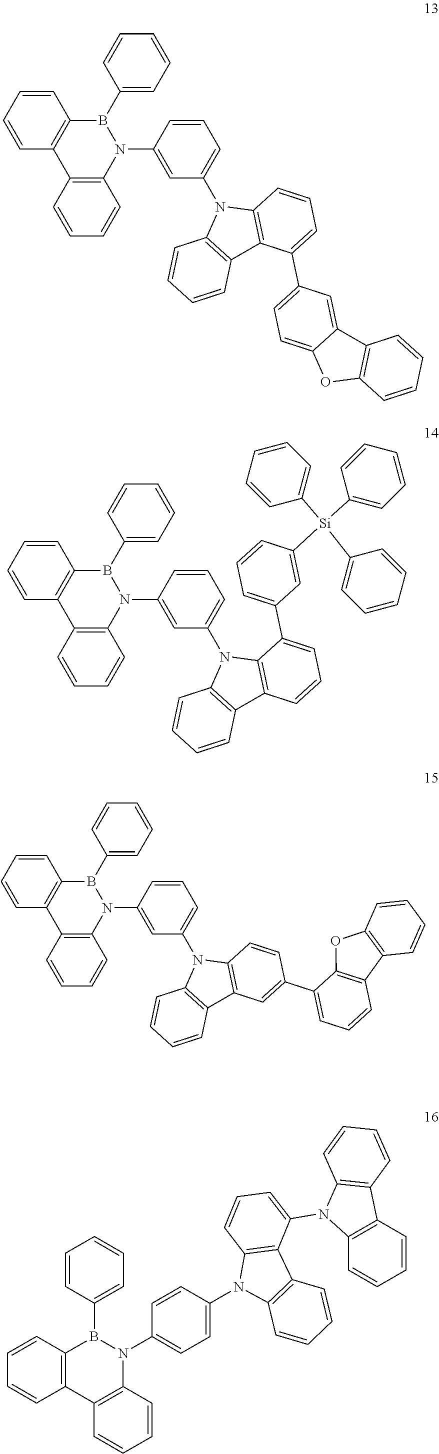 [SMILES: c1ccc(B2c3ccccc3-c3ccccc3N2c2cccc(-n3c4ccccc4c4c(-c5ccc6oc7ccccc7c6c5)cccc43)c2)cc1 ; c1ccc(B2c3ccccc3-c3ccccc3N2c2cccc(-n3c4ccccc4c4cccc(-c5cccc([Si](c6ccccc6)(c6ccccc6)c6ccccc6)c5)c43)c2)cc1 ; c1ccc(B2c3ccccc3-c3ccccc3N2c2cccc(-n3c4ccccc4c4cc(-c5cccc6c5oc5ccccc56)ccc43)c2)cc1 ; c1ccc(B2c3ccccc3-c3ccccc3N2c2ccc(-n3c4ccccc4c4c(-n5c6ccccc6c6ccccc65)cccc43)cc2)cc1]

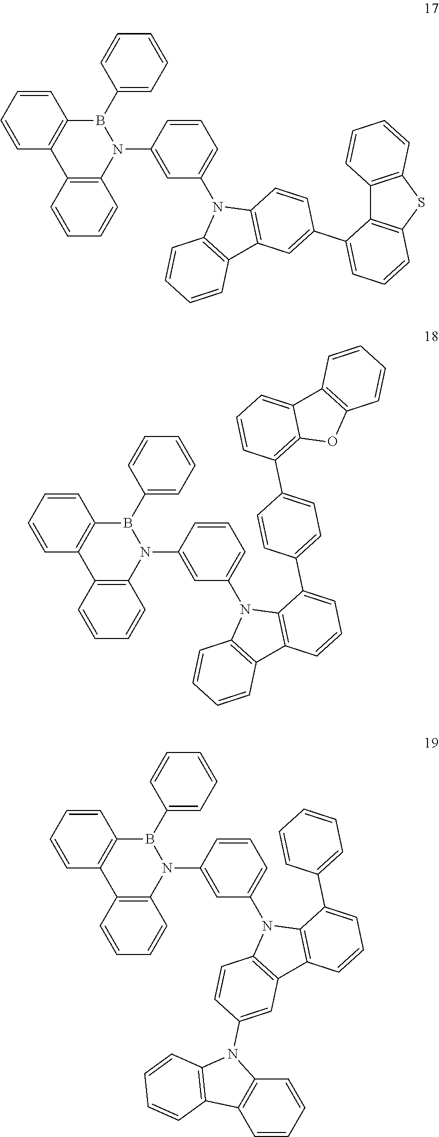 [SMILES: c1ccc(B2c3ccccc3-c3ccccc3N2c2cccc(-n3c4ccccc4c4cc(-c5cccc6sc7ccccc7c56)ccc43)c2)cc1 ; c1ccc(B2c3ccccc3-c3ccccc3N2c2cccc(-n3c4ccccc4c4cccc(-c5ccc(-c6cccc7c6oc6ccccc67)cc5)c43)c2)cc1 ; c1ccc(B2c3ccccc3-c3ccccc3N2c2cccc(-n3c4ccc(-n5c6ccccc6c6ccccc65)cc4c4cccc(-c5ccccc5)c43)c2)cc1]

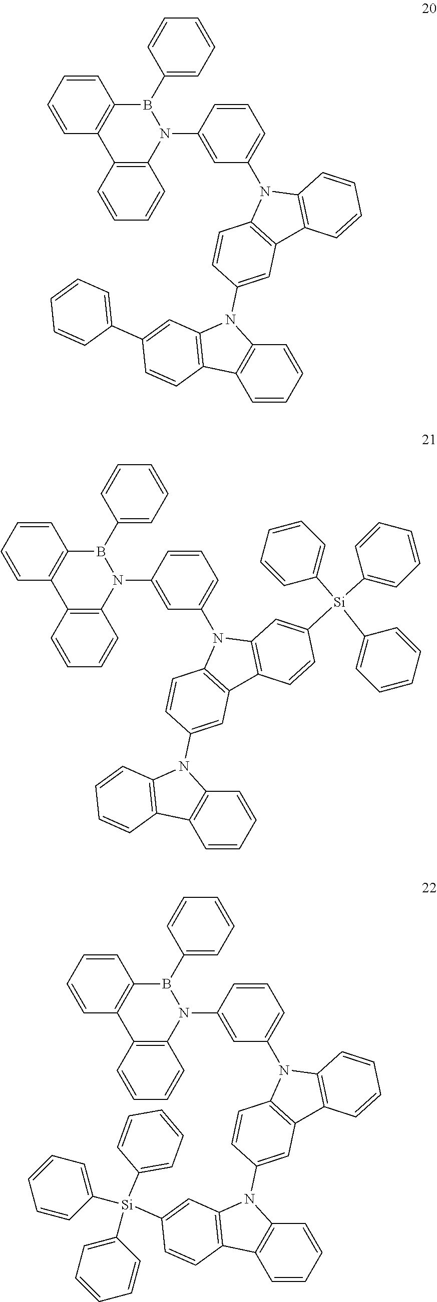 [SMILES: c1ccc(B2c3ccccc3-c3ccccc3N2c2cccc(-n3c4ccccc4c4cc(-n5c6ccccc6c6ccc(-c7ccccc7)cc65)ccc43)c2)cc1 ; c1ccc(B2c3ccccc3-c3ccccc3N2c2cccc(-n3c4ccc(-n5c6ccccc6c6ccccc65)cc4c4ccc([Si](c5ccccc5)(c5ccccc5)c5ccccc5)cc43)c2)cc1 ; c1ccc(B2c3ccccc3-c3ccccc3N2c2cccc(-n3c4ccccc4c4cc(-n5c6ccccc6c6ccc([Si](c7ccccc7)(c7ccccc7)c7ccccc7)cc65)ccc43)c2)cc1]

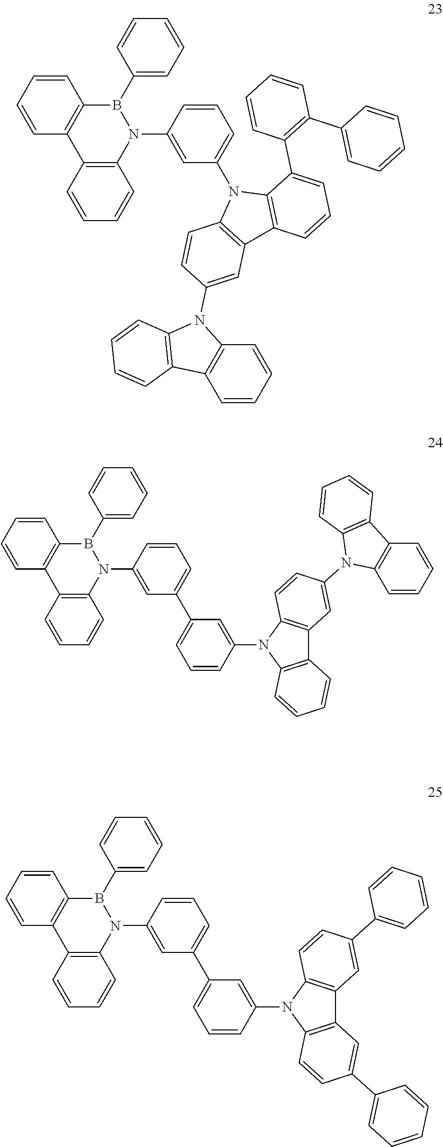 [SMILES: c1ccc(B2c3ccccc3-c3ccccc3N2c2cccc(-n3c4ccc(-n5c6ccccc6c6ccccc65)cc4c4cccc(-c5ccccc5-c5ccccc5)c43)c2)cc1 ; c1ccc(B2c3ccccc3-c3ccccc3N2c2cccc(-c3cccc(-n4c5ccccc5c5cc(-n6c7ccccc7c7ccccc76)ccc54)c3)c2)cc1 ; c1ccc(B2c3ccccc3-c3ccccc3N2c2cccc(-c3cccc(-n4c5ccc(-c6ccccc6)cc5c5cc(-c6ccccc6)ccc54)c3)c2)cc1]

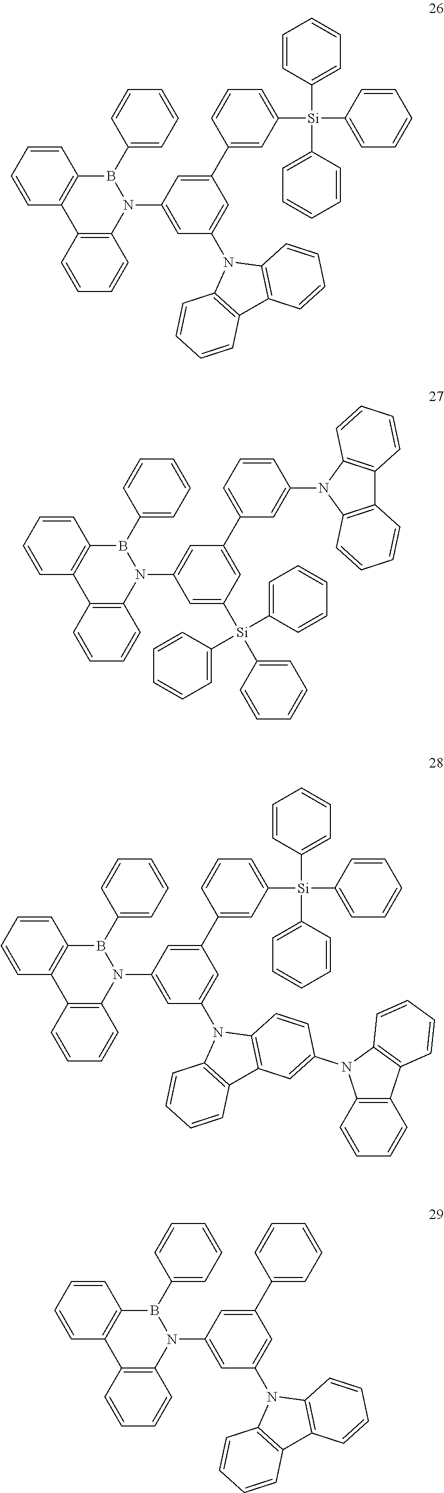 [SMILES: c1ccc(B2c3ccccc3-c3ccccc3N2c2cc(-c3cccc([Si](c4ccccc4)(c4ccccc4)c4ccccc4)c3)cc(-n3c4ccccc4c4ccccc43)c2)cc1 ; c1ccc(B2c3ccccc3-c3ccccc3N2c2cc(-c3cccc(-n4c5ccccc5c5ccccc54)c3)cc([Si](c3ccccc3)(c3ccccc3)c3ccccc3)c2)cc1 ; c1ccc(B2c3ccccc3-c3ccccc3N2c2cc(-c3cccc([Si](c4ccccc4)(c4ccccc4)c4ccccc4)c3)cc(-n3c4ccccc4c4cc(-n5c6ccccc6c6ccccc65)ccc43)c2)cc1 ; c1ccc(B2c3ccccc3-c3ccccc3N2c2cc(-c3ccccc3)cc(-n3c4ccccc4c4ccccc43)c2)cc1]

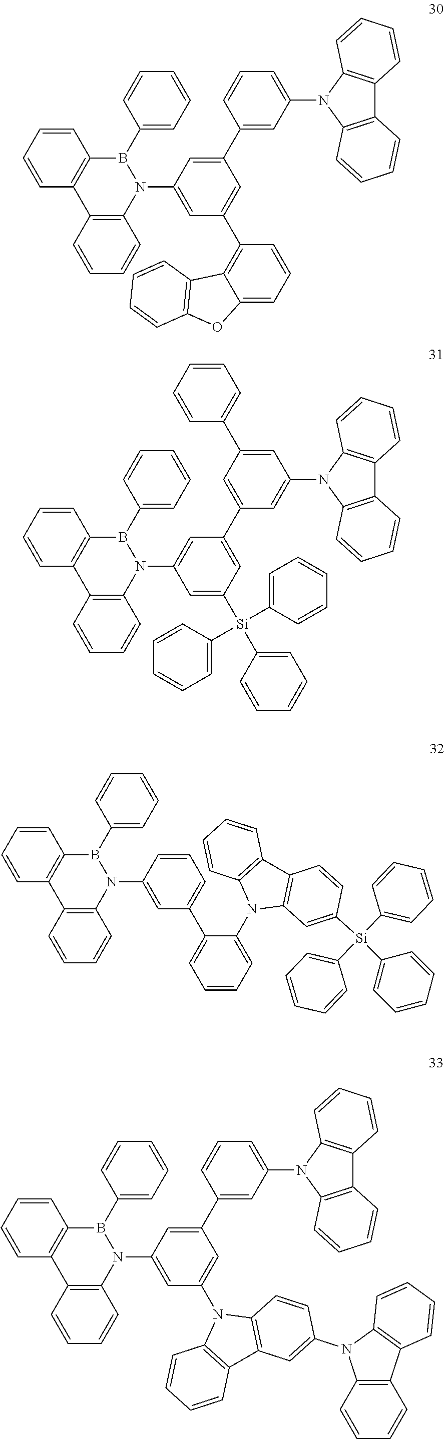

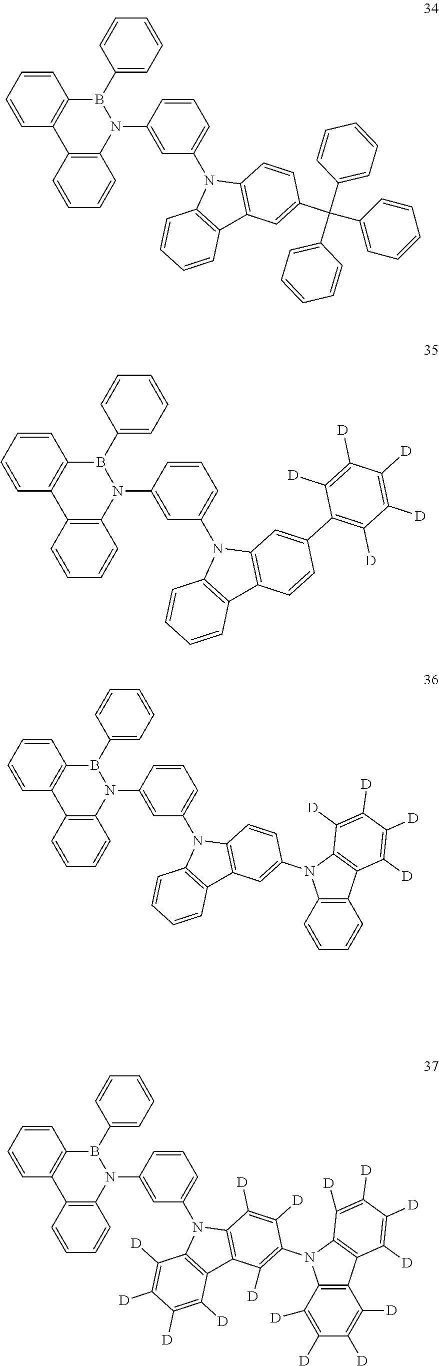 [SMILES: c1ccc(B2c3ccccc3-c3ccccc3N2c2cccc(-n3c4ccccc4c4cc(C(c5ccccc5)(c5ccccc5)c5ccccc5)ccc43)c2)cc1 ; [2H]c1c([2H])c([2H])c(-c2ccc3c4ccccc4n(-c4cccc(N5B(c6ccccc6)c6ccccc6-c6ccccc65)c4)c3c2)c([2H])c1[2H] ; [2H]c1c([2H])c([2H])c2c(c1[2H])c1ccccc1n2-c1ccc2c(c1)c1ccccc1n2-c1cccc(N2B(c3ccccc3)c3ccccc3-c3ccccc32)c1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cccc(N2B(c3ccccc3)c3ccccc3-c3ccccc32)c1]

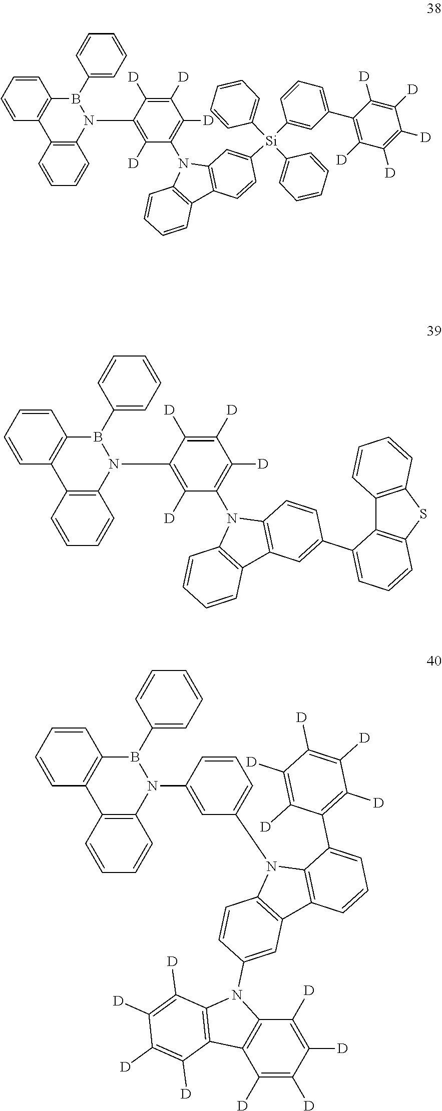 [SMILES: [2H]c1c([2H])c([2H])c(-c2cccc([Si](c3ccccc3)(c3ccccc3)c3ccc4c5ccccc5n(-c5c([2H])c([2H])c([2H])c(N6B(c7ccccc7)c7ccccc7-c7ccccc76)c5[2H])c4c3)c2)c([2H])c1[2H] ; [2H]c1c([2H])c(N2B(c3ccccc3)c3ccccc3-c3ccccc32)c([2H])c(-n2c3ccccc3c3cc(-c4cccc5sc6ccccc6c45)ccc32)c1[2H] ; [2H]c1c([2H])c([2H])c(-c2cccc3c4cc(-n5c6c([2H])c([2H])c([2H])c([2H])c6c6c([2H])c([2H])c([2H])c([2H])c65)ccc4n(-c4cccc(N5B(c6ccccc6)c6ccccc6-c6ccccc65)c4)c23)c([2H])c1[2H]]

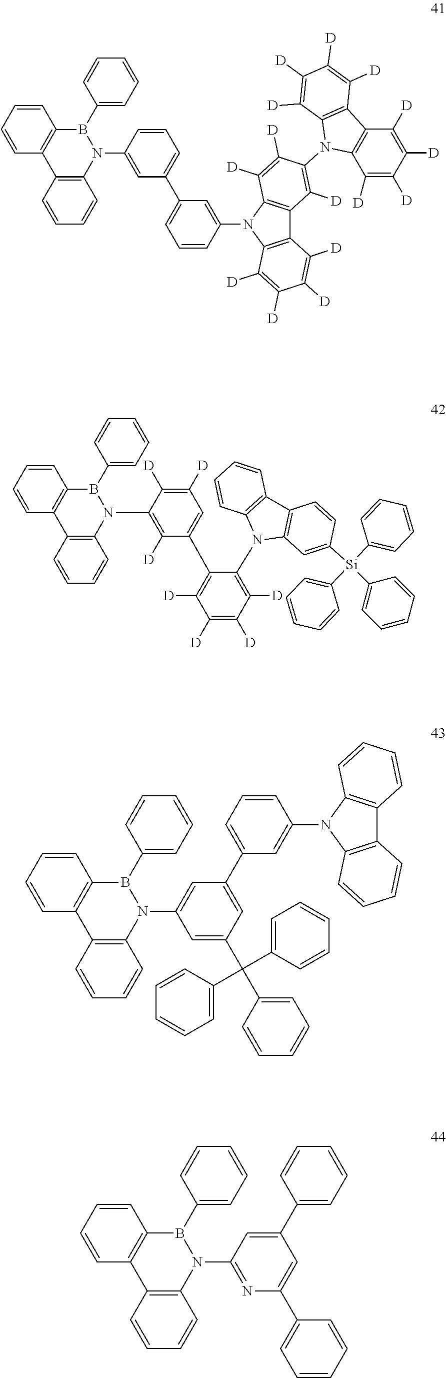 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cccc(-c2cccc(N3B(c4ccccc4)c4ccccc4-c4ccccc43)c2)c1 ; [2H]c1cc(-c2c([2H])c([2H])c([2H])c([2H])c2-n2c3ccccc3c3ccc([Si](c4ccccc4)(c4ccccc4)c4ccccc4)cc32)c([2H])c(N2B(c3ccccc3)c3ccccc3-c3ccccc32)c1[2H] ; c1ccc(B2c3ccccc3-c3ccccc3N2c2cc(-c3cccc(-n4c5ccccc5c5ccccc54)c3)cc(C(c3ccccc3)(c3ccccc3)c3ccccc3)c2)cc1 ; c1ccc(B2c3ccccc3-c3ccccc3N2c2cc(-c3ccccc3)cc(-c3ccccc3)n2)cc1]

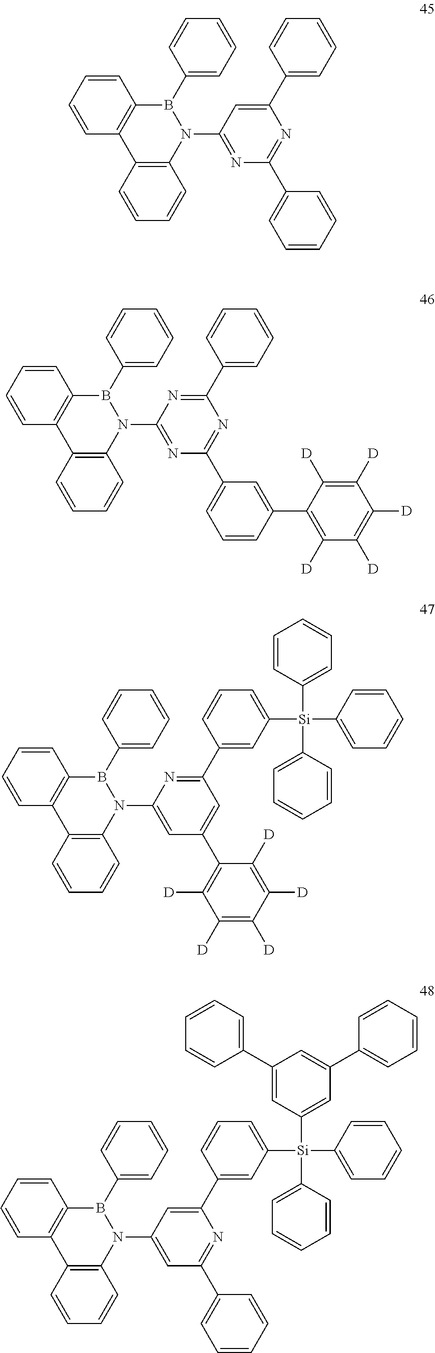 [SMILES: c1ccc(B2c3ccccc3-c3ccccc3N2c2cc(-c3ccccc3)nc(-c3ccccc3)n2)cc1 ; [2H]c1c([2H])c([2H])c(-c2cccc(-c3nc(-c4ccccc4)nc(N4B(c5ccccc5)c5ccccc5-c5ccccc54)n3)c2)c([2H])c1[2H] ; [2H]c1c([2H])c([2H])c(-c2cc(-c3cccc([Si](c4ccccc4)(c4ccccc4)c4ccccc4)c3)nc(N3B(c4ccccc4)c4ccccc4-c4ccccc43)c2)c([2H])c1[2H] ; c1ccc(B2c3ccccc3-c3ccccc3N2c2cc(-c3ccccc3)nc(-c3cccc([Si](c4ccccc4)(c4ccccc4)c4cc(-c5ccccc5)cc(-c5ccccc5)c4)c3)c2)cc1]

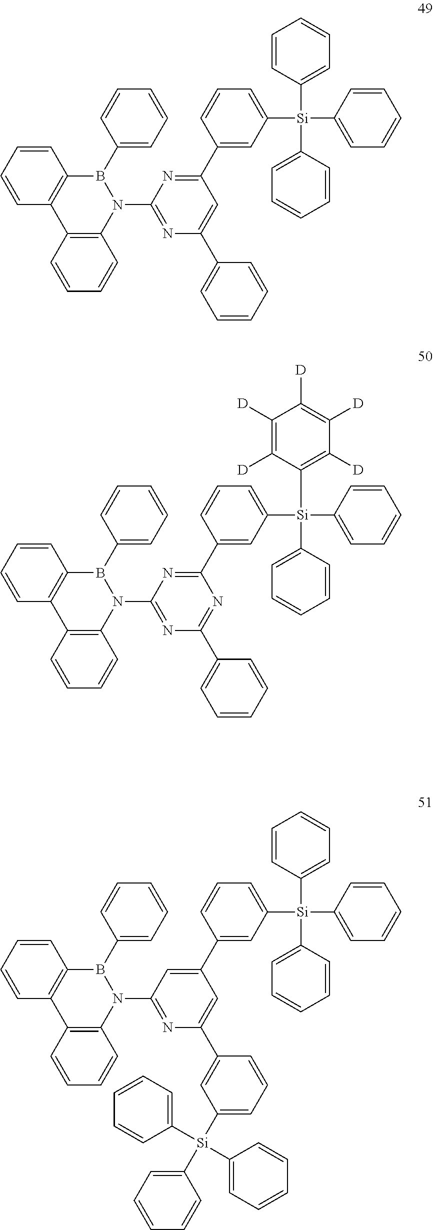 [SMILES: c1ccc(B2c3ccccc3-c3ccccc3N2c2nc(-c3ccccc3)cc(-c3cccc([Si](c4ccccc4)(c4ccccc4)c4ccccc4)c3)n2)cc1 ; [2H]c1c([2H])c([2H])c([Si](c2ccccc2)(c2ccccc2)c2cccc(-c3nc(-c4ccccc4)nc(N4B(c5ccccc5)c5ccccc5-c5ccccc54)n3)c2)c([2H])c1[2H] ; c1ccc(B2c3ccccc3-c3ccccc3N2c2cc(-c3cccc([Si](c4ccccc4)(c4ccccc4)c4ccccc4)c3)cc(-c3cccc([Si](c4ccccc4)(c4ccccc4)c4ccccc4)c3)n2)cc1]

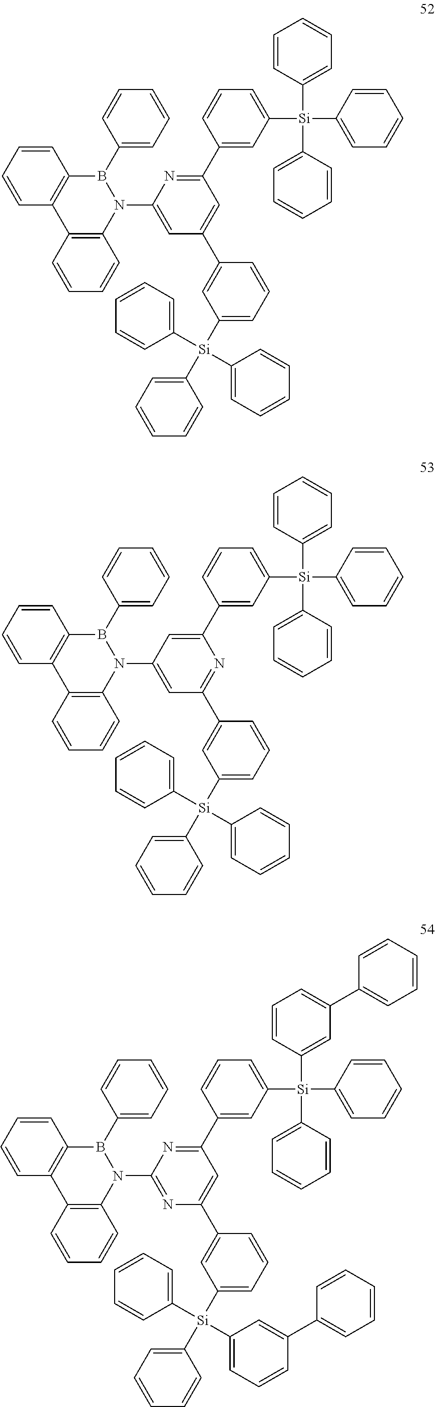 [SMILES: c1ccc(B2c3ccccc3-c3ccccc3N2c2cc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; c1ccc(B2c3ccccc3-c3ccccc3N2c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; c1ccc(B2c3ccccc3-c3ccccc3N2c2nc(-c3cccc([Si](c4ccccc4)(c4ccccc4)c4cccc(-c5ccccc5)c4)c3)cc(-c3cccc([Si](c4ccccc4)(c4ccccc4)c4cccc(-c5ccccc5)c4)c3)n2)cc1]

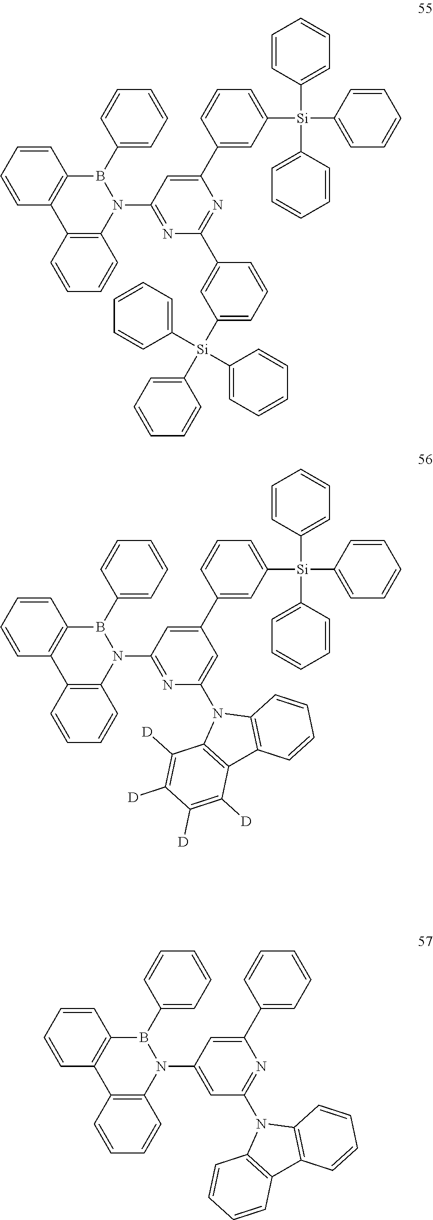 [SMILES: c1ccc(B2c3ccccc3-c3ccccc3N2c2cc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; [2H]c1c([2H])c([2H])c2c(c1[2H])c1ccccc1n2-c1cc(-c2cccc([Si](c3ccccc3)(c3ccccc3)c3ccccc3)c2)cc(N2B(c3ccccc3)c3ccccc3-c3ccccc32)n1 ; c1ccc(B2c3ccccc3-c3ccccc3N2c2cc(-c3ccccc3)nc(-n3c4ccccc4c4ccccc43)c2)cc1]

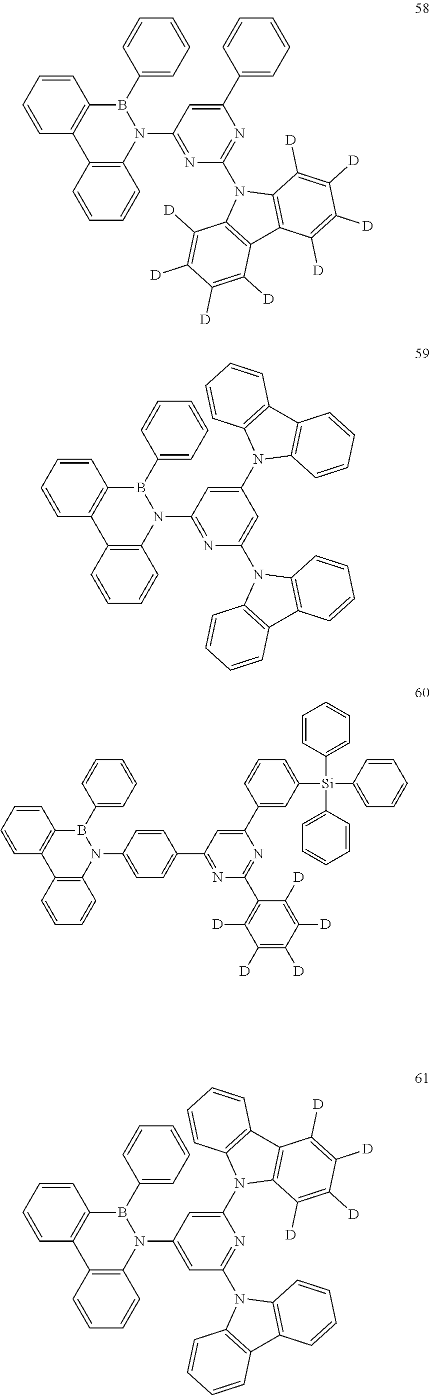 [SMILES: [2H]c1c([2H])c([2H])c2c(c1[2H])c1c([2H])c([2H])c([2H])c([2H])c1n2-c1nc(-c2ccccc2)cc(N2B(c3ccccc3)c3ccccc3-c3ccccc32)n1 ; c1ccc(B2c3ccccc3-c3ccccc3N2c2cc(-n3c4ccccc4c4ccccc43)cc(-n3c4ccccc4c4ccccc43)n2)cc1 ; [2H]c1c([2H])c([2H])c(-c2nc(-c3ccc(N4B(c5ccccc5)c5ccccc5-c5ccccc54)cc3)cc(-c3cccc([Si](c4ccccc4)(c4ccccc4)c4ccccc4)c3)n2)c([2H])c1[2H] ; [2H]c1c([2H])c([2H])c2c(c1[2H])c1ccccc1n2-c1cc(N2B(c3ccccc3)c3ccccc3-c3ccccc32)cc(-n2c3ccccc3c3ccccc32)n1]

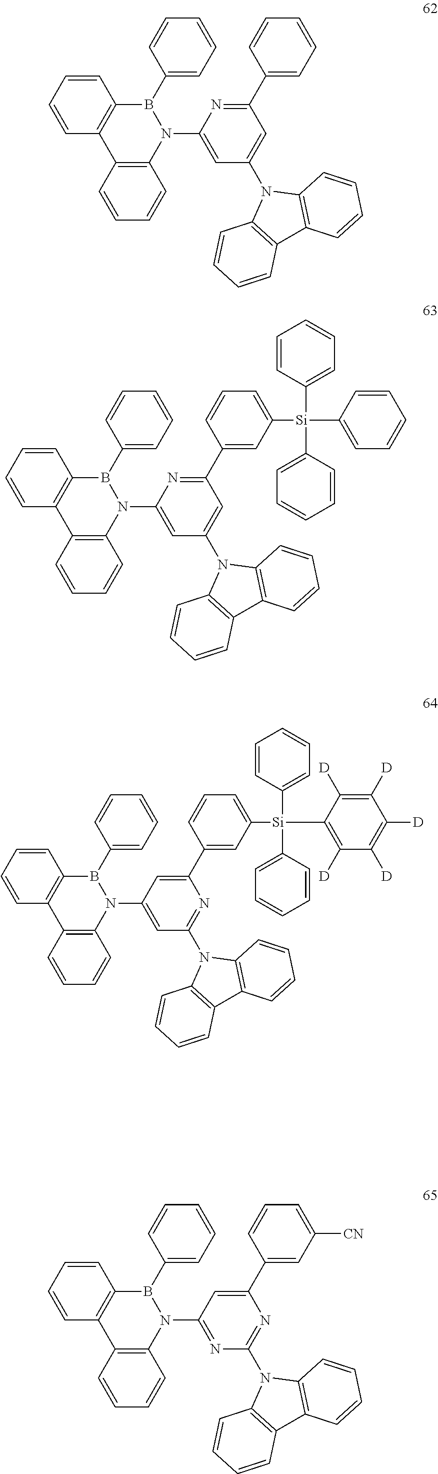 [SMILES: c1ccc(B2c3ccccc3-c3ccccc3N2c2cc(-n3c4ccccc4c4ccccc43)cc(-c3ccccc3)n2)cc1 ; c1ccc(B2c3ccccc3-c3ccccc3N2c2cc(-n3c4ccccc4c4ccccc43)cc(-c3cccc([Si](c4ccccc4)(c4ccccc4)c4ccccc4)c3)n2)cc1 ; [2H]c1c([2H])c([2H])c([Si](c2ccccc2)(c2ccccc2)c2cccc(-c3cc(N4B(c5ccccc5)c5ccccc5-c5ccccc54)cc(-n4c5ccccc5c5ccccc54)n3)c2)c([2H])c1[2H] ; N#Cc1cccc(-c2cc(N3B(c4ccccc4)c4ccccc4-c4ccccc43)nc(-n3c4ccccc4c4ccccc43)n2)c1]

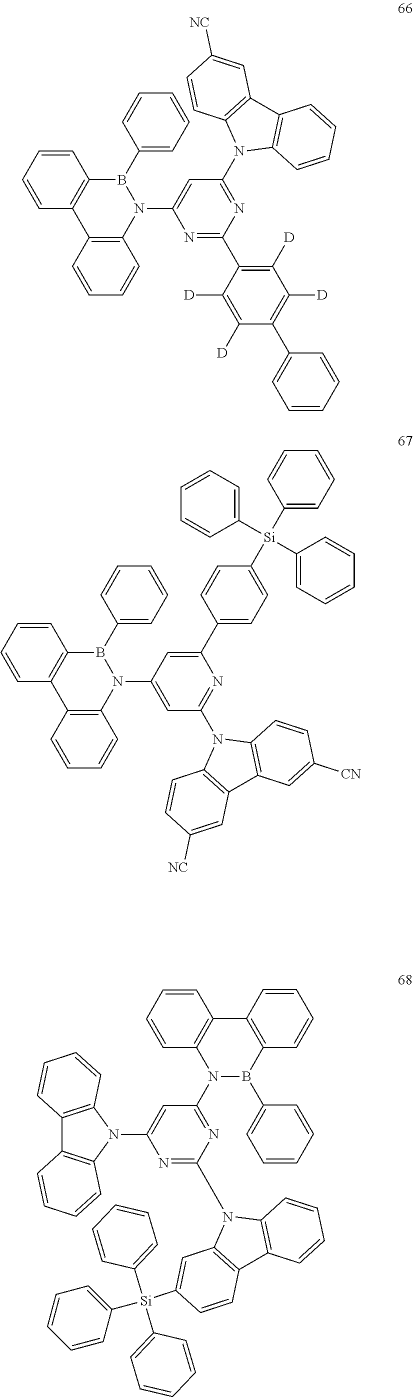

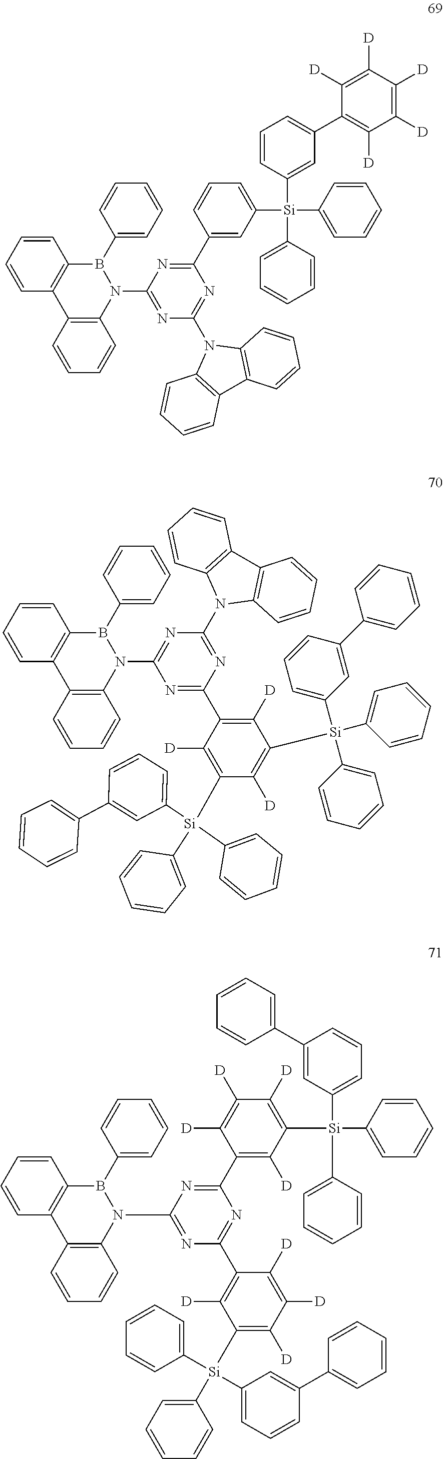

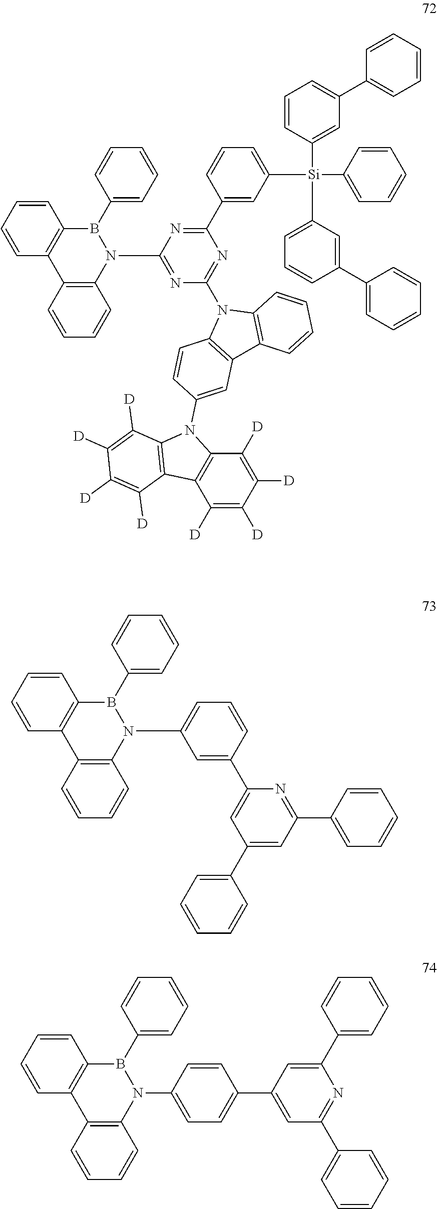 [SMILES: [2H]c1c([2H])c([2H])c2c(c1[2H])c1c([2H])c([2H])c([2H])c([2H])c1n2-c1ccc2c(c1)c1ccccc1n2-c1nc(-c2cccc([Si](c3ccccc3)(c3cccc(-c4ccccc4)c3)c3cccc(-c4ccccc4)c3)c2)nc(N2B(c3ccccc3)c3ccccc3-c3ccccc32)n1 ; c1ccc(B2c3ccccc3-c3ccccc3N2c2cccc(-c3cc(-c4ccccc4)cc(-c4ccccc4)n3)c2)cc1 ; c1ccc(B2c3ccccc3-c3ccccc3N2c2ccc(-c3cc(-c4ccccc4)nc(-c4ccccc4)c3)cc2)cc1]

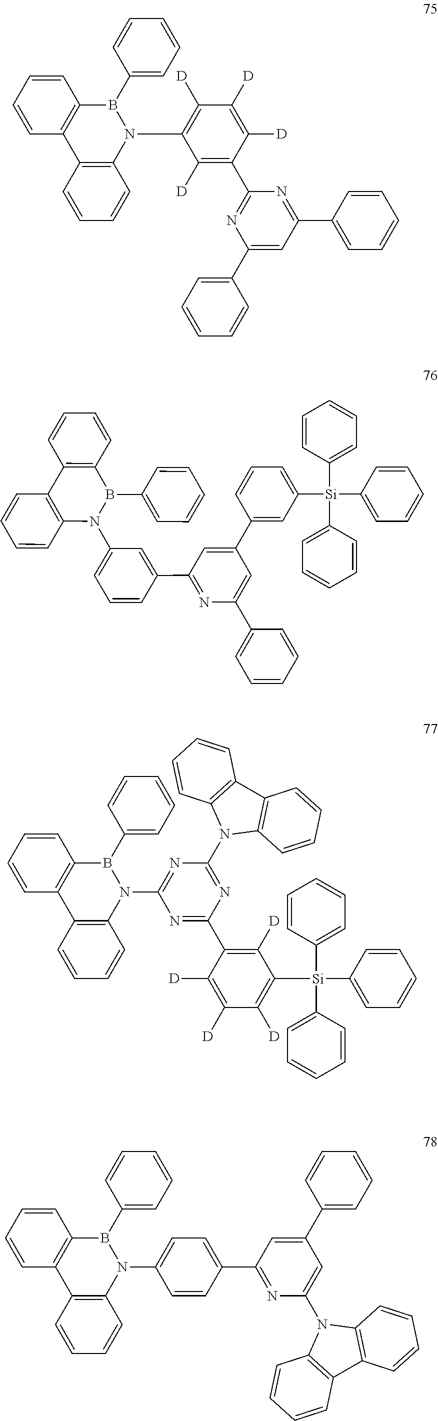 [SMILES: [2H]c1c([2H])c(-c2nc(-c3ccccc3)cc(-c3ccccc3)n2)c([2H])c(N2B(c3ccccc3)c3ccccc3-c3ccccc32)c1[2H] ; c1ccc(B2c3ccccc3-c3ccccc3N2c2cccc(-c3cc(-c4cccc([Si](c5ccccc5)(c5ccccc5)c5ccccc5)c4)cc(-c4ccccc4)n3)c2)cc1 ; [2H]c1c([2H])c(-c2nc(N3B(c4ccccc4)c4ccccc4-c4ccccc43)nc(-n3c4ccccc4c4ccccc43)n2)c([2H])c([Si](c2ccccc2)(c2ccccc2)c2ccccc2)c1[2H] ; c1ccc(B2c3ccccc3-c3ccccc3N2c2ccc(-c3cc(-c4ccccc4)cc(-n4c5ccccc5c5ccccc54)n3)cc2)cc1]

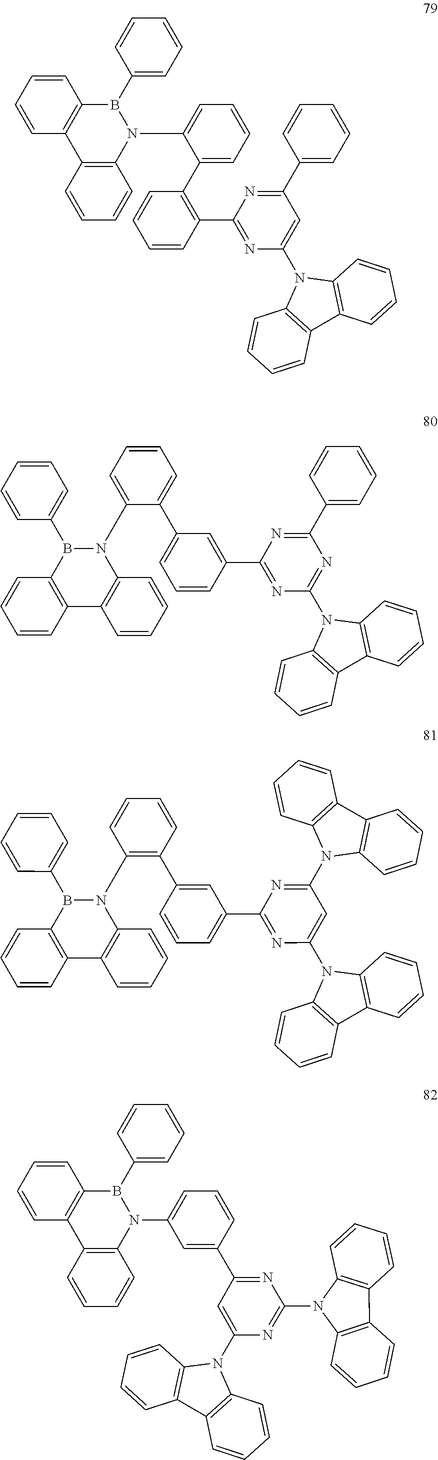

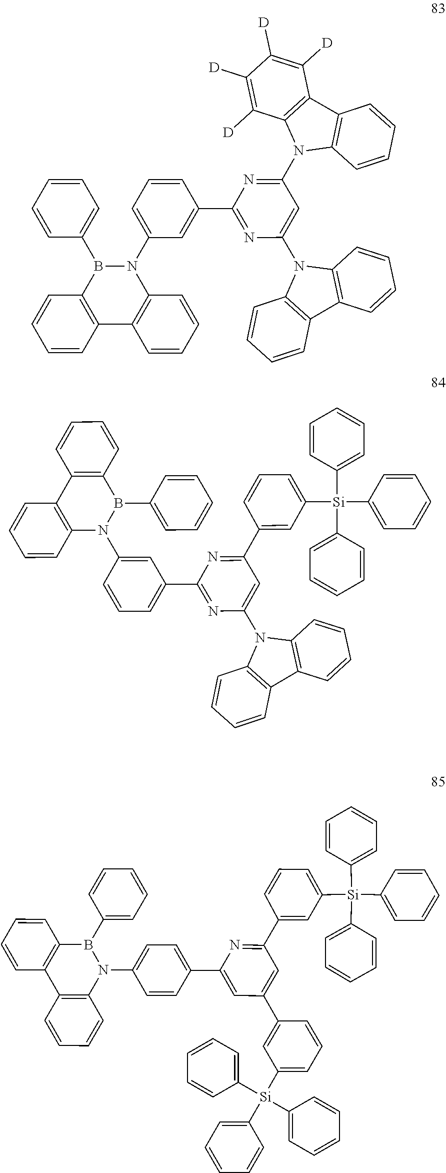 [SMILES: [2H]c1c([2H])c([2H])c2c(c1[2H])c1ccccc1n2-c1cc(-n2c3ccccc3c3ccccc32)nc(-c2cccc(N3B(c4ccccc4)c4ccccc4-c4ccccc43)c2)n1 ; c1ccc(B2c3ccccc3-c3ccccc3N2c2cccc(-c3nc(-c4cccc([Si](c5ccccc5)(c5ccccc5)c5ccccc5)c4)cc(-n4c5ccccc5c5ccccc54)n3)c2)cc1 ; c1ccc(B2c3ccccc3-c3ccccc3N2c2ccc(-c3cc(-c4cccc([Si](c5ccccc5)(c5ccccc5)c5ccccc5)c4)cc(-c4cccc([Si](c5ccccc5)(c5ccccc5)c5ccccc5)c4)n3)cc2)cc1]

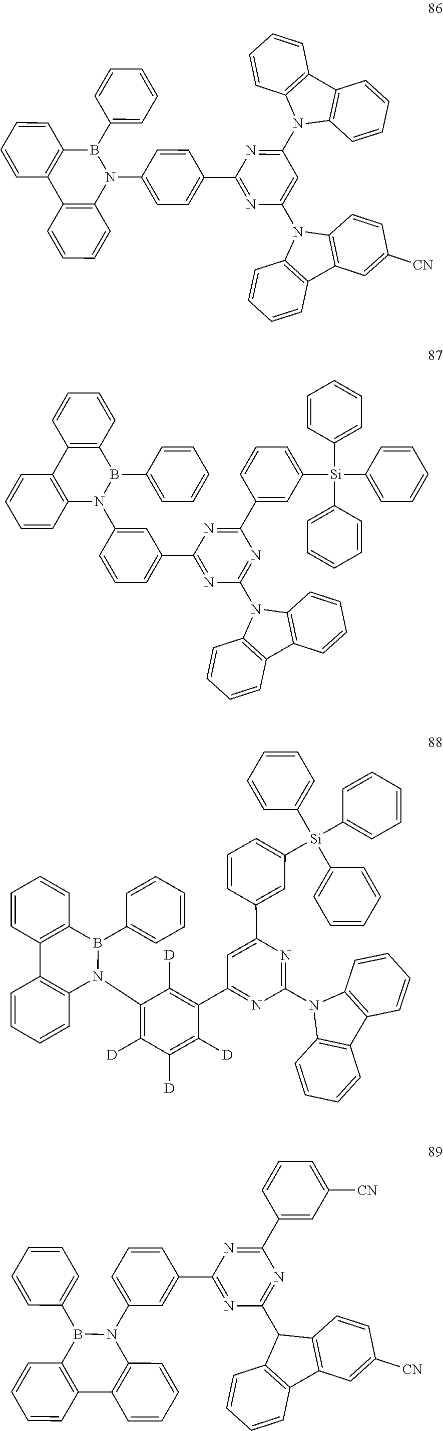 [SMILES: N#Cc1ccc2c(c1)c1ccccc1n2-c1cc(-n2c3ccccc3c3ccccc32)nc(-c2ccc(N3B(c4ccccc4)c4ccccc4-c4ccccc43)cc2)n1 ; c1ccc(B2c3ccccc3-c3ccccc3N2c2cccc(-c3nc(-c4cccc([Si](c5ccccc5)(c5ccccc5)c5ccccc5)c4)nc(-n4c5ccccc5c5ccccc54)n3)c2)cc1 ; [2H]c1c([2H])c(-c2cc(-c3cccc([Si](c4ccccc4)(c4ccccc4)c4ccccc4)c3)nc(-n3c4ccccc4c4ccccc43)n2)c([2H])c(N2B(c3ccccc3)c3ccccc3-c3ccccc32)c1[2H] ; N#Cc1cccc(-c2nc(-c3cccc(N4B(c5ccccc5)c5ccccc5-c5ccccc54)c3)nc(C3c4ccccc4-c4cc(C#N)ccc43)n2)c1]

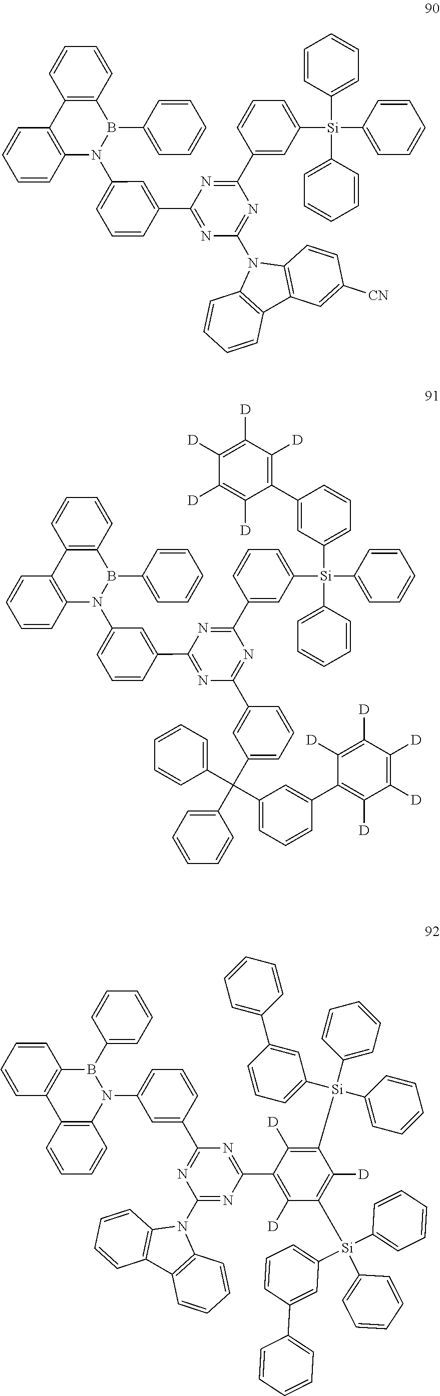

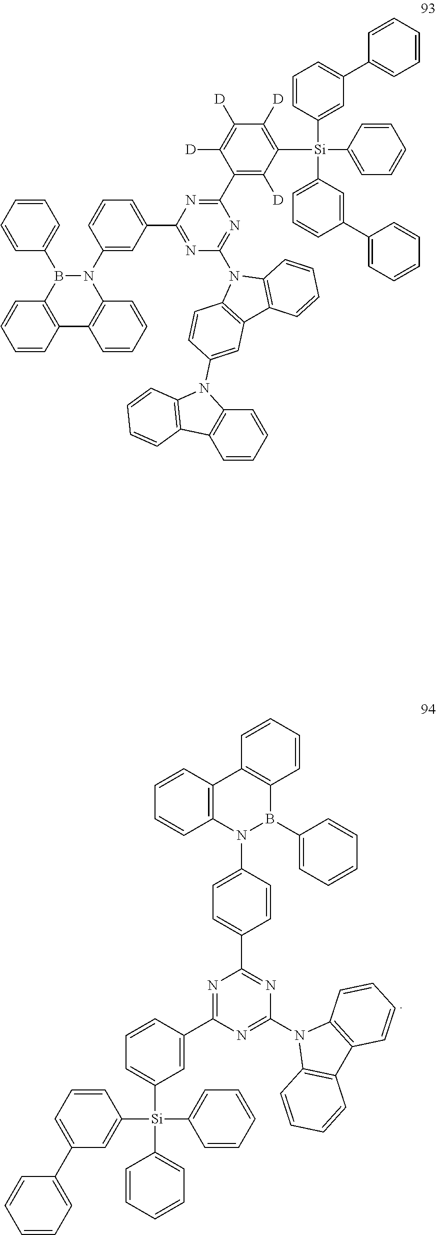

A polycyclic compound according to an embodiment may include a fused ring of three rings, which contains B and N as ring-forming atoms, and a carbazole group, a pyridine group, a pyrimidine group, or a triazine group as a substituent bonded to the fused ring of three rings. In the fused ring of three rings, B and N may be the ring-forming atoms that form a central cyclic group among the three cyclic groups.

A carbazole group, a pyridine group, a pyrimidine group, and a triazine group are substituted or unsubstituted, and may be directly or indirectly bonded to N, which is a ring-forming atom of the fused ring of three rings. When a substituent bonded to the fused ring of three rings is a carbazole group, the substituent may be indirectly bonded to N, which is a ring-forming atom of the fused ring of three rings through a phenyl group. When a substituent bonded to the fused ring of three rings is a pyridine group, a pyrimidine group, or a triazine group, the substituent may be directly bonded to N, which is a ring-forming atom of the fused ring, or may be indirectly bonded through a phenyl group.

The polycyclic compound according to an embodiment contains a carbazole group, which is an electron donating group (EDG), and/or a pyridine group, a pyrimidine group, or a triazine group, which is an electron withdrawing group (EWG), and may thus have enhanced hole and charge injection properties. Accordingly, a light emitting element ED including the polycyclic compound according to an embodiment may have a reduced driving voltage and an excellent or suitable charge balance, thereby increasing luminous efficiency.

The polycyclic compound according to an embodiment including a carbazole group, a pyridine group, a pyrimidine group, and/or a triazine group have greater (larger) molecules in size (because of the inclusion of the foregoing groups), thereby increasing glass transition temperature and thermal stability. In some embodiments, because of the inclusion of a carbazole group, a pyridine group, a pyrimidine group, and/or a triazine group in the polycyclic compound, the energy level (T1) of triplet state remains high, and accordingly when utilized as a host material of the emission layer EML in the light emitting element ED, the polycyclic compound may contribute to enhancing the driving voltage and efficiency of the light emitting element ED.

An emission layer EML may include a host and a dopant, and the host of the emission layer EML may include the polycyclic compound according to an embodiment. The emission layer EML may be a layer of phosphorescence or a layer of thermally activated delayed fluorescence (TADF). The polycyclic compound according to an embodiment may be utilized as a host material for phosphorescence and as a host material for thermally activated delayed fluorescence. For example, the polycyclic compound according to an embodiment may be utilized as a host material for blue phosphorescence. For example, the emission layer EML may include, as a dopant material, a metal complex including Ir as a central metal. However, this is merely an example, and the embodiment of the present disclosure is not limited thereto.

The emission layer EML may have, for example, a thickness of about 100 Å to about 1000 Å or about 100 Å to about 300 Å. The emission layer EML may have a single layer formed of a single material, a single layer formed of a plurality of different materials, or a multilayer structure having a plurality of layers formed of a plurality of different materials. The emission layer EML may further include compounds that will be described in addition to the polycyclic compound according to an embodiment.

The emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

The emission layer EML may include a compound represented by Formula E-1. The compound represented by Formula E-1 may be utilized as a fluorescent host material.

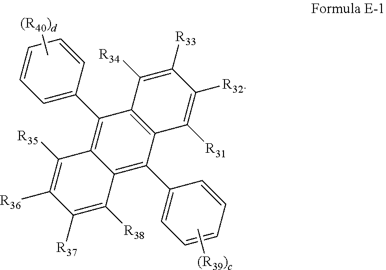

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring. In Formula E-1, R₃₁ to R₄₀ may be linked to an adjacent group to form a saturated hydrocarbon ring, an unsaturated hydrocarbon ring, a saturated heterocycle, or an unsaturated heterocycle.

In Formula E-1, c and d may each independently be an integer from 0 to 5. When c is an integer of 2 or greater, a plurality of R₃₉s may all be the same or at least one may be different from the others. When d is an integer of 2 or greater, a plurality of R₄₀s may all be the same or at least one may be different from the others. Formula E-1 may be represented by any one selected from among compounds E1 to E19.

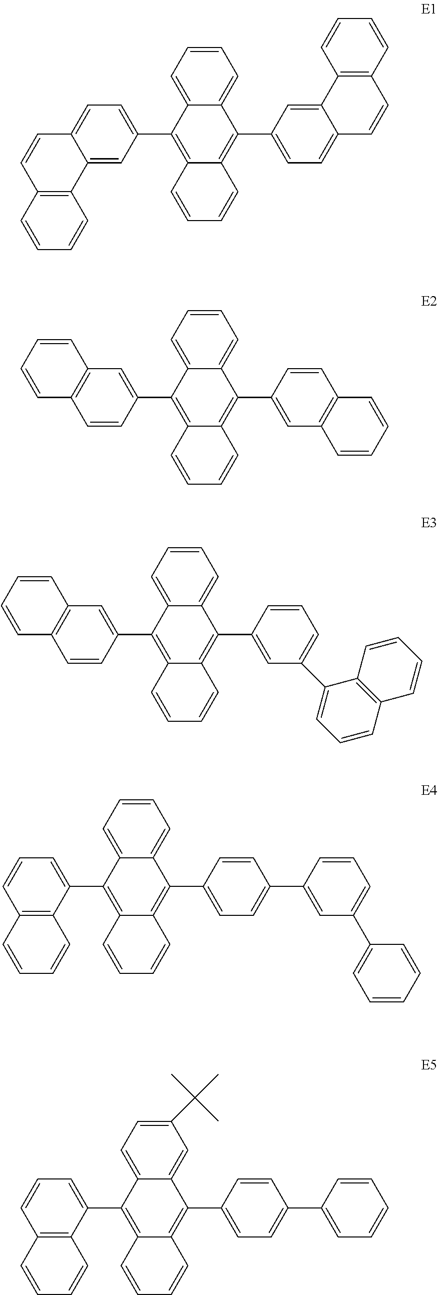

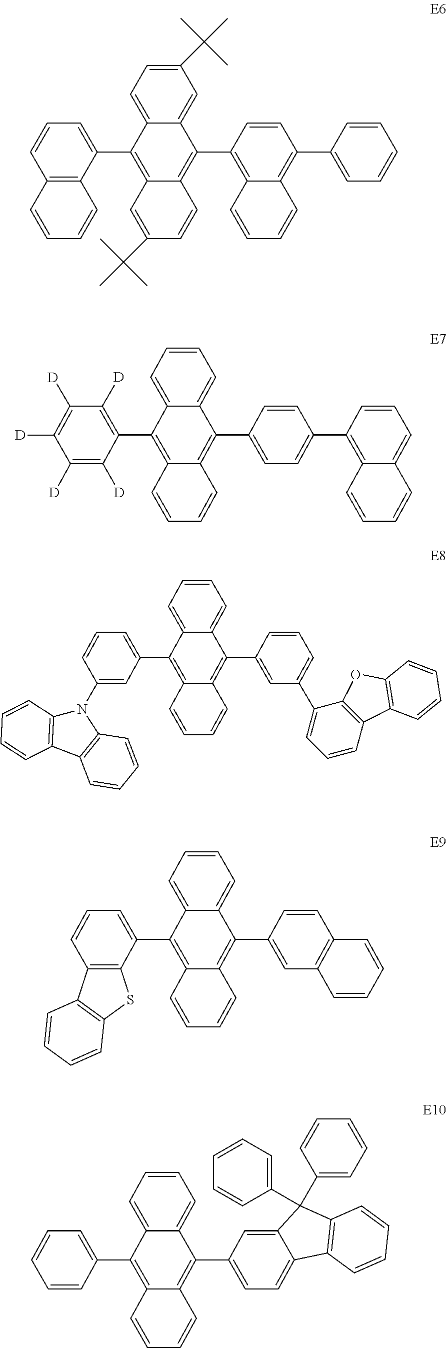

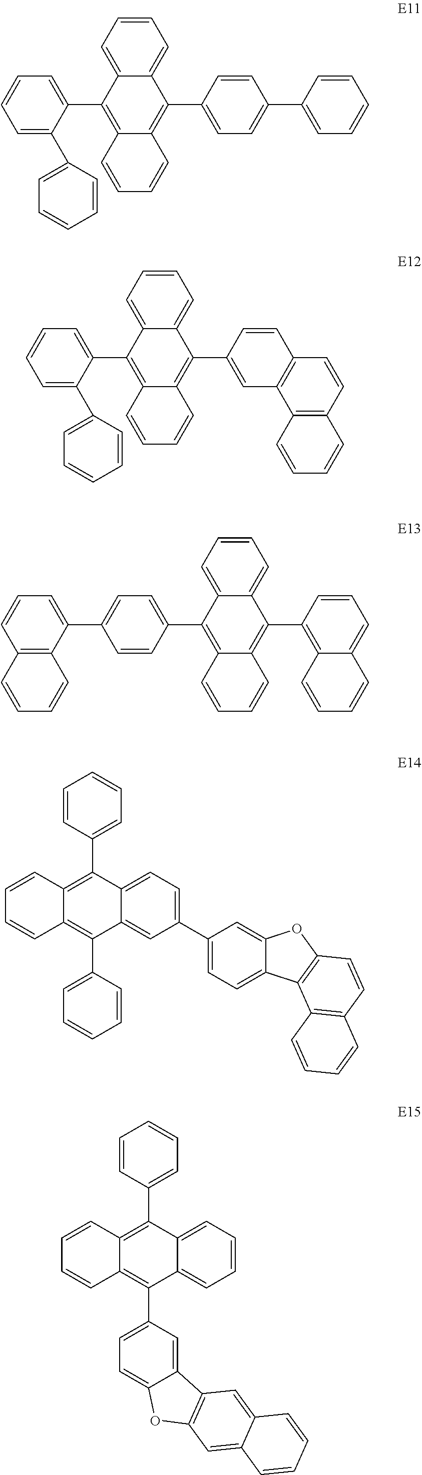

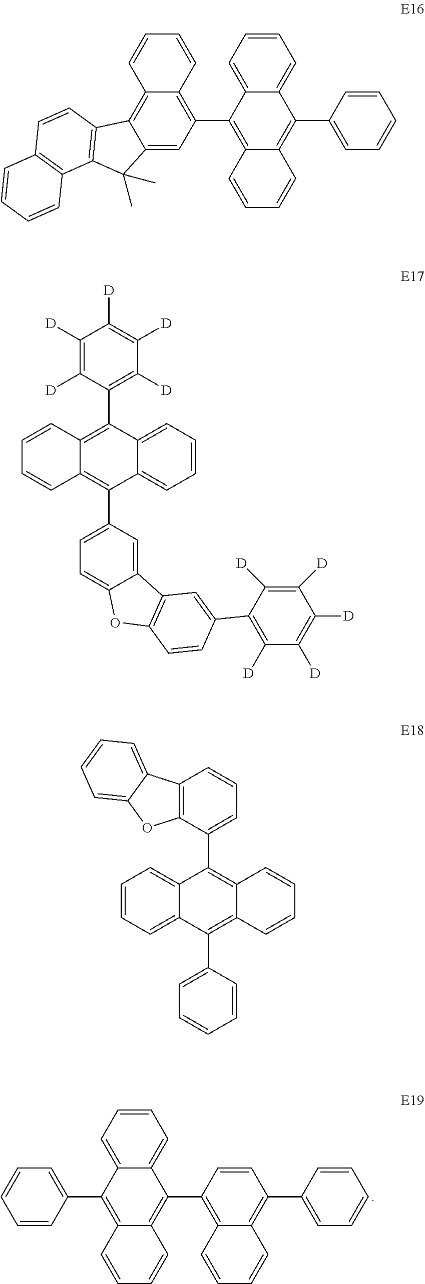

In an embodiment, the emission layer EML may include a compound represented by Formula E-2a or Formula E-2b. The compound represented by Formula E-2a or Formula E-2b may be utilized as a phosphorescent host material.

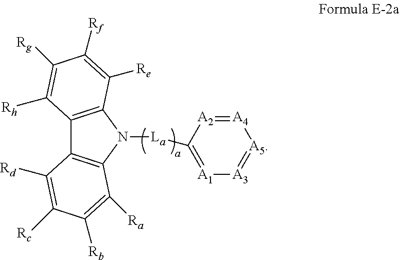

In Formula E-2a, a may be an integer from 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. When a is an integer of 2 or greater, a plurality of Las may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may be N or Crᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, and/or linked to an adjacent group to form a ring. Rₐ to Rᵢ may be linked to an adjacent group to form a hydrocarbon ring or a heterocycle containing N, O, S, etc. as a ring-forming atom.

In Formula E-2a, two or three (substituents) selected from among A₁ to A₅ may be N, and each of the reminder of A₁ to A₅ may be Crᵢ.

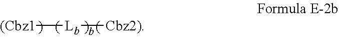

In Formula E-2b, Cbz1 and Cbz2 may each independently be an unsubstituted carbazole group or an aryl-substituted carbazole group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms, b may be an integer from 0 to 10, and when b is an integer of 2 or greater, a plurality of L_{b}s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among compounds from (e.g., of or in) Compound Group E-2. However, the compounds listed in Compound Group E-2 are merely examples, and the compound represented by Formula E-2a or Formula E-2b is not limited to those listed in Compound Group E-2.

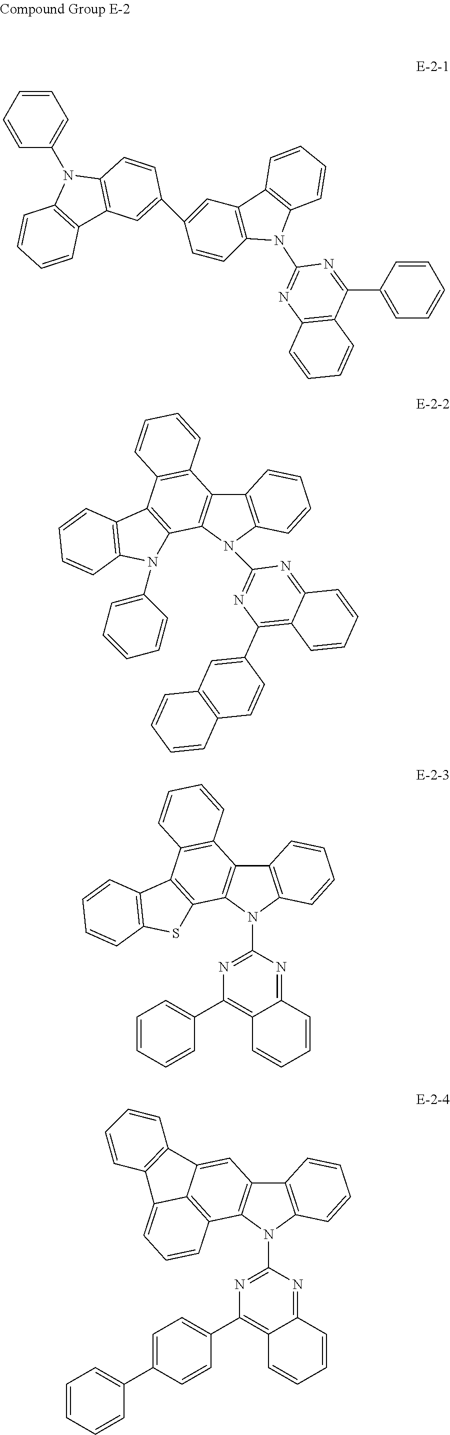

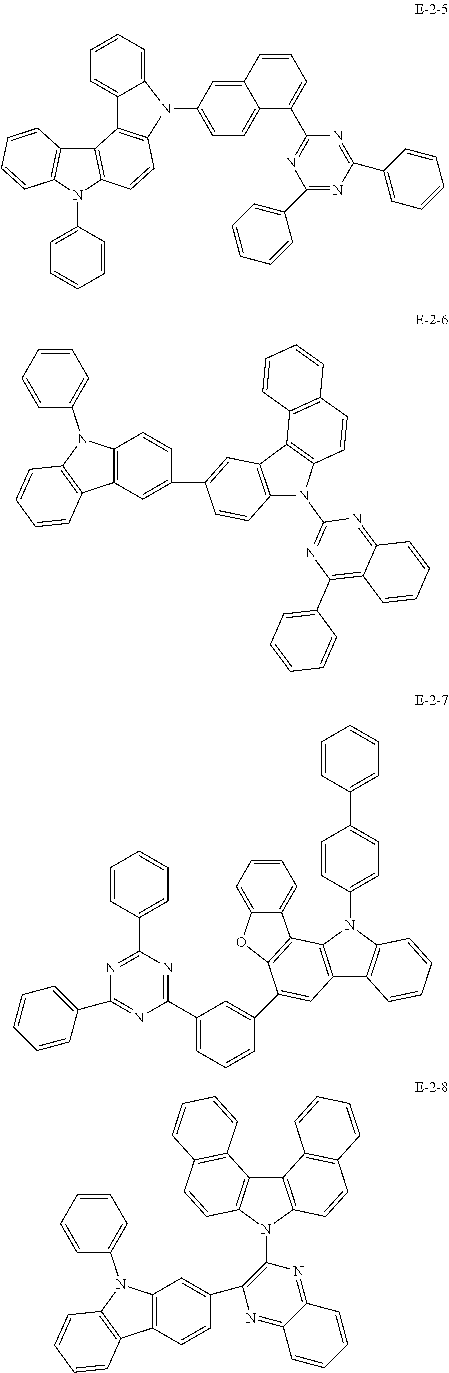

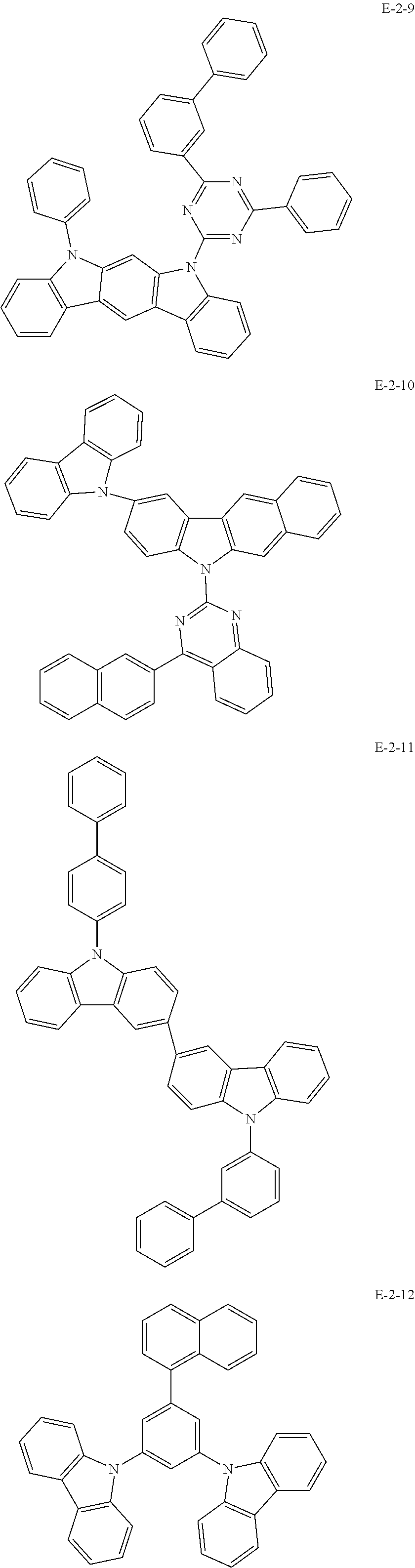

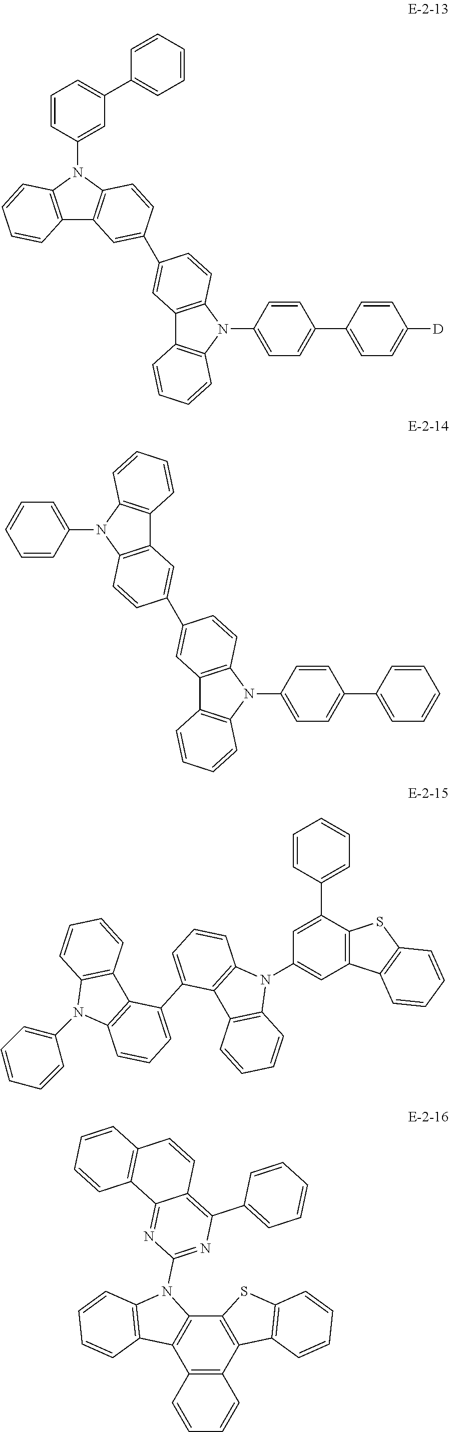 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1]

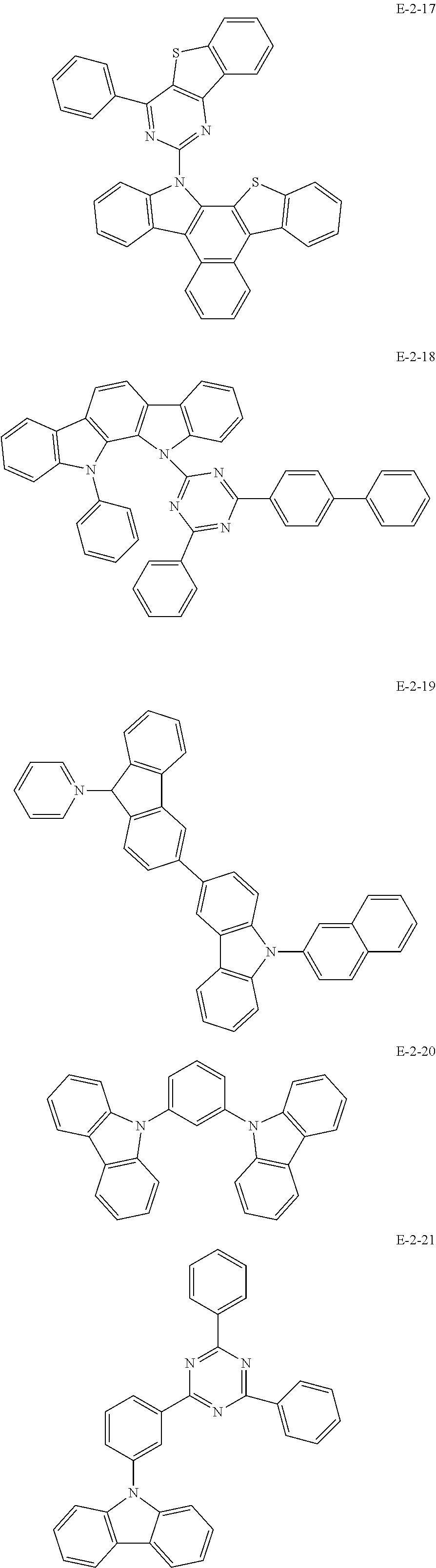

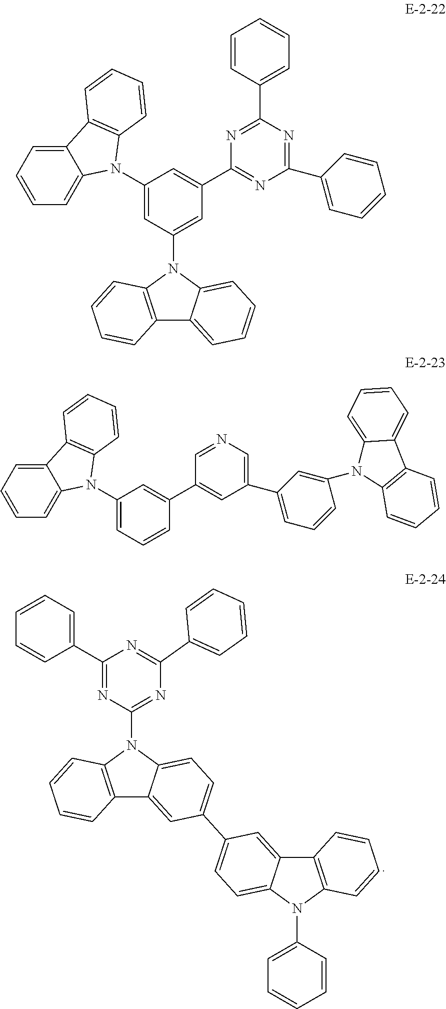 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material generally utilized/generally available in the art as a host material. For example, the emission layer EML may include, as a host material, at least one selected from among bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazolyl-9-yl)benzene (mCP), 2,8-bis(diphenylphosphoryl)dibenzofuran (PPF), 4,4′,4″-tris(carbazol-9-yl)-triphenylamine (TCTA), and 1,3,5-tris(1-phenyl-1H-benzo[d]imidazol-2-yl)benzene (TPBi). However, the embodiment of the present disclosure is not limited thereto, and for example, tris(8-hydroxyquinolino)aluminum (Alq₃), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be utilized as a host material.

The emission layer EML may include a compound represented by Formula M-a or Formula M-b. The compound represented by Formula M-a or Formula M-b may be utilized as a phosphorescent dopant material.

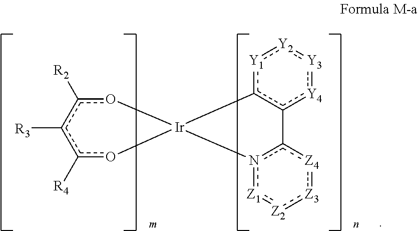

In Formula M-a, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring. In Formula M-a, m may be 0 or 1, and n may be 2 or 3. In Formula M-a, when m is 0, n is 3, and when m is 1, n is 2.

The compound represented by Formula M-a may be utilized as a phosphorescent dopant. The compound represented by Formula M-a may be represented by any one selected from among compounds M-a1 to M-a25. However, the compounds M-a1 to M-a25 are merely examples, and the compound represented by Formula M-a is not limited to those represented by the compounds M-a1 to M-a25.

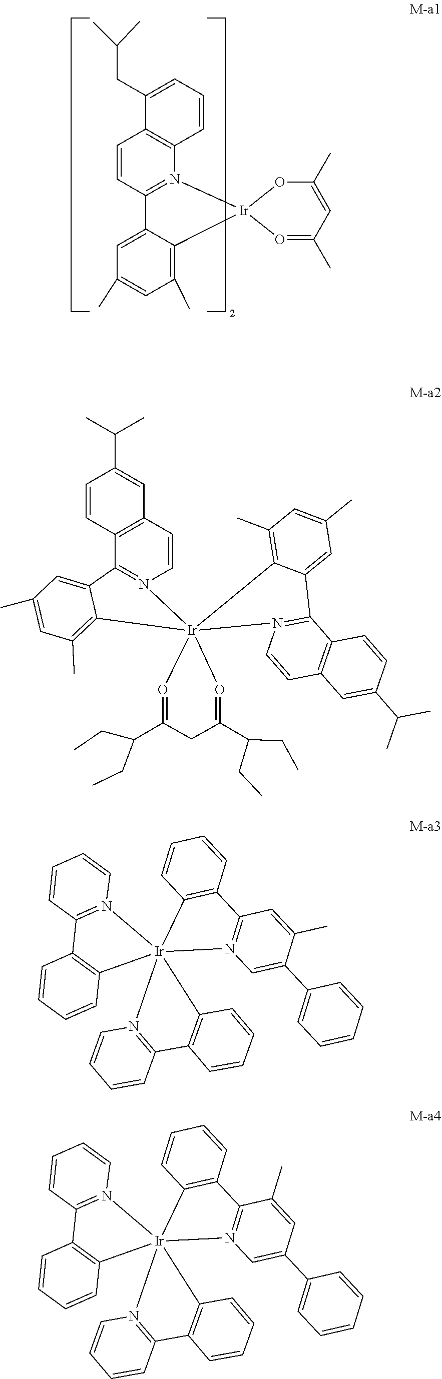

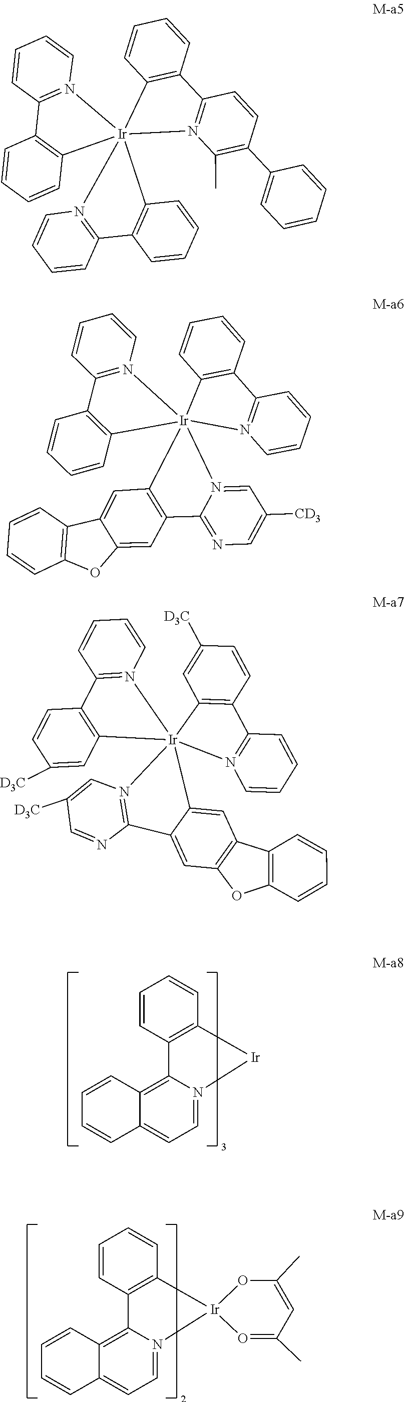

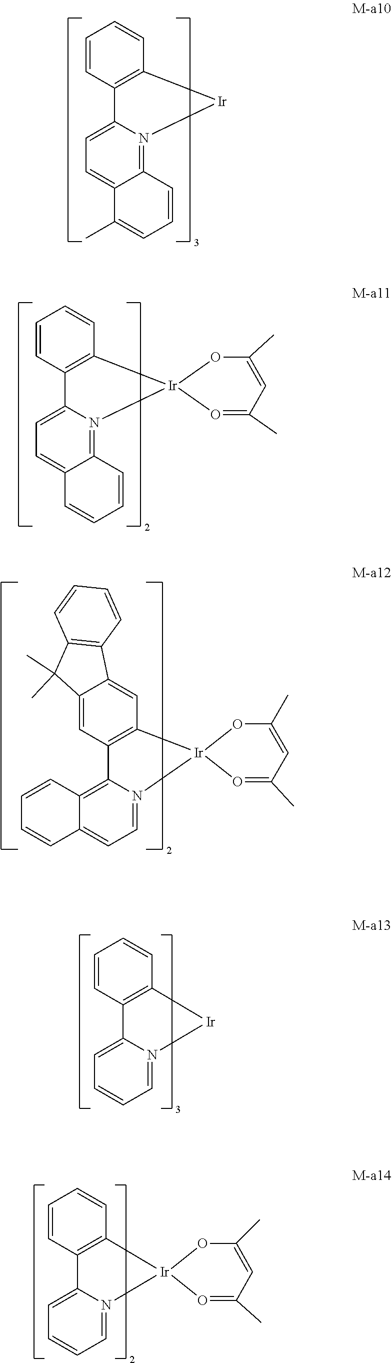

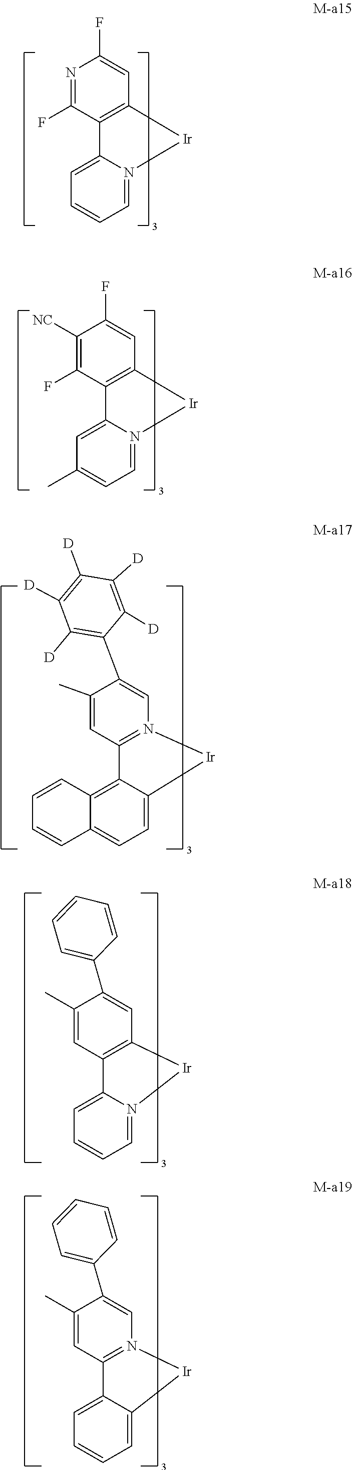

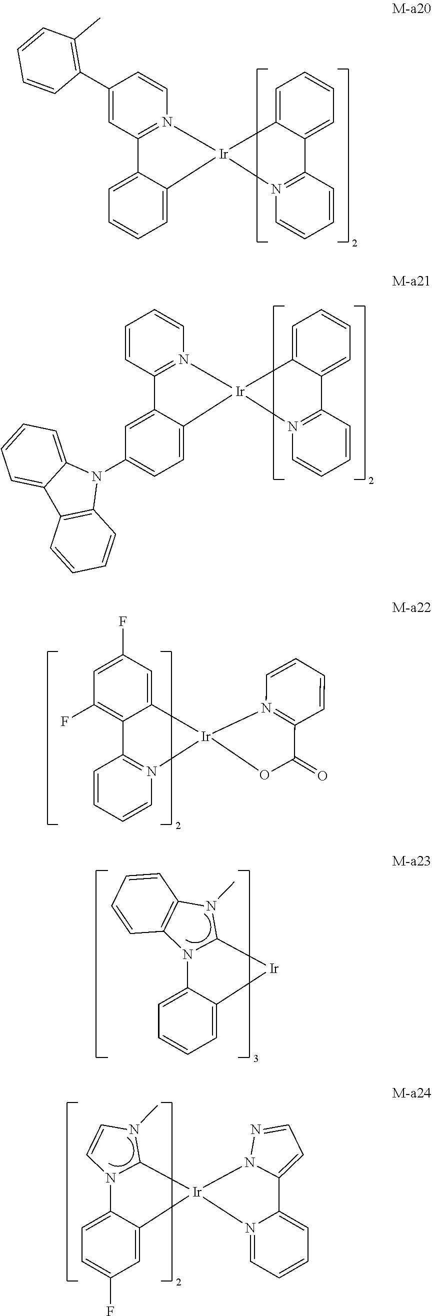

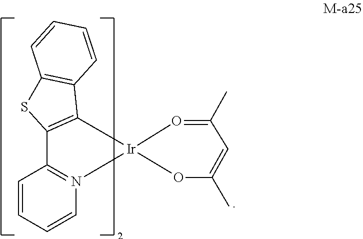

The compounds M-a1 and M-a2 may be utilized as a red dopant material, 15 and the compounds M-a3 to M-a7 may be utilized as a green dopant material.

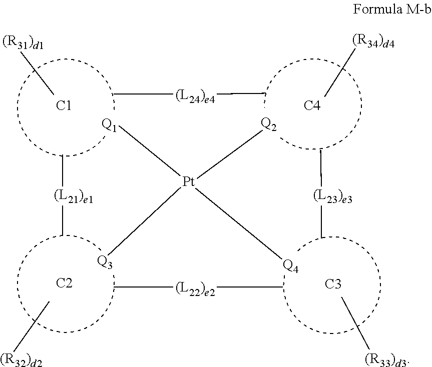

In Formula M-b, Q₁ to Q₄ may each independently be C or N, and C1 to C4 may each independently be a substituted or unsubstituted hydrocarbon ring having 5 to 30 ring-forming carbon atoms, or a substituted or unsubstituted heterocycle having 2 to 30 ring-forming carbon atoms. L21 to L24 may each independently be a direct linkage,

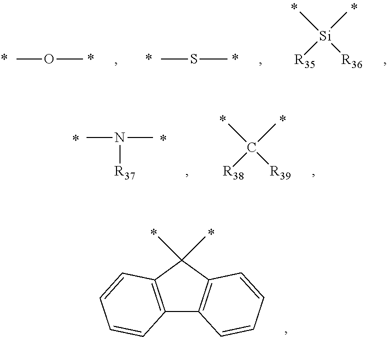

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and el to e4 may each independently be 0 or 1.

In Formula M-b, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring. d1 to d4 may each independently be an integer from 0 to 4.

The compound represented by Formula M-b may be utilized as a blue phosphorescent dopant or a green phosphorescent dopant. The compound represented by Formula M-b may be represented by any one selected from among compounds below. However, the compounds below are merely examples, and the compound represented by Formula M-b is not limited to those represented by the compounds below.

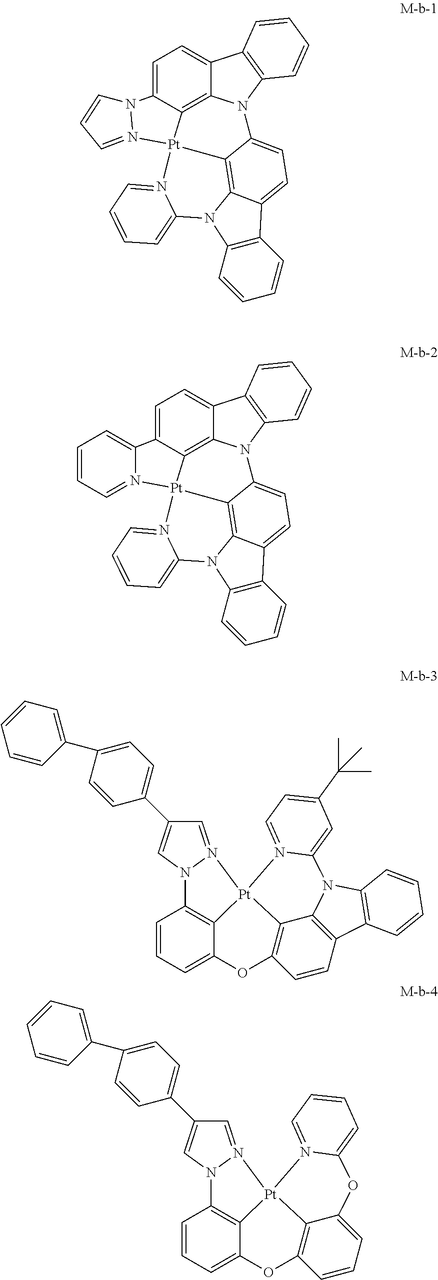

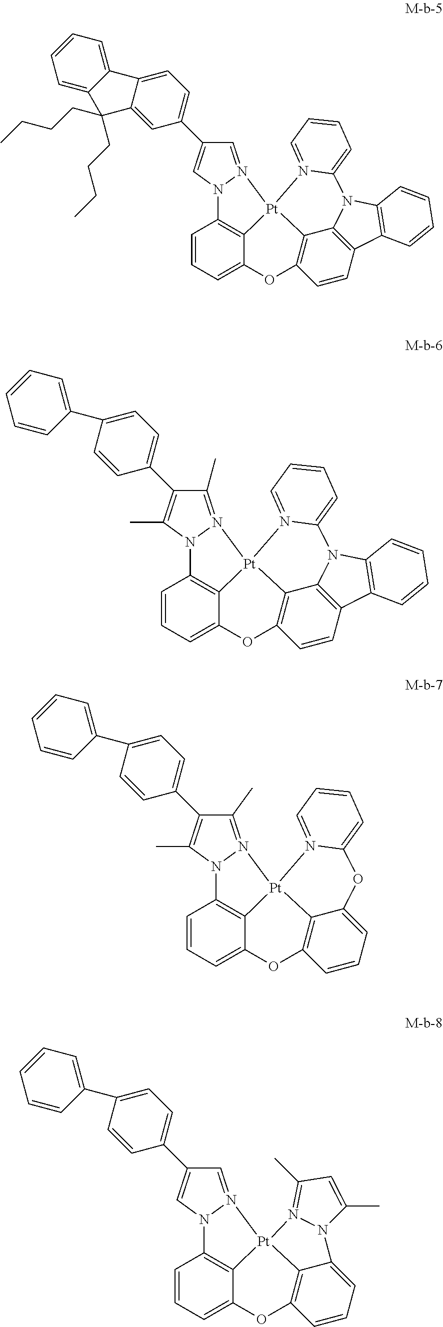

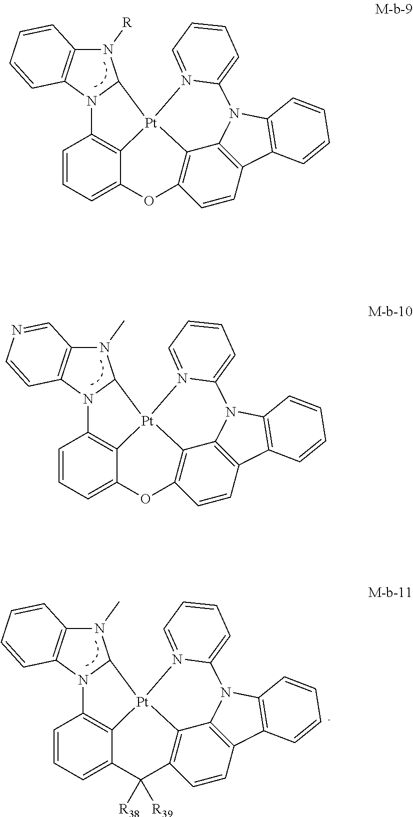

In the compounds above, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML may include a compound represented by any one selected from among Formulas F-a to F-c. The compounds represented by Formulas F-a to F-c may be utilized as a fluorescent dopant material.

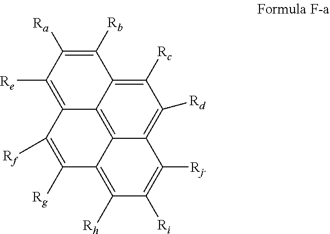

In Formula F-a, two (substituents) selected from among Rₐ to Rⱼ may each independently be substituted with *—NAr₁Ar₂. Each of the reminder of Rₐ to Rⱼ which is not substituted with *—NAr₁Ar₂ may independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

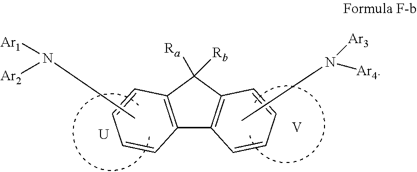

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, and/or linked to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. In Formula F-b, the number of rings represented by U and V may each independently be 0 or 1.

For example, In Formula F-b, when the number of U or V is 1, one ring forms a fused ring in a portion indicated by U or V, and when the number of U or V is 0, it refers to no ring that is indicated by U or V is present (e.g., the ring indicated by U or V does not exist). For example, when the number of U is 0 and the number of V is 1, or when the number of U is 1 and the number of V is 0, a fused ring having a fluorene core of Formula F-b may be a cyclic compound having four rings. In some embodiments, when both (e.g., simultaneously) U and V are each 0, the fused ring of Formula F-b may be a cyclic compound having three rings. In some embodiments, when both (e.g., simultaneously) U and V are each 1, the fused ring having a fluorene core of Formula F-b may be a cyclic compound having five rings.

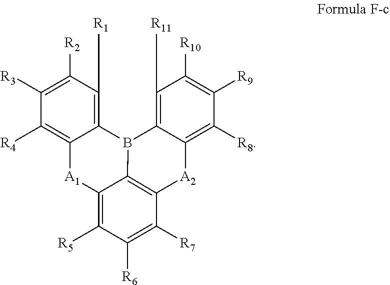

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring.

In Formula F-c, A₁ and A₂ may each independently be bonded to substituents of neighboring rings to form a condensed ring. For example, when A₁ and A₂ may each independently be NRₘ, A₁ may be bonded to R₄ or R₅ to form a ring. In some embodiments, A₂ may be bonded to R₇ or R₈ to form a ring.

The emission layer EML may include, as a generally utilized/generally available dopant material, styryl derivatives (e.g., 1,4-bis[2-(3-N-ethylcarbazolyl)vinyl]benzene (BCzVB), 4-(di-p-tolylamino)-4″-[(di-p-tolylamino)styryl]stilbene (DPAVB), and N-(4-((E)-2-(6-((E) (diphenylamino)styryl)naphthalen-2-yl)vinyl)phenyl)-N-phenylbenzenamine (N-BDAVBi)), perylene and derivatives thereof (e.g., 2,5,8,11-tetra-t-butylperylene (TBP)), pyrene and/or derivatives thereof (e.g., 1,1-dipyrene, 1,4-dipyrenylbenzene, 1,4-bis(N,N-diphenylamino)pyrene), etc.

The emission layer EML may include a generally utilized/generally available phosphorescent dopant material. For example, as a phosphorescent dopant, a metal complex including iridium (Ir), platinum (Pt), osmium (Os), gold (Au), titanium (Ti), zirconium (Zr), hafnium (Hf), europium (Eu), thulium (Tm), and/or terbium (Tb) may be utilized. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), platinum octaethyl porphyrin (PtOEP), etc. may be utilized as a phosphorescent dopant. However, the embodiment of the present disclosure is not limited thereto.

The emission layer EML may include a quantum dot material. The core of a quantum dot may be selected from a Group II-VI compound, a Group III-VI compound, a Group compound, a Group III-V compound, a Group III-II-V compound, a Group IV-VI compound, a Group IV element, a Group IV compound, and one or more combinations thereof.

The Group II-VI compound may be selected from the group including (e.g., consisting of) a binary compound selected from the group including (e.g., consisting of) CdSe, CdTe, CdS, ZnS, ZnSe, ZnTe, ZnO, HgS, HgSe, HgTe, MgSe, MgS, and one or more compounds or mixtures thereof, a ternary compound selected from the group including (e.g., consisting of) CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and one or more compounds or mixtures thereof, and/or a quaternary compound selected from the group including (e.g., consisting of) HgZnTeS, CdZnSeS, CdZnSeTe, CdZnSTe, CdHgSeS, CdHgSeTe, CdHgSTe, HgZnSeS, HgZnSeTe, HgZnSTe, and one or more compounds or mixtures thereof.

The Group III-VI compound may include a binary compound such as In₂S₃ and In₂Se₃, a ternary compound such as InGaS₃ and InGaSe₃, or one or more combinations thereof.

The Group I-III-VI compound may include a ternary compound selected from the group including (e.g., consisting of) AgInS, AgInS₂, CuInS, CuInS₂, AgGaS₂, CuGaS₂ CuGaO₂, AgGaO₂, AgAlO₂, and one or more compounds or mixtures thereof, and/or a quaternary compound such as AgInGaS₂ and CuInGaS₂ (the quaternary compound may be used alone or in combination with any of the foregoing compounds or mixtures; and the quaternary compound may also be combined with other quaternary compounds).

The Group III-V compound may be selected from the group including (e.g., consisting of) a binary compound selected from the group including (e.g., consisting of) GaN, GaP, GaAs, GaSb, AlN, AlP, AlAs, AlSb, InN, InP, InAs, InSb, and one or more compounds or mixtures thereof, a ternary compound selected from the group including (e.g., consisting of) GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and one or more compounds or mixtures thereof, and/or a quaternary compound selected from the group including (e.g., consisting of) GaAlNP, GaAlNAs, GaAlNSb, GaAlPAs, GaAlPSb, GaInNP, GaInNAs, GaInNSb, GaInPAs, GaInPSb, InAlNP, InAINAs, InAlNSb, InAlPAs, InAlPSb, and one or more compounds or mixtures thereof. The Group III-V compound may further include a Group II metal. For example, InZnP, etc. may be selected as a Group III-II-V compound.

The Group IV-VI compound may be selected from the group including (e.g., consisting of) a binary compound selected from the group including (e.g., consisting of) SnS, SnSe, SnTe, PbS, PbSe, PbTe, and one or more compounds or mixtures thereof, a ternary compound selected from the group including (e.g., consisting of) SnSeS, SnSeTe, SnSTe, PbSeS, PbSeTe, PbSTe, SnPbS, SnPbSe, SnPbTe, and one or more compounds or mixtures thereof, and/or a quaternary compound selected from the group including (e.g., consisting of) SnPbSSe, SnPbSeTe, SnPbSTe, and one or more compounds or mixtures thereof. The Group IV element may be selected from the group including (e.g., consisting of) Si, Ge, and one or more elements or mixtures thereof. The Group IV compound may be a binary compound selected from the group including (e.g., consisting of) SiC, SiGe, and one or more compounds or mixtures thereof.

In this embodiment, a binary compound, a ternary compound, or a quaternary compound may be present in a particle form in a substantially uniform concentration distribution, or may be present in substantially the same particle form in a partially different concentration distribution. In some embodiments, a core/shell structure in which one quantum dot surrounds another quantum dot may be present. The core/shell structure may have a concentration gradient in which the concentration of an element present in the shell decreases towards the core.

In some embodiments, a quantum dot may have the core/shell structure including a core having nano-crystals, and a shell around (e.g., surrounding) the core, which are described above. The shell of the quantum dot may serve as a protection layer to prevent or reduce the chemical deformation of the core so as to keep semiconductor properties, and/or a charging layer to impart electrophoresis properties to the quantum dot. The shell may be a single layer or multiple layers. Examples of the shell of the quantum dot may be a metal or non-metal oxide, a semiconductor compound, or one or more combinations thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or a ternary compound such as MgAl₂O₄, CoFe₂O₄, NiFe₂O₄, and/or CoMn₂O₄, but the embodiment of the present disclosure is not limited thereto.

In some embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the embodiment of the present disclosure is not limited thereto.

A quantum dot may have a full width of half maximum (FWHM) of a light emitting wavelength spectrum of about 45 nm or less, about 40 nm or less, or about 30 nm or less, and color purity or color reproducibility may be enhanced in the above ranges. In some embodiments, light emitted through such a quantum dot is emitted in all directions, and thus a wide viewing angle may be improved (increased).

In some embodiments, the form of a quantum dot is not limited as long as it is a form commonly utilized in the art, but for example, a quantum dot in the form of a substantially spherical, pyramidal, multi-arm, or cubic nanoparticles, nanotubes, nanowires, nanofibers, nanoplatelets, etc. may be utilized. The quantum dot may control the colors of emitted light according to the particle size thereof, and thus the quantum dot may have one or more suitable light emission colors such as blue, red, green, etc.

Referring back to FIGS. 3 to 6, the first electrode EL1 has conductivity (e.g., is a conductor). The first electrode EL1 may be formed of a metal material, a metal alloy or a conductive compound. The first electrode EL1 may be an anode or a cathode. However, the embodiment of the present disclosure is not limited thereto. In some embodiments, the first electrode EL1 may be a pixel electrode. The first electrode EU may be a transmissive electrode, a transflective electrode, or a reflective electrode. The first electrode may include at least one selected from among Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, or one or more oxides thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, compounds thereof, or mixtures thereof (e.g., a mixture of Ag and Mg). In some embodiments, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the first electrode EL1 may have a three-layer structure of ITO/Ag/ITO, but is not limited thereto. In some embodiments, the first electrode EU may include the above-described metal materials, a combination of two or more metal materials selected from the above-described metal materials, or oxides of the above-described metal materials, and the embodiment of the present disclosure is not limited thereto. The first electrode EL1 may have a thickness of about 700 Å to about 10000 Å. For example, the first electrode EL1 may have a thickness of 1000 Å to about 3000 Å.

The hole transport region HTR is provided on the first electrode EL1. The hole transport region HTR may include at least one among a hole injection layer HIL, a hole transport layer HTL, a buffer layer, a light emitting auxiliary layer, and an electron blocking layer EBL. The hole transport region HTR may have, for example, a thickness of about 50 Å to about 15000 Å.

The hole transport region HTR may have a single layer formed of a single material, a single layer formed of a plurality of different materials, or a multilayer structure having a plurality of layers formed of a plurality of different materials. For example, the hole transport region HTR may have a single-layer structure formed of the hole injection layer HIL or the hole transport layer HTL, or a single-layer structure formed of a hole injection material or a hole transport material.

For example, the hole transport region HTR may have a single-layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1. However, this is merely an example, and the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1.

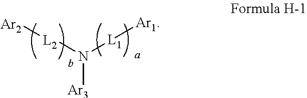

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer from 0 to 10. When a or b is an integer of 2 or greater, a plurality of L₁s and L₂s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may each independently be a substituted or unsubstituted aryl group having 6 to 30 ring-forming carbon atoms.

A compound represented by Formula H-1 may be a monoamine compound. In some embodiments, the compound represented by Formula H-1 may be a diamine compound in which at least one of Ar₁ to Ar₃ includes an amine group as a substituent. In some embodiments, the compound represented by Formula H-1 may be a carbazole-based compound including a substituted or unsubstituted carbazole group in at least one of Ar₁ or Ar₂ or a substituted or unsubstituted fluorene-based group in at least one of Ar₁ or Ar₂.

The compound represented by Formula H-1 may be represented by any one selected from among compounds from Compound Group H. However, the compounds listed in Compound Group H are merely examples, and the compound represented by Formula H-1 is not limited to the those listed in Compound Group H.

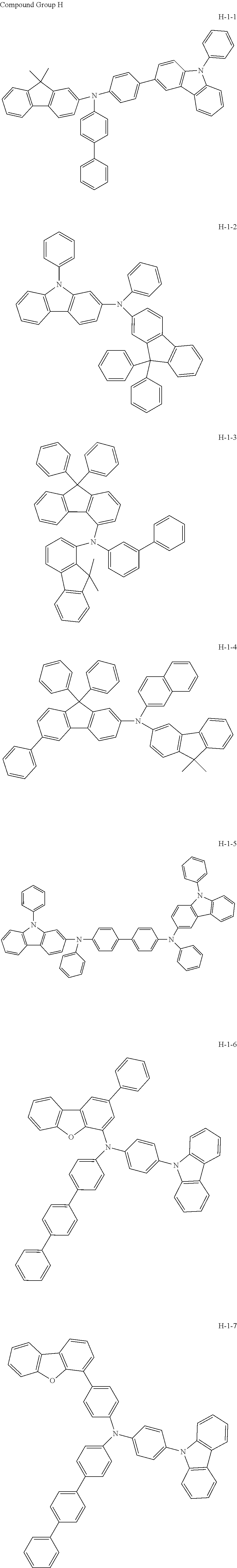

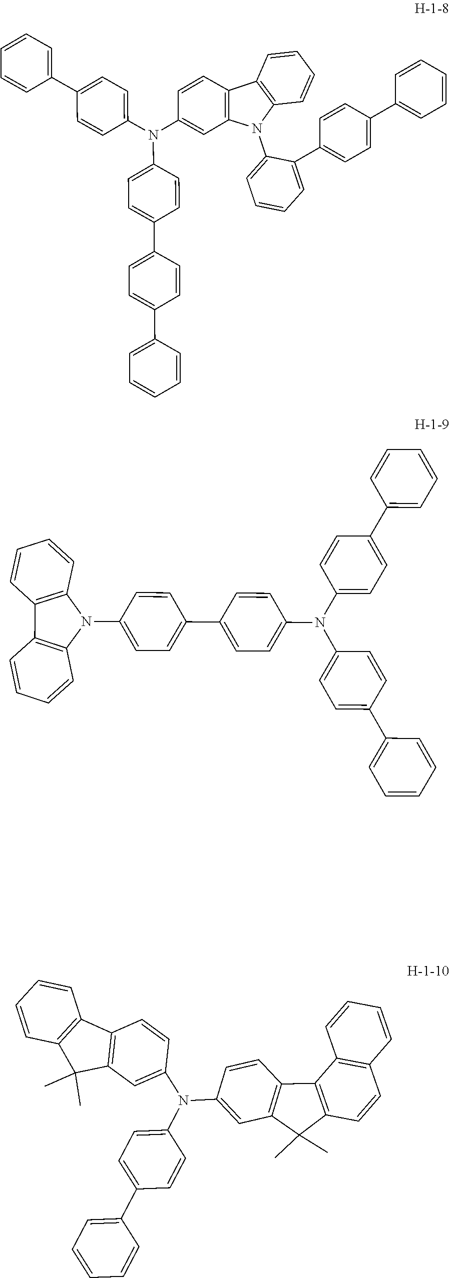 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

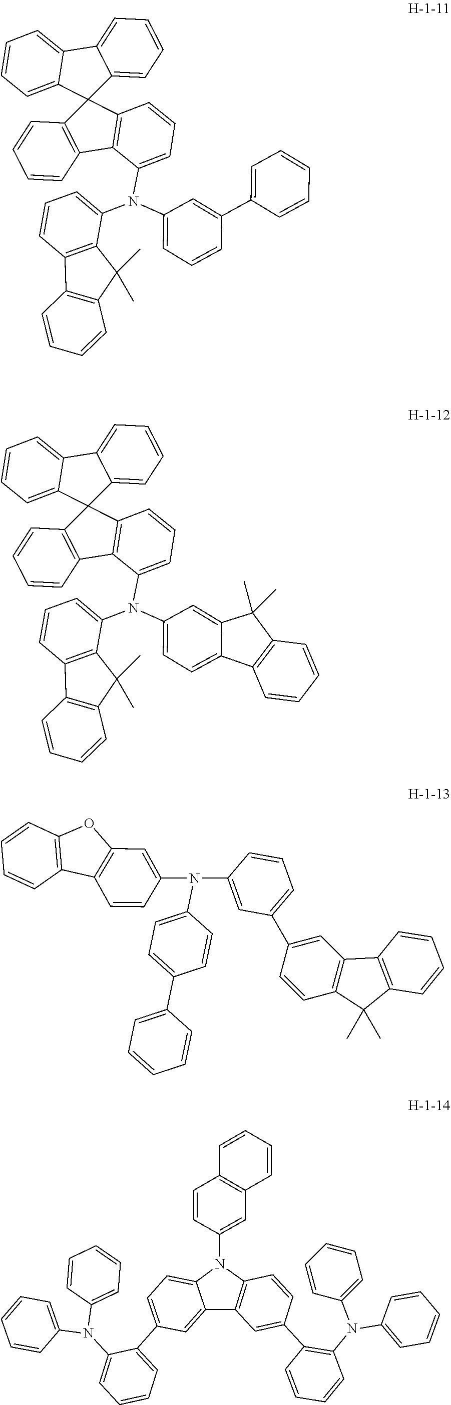 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1]

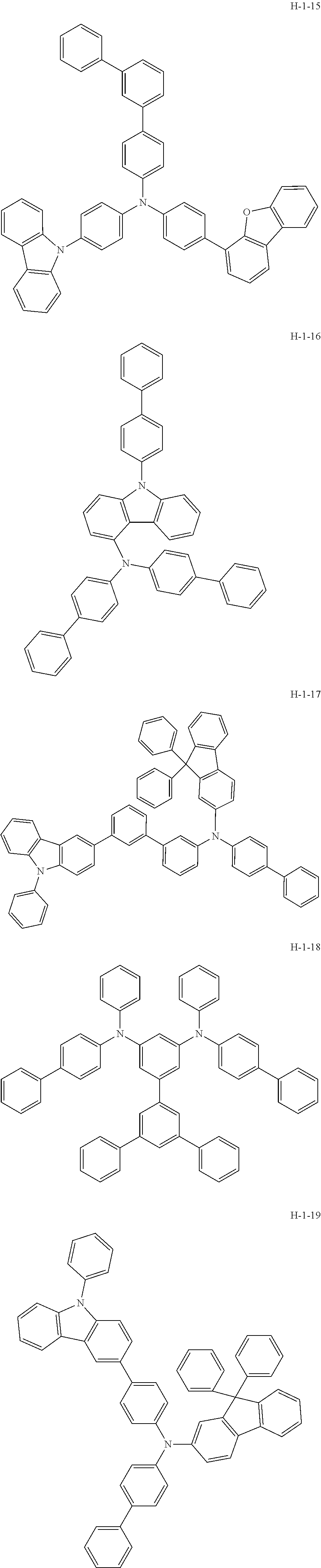

The hole transport region HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/Dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium tetrakis(pentafluorophenyl)borate, dipyrazino[2,3-f: 2′,3′-h] quinoxaline-2,3,6,7,10,11-hexacarbonitrile (HAT-CN), etc.

In some embodiments, the hole transport region HTR may include carbazole-based derivatives such as N-phenyl carbazole and polyvinyl carbazole, fluorene-based derivatives, N,N′-bis(3-methylphenyl)-N,N′-diphenyl-[1,1-biphenyl]-4,4′-diamine (TPD), triphenylamine-based derivatives such as 4,4′,4″-tris(N-carbazolyl)triphenylamine (TCTA), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 9-(4-tert-Butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzenem (DCP) etc.

The hole transport region HTR may include the compounds of the hole transport region described above in at least one selected from among the hole injection layer HIL, the hole transport layer HTL, and the electron blocking layer EBL.

The hole transport region HTR may have a thickness of about 100 Å to about 10000 Å, for example, about 100 Å to about 5000 Å. When the hole transport region HTR includes the hole injection layer HIL, the hole injection layer HIL may have a thickness of, for example, about 30 Å to about 1000 Å. When the hole transport region HTR includes the hole transport layer HTL, the hole transport layer HTL may have a thickness of about 30 Å to about 1000 Å. When the hole transport region HTR includes the electron blocking layer EBL, the electron blocking layer EBL may have a thickness of, for example, about 10 Å to about 1000 Å. When the thicknesses of the hole transport region HTR, the hole injection layer HIL, the hole transport layer HTL, and the electron blocking layer EBL satisfy the above-described ranges, satisfactory (suitable) hole transport properties may be obtained without a substantial increase in driving voltage.

The hole transport region HTR may further include, in addition to the above-described materials, a charge generation material to increase conductivity. The charge generation material may be substantially uniformly or non-uniformly dispersed in the hole transport region HTR. The charge generation material may be, for example, a p-dopant. The p-dopant may include at least one of halogenated metal compounds, quinone derivatives, metal oxides, or cyano group-containing compounds, but is not limited thereto. For example, the p-dopant may include one or more halogenated metal compounds such as CuI and/or RbI, quinone derivatives such as tetracyanoquinodimethane (TCNQ) and/or 2,3,5,6-tetrafluoro-7,7,8,8-tetracyanoquinodimethane (F4-TCNQ), metal oxides such as tungsten oxides and/or molybdenum oxides, cyano group-containing compounds such as dipyrazino[2,3-f: 2′,3′-h] quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but is not limited thereto.

As described above, the hole transport region HTR may further include at least one of a buffer layer or an electron blocking layer EBL in addition to the hole injection layer HIL and the hole transport layer HTL. The buffer layer may compensate for a resonance distance according to wavelengths of light emitted from an emission layer EML, and may thus increase luminous efficiency. Materials which may be included in the hole transport region HTR may be utilized as materials included in the buffer layer. The electron blocking layer EBL is a layer that serves to prevent or reduce electrons from being injected from the electron transport region ETR to the hole transport region HTR.

In the light emitting element ED of an embodiment illustrated in FIGS. 3 to 6, an electron transport region ETR is provided on the emission layer EML. The electron transport region ETR may include at least one selected from among a hole blocking layer HBL, an electron transport layer ETL, and an electron injection layer EIL, but the embodiment of the present disclosure is not limited thereto.

The electron transport region ETR may have a single layer formed of a single material, a single layer formed of a plurality of different materials, or a multilayer structure having a plurality of layers formed of a plurality of different materials.

For example, the electron transport region ETR may have a single layer structure of an electron injection layer EIL or an electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, or a hole blocking layer HBL/electron transport layer ETL/electron injection layer EIL are stacked in order from the emission layer EML, but is not limited thereto. The electron transport region ETR may have a thickness of, for example, about 1000 Å to about 1500 Å.

The electron transport region ETR may be formed utilizing one or more suitable methods such as a vacuum deposition method, a spin coating method, a cast method, a Langmuir-Blodgett (LB) method, an inkjet printing method, a laser printing method, a laser induced thermal imaging (LITI) method, etc.

The electron transport region ETR may include a compound represented by Formula ET-1.

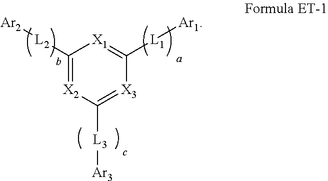

In Formula ET-1, at least one of X₁ to X₃ is N and each of the remainder of X₁ to X₃ (those that are not N) are Crₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are an integer of 2 or greater, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), or one or more compounds or mixtures thereof.

In some embodiments, the electron transport region ETR may include one or more halogenated metals such as LiF, NaCl, CsF, RbCl, RbI, CuI, and/or KI, lanthanide metals such as Yb, co-deposition materials of a halogenated metal and a lanthanide metal. For example, the electron transport region ETR may include KI:Yb, RbI:Yb, LiF:Yb, etc. as a co-deposition material. For the electron transport region ETR, a metal oxide such as Li₂O and/or BaO, or 8-hydroxyl-lithium quinolate (Liq), etc. may be utilized, but the embodiment of the present disclosure is not limited thereto. The electron transport region ETR may also be formed of a mixture material of an electron transport material and an insulating organo-metal salt. The organo-metal salt may be a material having an energy band gap of about 4 eV or greater. For example, the organo-metal salt may include, for example, one or more metal acetates, metal benzoates, metal acetoacetates, metal acetylacetonates, or metal stearates.

The electron transport region ETR may further include, for example, at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the materials described above, but the embodiment of the present disclosure is not limited thereto.

The electron transport region ETR may include one or more of the compounds of the electron transport region described above in at least one selected from among the electron injection layer EIL, the electron transport layer ETL, and the hole blocking layer HBL.

When the electron transport region ETR includes the electron transport layer ETL, the electron transport layer ETL may have a thickness of about 100 Å to about 1000 Å, for example, about 150 Å to about 500 Å. When the thickness of the electron transport layer ETL satisfies the above-described ranges, satisfactory suitable electron transport properties may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described ranges, satisfactory (suitable) electron injection properties may be obtained without a substantial increase in driving voltage.

The second electrode EL2 is provided on the electron transport region ETR. The second electrode EL2 may be a common electrode. The second electrode EL2 may be a cathode or an anode but the embodiment of the present disclosure is not limited thereto. For example, when the first electrode EL1 is an anode, the second electrode EL2 may be a cathode, and when the first electrode EL1 is a cathode, the second electrode EL2 may be an anode. The second electrode EL2 may include at least one selected from Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, or one or more oxides thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or one or more compounds or mixtures thereof (e.g., AgMg, AgYb, or MgYb). In some embodiments, the second electrode EL2 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the second electrode EL2 may include the above-described metal materials, a combination of two or more metal materials selected from the above-described metal materials, or one or more oxides of the above-described metal materials.

The second electrode EL2 may be connected with an auxiliary electrode. When the second electrode EL2 is connected with the auxiliary electrode, the resistance of the second electrode EL2 may decrease.

A capping layer CPL may be further disposed on the second electrode EL2 of the light emitting element ED of an embodiment. The capping layer CPL may include a multilayer or a single layer.

In an embodiment, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiN_{X}, SiOy, etc.

For example, when the capping layer CPL includes an organic material, the organic material may include α-NPD, NPB, TPD, m-MTDATA, Alq₃ CuPc, N4,N4,N4′,N4′-tetra(biphenyl-4-yl) biphenyl-4,4′-diamine (TPD15), 4,4′,4″-tris(carbazol-9-yl)triphenylamine (TCTA), etc., or may include epoxy resins or acrylates such as methacrylates. However, the embodiment of the present disclosure is not limited thereto, and the capping layer CPL may include, for example, one or more compounds P1 to P5.

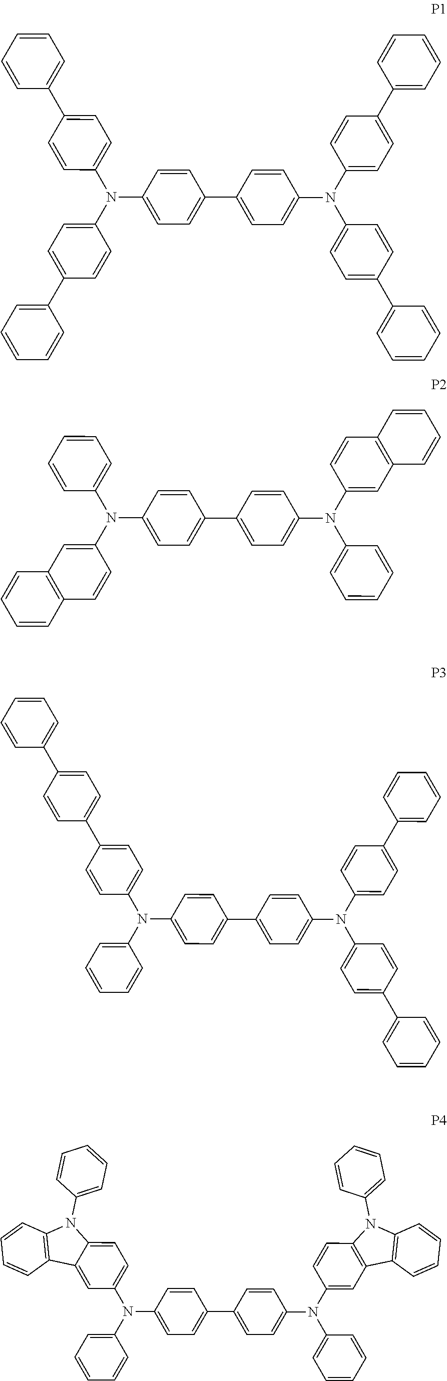 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

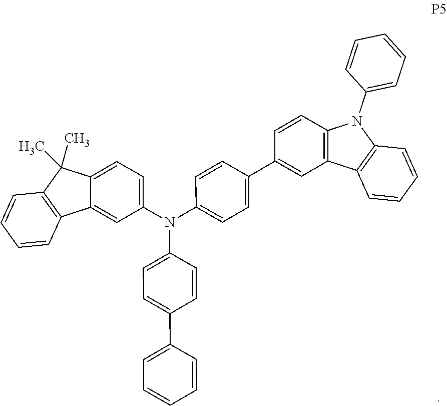 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The capping layer CPL may have a refractive index of about 1.6 or greater. For example, the capping layer CPL may have a refractive index of about 1.6 or greater in a wavelength range of about 550 nm to about 660 nm.

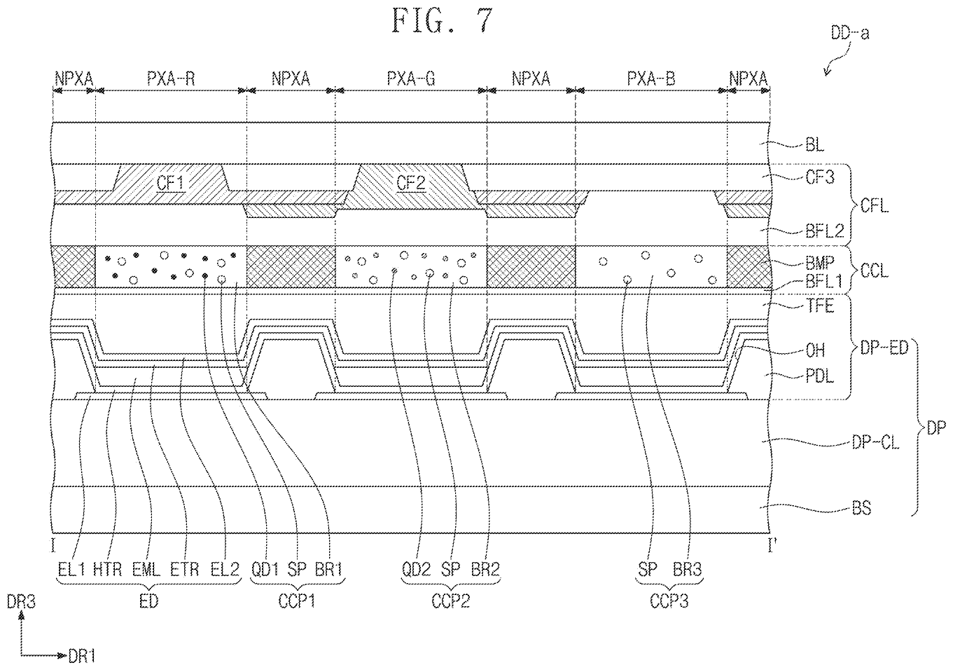

FIGS. 7 to 10 are each a cross-sectional view of a display device according to an embodiment. Hereinafter, in the description of the display device according to an embodiment with reference to FIGS. 7 and 10, content (e.g., amount) overlapping the one described above with reference to FIGS. 1 to 6 may not be described again, and the differences will primarily be described.

Referring to FIG. 7, a display device DD according to an embodiment may include a display panel DP having a display element layer DP-ED, a light control layer CCL on the display panel DP, and a color filter layer CFL. In an embodiment shown in FIG. 7, the display panel DP may include a base layer BS, a circuit layer DP-CL provided on the base layer BS, and a display element layer DP-ED, and the display element layer DP-ED may include a light emitting element ED.

The light emitting element ED may include a first electrode EL1, a hole transport region HTR on the first electrode EL1, an emission layer EML on the hole transport region HTR, an electron transport region ETR on the emission layer EML, and a second electrode EL2 on the electron transport region ETR. A structure of the light emitting element ED shown in FIG. 7 may be the same as the structure of the light emitting element of FIGS. 3 to 6 described above.

Referring to FIG. 7, the emission layer EML may be disposed in the openings OH defined in the pixel defining films PDL. For example, the emission layer EML separated by the pixel defining films PDL and provided corresponding to each of light emitting regions PXA-R, PXA-G, and PXA-B may emit light in substantially the same wavelength ranges. In the display device DD of an embodiment, the emission layer EML may emit blue light. In an embodiment, the emission layer EML may be provided as a common layer throughout the light emitting regions PXA-R, PXA-G, and PXA-B.

The light control layer CCL may be on the display panel DP. The light control layer CCL may include a photoconverter. The photoconverter may be a quantum dot or a phosphor. The photoconverter may convert the wavelength of received light, and emit the resulting light. For example, the light control layer CCL may be a layer containing one or more quantum dots or phosphors.

The light control layer CCL may include a plurality of light control units CCP1, CCP2, and CCP3. The light control units CCP1, CCP2, and CCP3 may be spaced apart from (separated from) each other.

Referring to FIG. 7, a division pattern BMP may be disposed between the light control units CCP1, CCP2, and CCP3 spaced apart from (separated from) each other, but the embodiment of the present disclosure is not limited thereto. In FIG. 7, the division pattern BMP is shown to not overlap the light control units CCP1, CCP2, and CCP3, but edges of the light control units CCP1, CCP2, and CCP3 may overlap at least a portion of the division pattern BMP.

The light control layer CCL may include a first light control unit CCP1 including a first quantum dot QD1 for converting first color light provided from the light emitting element ED into second color light, a second light control unit CCP2 including a second quantum dot QD2 for converting the first color light into third color light, and a third light control unit CCP3 transmitting the first color light.

In an embodiment, the first light control unit CCP1 may provide red light, which is the second color light, and the second light control unit CCP2 may provide green light, which is the third color light. The third light control unit CCP3 may transmit and provide blue light, which is the first color light provided from the light emitting element ED. For example, the first quantum dot QD1 may be a red quantum dot and the second quantum dot QD2 may be a green quantum dot. The same descriptions above may be applied to the quantum dots QD1 and QD2.

In some embodiments, the light control layer CCL may further include scatterers SP. The first light control unit CCP1 may include the first quantum dot QD1 and the scatterers SP, the second light control unit CCP2 may include the second quantum dot QD2 and the scatterers SP, and the third light control unit CCP3 may not include (e.g., may exclude) any quantum dot but may still include the scatterers SP.

The scatterers SP may be inorganic particles. For example, the scatterers SP may include at least one selected from among TiO₂, ZnO, Al₂O₃, SiO₂, and hollow silica. The scatterers SP may include any one selected from among TiO₂, ZnO, Al₂O₃, SiO₂, and hollow silica, or may be a mixture of two or more materials selected from among TiO₂, ZnO, Al₂O₃, SiO₂, and hollow silica.

The first light control unit CCP1, the second light control unit CCP2, and the third light control unit CCP3 may include base resins BR1, BR2, and BR3 for dispersing the quantum dots QD1 and QD2 and the scatterers SP. In an embodiment, the first light control unit CCP1 may include the first quantum dot QD1 and the scatterers SP dispersed in the first base resin BR1, the second light control unit CCP2 may include the second quantum dot QD2 and the scatterers SP dispersed in the second base resin BR2, and the third light control unit CCP3 may include the scatterers SP dispersed in the third base resin BR3.

The base resins BR1, BR2, and BR3 are a medium in which the quantum dots QD1 and QD2 and the scatterers SP are dispersed, and may be formed of one or more suitable resin compositions, which may be generally referred to as a binder. For example, the base resins BR1, BR2, and BR3 may be an acrylic-based resin, a urethane-based resin, a silicone-based resin, an epoxy-based resin, etc. The base resins BR1, BR2, and BR3 may be a transparent resin. In an embodiment, the first base resin BR1, the second base resin BR2, and the third base resin BR3 may each be the same as or different from each other.

The light control layer CCL may include a barrier layer BFL1. The barrier layer BFL1 may serve to prevent or reduce moisture and/or oxygen (hereinafter referred to as “moisture/oxygen”) from being introduced. The barrier layer BFL1 may prevent or reduce the light control units CCP1, CCP2, and CCP3 from being exposed to moisture/oxygen. The barrier layer BFL1 may cover the light control units CCP1, CCP2, and CCP3. In some embodiments, a barrier layer BFL2 may be provided between the light control units CCP1, CCP2, and CCP3 and the color filter layer CFL.

The barrier layers BFL1 and BFL2 may include at least one inorganic layer. For example, the barrier layers BFL1 and BFL2 may be formed of an inorganic material. For example, the barrier layers BFL1 and BFL2 may be formed including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film in which light transmittance is secured, etc. The barrier layers BFL1 and BFL2 may further include an organic film. The barrier layers BFL1 and BFL2 may be formed of a single layer or a plurality of layers.

In the display device DD of an embodiment, the color filter layer CFL may be on the light control layer CCL. For example, the color filter layer CFL may be directly on the light control layer CCL. In this embodiment, the barrier layer BFL2 may not be provided.

The color filter layer CFL may include filters CF1, CF2, and CF3. For example, the color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. The filters CF1, CF2, and CF3 may each include a polymer photosensitive resin, a pigment or a dye. The first filter CF1 may include a red pigment and/or a red dye, the second filter CF2 may include a green pigment and/or a green dye, and the third filter CF3 may include a blue pigment and/or a blue dye. The embodiment of the present disclosure is not limited thereto, and the third filter CF3 may not include (e.g., may exclude) any pigment or dye. The third filter CF3 may include a polymer photosensitive resin, but not include any pigment or dye. The third filter CF3 may be transparent. The third filter CF3 may be formed of a transparent photosensitive resin.

In some embodiments, the first filter CF1 and the second filter CF2 may be yellow filters. The first filter CF1 and the second filter CF2 may not be separated from each other and may be provided as a single body.

The first to third filters CF1, CF2, and CF3 may be disposed corresponding to the red light emitting region PXA-R, the green light emitting region PXA-G, and the blue light emitting region PXA-B, respectively.

The color filter layer CFL may further include a light blocking unit. The light blocking unit may be a black matrix. The light blocking unit may be formed including an organic light blocking material or an inorganic light blocking material, both (e.g., simultaneously) including a black pigment and/or a black dye. The light blocking unit may prevent or reduce light leakage, and separate boundaries between the adjacent filters CF1, CF2, and CF3.

The base substrate BL may be on the color filter layer CFL. The base substrate BL may be a member providing a base surface on which the color filter layer CFL and the light control layer CCL are disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, the base substrate BL may not be provided.

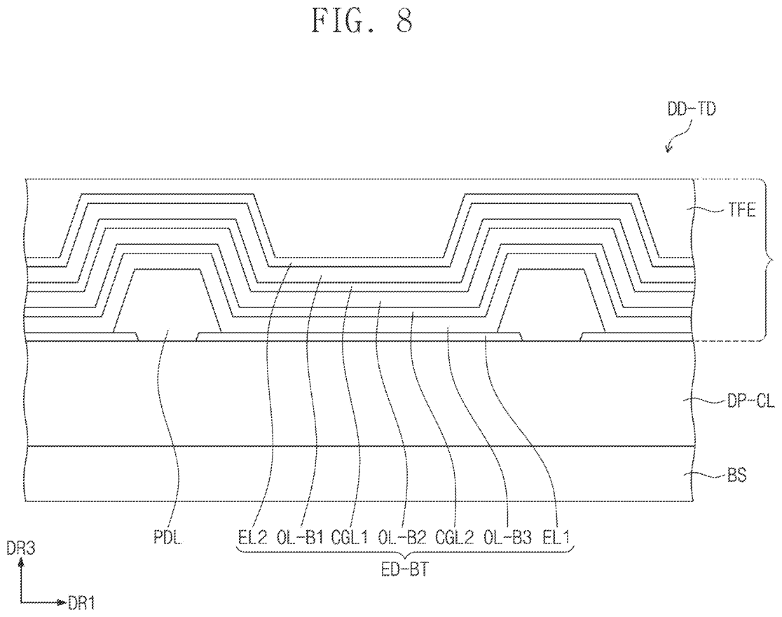

FIG. 8 is a cross-sectional view showing a portion of a display device according to an embodiment. FIG. 8 shows a cross-sectional view of a portion corresponding to the display panel DP of FIG. 7. In a display device DD-TD of an embodiment, a light emitting element ED-BT may include a plurality of light emitting structures OL-B1, OL-B2, and OL-B3. The light emitting element ED-BT may include the first electrode EU and the second electrode EL2 facing each other, and the plurality of light emitting structures OL-B1, OL-B2, and OL-B3 provided by being sequentially stacked in a thickness direction between the first electrode EL1 and the second electrode EL2. At least one of the light emitting structures selected from among OL-B1, OL-B2, and OL-B3 shown in FIG. 8 may include a polycyclic compound according to an embodiment.

The light emitting structures OL-B1, OL-B2, and OL-B3 each may include the emission layer EML (FIG. 7), a hole transport region HTR and an electron transport region ETR disposed with the emission layer EML (FIG. 7) therebetween. For example, the light emitting element ED-BT included in the display device DD-TD of an embodiment may be a light emitting element having a tandem structure including a plurality of emission layers.

In an embodiment illustrated in FIG. 8, light emitted from each of the light emitting structures (e.g., OL-B1, OL-B2, and/or OL-B3) may all be blue light emitting structures (e.g., may each emit light in the blue wavelength range). However, the embodiment of the present disclosure is not limited thereto, and wavelength ranges of light emitted from each of the light emitting structures OL-B1, OL-B2, and/or OL-B3 may be different from each other. For example, the light emitting element ED-BT including the plurality of light emitting structures OL-B1, OL-B2, and OL-B3 emitting light (e.g., light beams) in different wavelength ranges may emit white light (e.g., a combined white light).

Charge generation layers CGL1 and CGL2 may be disposed between neighboring light emitting structures OL-B1, OL-B2, and OL-B3. The charge generation layers CGL1 and CGL2 may include a p-type or kind charge generation layer (e.g., P-charge generation layer) and/or an n-type or kind charge generation layer (e.g., N-charge generation layer).

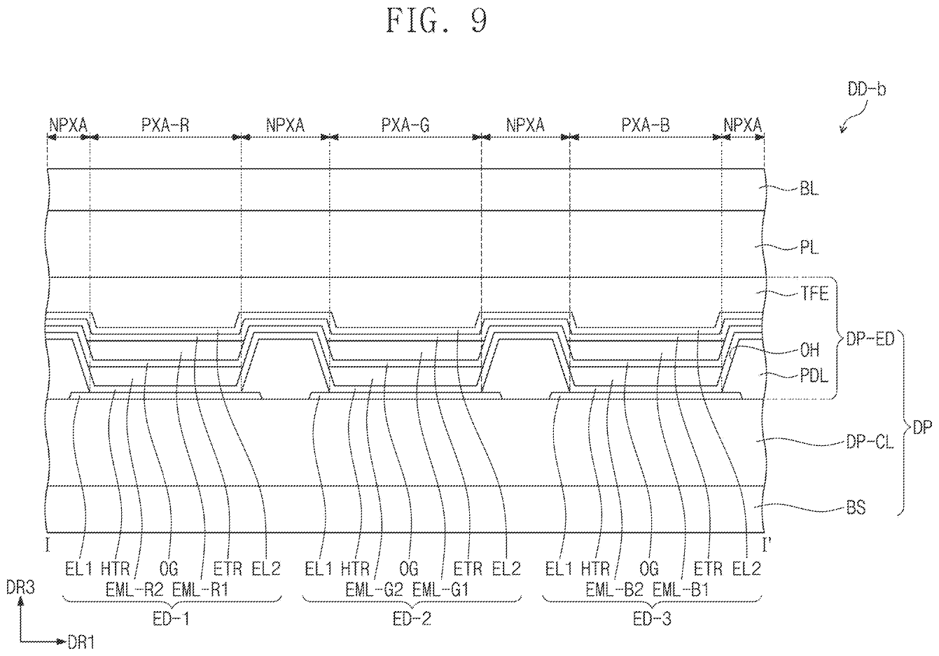

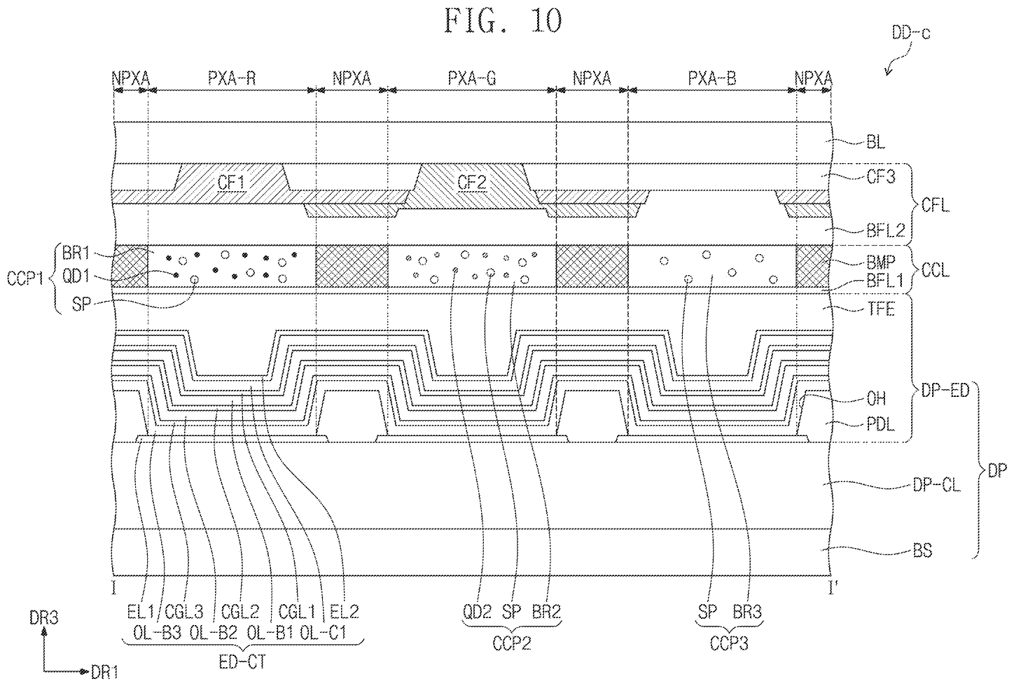

Referring to FIG. 9, a display device DD-b according to an embodiment may include light emitting elements ED-1, ED-2, and ED-3 in which two emission layers are stacked. Compared to the display device DD according to an embodiment shown in FIG. 2, the difference is that in an embodiment shown in FIG. 9, the first to third light emitting elements ED-1, ED-2, and ED-3 each include two emission layers stacked in a thickness direction. In each of the first to third light emitting elements ED-1, ED-2, and ED-3, the two emission layers may emit (may each) light in substantially the same wavelength range.

At least one of the first to third light emitting elements selected from among ED-1, ED-2, and ED-3 shown in FIG. 9 may include a polycyclic compound according to an embodiment. The first light emitting element ED-1 may include a first red emission layer EML-R1 and a second red emission layer EML-R2. The second light emitting element ED-2 may include a first green emission layer EML-G1 and a second green emission layer EML-G2. In some embodiments, the third light emitting element ED-3 may include a first blue emission layer EML-B1 and a second blue emission layer EML-B2. A light emitting auxiliary portion OG may be between the first red emission layer EML-R1 and the second red emission layer EML-R2 (along the thickness direction), between the first green emission layer EML-G1 and the second green emission layer EML-G2, and between the first blue emission layer EML-B1 and the second blue emission layer EML-B2.

The light emitting auxiliary portion OG may include a single layer or multiple layers. The light emitting auxiliary portion OG may include a charge generation layer. For example, the light emitting auxiliary portion OG may include an electron transport region, a charge generation layer, and a hole transport region that are sequentially stacked. The light emitting auxiliary portion OG may be provided as a common layer throughout the first to third light emitting elements ED-1, ED-2, and ED-3. However, the embodiment of the present disclosure is not limited thereto, and the light emitting auxiliary portion OG may be provided to be patterned inside the openings OH defined in the pixel defining films PDL.

The first red emission layer EML-R1, the first green emission layer EML-G1, and the first blue emission layer EML-B1 may be between the hole transport region HTR and the emission auxiliary portion OG. The second red emission layer EML-R2, the second green emission layer EML-G2, and the second blue emission layer EML-B2 may be between the emission auxiliary portion OG and the electron transport region ETR.

For example, the light emitting element ED-1 may include the first electrode EL1, the hole transport region HTR, the second red emission layer EML-R2, the emission auxiliary portion OG, the first red emission layer EML-R1, the electron transport region ETR, and the second electrode EL2, which are sequentially stacked (in the stated order). The second light emitting element ED-2 may include the first electrode EL1, the hole transport region HTR, the second green emission layer EML-G2, the emission auxiliary portion OG, the first green emission layer EML-G1, the electron transport region ETR, and the second electrode EL2, which are sequentially stacked. The third light emitting element ED-3 may include the first electrode EL1, the hole transport region HTR, the second blue emission layer EML-B2, the emission auxiliary portion OG, the first blue emission layer EML-B1, the electron transport region ETR, and the second electrode EL2, which are sequentially stacked.

An optical auxiliary layer PL may be on the display element layer DP-ED. The optical auxiliary layer PL may include a polarizing layer. The optical auxiliary layer PL may be on the display panel DP to control reflected light in the display panel DP due to external light. In some embodiments, the optical auxiliary layer PL may not be provided in the display device according to an embodiment.

Unlike FIGS. 8 and 9, the display device DD-c of FIG. 10 is illustrated to include four light emitting structures OL-B1, OL-B2, OL-B3, and OL-C1. The light emitting element ED-BT may include the first electrode EL1 and the second electrode EL2 facing each other, and the first to fourth light emitting structures OL-B1, OL-B2, OL-B3, and OL-C1 sequentially stacked in a thickness direction between the first electrode EL1 and the second electrode EL2. At least one of the first to fourth light emitting structures selected from among OL-B1, OL-B2, OL-B3, and OL-C1 may include a polycyclic compound according to an embodiment.

Among the four light emitting structures, the first to third light emitting structures OL-B1, OL-B2, and OL-B3 may emit blue light, and the fourth light emitting structure OL-C1 may emit green light. However, the embodiment of the present disclosure is not limited thereto, and the first to fourth light emitting structures OL-B1, OL-B2, OL-B3, and OL-C1 may emit light having different wavelength ranges.

Charge generation layers CGL1, CGL2, and CGL3 may be disposed between the first to fourth light emitting structures OL-B1, OL-B2, OL-B3, and OL-C1 (respectively). The charge generation layers CGL1, CGL2 and CGL3 disposed between the neighboring light emitting structures OL-B1, OL-B2, OL-B3, and OL-C1 may include a p-type or kind charge generation layer and/or an n-type or kind charge generation layer.

Hereinafter, with reference to Examples and Comparative Examples, a polycyclic compound and a light emitting element according to an embodiment of the present disclosure will be described in more detail. The Examples shown below are merely examples to assist in the understanding of the present disclosure, and the scope of the present disclosure is not limited thereto.

### Examples

### 1. Synthesis of Polycyclic Compounds of Examples

First, a process of synthesizing polycyclic compounds according to an embodiment of the present disclosure will be described in more detail by presenting a process of synthesizing each of Compounds, 12, 15, 22, 37, 53, 70, 80, 87, and 90 as an example. A process of synthesizing polycyclic compound(s), which will be described hereinafter, is provided merely as an example, and thus a process of synthesizing compound(s) according to an embodiment of the present disclosure is not limited to the Examples below.

### (1) Synthesis of Compound 12

Polycyclic Compound 12 according to an embodiment may be synthesized by, for example, a process of Reaction Formula 1.

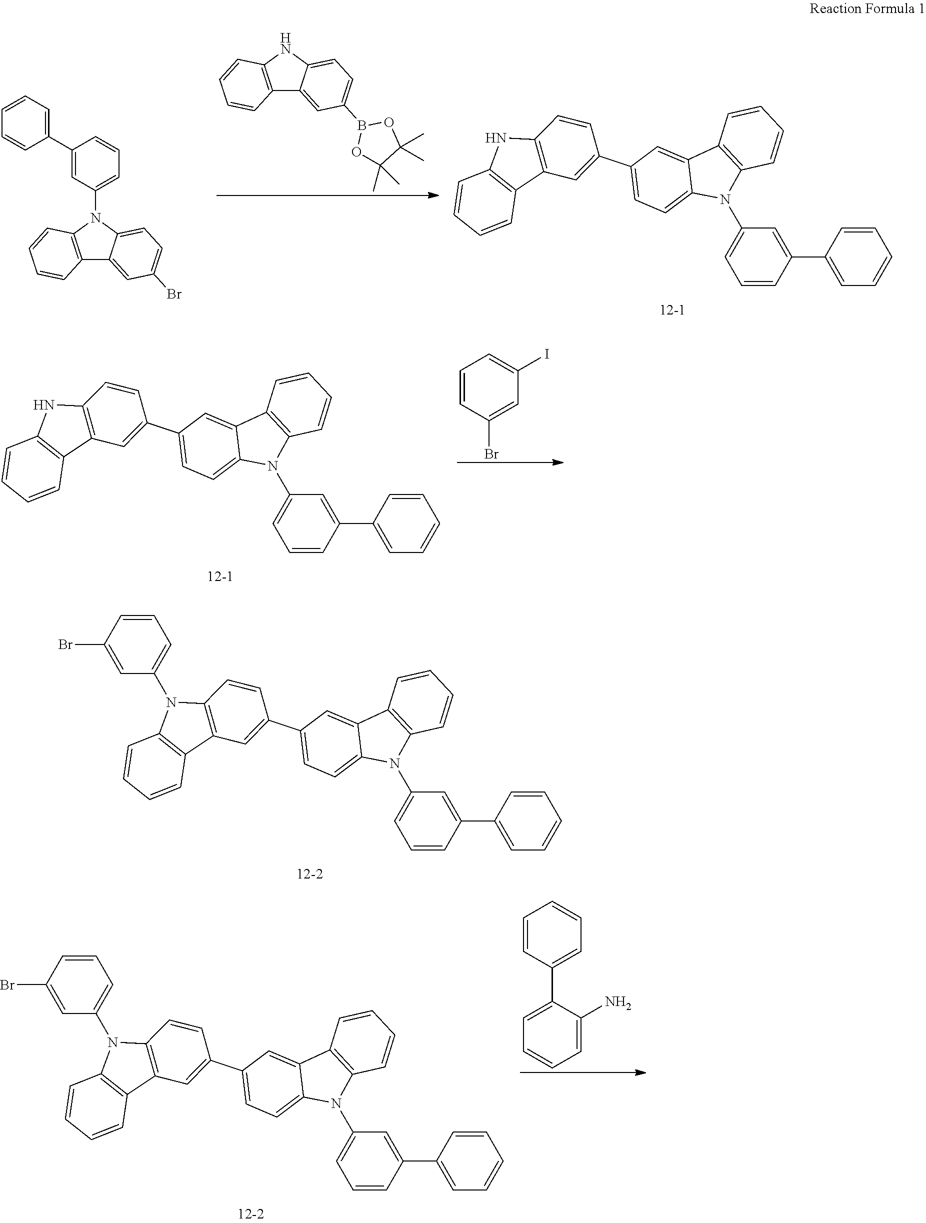

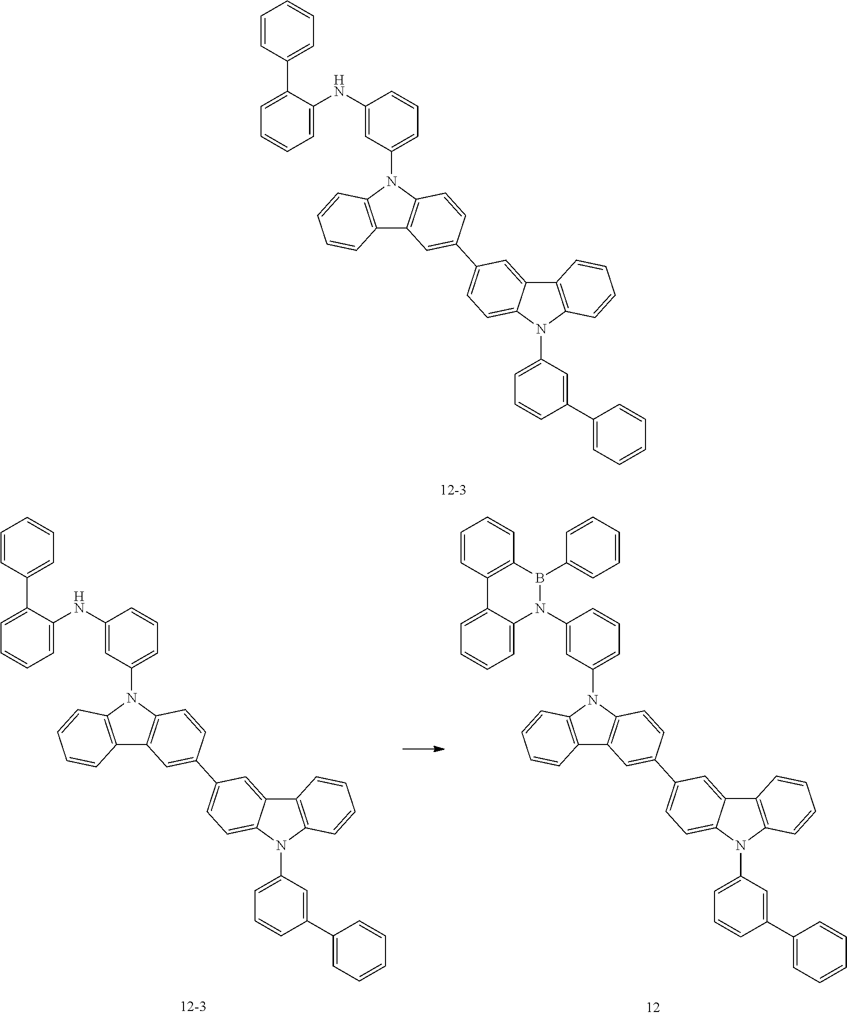 [SMILES: c1ccc(-c2cccc(-n3c4ccccc4c4cc(-c5ccc6c(c5)c5ccccc5n6-c5cccc(Nc6ccccc6-c6ccccc6)c5)ccc43)c2)cc1 ; c1ccc(-c2cccc(-n3c4ccccc4c4cc(-c5ccc6c(c5)c5ccccc5n6-c5cccc(Nc6ccccc6-c6ccccc6)c5)ccc43)c2)cc1 ; c1ccc(B2c3ccccc3-c3ccccc3N2c2cccc(-n3c4ccccc4c4cc(-c5ccc6c(c5)c5ccccc5n6-c5cccc(-c6ccccc6)c5)ccc43)c2)cc1]

### Synthesis of Intermediate 12-1

9-([1,1′-biphenyl]-3-yl0-3-bromo-9H-carbazole (CAS No.=1428551-28-3) and 3-(4,4,5,5-tetramethyl-1,3,2-dioxaborolane-2-yl)-9H-carbazole (CAS No.=855738-89-5) were subjected to reaction under Pd catalyst conditions to obtain Intermediate 12-1. The M+1 peak value was confirmed for Intermediate 12-1 through liquid chromatography-mass spectrometry (LC-MS). C₃₆H₂₄N₂: M+1 485.18

### Synthesis of Intermediate 12-2

Intermediate 12-1 and 1-bromo-3-iodobenzene (CAS No.=591-18-4) were subjected to reaction under Cu catalyst conditions to obtain Intermediate 12-2. The M+1 peak value was confirmed for Intermediate 12-2 through liquid chromatography-mass spectrometry (LC-MS). C₄₂H₂₇BrN₂: M+1 639.15

### Synthesis of Intermediate 12-3

Intermediate 12-2 and (1,1′-biphenyl)-2-amine (CAS No.=90-41-5) were subjected to reaction under Pd catalyst conditions to obtain Intermediate 12-3. The M+1 peak value was confirmed for Intermediate 12-3 through liquid chromatography-mass spectrometry (LC-MS). C₅₄H₃₇N₃: M+1 728.30

### Synthesis of Compound 12

Intermediate 12-3 (6 g) and triethylamine (7 mL) were dissolved in 1,2-dichlorobenzene (40 mL) in a reaction vessel, and the mixture was stirred at room temperature while dichlorophenylborane (3.3 mL) was slowly added dropwise. After the dropwise addition, the mixture was stirred at 180° C. for 24 hours. When the reaction was completed, the reaction solution was extracted with dichloromethane, the collected organic layer was dried over magnesium sulfate, and the residue obtained after evaporating the solvent was recrystallized utilizing toluene and n-hexane to obtain Compound 12 (2.3 g, yield: 35%). Compound 12 was confirmed through LC-MS and ¹H-NMR.

### (2) Synthesis of Compound 15

Polycyclic Compound 15 according to an embodiment may be synthesized by, for example, a process of Reaction Formula 2.

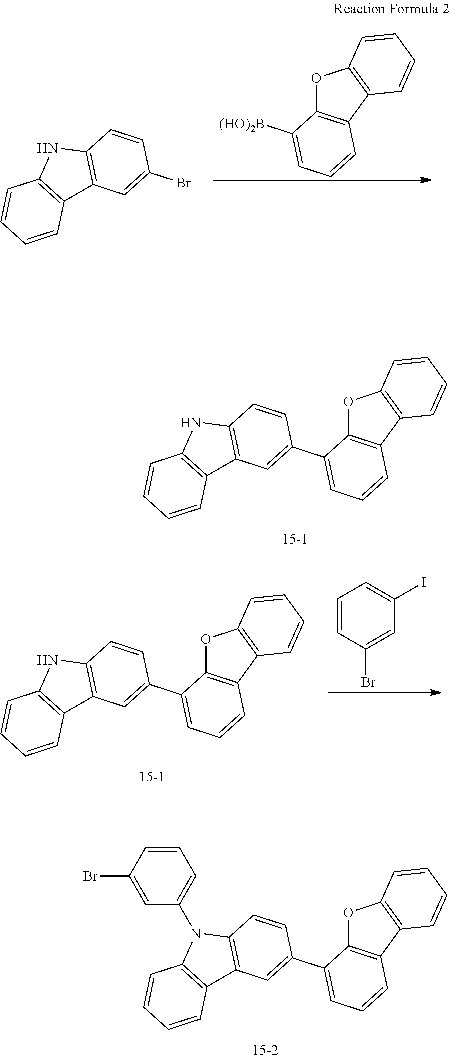

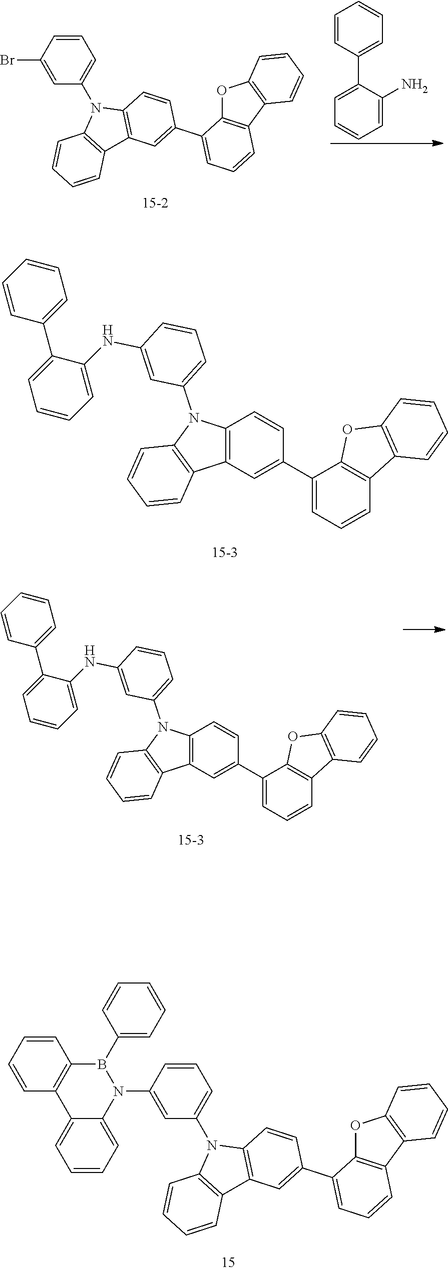

### Synthesis of Intermediate 15-1

3-bromo-9H-carbazole (CAS No.=1592-95-6) and dibenzofuran-4-ylboronic acid (CAS No.=100124-06-9) were subjected to reaction under Pd catalyst conditions to obtain Intermediate 15-1. The M+1 peak value was confirmed for Intermediate 15-1 through liquid chromatography-mass spectrometry (LC-MS). C24H15NO: M+1 334.11

### Synthesis of Intermediate 15-2

Intermediate 15-2 was synthesized in substantially the same manner as in the synthesis of Intermediate 12-2, except that Intermediate 15-1 was utilized instead of Intermediate 12-2. The M+1 peak value was confirmed for Intermediate 15-2 through liquid chromatography-mass spectrometry (LC-MS). C₃₀H₁₈BrNO: M+1 488.04

### Synthesis of Intermediate 15-3

Intermediate 15-3 was synthesized in substantially the same manner as in the synthesis of Intermediate 12-3, except that Intermediate 15-2 was utilized instead of Intermediate 12-2. The M+1 peak value was confirmed for Intermediate 15-3 through liquid chromatography-mass spectrometry (LC-MS). C₄₂H₂₈N₂O: M+1 577.21

### Synthesis of Compound 15

Compound 15 was synthesized in substantially the same manner as in the synthesis of Compound 12, except that Intermediate 15-3 was utilized instead of Intermediate 12-3. Compound 15 (2.2 g, yield: 38%) was obtained. Compound 15 was confirmed through LC-MS and ¹H-NMR.

### (3) Synthesis of Compound 22

Polycyclic Compound 22 according to an embodiment may be synthesized by, for example, processes of Reaction Formulas 3-1 and 3-2.

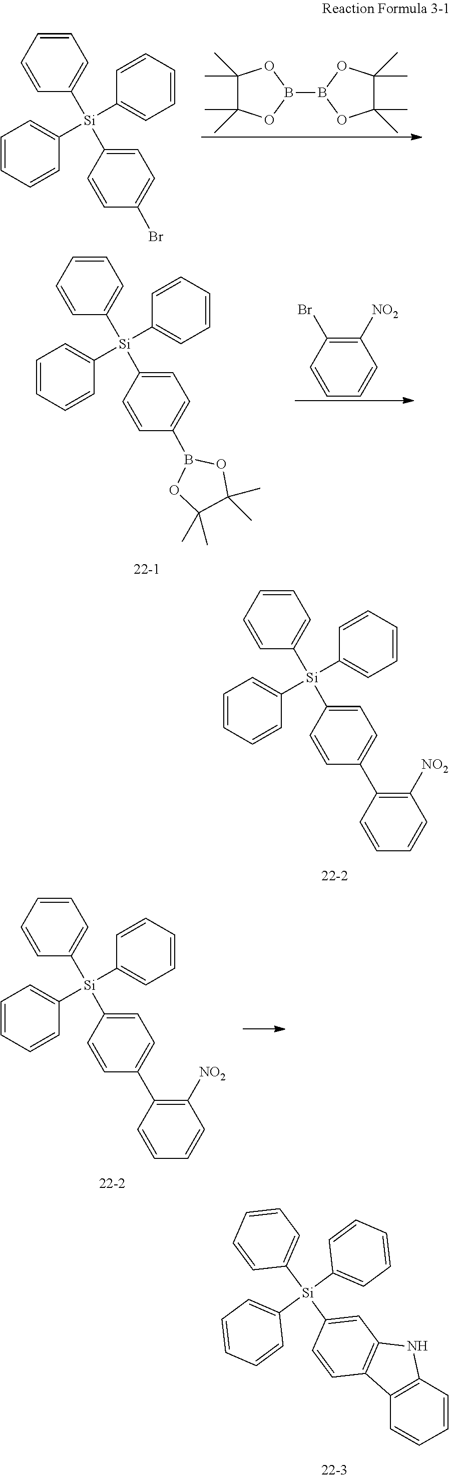

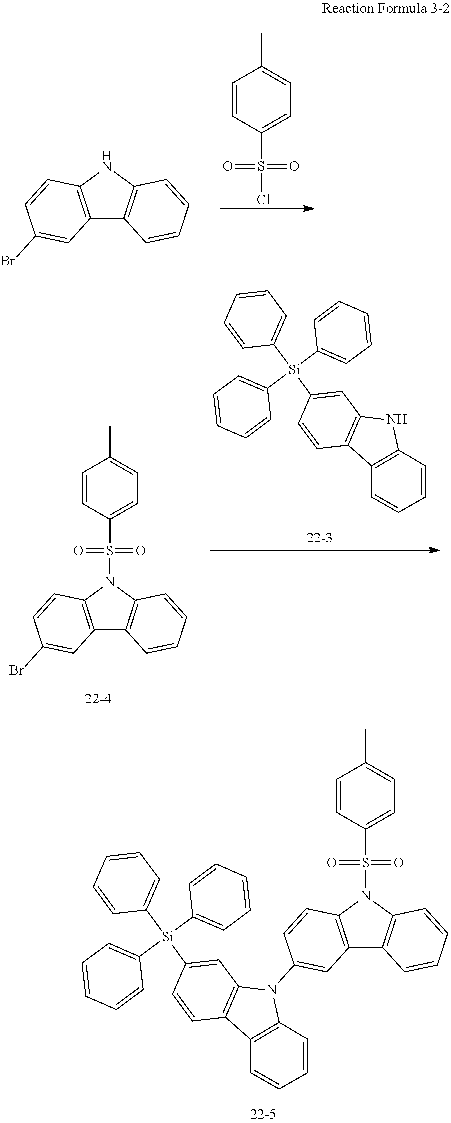 [SMILES: Brc1ccc2[nH]c3ccccc3c2c1 ; Cc1ccc(S(=O)(=O)Cl)cc1 ; Cc1ccc(S(=O)(=O)n2c3ccccc3c3cc(Br)ccc32)cc1 ; c1ccc([Si](c2ccccc2)(c2ccccc2)c2ccc3c(c2)[nH]c2ccccc23)cc1 ; Cc1ccc(S(=O)(=O)n2c3ccccc3c3cc(-n4c5ccccc5c5ccc([Si](c6ccccc6)(c6ccccc6)c6ccccc6)cc54)ccc32)cc1]

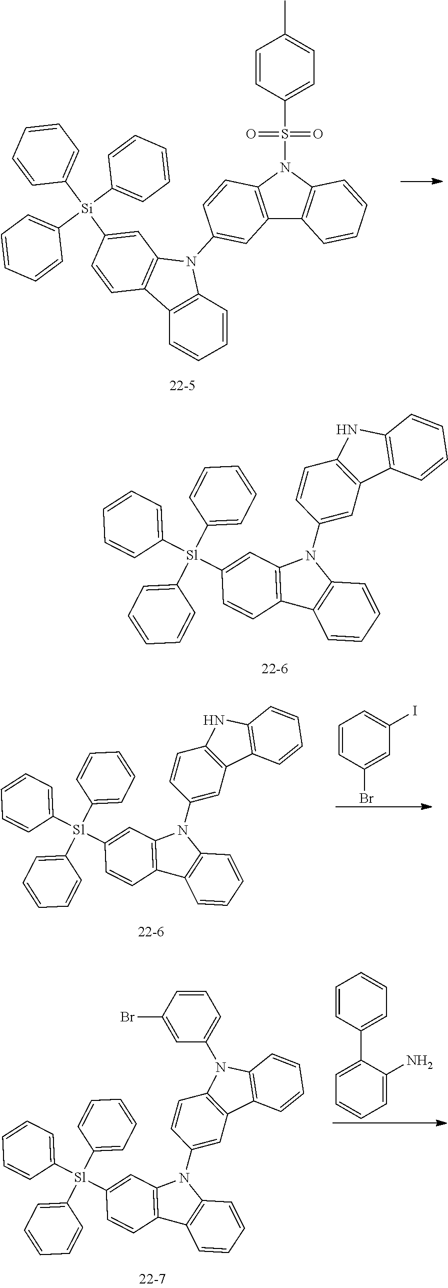

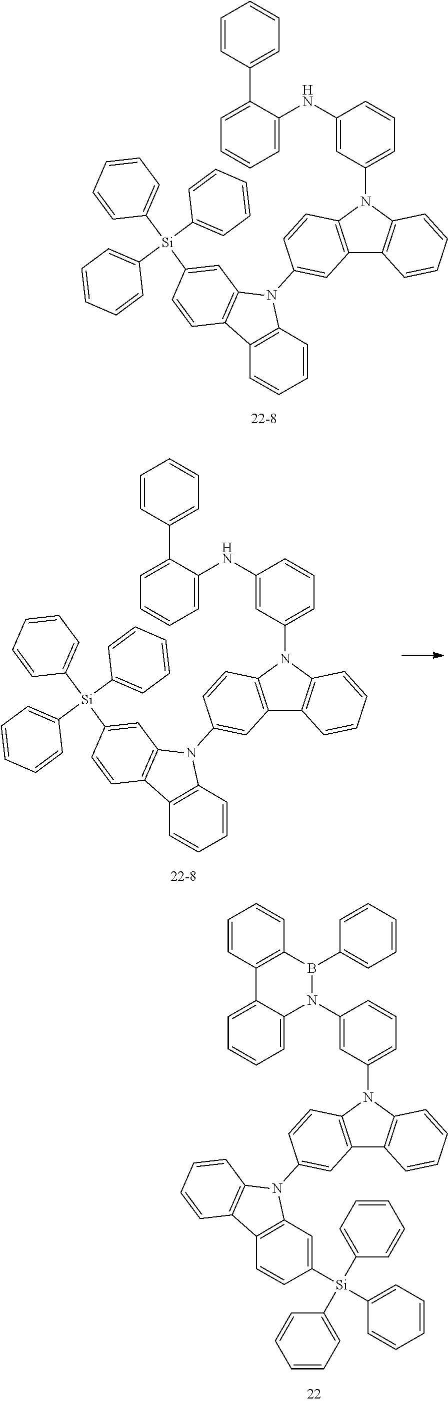 [SMILES: c1ccc(-c2ccccc2Nc2cccc(-n3c4ccccc4c4cc(-n5c6ccccc6c6ccc([Si](c7ccccc7)(c7ccccc7)c7ccccc7)cc65)ccc43)c2)cc1 ; c1ccc(-c2ccccc2Nc2cccc(-n3c4ccccc4c4cc(-n5c6ccccc6c6ccc([Si](c7ccccc7)(c7ccccc7)c7ccccc7)cc65)ccc43)c2)cc1 ; c1ccc(B2c3ccccc3-c3ccccc3N2c2cccc(-n3c4ccccc4c4cc(-n5c6ccccc6c6ccc([Si](c7ccccc7)(c7ccccc7)c7ccccc7)cc65)ccc43)c2)cc1]

### Synthesis of Intermediate 22-1

(4-bromophenyl)triphenylsilane (CAS No.=18737-40-1) and bis(pinacolato)diboron (CAS No.=73183-34-3) were subjected to reaction under Pd catalyst conditions to obtain Intermediate 22-1. The M+1 peak value was confirmed for Intermediate 22-1 through liquid chromatography-mass spectrometry (LC-MS). C₃₀H₃₁BO₂Si: M+1 463.22

### Synthesis of Intermediate 22-2

Intermediate 22-1 and 1-bromo-2-nitrobenzene (CAS No.=577-19-5) were subjected to reaction under Pd catalyst conditions to obtain Intermediate 22-2. The M+1 peak value was confirmed for Intermediate 22-2 through liquid chromatography-mass spectrometry (LC-MS). C₃₀H₂₃NO₂Si: M+1 458.18

### Synthesis of Intermediate 22-3

Intermediate 22-2 and triphenylphosphine (CAS No.=603-35-0) were subjected to reaction to obtain Intermediate 22-3. The M+1 peak value was confirmed for Intermediate 22-3 through liquid chromatography-mass spectrometry (LC-MS). C₃₀H₂₃NSi: M+1 426.12

### Synthesis of Intermediate 22-4

3-bromo-9H-carbazole (CAS No.=1592-95-6), potassium hydroxide, and 4-toluenesulfonyl chloride (CAS No.=98-59-9) were subjected to reaction to obtain Intermediate 22-4. The M+1 peak value was confirmed for Intermediate 22-4 through liquid chromatography-mass spectrometry (LC-MS). C₁₉H₁₄BrNO₂S: M+1 399.98

### Synthesis of Intermediate 22-5

Intermediate 22-3 and Intermediate 22-4 were subjected to reaction under Pd catalyst conditions to obtain Intermediate 22-5. The M+1 peak value was confirmed for Intermediate 22-5 through liquid chromatography-mass spectrometry (LC-MS). C₄₉H₃₆N₂O₂SSi: M+1 745.25

### Synthesis of Intermediate 22-6

Intermediate 22-5 and sodium hydroxide were subjected to reaction to obtain Intermediate 22-6. The M+1 peak value was confirmed for Intermediate 22-6 through liquid chromatography-mass spectrometry (LC-MS). C₄₂H₃₀N₂Si: M+1 591.18

### Synthesis of Intermediate 22-7

Intermediate 22-7 was synthesized in substantially the same manner as in the synthesis of Intermediate 12-2, except that Intermediate 22-6 was utilized instead of Intermediate 12-1. The M+1 peak value was confirmed for Intermediate 22-7 through liquid chromatography-mass spectrometry (LC-MS). C₄₈H₃₃BrN₂Si: M+1 745.18

### Synthesis of Intermediate 22-8

Intermediate 22-8 was synthesized in substantially the same manner as in the synthesis of Intermediate 12-3, except that Intermediate 22-7 was utilized instead of Intermediate 12-2. The M+1 peak value was confirmed for Intermediate 22-8 through liquid chromatography-mass spectrometry (LC-MS). C₆₀H₄₃N₃Si: M+1 834.31

### Synthesis of Compound 22

Compound 22 was synthesized in substantially the same manner as in the synthesis of Compound 12, except that Intermediate 22-8 was utilized instead of Intermediate 12-3. Compound 22 (2.6 g, yield: 34%) was obtained. Compound 22 was confirmed through LC-MS and ¹H-NMR.

### (4) Synthesis of Compound 37

Polycyclic compound 37 according to an embodiment may be synthesized by, for example, a process of Reaction Formula 4.

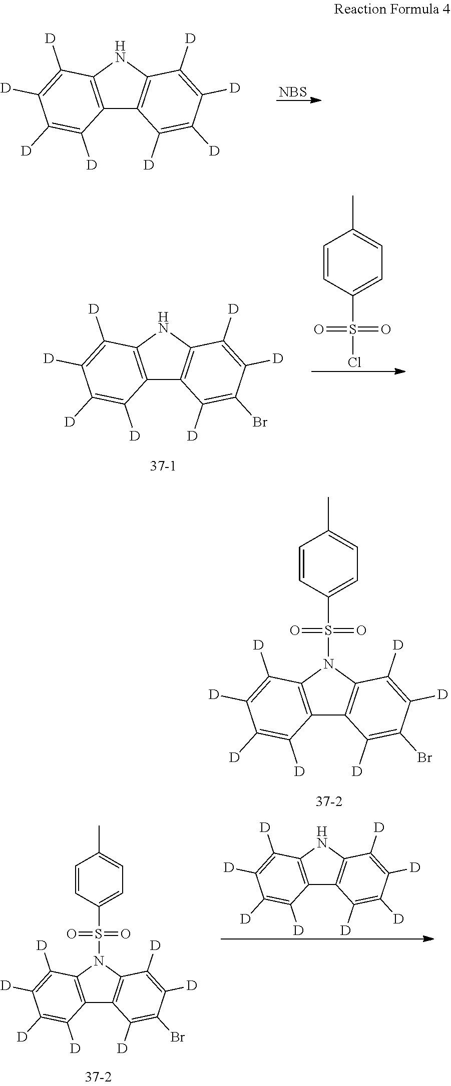

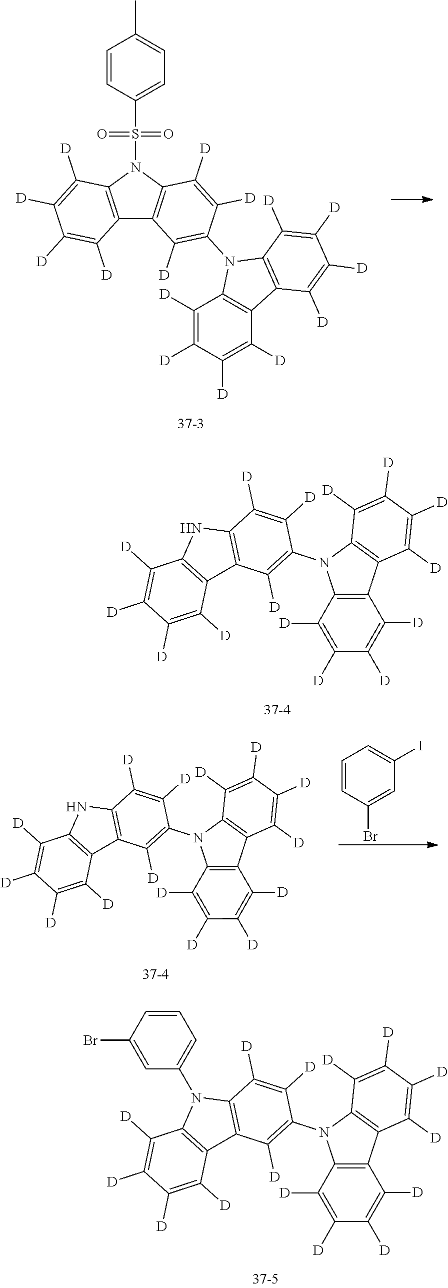

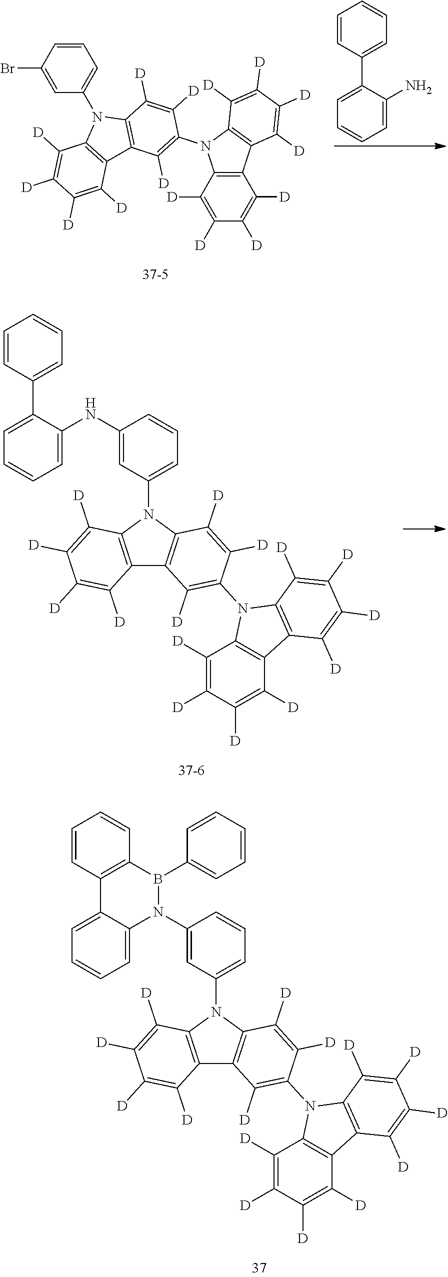

### Synthesis of Intermediate 37-1

9H-carbazole-1,2,3,4,5,6,7,8-d₈ (CAS No.=38537-24-5) and N-bromosuccinimide (NBS, CAS No.=128-08-5) were subjected to reaction to obtain Intermediate 37-1. The M+1 peak value was confirmed for Intermediate 37-1 through liquid chromatography-mass spectrometry (LC-MS). C₁₂HD₇BrN: M+1 253.03

### Synthesis of Intermediate 37-2

Intermediate 37-2 was synthesized in substantially the same manner as in the synthesis of Intermediate 22-4, except that Intermediate 37-1 was utilized instead of 3-bromo-9H-carbazole (CAS No.=1592-95-6). The M+1 peak value was confirmed for Intermediate 37-2 through liquid chromatography-mass spectrometry (LC-MS). C₁₉H₇D₇BrNO₂S: M+1 407.14

### Synthesis of Intermediate 37-3

Intermediate 37-2 and 9H-carbazole-1,2,3,4,5,6,7,8-d₈ (CAS No.=38537-24-5) were subjected to reaction under Pd catalyst conditions to obtain Intermediate 37-3. The M+1 peak value was confirmed for Intermediate 37-3 through liquid chromatography-mass spectrometry (LC-MS). C₃₁H₇D₁₅N₂O₂S: M+1 502.22

### Synthesis of Intermediate 37-4

Intermediate 37-4 was synthesized in substantially the same manner as in the synthesis of Intermediate 22-6, except that Intermediate 37-3 was utilized instead of Intermediate 22-5. The M+1 peak value was confirmed for Intermediate 37-4 through liquid chromatography-mass spectrometry (LC-MS). C₂₄HD₁₅N₂: M+1 348.22

### Synthesis of Intermediate 37-5

Intermediate 37-5 was synthesized in substantially the same manner as in the synthesis of Intermediate 12-2, except that Intermediate 37-4 was utilized instead of Intermediate 12-1. The M+1 peak value was confirmed for Intermediate 37-5 through liquid chromatography-mass spectrometry (LC-MS). C₃₀H₄D₁₅BrN₂: M+1 502.15

### Synthesis of Intermediate 37-6

Intermediate 37-6 was synthesized in substantially the same manner as in the synthesis of Intermediate 12-3, except that Intermediate 37-5 was utilized instead of Intermediate 12-2. The M+1 peak value was confirmed for Intermediate 37-6 through liquid chromatography-mass spectrometry (LC-MS). C42H14D15N3: M+1 591.34

### Synthesis of Compound 37

Compound 37 was synthesized in substantially the same manner as in the synthesis of Compound 12, except that Intermediate 37-6 was utilized instead of Intermediate 12-3. Compound 37 (2 g, yield: 33%) was obtained. Compound 37 was confirmed through LC-MS and ¹H-NMR.

### (5) Synthesis of Compound 53

Polycyclic Compound 53 according to an embodiment may be synthesized by, for example, a process of Reaction Formula 5.

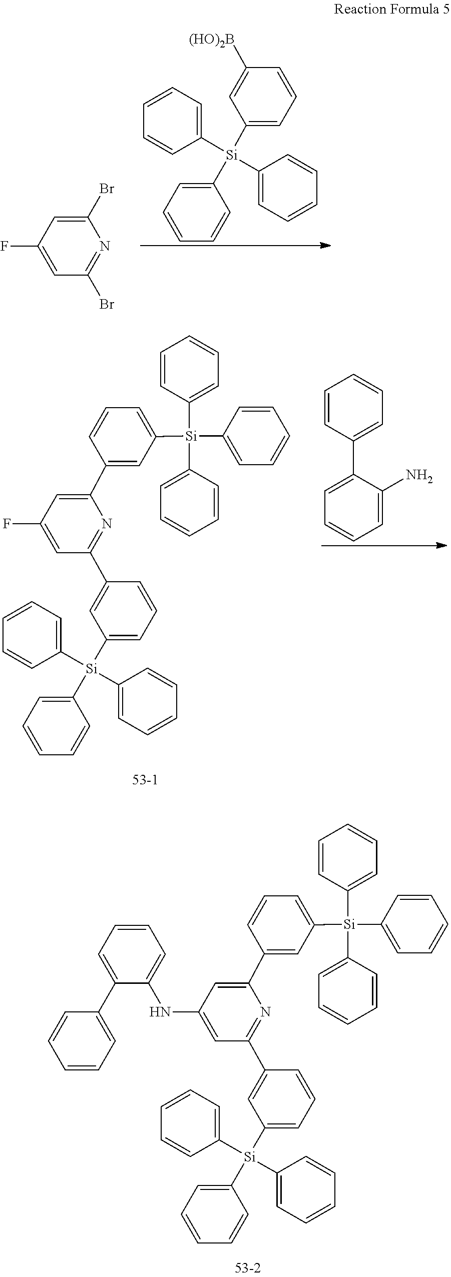

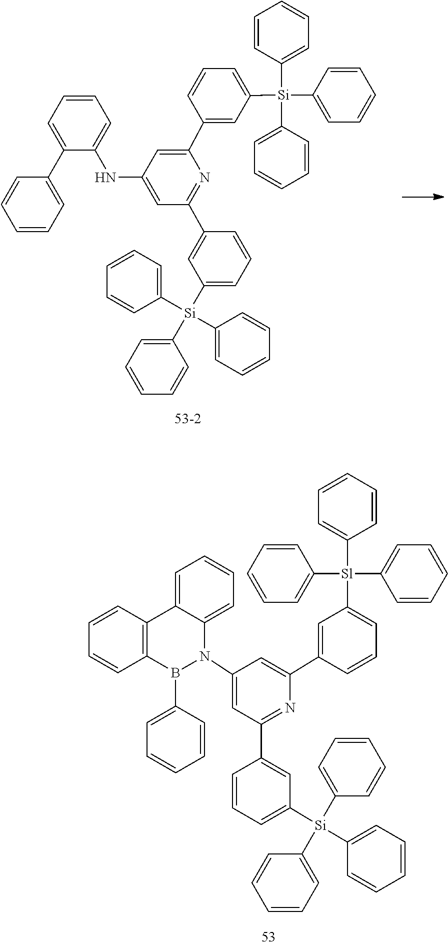

### Synthesis of Intermediate 53-1

2,6-dibromo-4-fluoropyridine (CAS No.=1214344-15-6) and (triphenylsilyl)phenyl)boronic acid (CAS No.=1253912-58-1) were subjected to reaction under Pd catalyst conditions to obtain Intermediate 53-1. The M+1 peak value was confirmed for Intermediate 53-1 through liquid chromatography-mass spectrometry (LC-MS). C₅₃H₄₀FNSi₂: M+1 766.28

### Synthesis of Intermediate 53-2

Intermediate 53-1, (1,1′-biphenyl)-2-amine (CAS No.=90-41-5), and potassium triphosphate were subjected to reaction under dimethylformamide to obtain Intermediate 53-2. The M+1 peak value was confirmed for Intermediate 53-2 through liquid chromatography-mass spectrometry (LC-MS). C₆₅H₅₀N₂Si₂: M+1 915.33

### Synthesis of Compound 53

Compound 53 was synthesized in substantially the same manner as in the synthesis of Compound 12, except that Intermediate 53-2 was utilized instead of Intermediate 12-3. Compound 53 (2.3 g, yield: 30%) was obtained. Compound 53 was confirmed through LC-MS and ¹H-NMR.

### (6) Synthesis of Compound 70

Polycyclic Compound 70 according to an embodiment may be synthesized by, for example, a process of Reaction Formula 6.

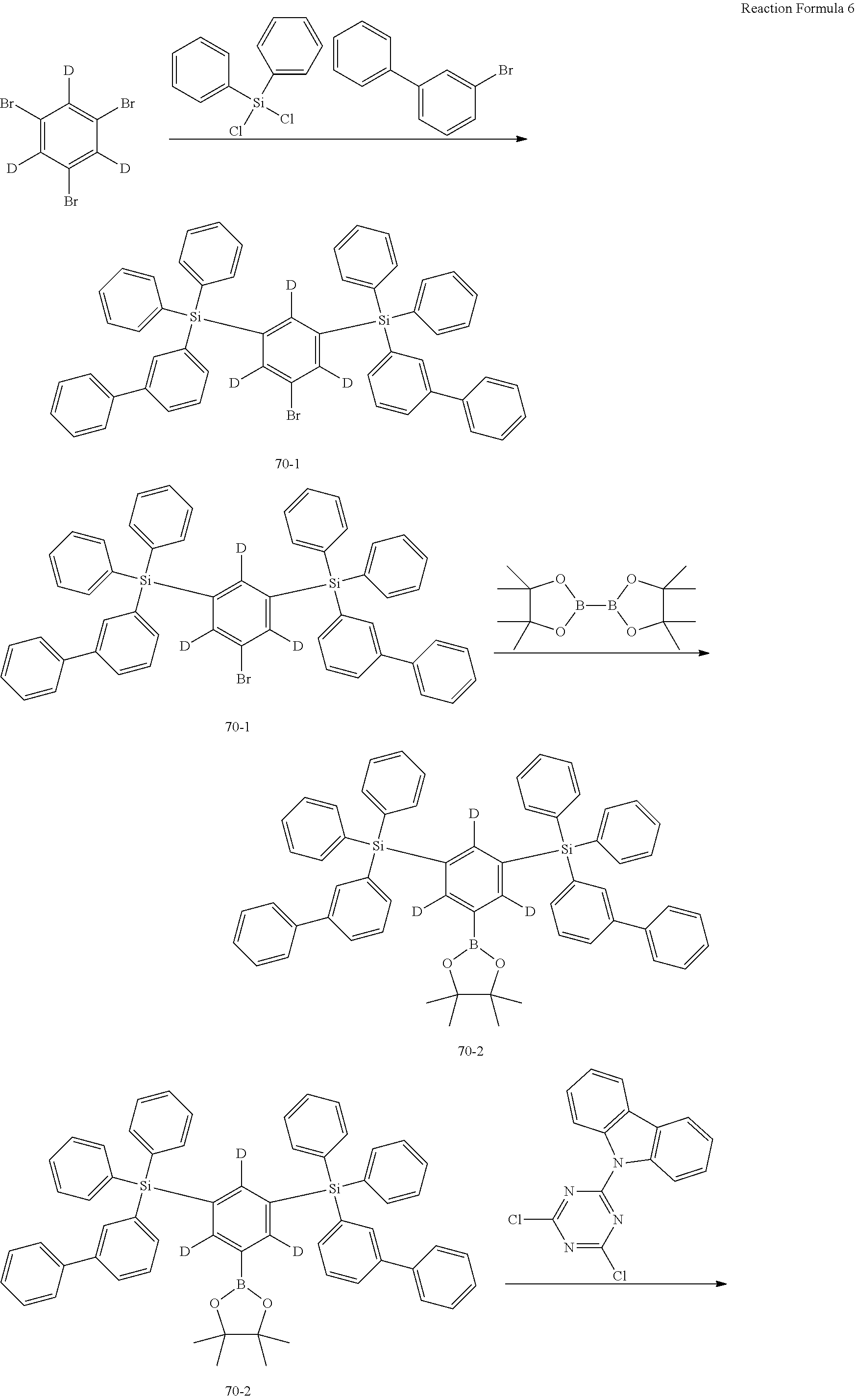

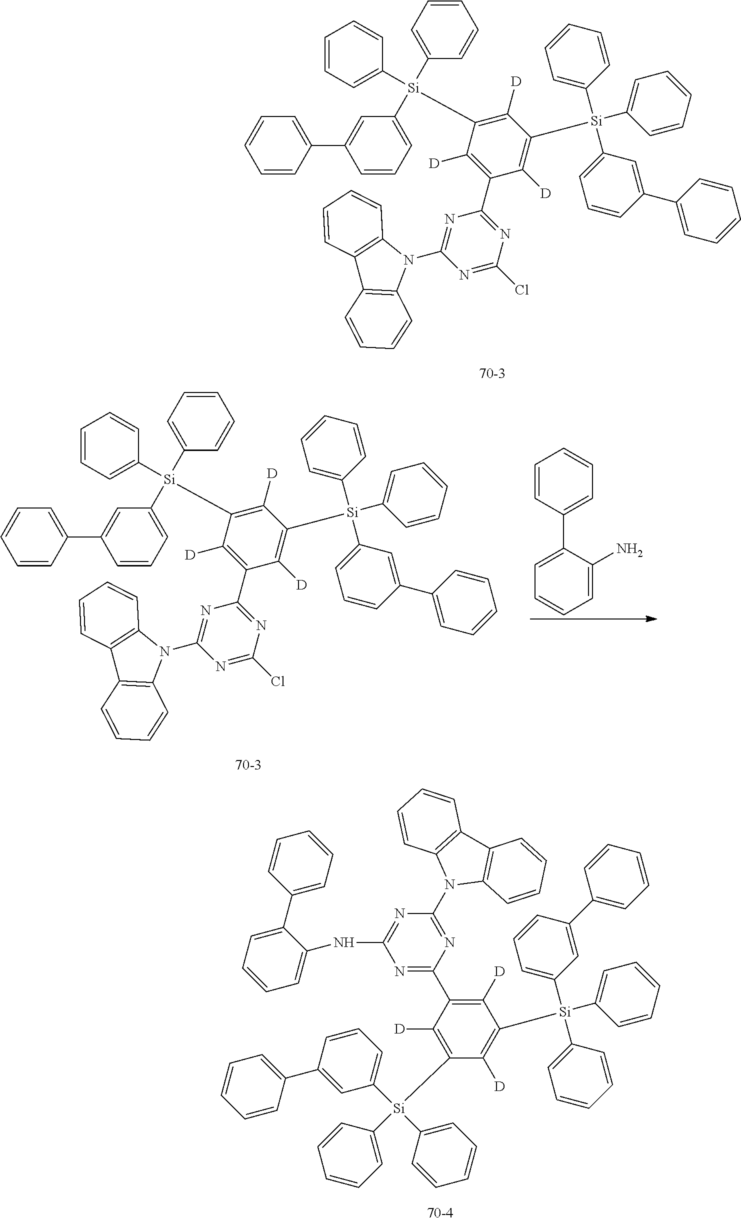

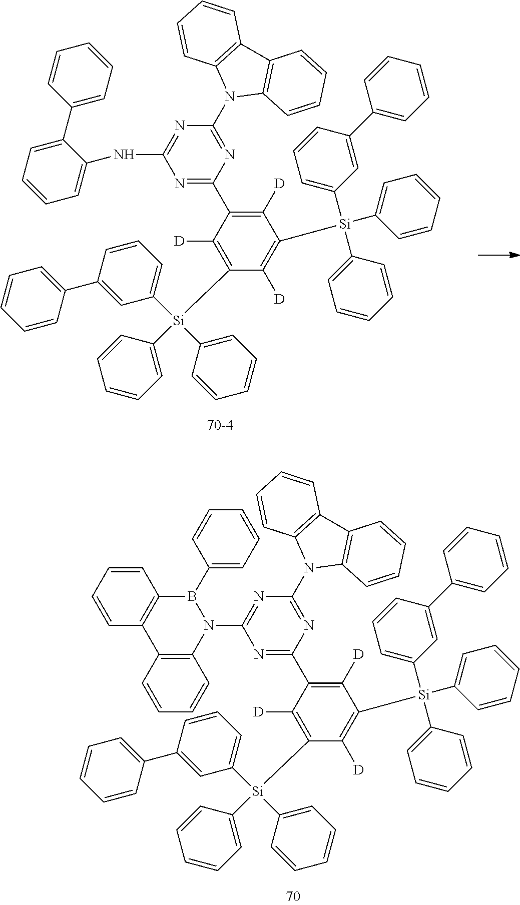 [SMILES: [2H]c1c(-c2nc(Nc3ccccc3-c3ccccc3)nc(-n3c4ccccc4c4ccccc43)n2)c([2H])c([Si](c2ccccc2)(c2ccccc2)c2cccc(-c3ccccc3)c2)c([2H])c1[Si](c1ccccc1)(c1ccccc1)c1cccc(-c2ccccc2)c1 ; [2H]c1c(-c2nc(N3B(c4ccccc4)c4ccccc4-c4ccccc43)nc(-n3c4ccccc4c4ccccc43)n2)c([2H])c([Si](c2ccccc2)(c2ccccc2)c2cccc(-c3ccccc3)c2)c([2H])c1[Si](c1ccccc1)(c1ccccc1)c1cccc(-c2ccccc2)c1]

### Synthesis of Intermediate 70-1

1,3,5-tribromobenzene-2,4,6-d₃ (CAS No.=52921-77-4) and 3-bromobiphenyl (CAS No.=2113-57-7) were respectively subjected to reaction with n-BuLi and then the reaction product was sequentially subjected to reaction with dichlorodiphenylsilane (CAS No.=80-10-4) to obtain intermediate 70-1. The M+1 peak value was confirmed for Intermediate 70-1 through liquid chromatography-mass spectrometry (LC-MS). C₅₄H₃₈D₃BrSi₂: M+1 828.22

### Synthesis of Intermediate 70-2

Intermediate 70-1 and bisphinacolatodiboron (CAS No.=73183-34-3) were subjected to reaction under Pd catalyst conditions to obtain Intermediate 70-2. The M+1 peak value was confirmed for Intermediate 70-2 through liquid chromatography-mass spectrometry (LC-MS). C₆₀H₅₀D₃BO₂Si₂: M+1 876.40

### Synthesis of Intermediate 70-3

Intermediate 70-2 and 9-(4,6-dichloro-1,3,5-triazine-2-yl)-9H-carbazole (CAS No.=24209-95-8) were subjected to reaction under Pd catalyst conditions to obtain Intermediate 70-3. The M+1 peak value was confirmed for Intermediate 70-3 through liquid chromatography-mass spectrometry (LC-MS). C₆₉H₄₆D₃ClN₄Si₂: M+1 1028.32

### Synthesis of Intermediate 70-4

Intermediate 70-3 and (1,1′-biphenyl)-2-amine (CAS No.=90-41-5) were subjected to reaction to obtain Intermediate 70-4. The M+1 peak value was confirmed for Intermediate 70-4 through liquid chromatography-mass spectrometry (LC-MS). C₈₁H₅₆D₃N₅Si₂: M+1 1161.44

### Synthesis of Compound 70

Compound 70 was synthesized in substantially the same manner as in the synthesis of Compound 12, except that Intermediate 70-4 was utilized instead of Intermediate 12-3. Compound 70 (1.7 g, yield: 26%) was obtained. Compound 70 was confirmed through LC-MS and ¹H-NMR.

### (7) Synthesis of Compound 80

Polycyclic Compound 80 according to an embodiment may be synthesized by, for example, a process of Reaction Formula 7.

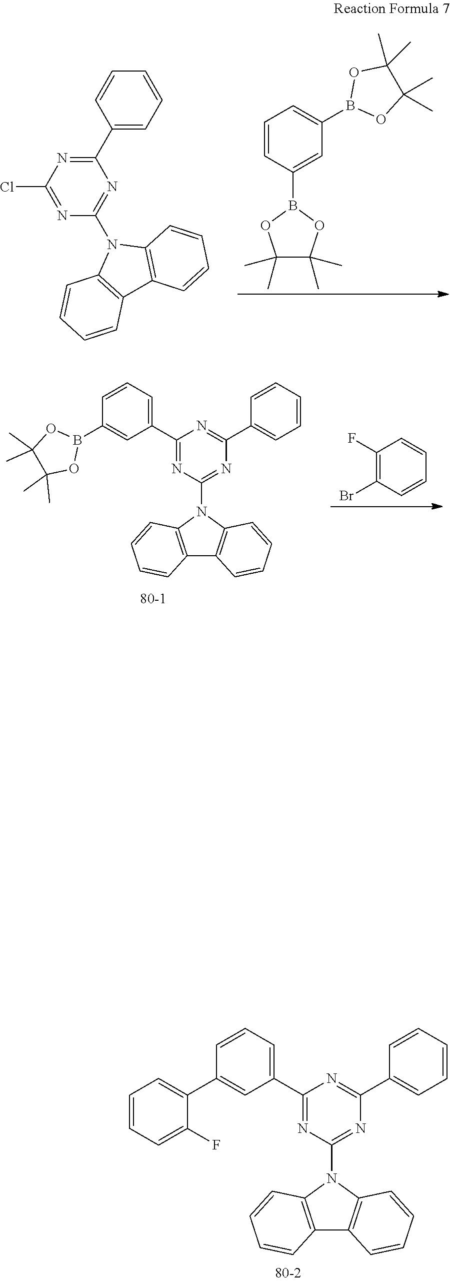

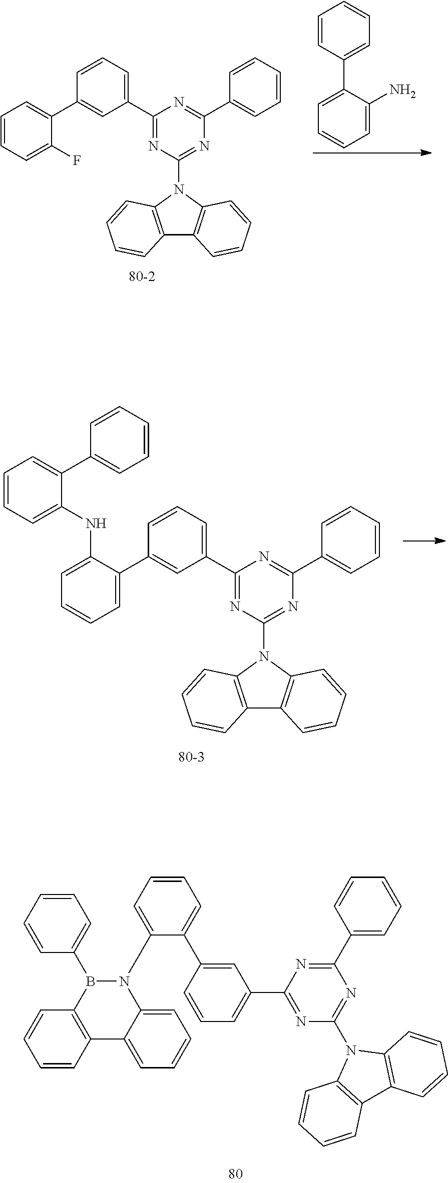

### Synthesis of Intermediate 80-1

9-(4-chloro-6-phenyl-1,3,5-triazine-2-yl)-9H-carbazole (CAS No.=1268244-56-9) and 1,3-bis(4,4,5,5-tetramethyl-1,3,2-dioxaborolane-2yl)benzene (CAS No.=196212-27-8) were subjected to reaction under Pd catalyst conditions to obtain Intermediate 80-1. The M+1 peak value was confirmed for Intermediate 80-1 through liquid chromatography-mass spectrometry (LC-MS). C₃₃H₂₉BN₄O₂: M+1 525.22

### Synthesis of Intermediate 80-2

Intermediate 80-1 and 1-bromo-2-fluorobenzene (CAS No.=1072-85-1) were subjected to reaction under Pd catalyst conditions to obtain Intermediate 80-2. The M+1 peak value was confirmed for Intermediate 80-2 through liquid chromatography-mass spectrometry (LC-MS). C₃₃H₂₁FN₄: M+1 493.20

### Synthesis of Intermediate 80-3

Intermediate 80-3 was synthesized in substantially the same manner as in the synthesis of Intermediate 53-2, except that Intermediate 80-2 was utilized instead of Intermediate 53-1. The M+1 peak value was confirmed for Intermediate 80-3 through liquid chromatography-mass spectrometry (LC-MS). C₄₅H₃₁N₅: M+1 642.26

### Synthesis of Compound 80

Compound 80 was synthesized in substantially the same manner as in the synthesis of Compound 12, except that Intermediate 80-3 was utilized instead of Intermediate 12-3. Compound 80 (3 g, yield: 38%) was obtained. Compound 80 was confirmed through LC-MS and ¹H-NMR.

### (8) Synthesis of Compound 87

Polycyclic Compound 87 according to an embodiment may be synthesized by, for example, a process of Reaction Formula 8.

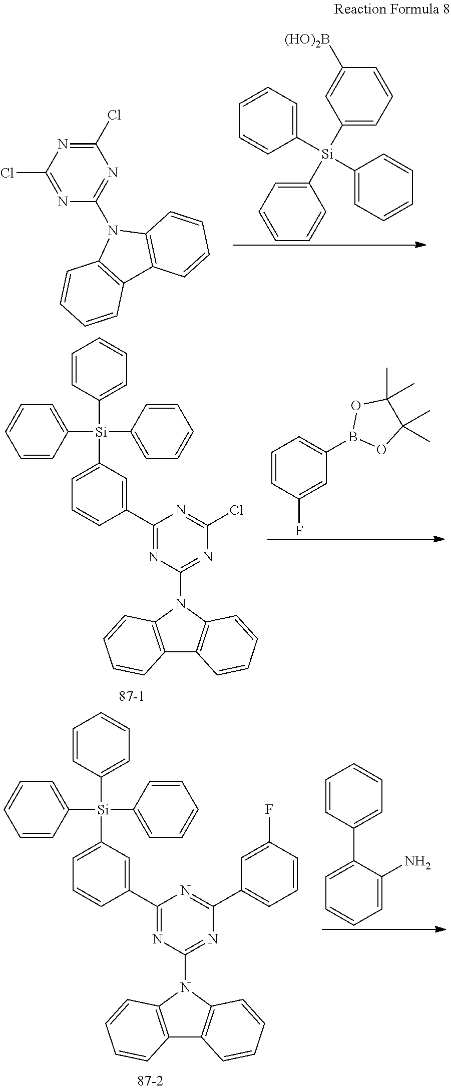

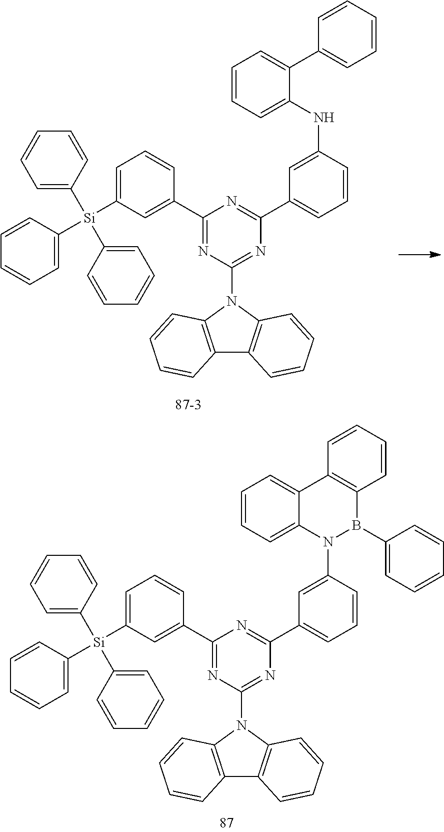 [SMILES: c1ccc(-c2ccccc2Nc2cccc(-c3nc(-c4cccc([Si](c5ccccc5)(c5ccccc5)c5ccccc5)c4)nc(-n4c5ccccc5c5ccccc54)n3)c2)cc1 ; c1ccc(B2c3ccccc3-c3ccccc3N2c2cccc(-c3nc(-c4cccc([Si](c5ccccc5)(c5ccccc5)c5ccccc5)c4)nc(-n4c5ccccc5c5ccccc54)n3)c2)cc1]

### Synthesis of Intermediate 87-1

9-(4,6-dichloro-1,3,5-triazine-2yl)-9H-carbazole (CAS No.=24209-95-8) and (3-triphenylsilyl)phenyl boronic acid (CAS No.=1253912-58-1) were subjected to reaction under Pd catalyst conditions to obtain Intermediate 87-1. The M+1 peak value was confirmed for Intermediate 87-1 through liquid chromatography-mass spectrometry (LC-MS). C₃₉H₂₇ClN₄Si: M+1 615.19

### Synthesis of Intermediate 87-2

Intermediate 87-1 and (3-fluorophenyl)-4,4,5,5-tetramethyl-1,3,2-dioxaborolane (CAS No.=936618-92-7) were subjected to reaction under Pd catalyst conditions to obtain Intermediate 87-2. The M+1 peak value was confirmed for Intermediate 87-2 through liquid chromatography-mass spectrometry (LC-MS). C₄₅H₃₁FN₄Si: M+1 675.22

### Synthesis of Intermediate 87-3

Intermediate 87-3 was synthesized in substantially the same manner as in the synthesis of Intermediate 53-2, except that Intermediate 87-2 was utilized instead of Intermediate 53-1. The M+1 peak value was confirmed for Intermediate 87-3 through liquid chromatography-mass spectrometry (LC-MS). C₅₇H₄₁N₅Si: M+1 824.32

### Synthesis of Compound 87

Compound 87 was synthesized in substantially the same manner as in the synthesis of Compound 12, except that Intermediate 87-3 was utilized instead of Intermediate 12-3. Compound 87 (2 g, yield: 30%) was obtained. Compound 87 was confirmed through LC-MS and ¹H-NMR.

### (9) Synthesis of Compound 90

Polycyclic Compound 90 according to an embodiment may be synthesized by, for example, a process of Reaction Formula 9.

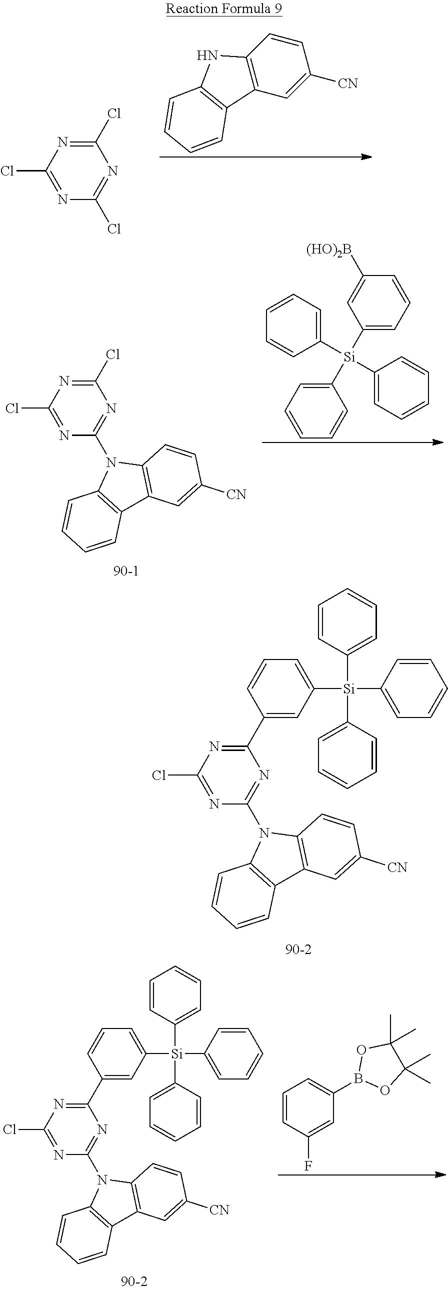

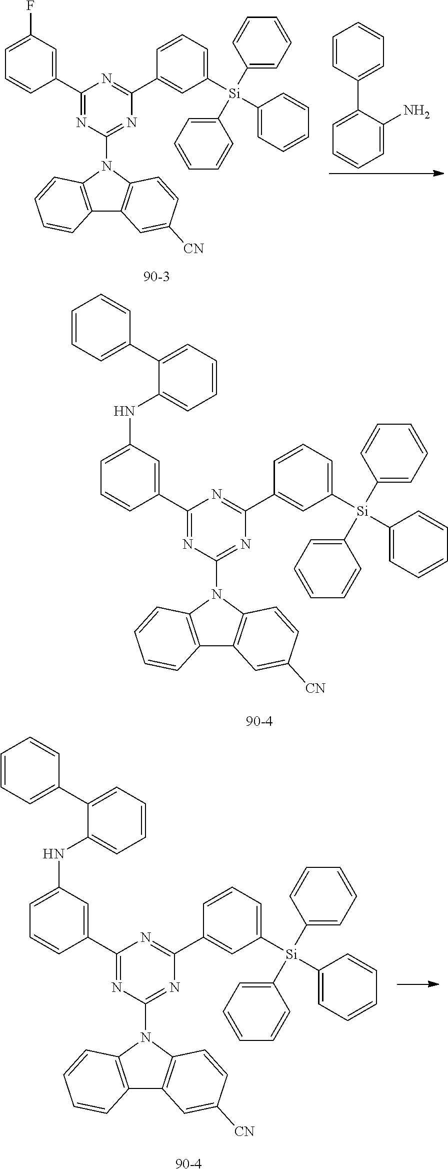

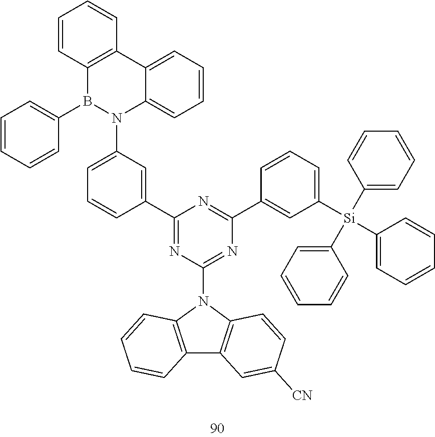 [SMILES: N#Cc1ccc2c(c1)c1ccccc1n2-c1nc(-c2cccc(N3B(c4ccccc4)c4ccccc4-c4ccccc43)c2)nc(-c2cccc([Si](c3ccccc3)(c3ccccc3)c3ccccc3)c2)n1]

### Synthesis of Intermediate 90-1

9H-carbazole-3-carbonitrile (CAS No.=57102-93-9) and n-BuLi were subjected to reaction and then the reaction product and 2,4,6-trichloropyrimidine (CAS No.=3764-01-0) were subjected to reaction to obtain Intermediate 90-1. The M+1 peak value was confirmed for Intermediate 90-1 through liquid chromatography-mass spectrometry (LC-MS). C₁₇H₈Cl₂N₄: M+1 339.01

### Synthesis of Intermediate 90-2

Intermediate 90-1 and (3-(triphenylsilyl)phenyl)boronic acid (CAS No.=1253912-58-1) were subjected to reaction under Pd catalyst conditions to obtain Intermediate 90-2. The M+1 peak value was confirmed for Intermediate 90-2 through liquid chromatography-mass spectrometry (LC-MS). C₄₁H₂₇ClN₄Si: M+1 639.18

### Synthesis of Intermediate 90-3

Intermediate 90-2 and (3-fluorophenyl)-4,4,5,5-tetramethyl-1,3,2-dioxaborolane (CAS No.=936618-92-7) were subjected to reaction under Pd catalyst conditions to obtain Intermediate 90-3. The M+1 peak value was confirmed for Intermediate 90-3 through liquid chromatography-mass spectrometry (LC-MS). C₄₇H₃₁FN₄Si: M+1 699.21

### Synthesis of Intermediate 90-4

Intermediate 90-4 was synthesized in substantially the same manner as in the synthesis of Intermediate 53-2, except that Intermediate 90-3 was utilized instead of Intermediate 53-1. The M+1 peak value was confirmed for Intermediate 90-4 through liquid chromatography-mass spectrometry (LC-MS). C₅₉H₄₁N₅S M+1 848.32

### Synthesis of Compound 90

Compound 90 was synthesized in substantially the same manner as in the synthesis of Compound 12, except that Intermediate 90-4 was utilized instead of Intermediate 12-3. Compound 90 (2.2 g, yield: 33%) was obtained. Compound 90 was confirmed through LC-MS and ¹H-NMR.

The molecular weight and NMR analysis results of the synthesized polycyclic compounds are shown in Table 1.

TABLE 1

| | | MS/FAB | |
|---|---|---|---|
| Compound | ¹H NMR | Calc | Found |
| 12 | 8.55 (d, 1H), 8.30 (d, 1H), 8.21-8.10 | 813.33 | 814.31 |
| | (m, 4H), 7.94-7.89 (m, 5H), 7.77-7.35 | | |
| | (m, 23H), 7.20-7.14 (m, 6H) | | |
| 15 | 8.55 (d, 1H), 8.10-7.89 (m, 8H), 7.77-7.75 | 662.25 | 663.22 |
| | (m, 4H), 7.54-7.32 (m, 13H), 7.17-7.13 (m, 5H) | | |
| 22 | 8.55 (d, 1H), 8.22 (d, 1H), 8.10 (d, 1H), 7.94 | 919.36 | 920.37 |
| | (d, 3H), 7.77-7.67 (m, 6H), 7.50-7.35 | | |
| | (m, 27H), 7.17-7.14 (m, 6H) | | |
| 37 | 8.10 (d, 1H), 7.94 (d, 1H), 7.76 | 676.36 | 677.34 |
| | (d, 3H), 7.50-7.35 (m, 8H), 7.16-7.14 (m, 4H) | | |
| 53 | 8.33 (d, 2H), 8.27 (s, 2H), 8.10 (d, 1H), 7.94 | 1000.38 | 1001.39 |
| | (d, 1H), 7.77-7.75 (m, 3H), 7.64 (t, 2H), 7.50-7.35 | | |
| | (m, 39H), 7.14 (t, 1H), 6.40 (s, 2H) | | |
| 70 | 8.55 (d, 1H), 8.19 (d, 1H), 8.10 | 1246.48 | 1247.50 |
| | (d, 1H), 7.94 (d, 2H), 7.88 (s, 2H), 7.77-7.75 | | |
| | (m, 7H), 7.50-7.36 (m, 42H), 7.20-7.14 (m, 3H) | | |
| 80 | 8.55 (d, 1H), 8.38-8.36 (m, 3H), 8.19 | 727.29 | 728.31 |
| | (d, 1H), 8.10 (d, 2H), 7.94 (m, 3H), 7.77-7.73 | | |
| | (m, 4H), 7.58-7.35 (m, 16H), 7.20-7.14 (m, 4H) | | |
| 87 | 8.55 (d, 1H), 8.38 (d, 1H), 8.19 | 909.35 | 910.33 |
| | (d, 1H), 8.10 (d, 1H), 7.94 (d, 3H), 7.88 | | |
| | (s, 1H), 7.77-7.75 (m, 3H), 7.55-7.16 (m, 33H) | | |
| 90 | 8.55 (d, 1H), 8.10 (d, 1H), 7.94 (d, 4H), 7.88 | 933.35 | 934.34 |
| | (s, 2H), 7.80-7.75 (m, 5H), 7.55-7.35 | | |
| | (m, 29H), 7.16-7.14 (m, 2H) | | |

### 2. Preparation and Evaluation of Light Emitting Elements

### (1) Preparation of Light Emitting Elements

Light emitting elements containing polycyclic compounds according to Example or Comparative Example Compounds were prepared through a process below. Light emitting elements of Examples 1 to 9 were prepared respectively utilizing polycyclic compounds 12, 15, 22, 37, 53, 70, 80, 87 and 90 as a host material of an emission layer. Light emitting elements of Comparative Examples 1 to 4 were prepared respectively utilizing Comparative Example Compounds CX1 to CX4 as a host material of an emission layer. For Comparative Example Compound CX1, mCP(1,3-bis(carbazol-9-yl)benzene) was utilized.

As a first electrode, an ITO substrate having a thickness of 1200 Å was utilized. The ITO substrate was subjected to ultrasonic cleaning utilizing isopropyl alcohol for 5 minutes and pure water for 5 minutes and ultraviolet irradiation for 30 minutes, and then exposed to ozone for cleaning. The cleaned ITO substrate was mounted on a vacuum deposition apparatus.

N,N′-di(1-naphthyl)-N,N′-diphenylbenzidine (NPB) was vacuum deposited on the cleaned ITO substrate to form a hole injection layer having a thickness of 300 Å. mCP was vacuum deposited on the hole injection layer to form a hole transport layer having a thickness of 200 Å.

Then, co-deposition (e.g., of an Example or Comparative compound as the host and a dopant) was performed at a weight ratio of 92:8 on the hole transport layer to form an emission layer having a thickness of 250 Å. Ir(pmp)3 was utilized as the dopant (e.g., a dopant material) of the emission layer, and Example Compounds or Comparative Example Compounds were each utilized as the host (e.g., a host material).

Thereafter, TAZ(3-(4-biphenylyl)-4-phenyl-5-tert-butylphenyl-1,2,4-triazole) was deposited to a thickness of 200 Å as an electron transport layer on an upper portion of the emission layer, and LiF, which is an alkali metal halide, was deposited to a thickness of 10 Å on an upper portion of the electron transport layer to form an electron injection layer. Al was vacuum deposited to a thickness of 100 Å to form a second electrode.

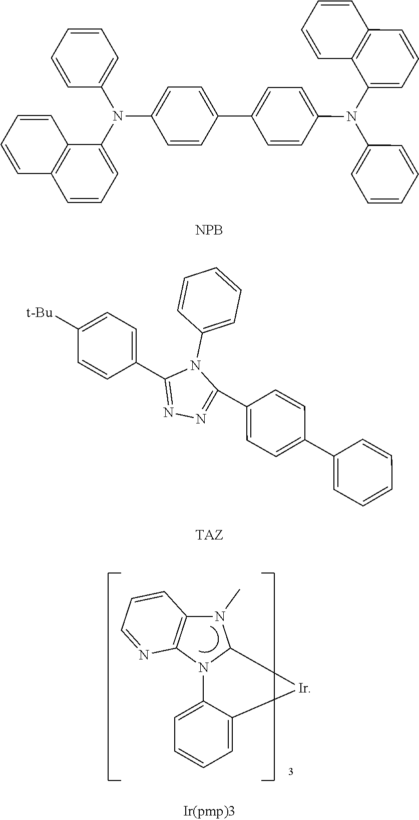

Example Compounds utilized in Examples 1 to 9 and Comparative Example Compounds utilized in Comparative Examples 1 to 4 are shown in Table 2.

TABLE 2

| Com- parative Example Compound CX1 | 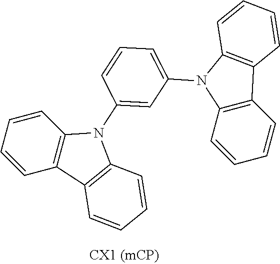 [SMILES: c1cc(-n2c3ccccc3c3ccccc32)cc(-n2c3ccccc3c3ccccc32)c1] | Com- parative Example Compound CX2 | 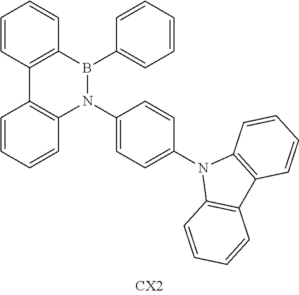 [SMILES: c1ccc(B2c3ccccc3-c3ccccc3N2c2ccc(-n3c4ccccc4c4ccccc43)cc2)cc1] |
|---|---|---|---|
| Com- parative Example Compound CX3 | 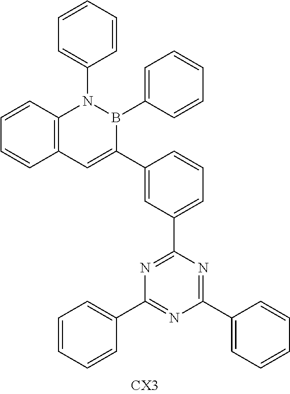 [SMILES: C1=C(c2cccc(-c3nc(-c4ccccc4)nc(-c4ccccc4)n3)c2)B(c2ccccc2)N(c2ccccc2)c2ccccc21] | | |
| Com- parative Example Compound CX4 | 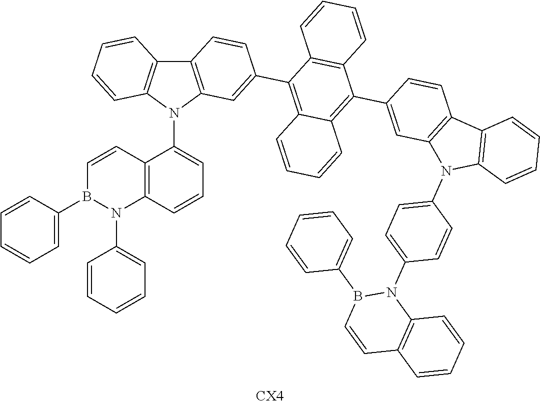 [SMILES: C1=Cc2ccccc2N(c2ccc(-n3c4ccccc4c4ccc(-c5c6ccccc6c(-c6ccc7c8ccccc8n(-c8cccc9c8C=CB(c8ccccc8)N9c8ccccc8)c7c6)c6ccccc56)cc43)cc2)B1c1ccccc1] | | |
| Compound 12 | 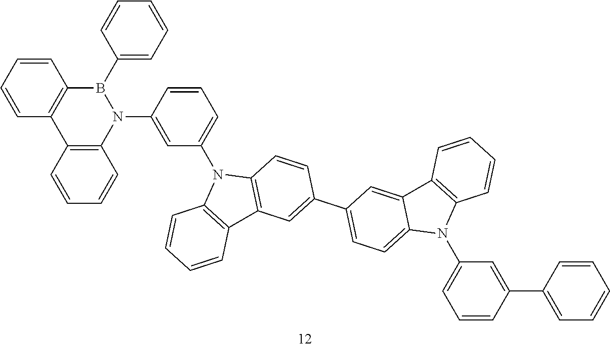 [SMILES: c1ccc(B2c3ccccc3-c3ccccc3N2c2cccc(-n3c4ccccc4c4cc(-c5ccc6c(c5)c5ccccc5n6-c5cccc(-c6ccccc6)c5)ccc43)c2)cc1] | | |
| Compound 15 | 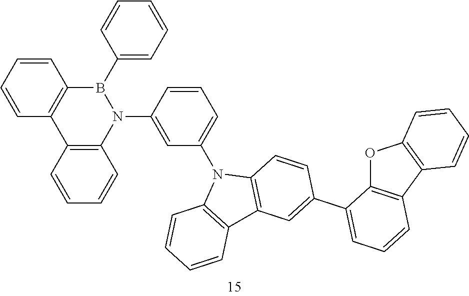 [SMILES: c1ccc(B2c3ccccc3-c3ccccc3N2c2cccc(-n3c4ccccc4c4cc(-c5cccc6c5oc5ccccc56)ccc43)c2)cc1] | | |
| Compound 22 | 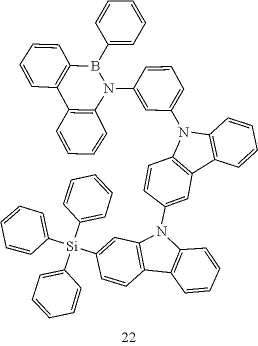 [SMILES: c1ccc(B2c3ccccc3-c3ccccc3N2c2cccc(-n3c4ccccc4c4cc(-n5c6ccccc6c6ccc([Si](c7ccccc7)(c7ccccc7)c7ccccc7)cc65)ccc43)c2)cc1] | Compound 37 | 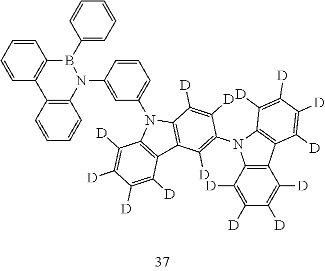 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cccc(N2B(c3ccccc3)c3ccccc3-c3ccccc32)c1] |
| Compound 53 | 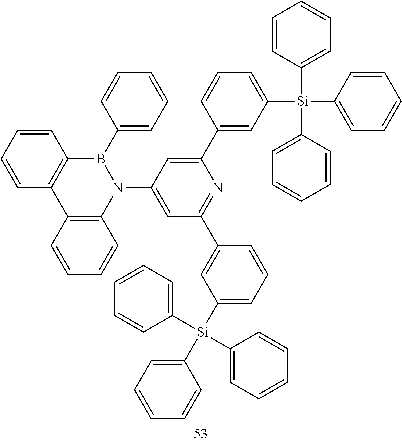 [SMILES: c1ccc(B2c3ccccc3-c3ccccc3N2c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1] | | |
| Compound 70 | 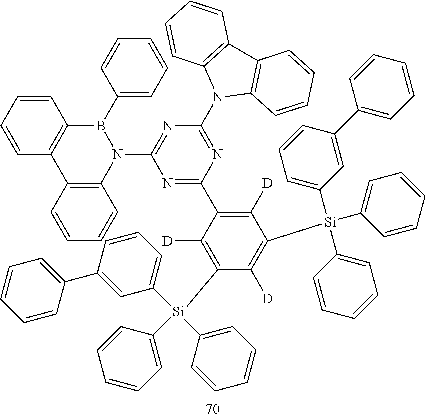 [SMILES: [2H]c1c(-c2nc(N3B(c4ccccc4)c4ccccc4-c4ccccc43)nc(-n3c4ccccc4c4ccccc43)n2)c([2H])c([Si](c2ccccc2)(c2ccccc2)c2cccc(-c3ccccc3)c2)c([2H])c1[Si](c1ccccc1)(c1ccccc1)c1cccc(-c2ccccc2)c1] | | |
| Compound 80 | 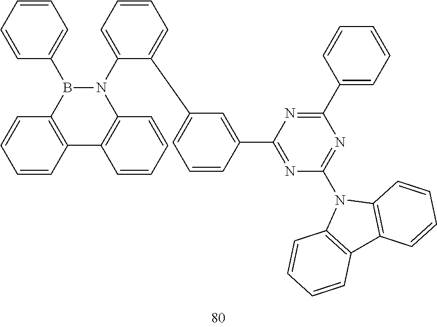 [SMILES: c1ccc(B2c3ccccc3-c3ccccc3N2c2ccccc2-c2cccc(-c3nc(-c4ccccc4)nc(-n4c5ccccc5c5ccccc54)n3)c2)cc1] | | |
| Compound 87 | 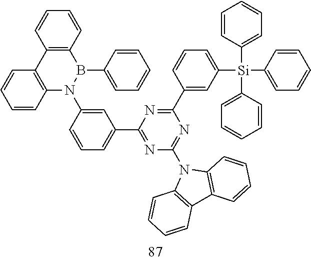 [SMILES: c1ccc(B2c3ccccc3-c3ccccc3N2c2cccc(-c3nc(-c4cccc([Si](c5ccccc5)(c5ccccc5)c5ccccc5)c4)nc(-n4c5ccccc5c5ccccc54)n3)c2)cc1] | Compound 90 | 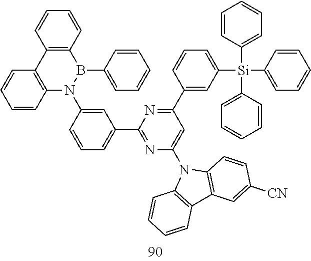 [SMILES: N#Cc1ccc2c(c1)c1ccccc1n2-c1cc(-c2cccc([Si](c3ccccc3)(c3ccccc3)c3ccccc3)c2)nc(-c2cccc(N3B(c4ccccc4)c4ccccc4-c4ccccc43)c2)n1] |

### (2) Characteristics Evaluation of Light Emitting Elements

Table 3 shows the characteristics evaluation of the light emitting elements of Examples and Comparative Examples. In each of the light emitting elements of Examples and Comparative Examples, the driving voltage at a current density of 2.3 mA/cm², a current density, and a maximum quantum efficiency were measured. The driving voltage and the current density were measured utilizing a source meter (2400 series from Keithley Instrument), and the maximum quantum efficiency was measured utilizing an external quantum efficiency measuring apparatus (C9920-2-12 from Hamamatsu Photonics Co., Ltd.) In the evaluation of the maximum quantum efficiency, the luminance and current densities were measured utilizing a luminance meter that was calibrated for wavelength sensitivity, and the maximum quantum efficiency was converted under the assumption that an angular luminance distribution (Lambertian) was obtained with respect to a fully diffused reflective surface.

TABLE 3

| | | | Current | Maximum | |
|---|---|---|---|---|---|
| | | Driving | density | quantum | |
| | | voltage | (mA/ | efficiency | Emitted |
| Item | Host material | (V) | cm²) | (%) | color |
| Example 1 | Compound 12 | 4.4 | 2.3 | 25.8 | blue |
| Example 2 | Compound 15 | 4.6 | 2.3 | 26.3 | blue |
| Example 3 | Compound 22 | 4.5 | 2.3 | 28.1 | blue |
| Example 4 | Compound 37 | 4.4 | 2.3 | 27.7 | blue |
| Example 5 | Compound 53 | 4.7 | 2.3 | 24.9 | blue |
| Example 6 | Compound 70 | 4.3 | 2.3 | 26.1 | blue |
| Example 7 | Compound 80 | 4.6 | 2.3 | 27.3 | blue |
| Example 8 | Compound 87 | 4.5 | 2.3 | 28.5 | blue |
| Example 9 | Compound 90 | 4.5 | 2.3 | 26.8 | blue |
| Comparative | Comparative | 5.5 | 2.3 | 22.3 | blue |
| Example 1 | Example | | | | |
| | Compound CX1 | | | | |
| Comparative | Comparative | 5.1 | 2.3 | 23.2 | blue |
| Example 2 | Example | | | | |
| | Compound CX2 | | | | |
| Comparative | Comparative | 4.9 | 2.3 | 21.8 | blue |
| Example 3 | Example | | | | |
| | Compound CX3 | | | | |
| Comparative | Comparative | 5.3 | 2.3 | 21.2 | blue |
| Example 4 | Example | | | | |
| | Compound CX4 | | | | |

Referring to Table 3, it is seen that, compared to the light emitting elements of Comparative Examples 1 to 4, the light emitting elements of Examples 1 to 9 each had a reduced driving voltage and satisfactory (suitable) efficiency. The light emitting elements of Examples 1 to 9 include Compounds 12, 15, 22, 37, 53, 70, 80, 87, and 90, and Compounds 12, 15, 22, 37, 53, 70, 80, 87, and 90 are polycyclic compounds according to the embodiments.

In Compounds 12, 15, 22, and 37, a substituted carbazole group is bonded to a fused ring of three rings, which contains B and N as ring-forming atoms. In Compounds 53, 70, 80, 87, and 90, a substituted pyridine group, a substituted pyrimidine group, or a substituted triazine group is bonded to a fused ring of three rings, which contains B and N as ring-forming atoms. In Compounds 12, 15, 22, 37, 53, 70, 80, 87, and 90, a carbazole group, a pyridine group, a pyrimidine group, or a triazine group is bonded to a fused ring of three rings, which contains B and N as ring-forming atoms, resulting in improvement of hole and charge injection properties. Accordingly, it is believed that the light emitting elements of Examples 1 to 9 each relatively exhibited a low driving voltage and a high efficiency.

The light emitting element of Comparative Example 1 includes Comparative Example Compound CX1. Comparative Example Compound CX1 is mCP, a generally utilized/generally available material, and does not contain a fused ring of three rings, which contains B and N as ring-forming atoms.

The light emitting element of Comparative Example 2 includes Comparative Example Compound CX2 in which a carbazole group is bonded to a fused ring of three rings, which contains B and N as ring-forming atoms through a phenyl group. Comparative Example Compound CX2 is an embodiment in which a carbazole group and a fused ring of three rings, which contains B and N as ring-forming atoms that are bonded together in para position of a phenyl group.

The light emitting element of Comparative Example 3 includes Comparative Example Compound CX3, and the light emitting element of Comparative Example 4 includes Comparative Example Compound CX4. Comparative Example Compound CX3 and Comparative Example Compound CX4 include a fused ring of two rings, which contains B and N as ring-forming atoms.

A light emitting element according to an embodiment may include a first electrode, a second electrode on the first electrode, and an emission layer between the first electrode and the second electrode. The emission layer may include a polycyclic compound according to an embodiment.

A polycyclic compound according to an embodiment may include a fused ring of three rings, which contains B and N as ring-forming atoms, and a carbazole group, a pyridine group, a pyrimidine group, or a triazine group may be bonded to the fused ring of three rings. The carbazole group, the pyridine group, the pyrimidine group, and the triazine group are substituted or unsubstituted, and may be bonded to N, which is a ring-forming atom of the fused ring of three rings. Accordingly, the polycyclic compound according to an embodiment may have excellent or suitable hole and charge injection properties, and increased material stability. The light emitting element including the polycyclic compound according to an embodiment may relatively have a reduced driving voltage and an increased efficiency.

A light emitting element according to an embodiment includes a polycyclic compound according to an embodiment, and may thus relatively exhibit a reduced driving voltage and high efficiency characteristics.

A polycyclic compound according to an embodiment may contribute to a reduction in driving voltage and an increase in efficiency of a light emitting element.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The light emitting device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A light emitting element comprising:
a first electrode;
a second electrode facing the first electrode; and
an emission layer between the first electrode and the second electrode, and comprising a polycyclic compound represented by Formula 1: 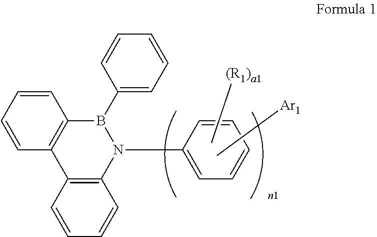
wherein in Formula 1,
n1 is an integer from 0 to 3,
Ar₁ is a substituted or unsubstituted carbazole group, a substituted or unsubstituted pyridine group, a substituted or unsubstituted pyrimidine group, or a substituted or unsubstituted triazine group,
when Ar₁ is an unsubstituted carbazole group, n1 is an integer from 1 to 3,
when n1 is 1 and Ar₁ is an unsubstituted carbazole group, Ar₁ is bonded in meta position with respect to N,
a1 is an integer from 0 to 4, and
R₁ is a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted hydrocarbon ring group having 6 to 60 ring-forming carbon atoms, a substituted or unsubstituted aryl group having 6 to 60 ring-forming carbon atoms, or a substituted or unsubstituted heterocyclic group having 2 to 60 ring-forming carbon atoms.

2. The light emitting element of claim 1, wherein in Formula 1, Ar₁ is represented by Formula 2-1 or Formula 2-2: 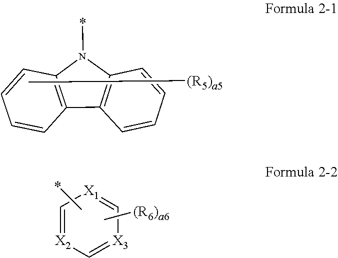
wherein in Formula 2-1,
a5 is an integer from 0 to 8, and
R₅ is a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms; and
wherein in Formula 2-2,
a6 is an integer from 0 to 2,
at least one of X₁ to X₃ is N and each of the remainder of X₁ to X₃ is independently CR₇, and
R₆ and R₇ are each independently a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms.

3. The light emitting element of claim 2, wherein in Formulas 2-1 and 2-2, R₅ and R₆ are each independently represented by any one selected from among RN-1 to RN-5: 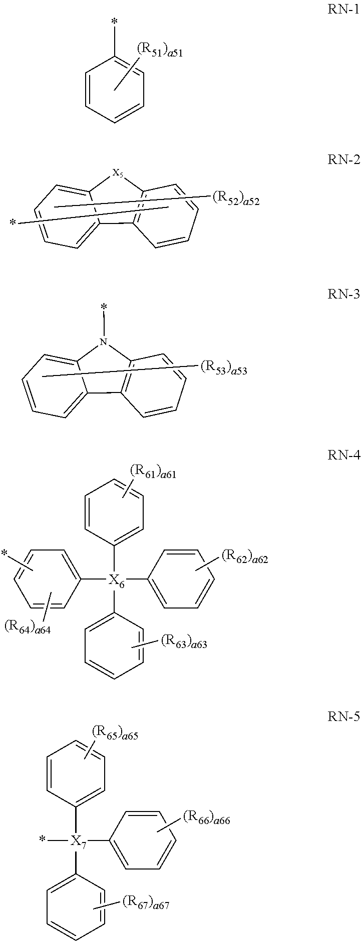
wherein in RN-2,
a52 is an integer from 0 to 7, and
X₅ is CR₅₄R₅₅, SiR₅₆R₅₇, NR₅₈, O, or S;
wherein in RN-3,
a53 is an integer from 0 to 8;
wherein in RN-4,
a64 is an integer from 0 to 4, and
X₆ is C or Si;
wherein in RN-5,
X₇ is C or Si; and
wherein in RN-1 to RN-5,
a51, a61 to a63, and a65 to a67 are each independently an integer from 0 to 5, and
R₅₁ to R₅₈ and R₆₁ to R₆₇ are each independently a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms.

4. The light emitting element of claim 1, wherein Formula 1 is represented by any one selected from among Formulas 1-1 to 1-5: 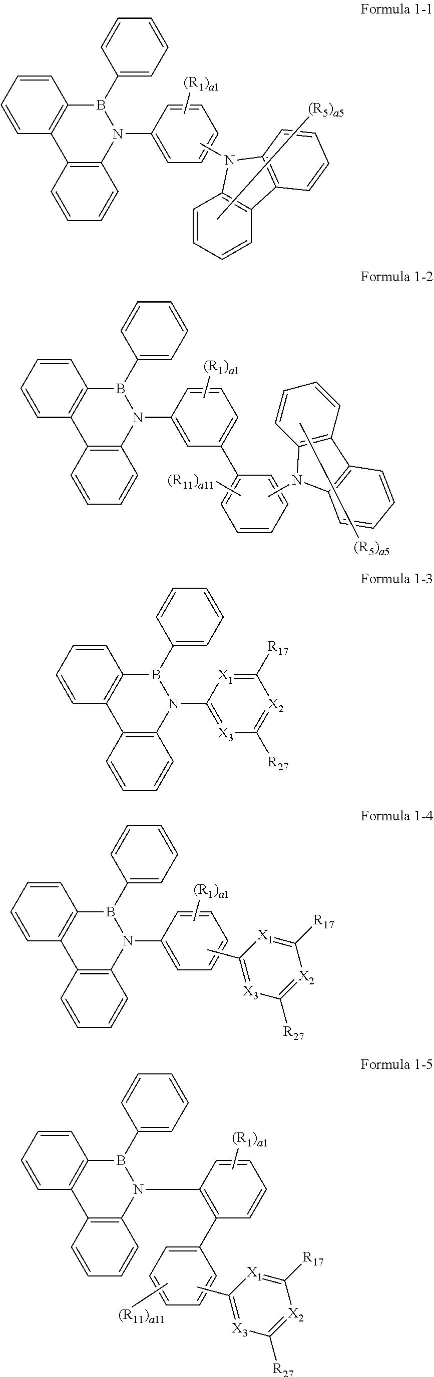
wherein in Formulas 1-1 and 1-2,
a5 is an integer from 0 to 8, and
R₅ is a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms;
wherein in Formulas 1-2 and 1-5,
a11 is an integer from 0 to 4, and
R₁₁ is a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted hydrocarbon ring group having 6 to 60 ring-forming carbon atoms, a substituted or unsubstituted aryl group having 6 to 60 ring-forming carbon atoms, or a substituted or unsubstituted heterocyclic group having 2 to 60 ring-forming carbon atoms;
wherein in Formulas 1-3 to 1-5,
at least one of X₁ to X₃ is N and each of the remainder of X₁ to X₃ is independently CR₇, and
R₇, R₁₇, and R₂₇ are each independently a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms; and
wherein in Formulas 1-1 to 1-5,
a1 and R₁ are the same as defined in Formula 1.

5. The light emitting element of claim 1, wherein Formula 1 is represented by any one selected from among Formulas 1-A1 to 1-A4: 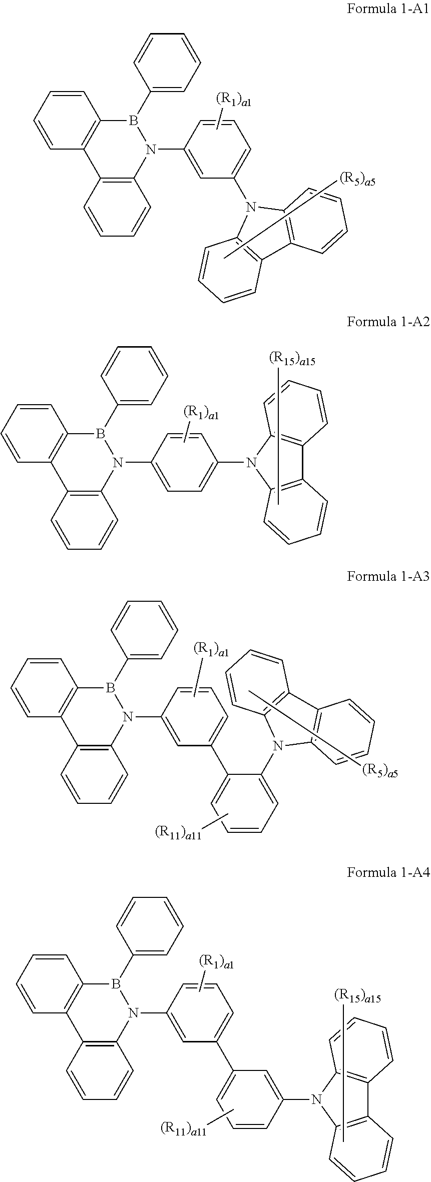
wherein in Formula 1-A2,
a15 is an integer from 1 to 8, and
R₁₅ is a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms;
wherein in Formulas 1-A3 and 1-A4,
a11 is an integer from 0 to 4, and
R₁₁ is a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted hydrocarbon ring group having 6 to 60 ring-forming carbon atoms, a substituted or unsubstituted aryl group having 6 to 60 ring-forming carbon atoms, or a substituted or unsubstituted heterocyclic group having 2 to 60 ring-forming carbon atoms;
wherein in Formulas 1-A1, 1-A3 and 1-A4,
a5 is an integer from 0 to 8, and
R₅ is a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms; and
wherein in Formulas 1-A1 to 1-A4,
a1 and R₁ are the same as defined in Formula 1.

6. The light emitting element of claim 1, wherein Formula 1 is represented by any one selected from among Formulas 1-B1 to 1-B5: 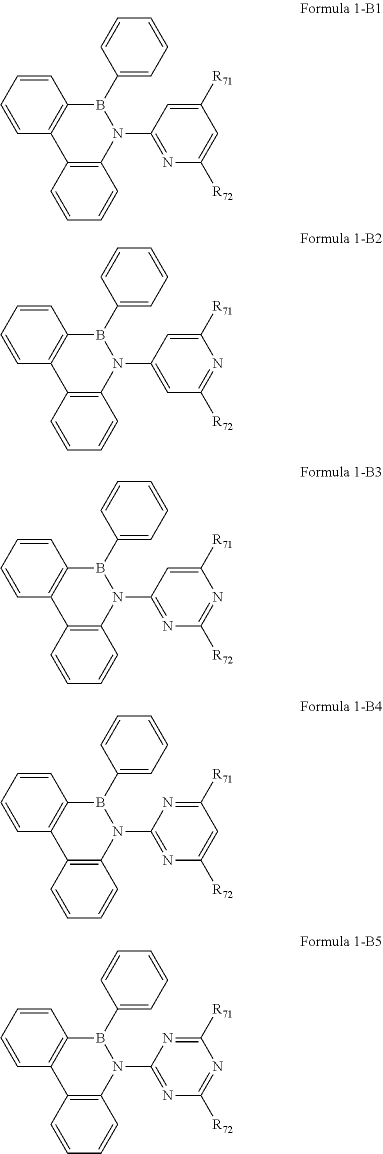
wherein in Formulas 1-B1 to 1-B5,
R₇₁ and R₇₂ are each independently a substituted or unsubstituted aryl group having 6 to 60 ring-forming carbon atoms, or a substituted or unsubstituted heteroaryl group having 2 to 60 ring-forming carbon atoms.

7. The light emitting element of claim 1, wherein Formula 1 is represented by any one selected from among Formulas 1-C1 to 1-C6: 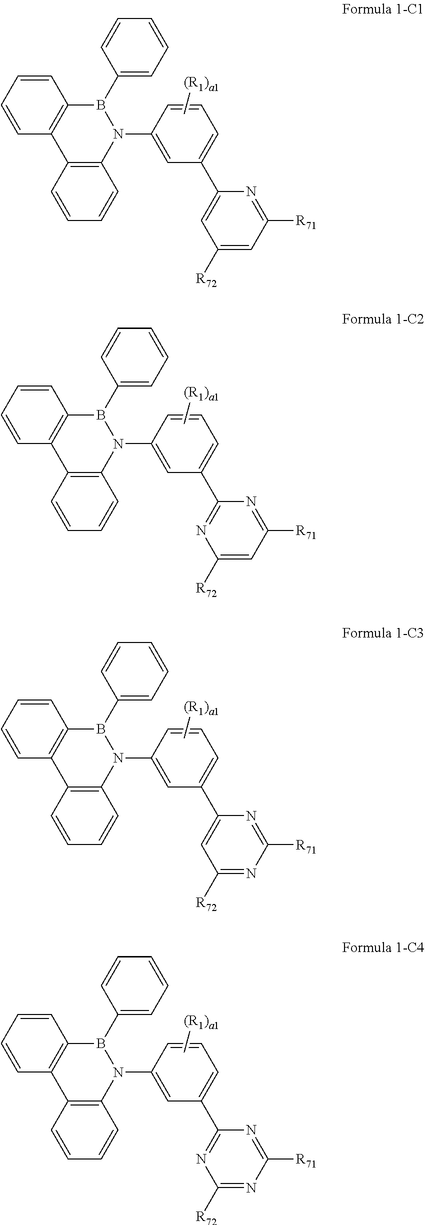 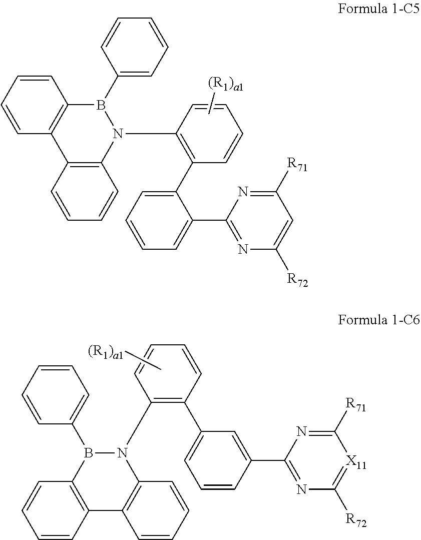
wherein in Formula 1-C6,
is CH or N; and
wherein in Formulas 1-C1 to 1-C6,
R₇₁ and R₇₂ are each independently a substituted or unsubstituted aryl group having 6 to 60 ring-forming carbon atoms, or a substituted or unsubstituted heteroaryl group having 2 to 60 ring-forming carbon atoms, and
a1 and R₁ are the same as defined in Formula 1.

8. The light emitting element of claim 1, wherein in Formula 1, R₁ is represented by any one selected from among R1-1 to R1-5: 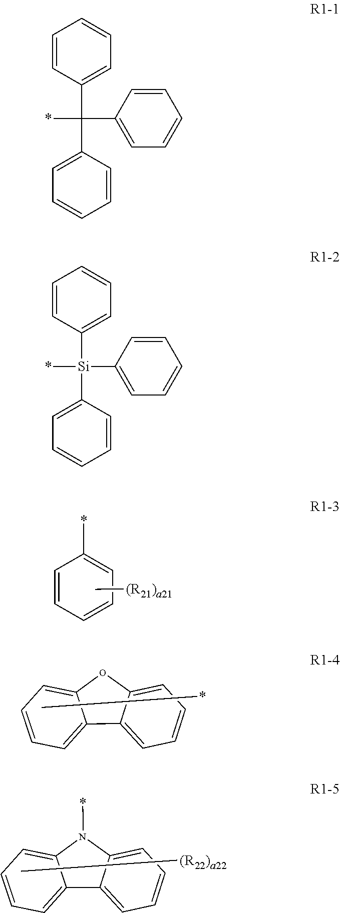
wherein in R1-3,
a21 is an integer from 0 to 5, and
R₂₁ is a hydrogen atom, a deuterium atom, a substituted or unsubstituted silyl group, or a substituted or unsubstituted carbazole group;
wherein in R1-5,
a22 is an integer from 0 to 8, and
R₂₂ is a hydrogen atom, a deuterium atom, or a substituted or unsubstituted carbazole group.

9. The light emitting element of claim 1, wherein the emission layer comprises a dopant and a host,
the host containing the polycyclic compound.

10. The light emitting element of claim 1, wherein the emission layer is a layer of phosphorescence, or a layer of thermally activated delayed fluorescence.

11. The light emitting element of claim 1, wherein the polycyclic compound is represented by any one selected from among compounds of Compound Group 1: 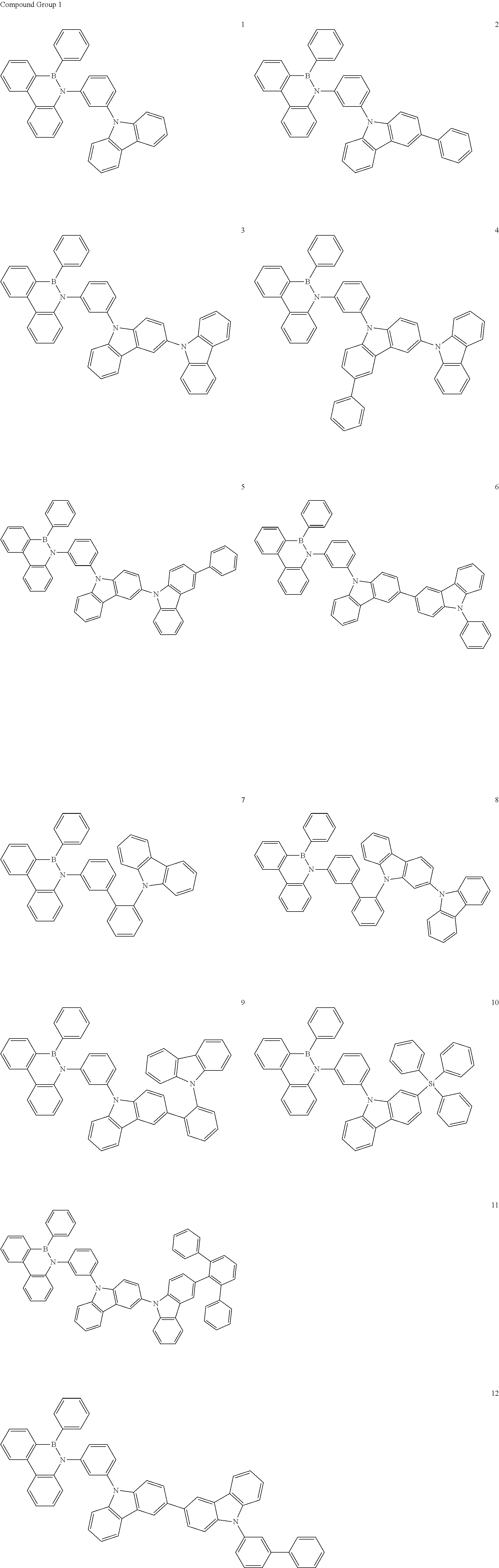 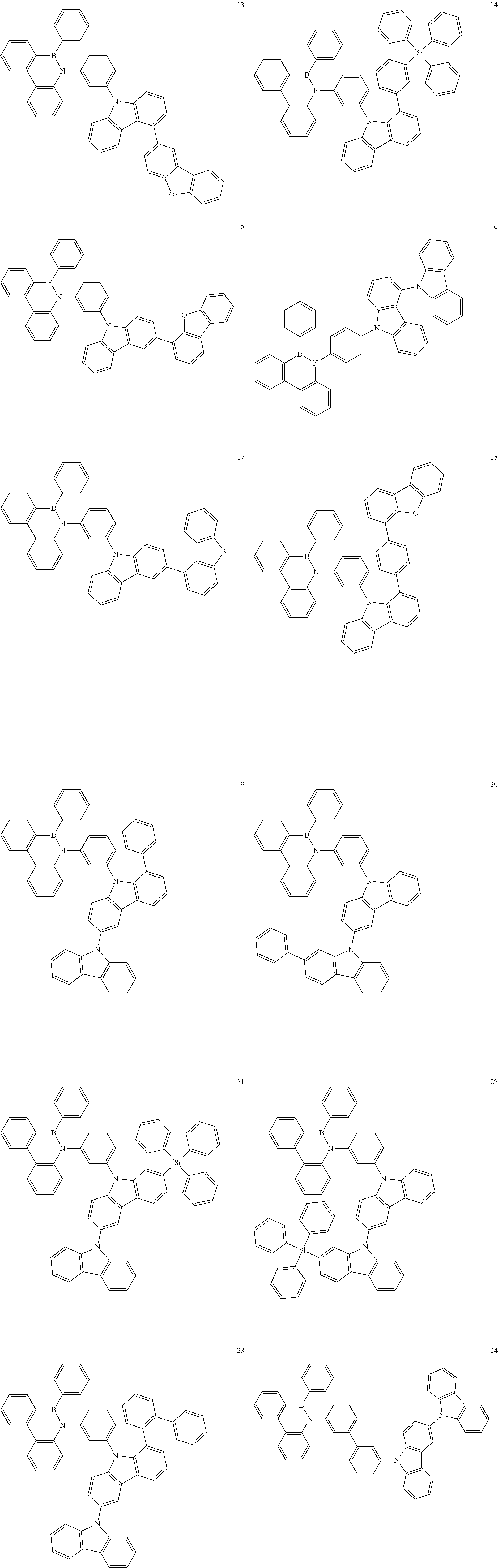 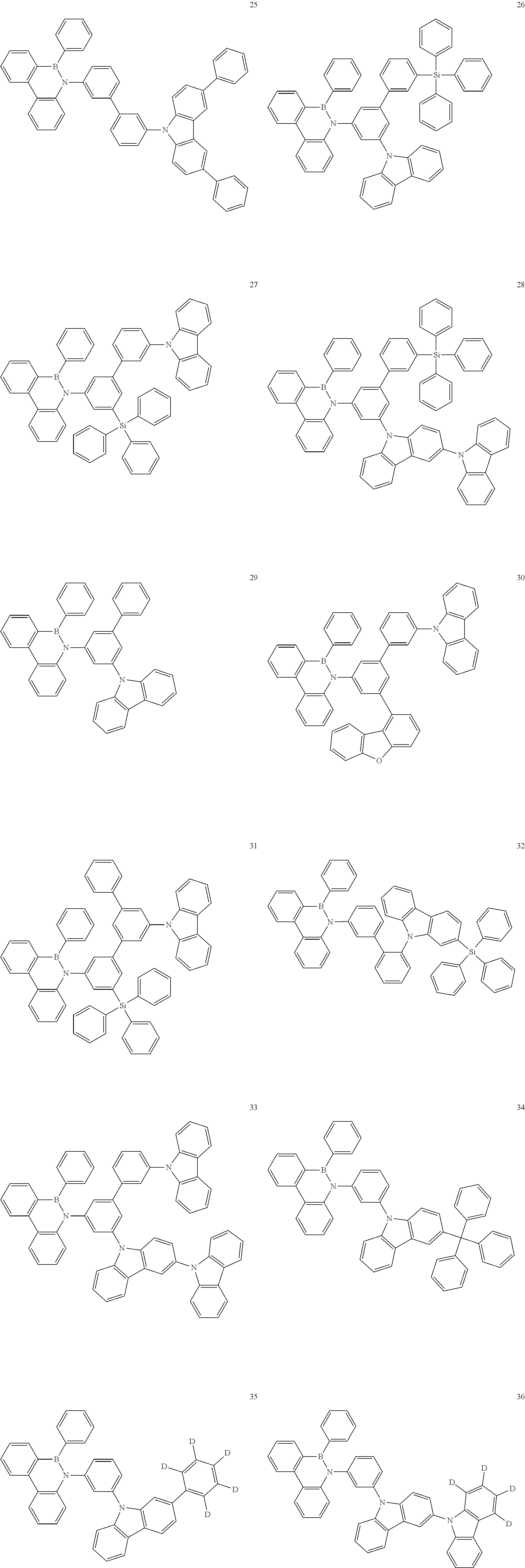 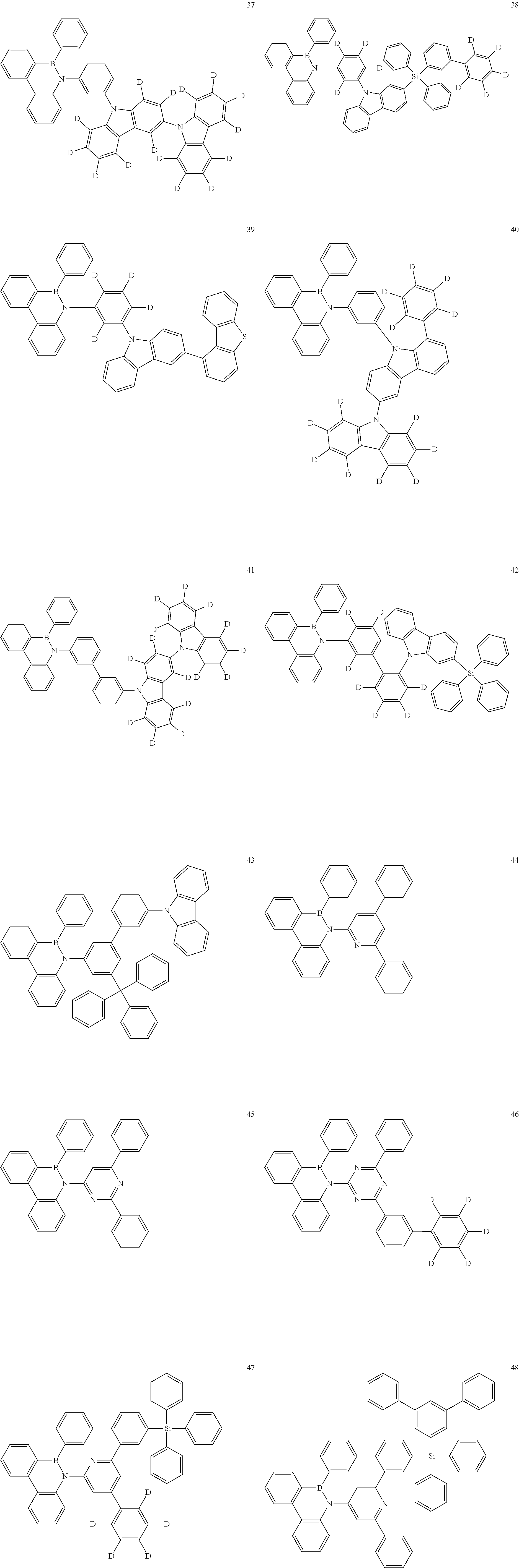 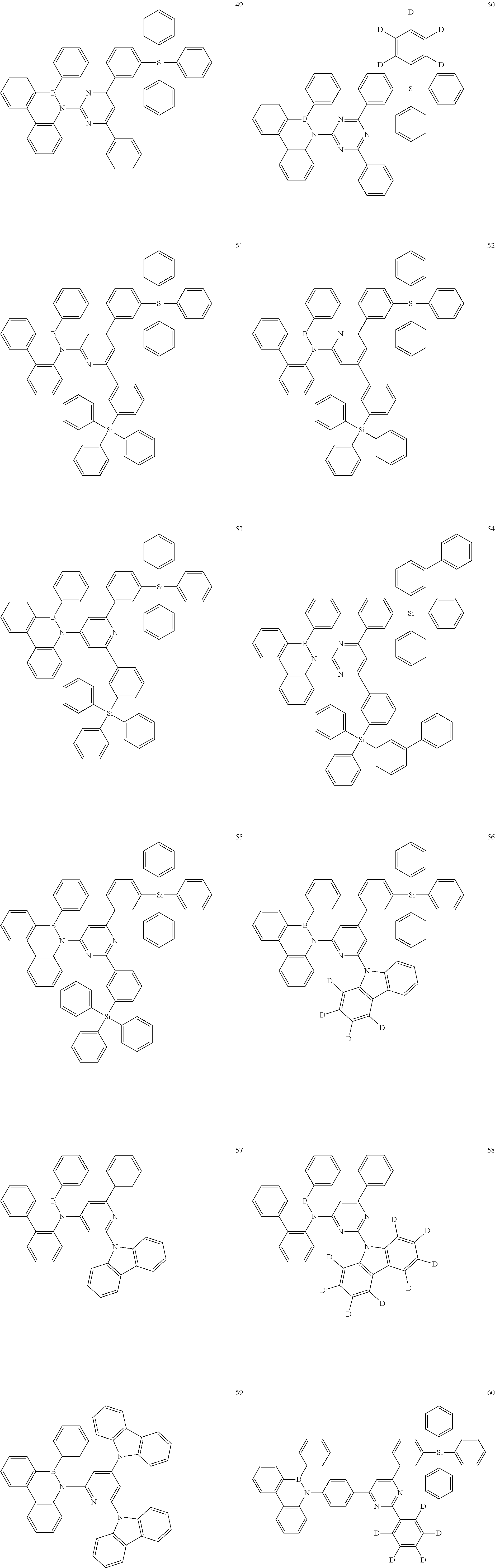 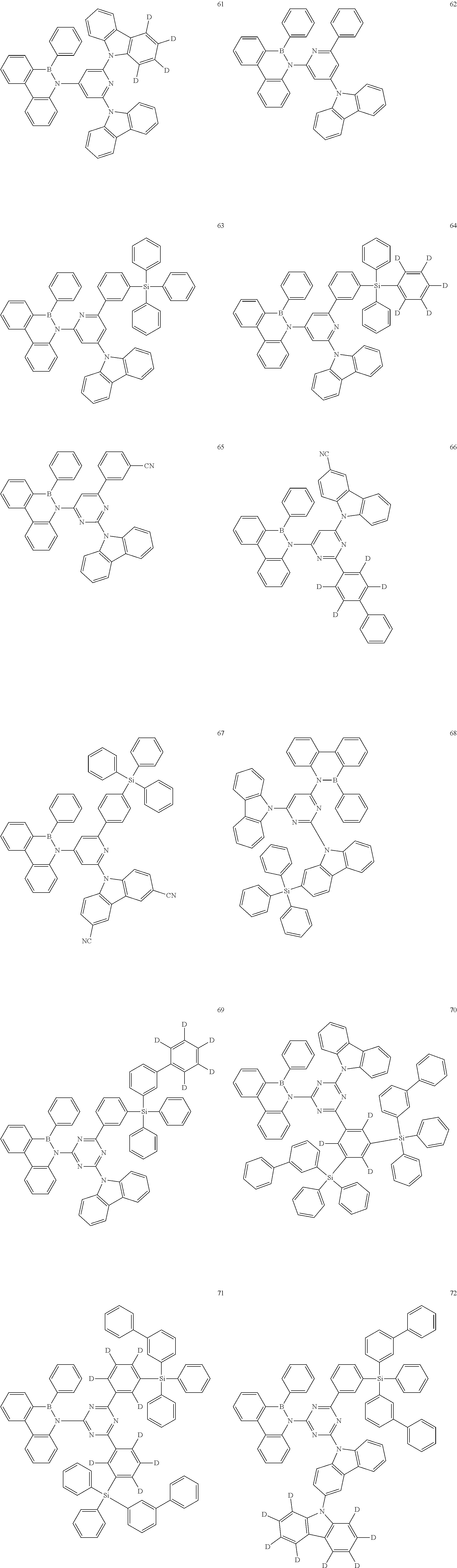 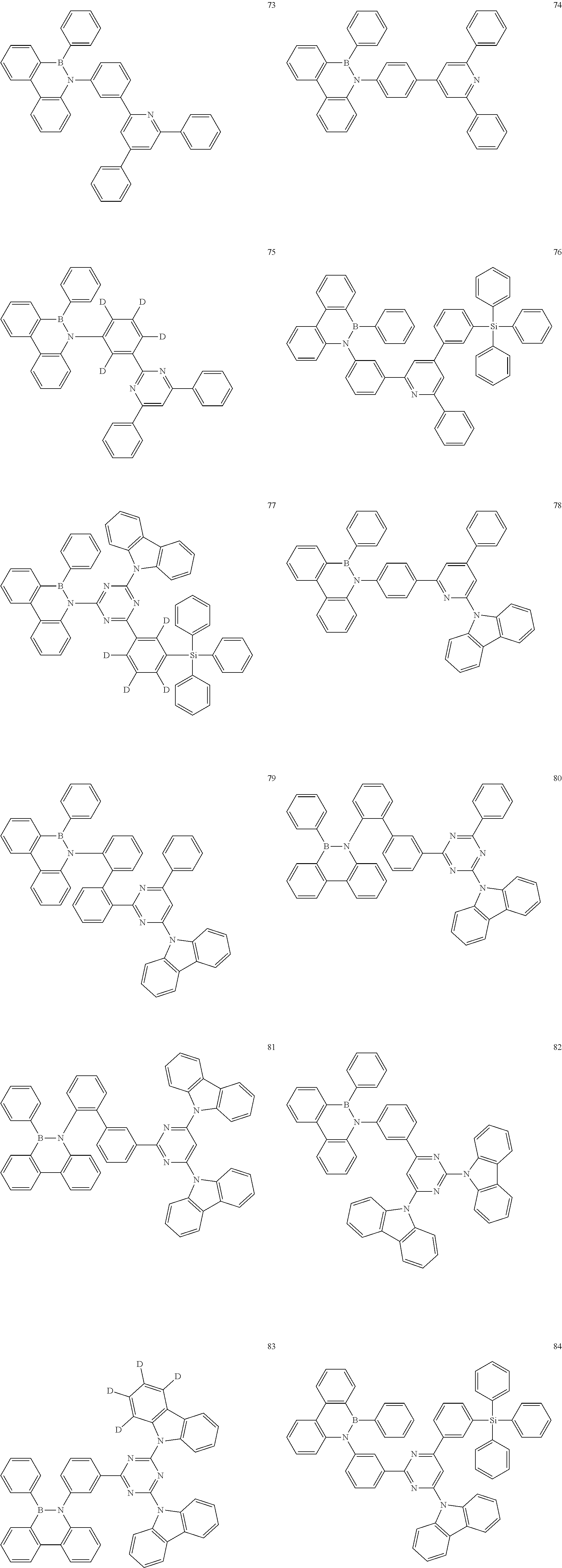 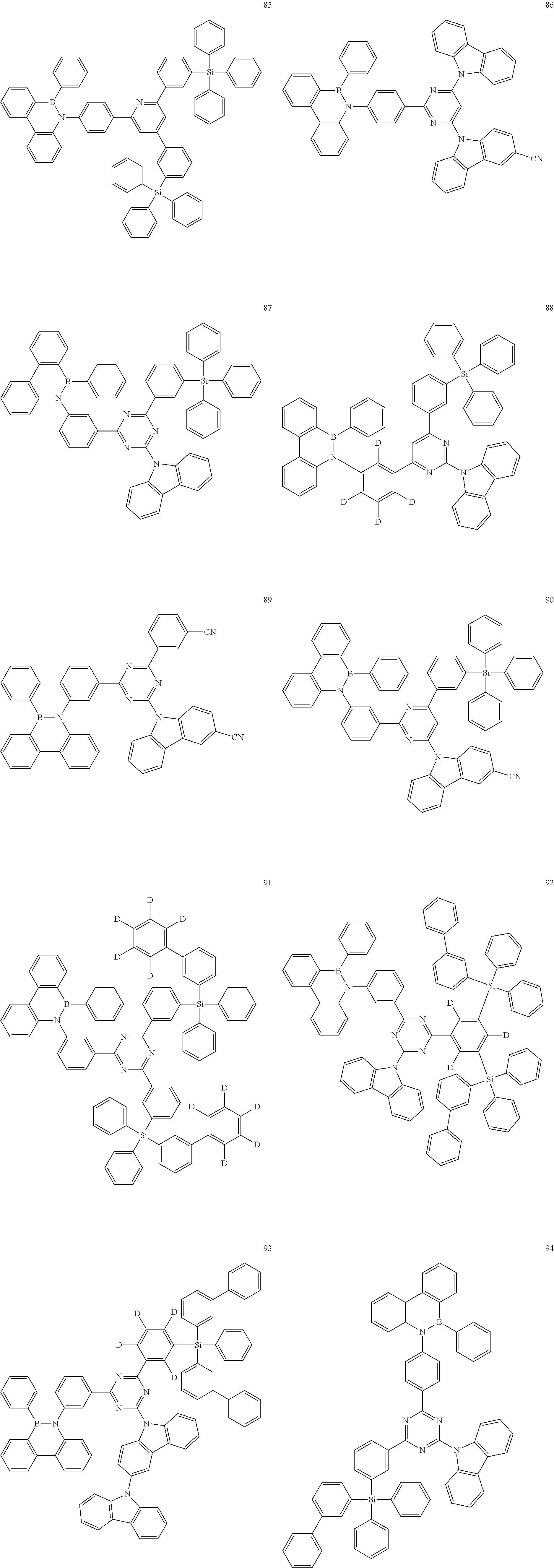
wherein in Compound Group 1, D is a deuterium atom.

12. A polycyclic compound represented by Formula 1: 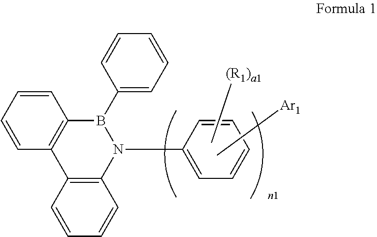
wherein in Formula 1,
n1 is an integer from 0 to 3,
Ar₁ is a substituted or unsubstituted carbazole group, a substituted or unsubstituted pyridine group, a substituted or unsubstituted pyrimidine group, or a substituted or unsubstituted triazine group,
when Ar₁ is an unsubstituted carbazole group, n1 is an integer from 1 to 3,
when n1 is 1 and Ar₁ is an unsubstituted carbazole group, Ar₁ is bonded in meta position with respect to N,
a1 is an integer from 0 to 4, and
R₁ is a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted hydrocarbon ring group having 6 to 60 ring-forming carbon atoms, a substituted or unsubstituted aryl group having 6 to 60 ring-forming carbon atoms, or a substituted or unsubstituted heterocyclic group having 2 to 60 ring-forming carbon atoms.

13. The polycyclic compound of claim 12, wherein in Formula 1, Ar₁ is represented by Formula 2-1 or Formula 2-2: 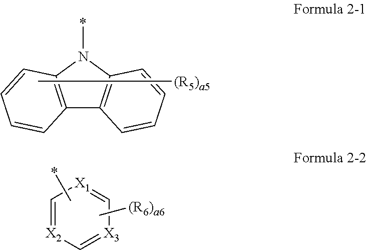
wherein in Formula 2-1,
a5 is an integer from 0 to 8, and
R₅ is a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms; and
wherein in Formula 2-2,
a6 is an integer from 0 to 2,
at least one of X₁ to X₃ is N and each of the reminder of X₁ to X₃ is independently CR₇, and
R₆ and R₇ are each independently a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms.

14. The polycyclic compound of claim 13, wherein in Formulas 2-1 and 2-2, R₅ and R₆ are each independently represented by any one selected from among RN-1 to RN-5: 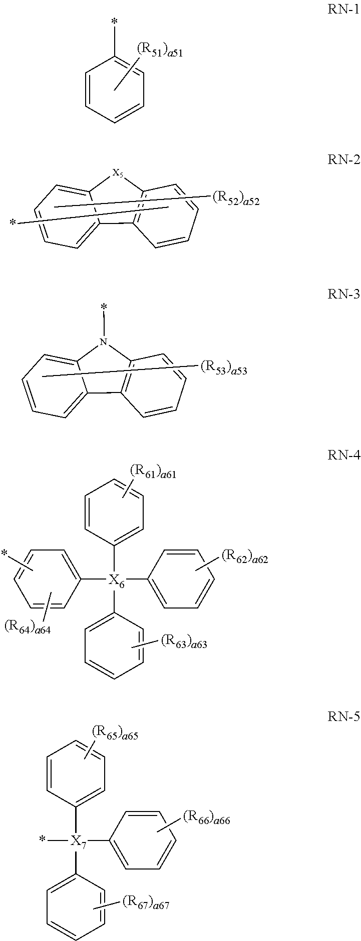
wherein in RN-2,
a52 is an integer from 0 to 7, and
X₅ is CR₅₄R₅₅, SiR₅₆R₅₇, NR₅₈, O, or S;
wherein in RN-3,
a53 is an integer from 0 to 8;
wherein in RN-4,
a64 is an integer from 0 to 4, and
X₆ is C or Si;
wherein in RN-5,
X₇ is C or Si; and
wherein in RN-1 to RN-5,
a51, a61 to a63, and a65 to a67 are each independently an integer from 0 to 5, and
R₅₁ to R₅₈ and R₆₁ to R₆₇ are each independently a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms.

15. The polycyclic compound of claim 12, wherein Formula 1 is represented by any one selected from among Formulas 1-1 to 1-5: 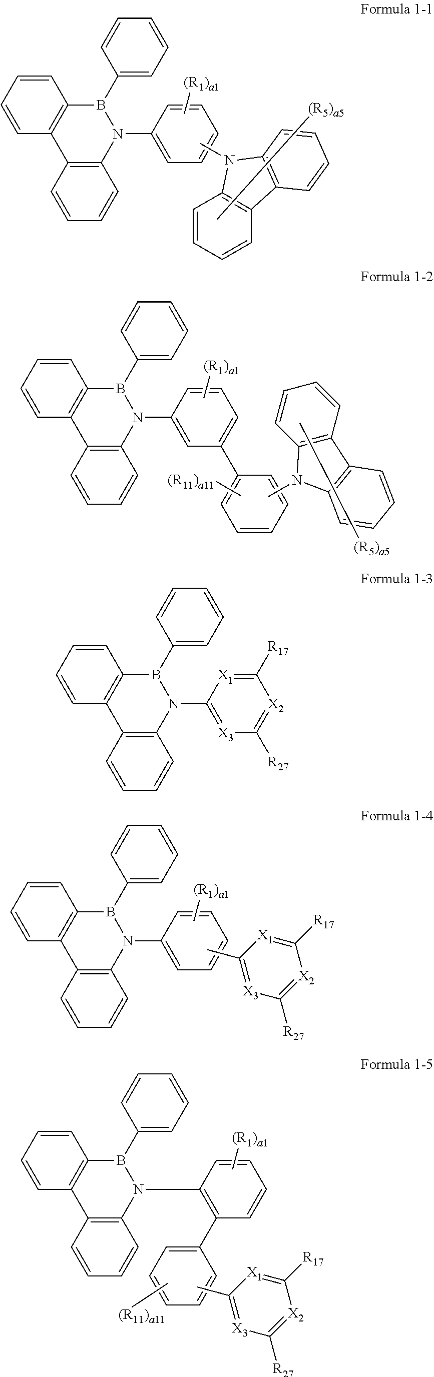
wherein in Formulas 1-1 and 1-2,
a5 is an integer from 0 to 8, and
R₅ is a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms;
wherein in Formulas 1-2 and 1-5,
a11 is an integer from 0 to 4, and
R₁₁ is a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted hydrocarbon ring group having 6 to 60 ring-forming carbon atoms, a substituted or unsubstituted aryl group having 6 to 60 ring-forming carbon atoms, or a substituted or unsubstituted heterocyclic group having 2 to 60 ring-forming carbon atoms;
wherein in Formulas 1-3 to 1-5,
at least one of X₁ to X₃ is N and each of the reminder of X₁ to X₃ is independently CR₇, and
R₇, R₁₇, and R₂₇ are each independently a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms; and
wherein in Formulas 1-1 to 1-5,
a1 and R₁ are the same as defined in Formula 1.

16. The polycyclic compound of claim 12, wherein Formula 1 is represented by any one selected from among Formulas 1-A1 to 1-A4: 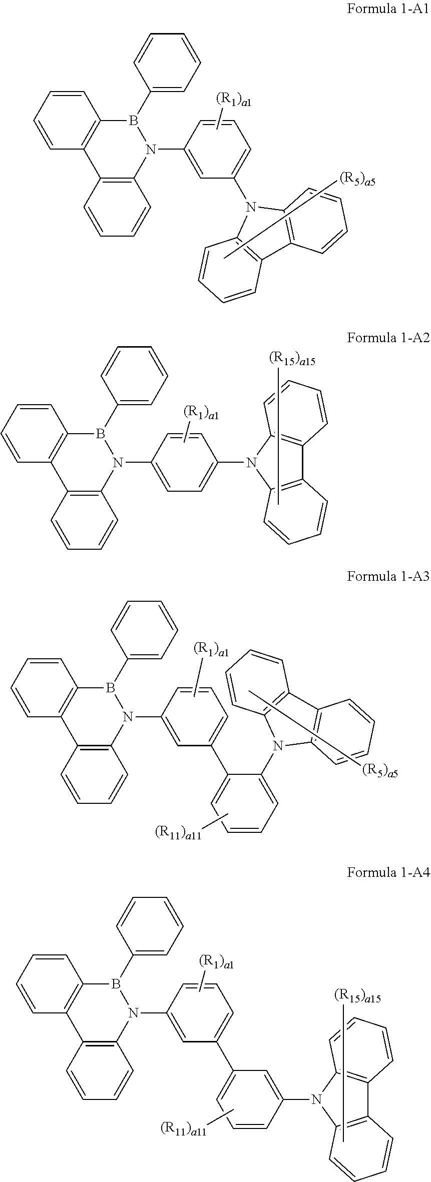
wherein in Formula 1-A2,
a15 is an integer from 1 to 8, and
R₁₅ is a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms;
wherein in Formulas 1-A3 and 1-A4,
a11 is an integer from 0 to 4, and
R₁₁ is a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted hydrocarbon ring group having 6 to 60 ring-forming carbon atoms, a substituted or unsubstituted aryl group having 6 to 60 ring-forming carbon atoms, or a substituted or unsubstituted heterocyclic group having 2 to 60 ring-forming carbon atoms;
wherein in Formulas 1-A1, 1-A3 and 1-A4,
a5 is an integer from 0 to 8, and
R₅ is a hydrogen atom, a deuterium atom, a halogen atom, a hydroxy group, a cyano group, a nitro group, a substituted or unsubstituted silyl group, a substituted or unsubstituted alkyl group having 1 to 10 carbon atoms, a substituted or unsubstituted aryl group having 6 to 60 ring-forming carbon atoms, or a substituted or unsubstituted heteroaryl group having 2 to 60 ring-forming carbon atoms; and
wherein in Formulas 1-A1 to 1-A4,
a1 and R₁ are the same as defined in Formula 1.

17. The polycyclic compound of claim 12, wherein Formula 1 is represented by any one selected from among Formulas 1-B1 to 1-B5: 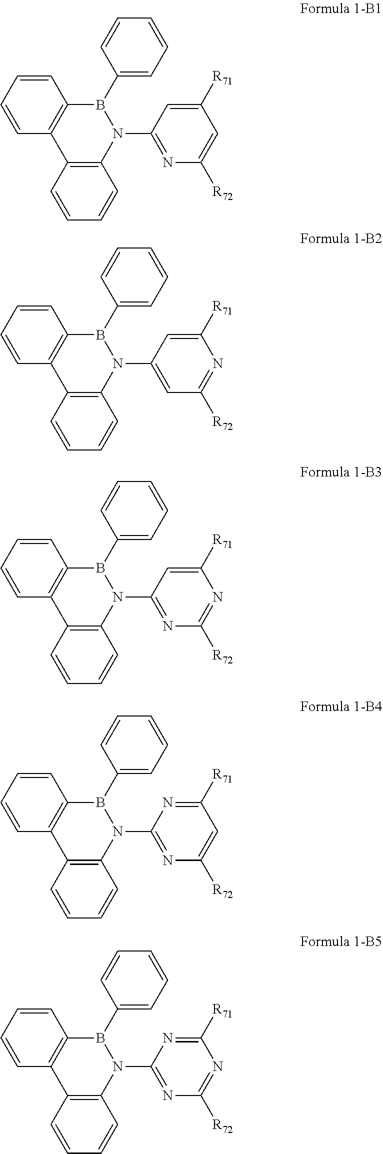
wherein in Formulas 1-B1 to 1-B5,
R₇₁ and R₇₂ are each independently a substituted or unsubstituted aryl group having 6 to 60 ring-forming carbon atoms, or a substituted or unsubstituted heteroaryl group having 2 to 60 ring-forming carbon atoms.

18. The polycyclic compound of claim 12, wherein Formula 1 is represented by any one selected from among Formulas 1-C1 to 1-C6: 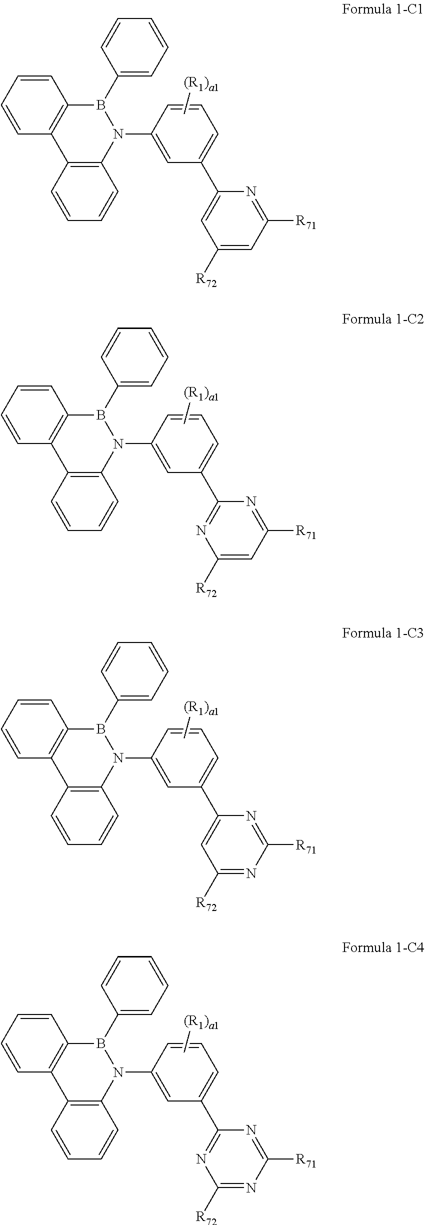 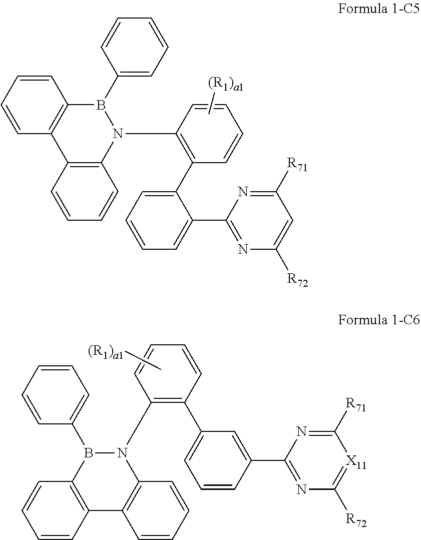
wherein in Formula 1-C6,
X₁₁ is CH or N; and
wherein in Formulas 1-C1 to 1-C6,
R₇₁ and R₇₂ are each independently a substituted or unsubstituted aryl group having 6 to 60 ring-forming carbon atoms, or a substituted or unsubstituted heteroaryl group having 2 to 60 ring-forming carbon atoms, and
a1 and R₁ are the same as defined in Formula 1.

19. The polycyclic compound of claim 12, wherein in Formula 1, at least one of R₁ or Ar₁ comprises a deuterium atom or a substituent containing a deuterium atom.

20. The polycyclic compound of claim 12, wherein Formula 1 is represented by any one selected from among compounds of Compound Group 1: 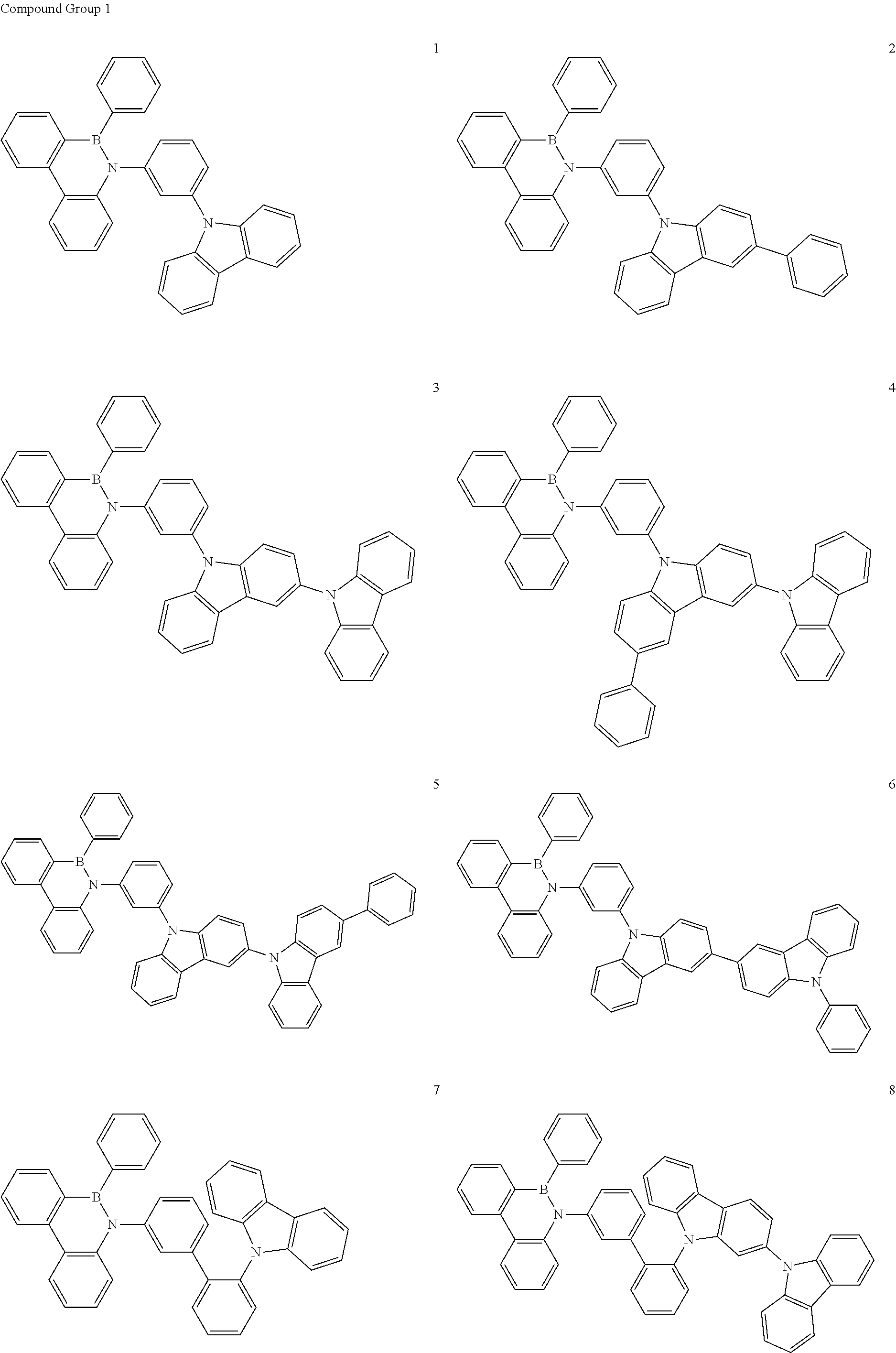 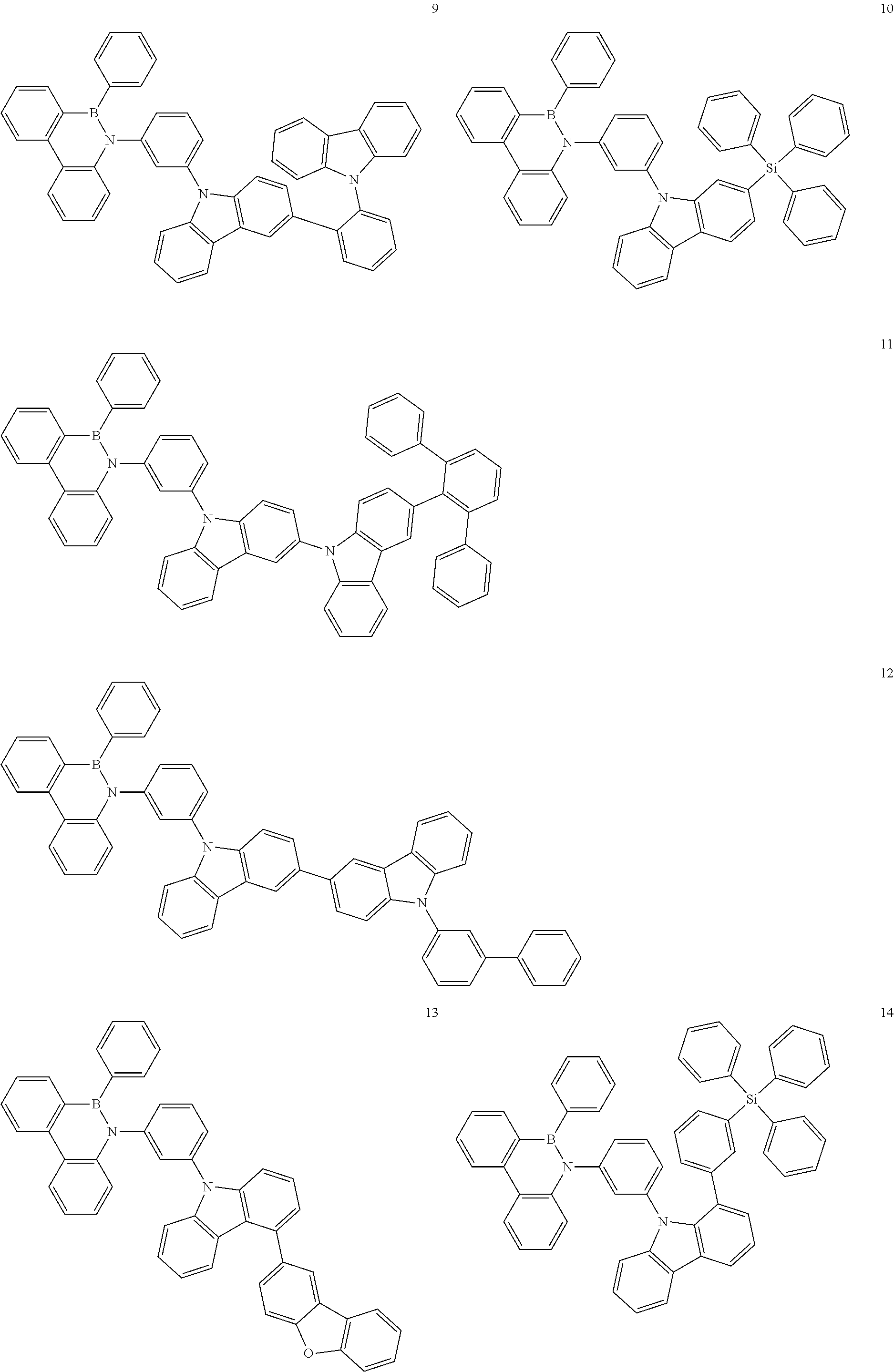 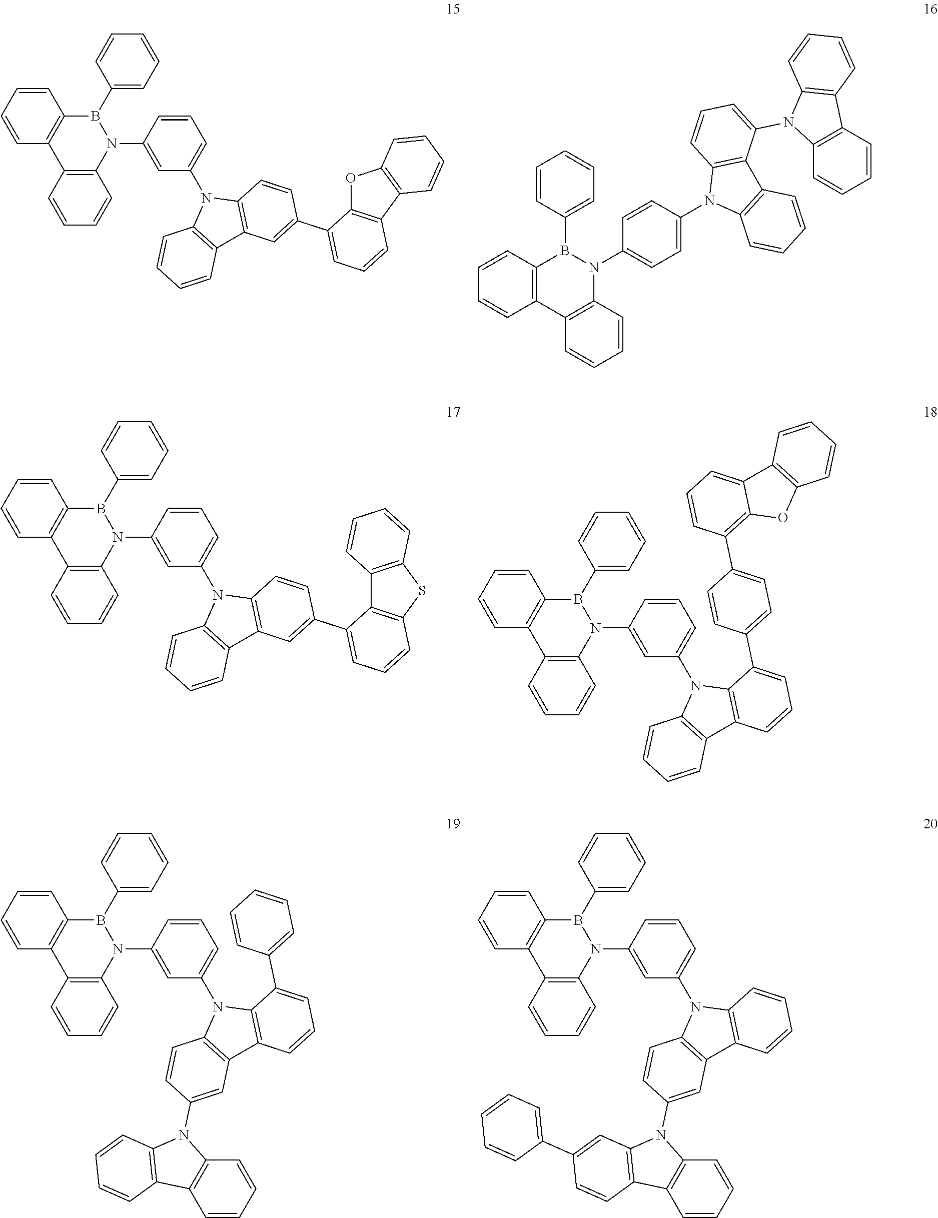 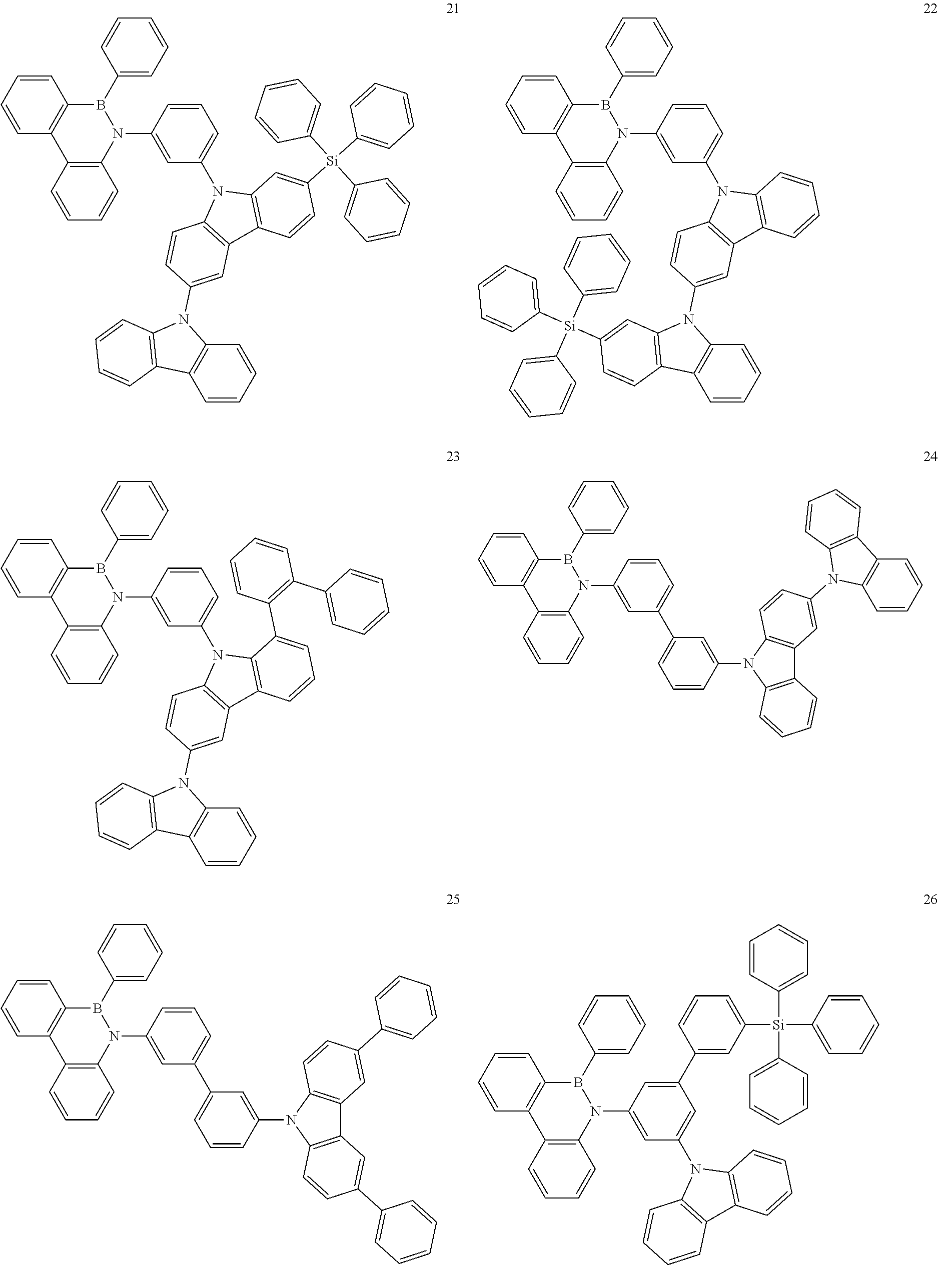 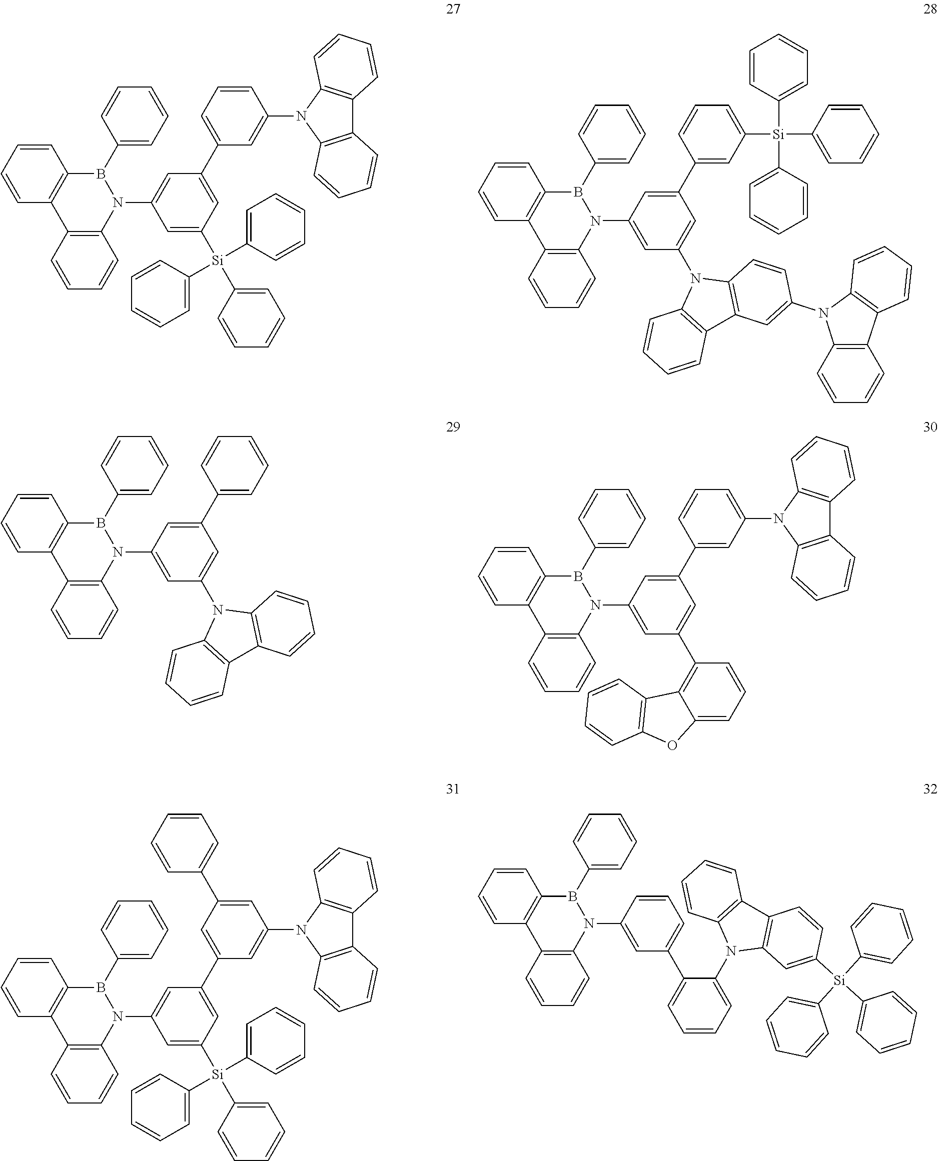 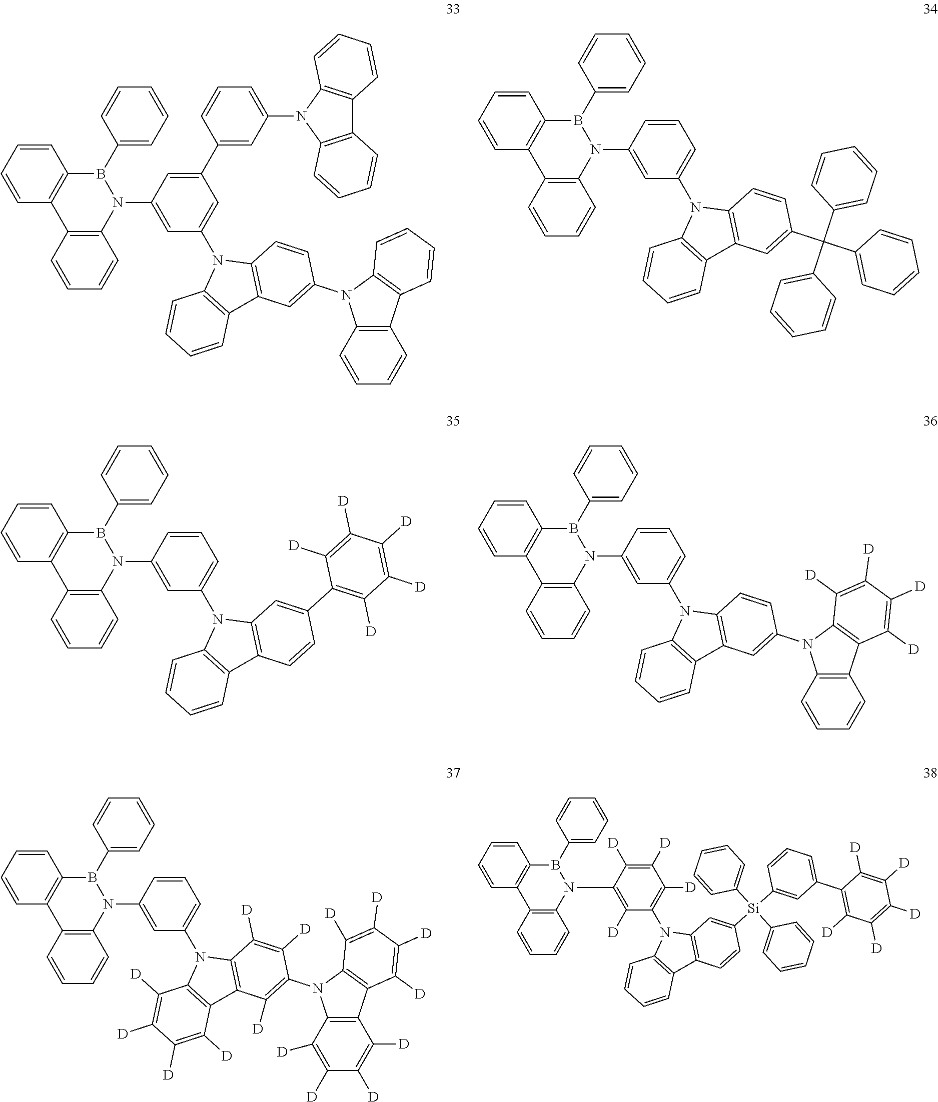 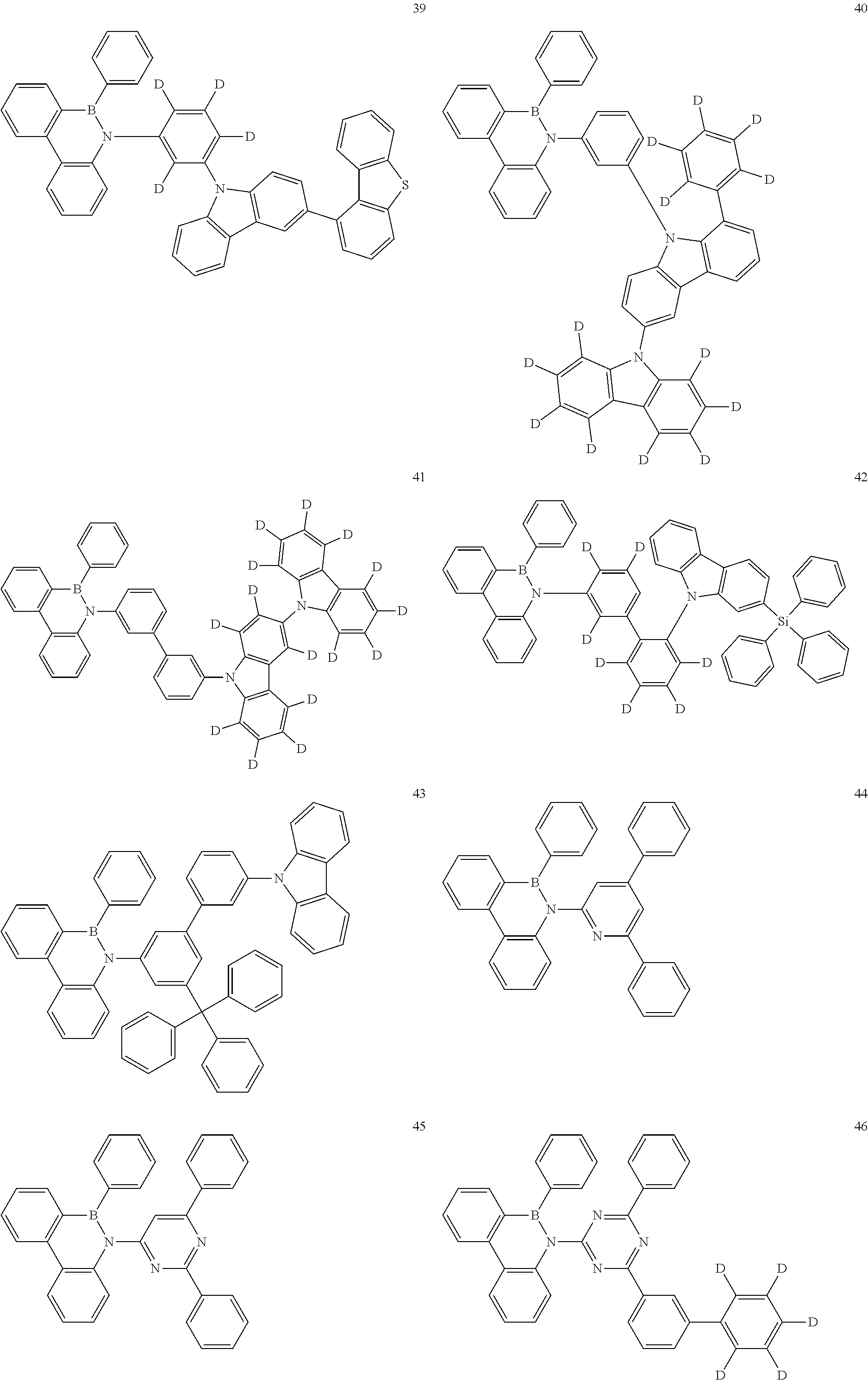 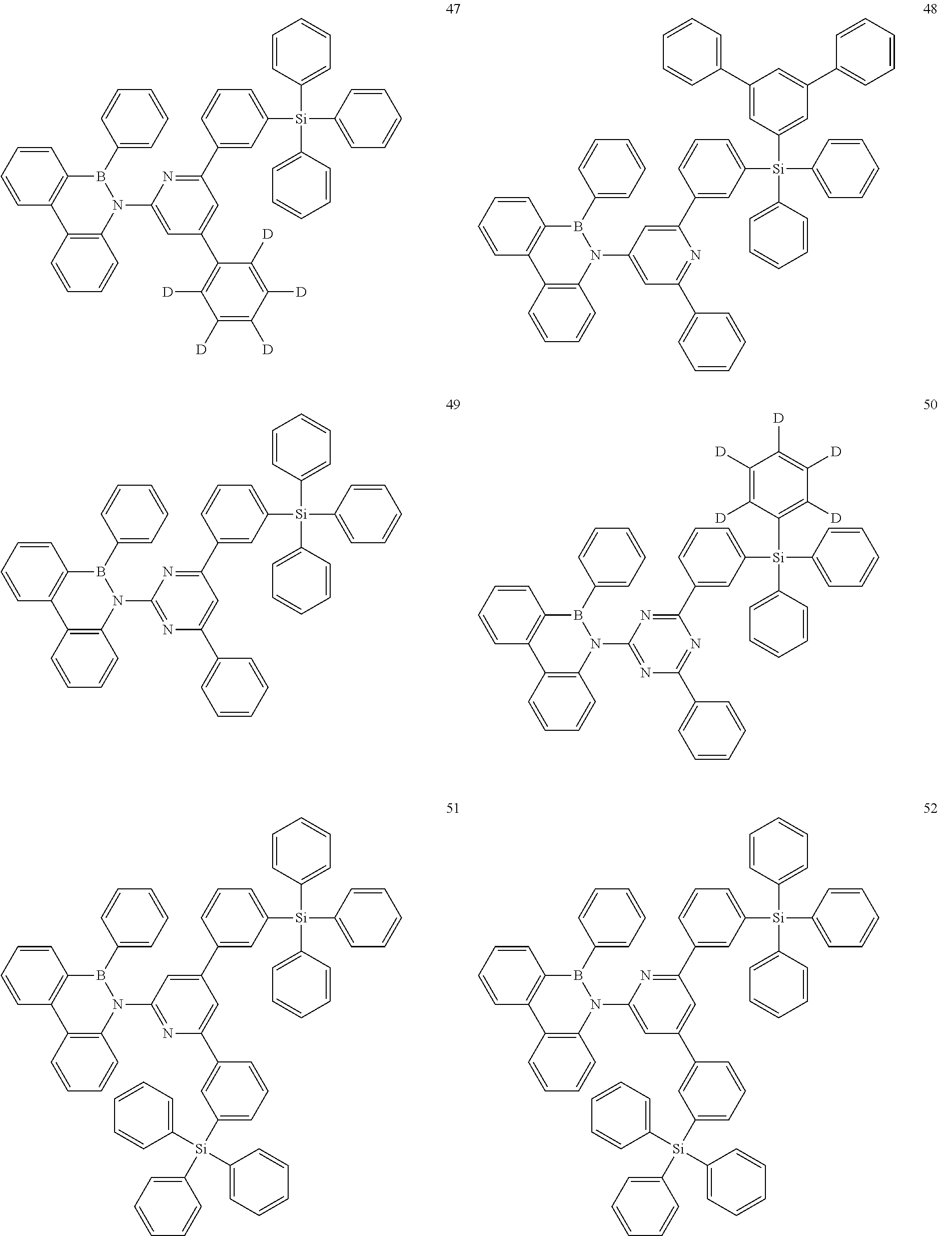 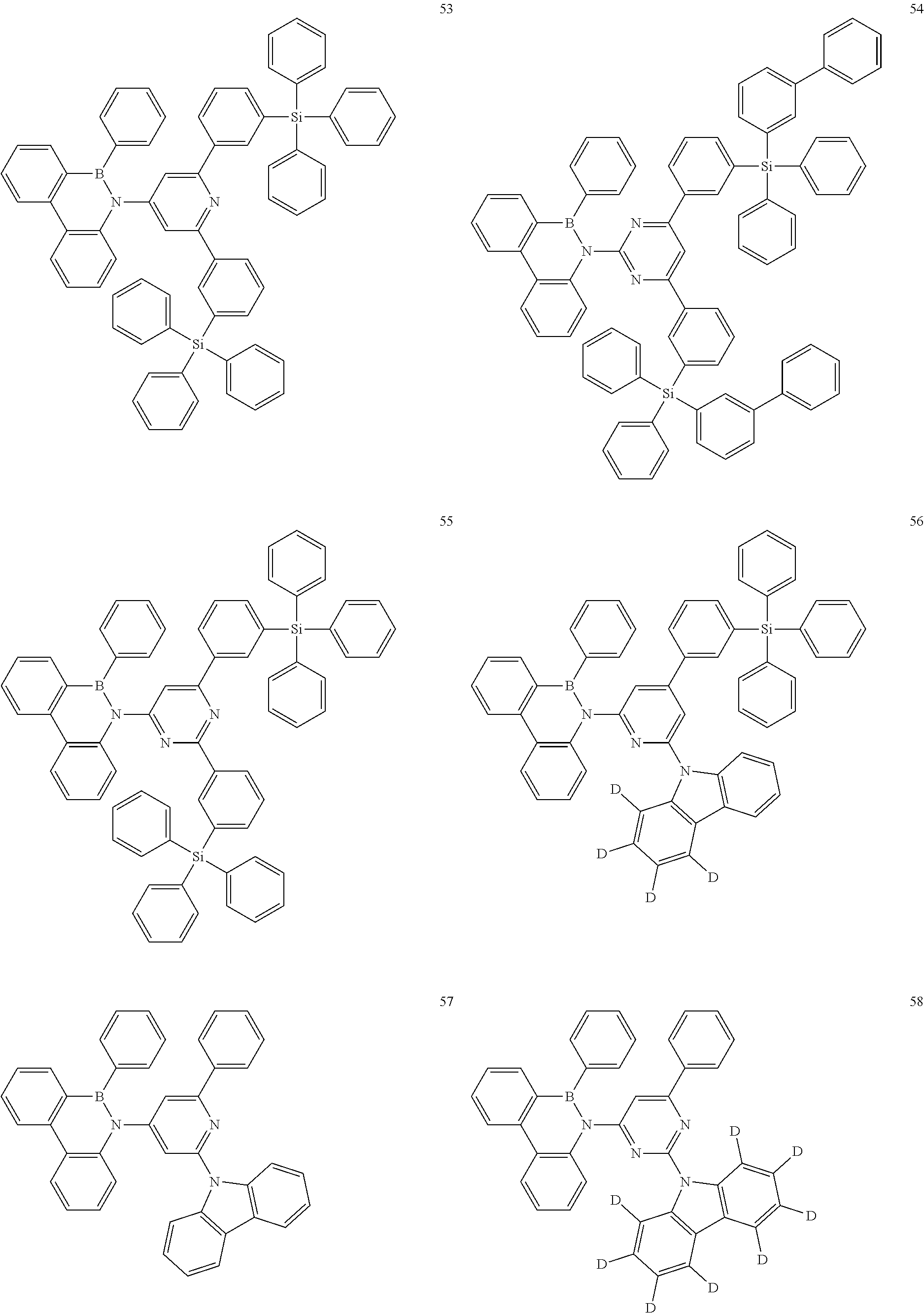 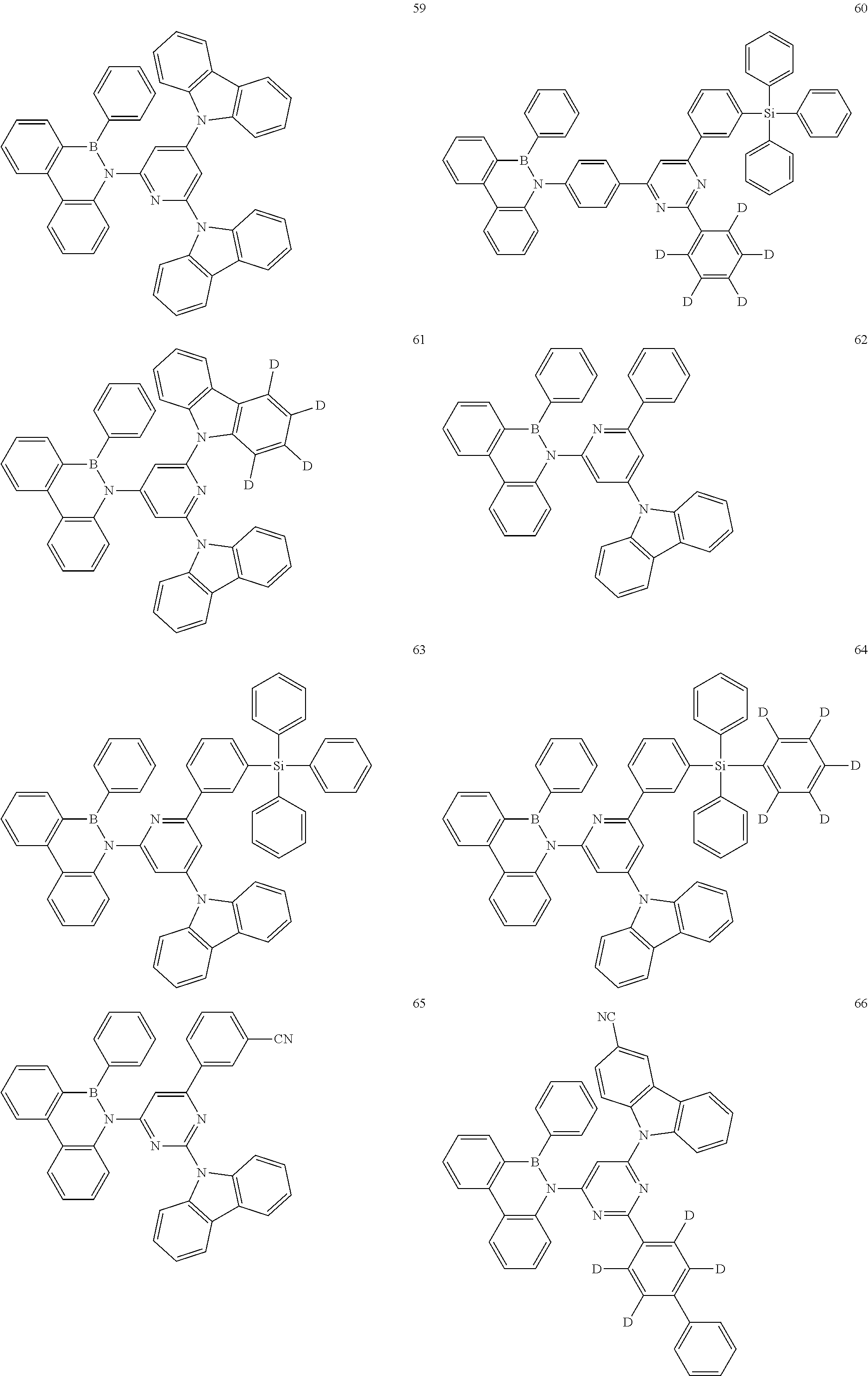 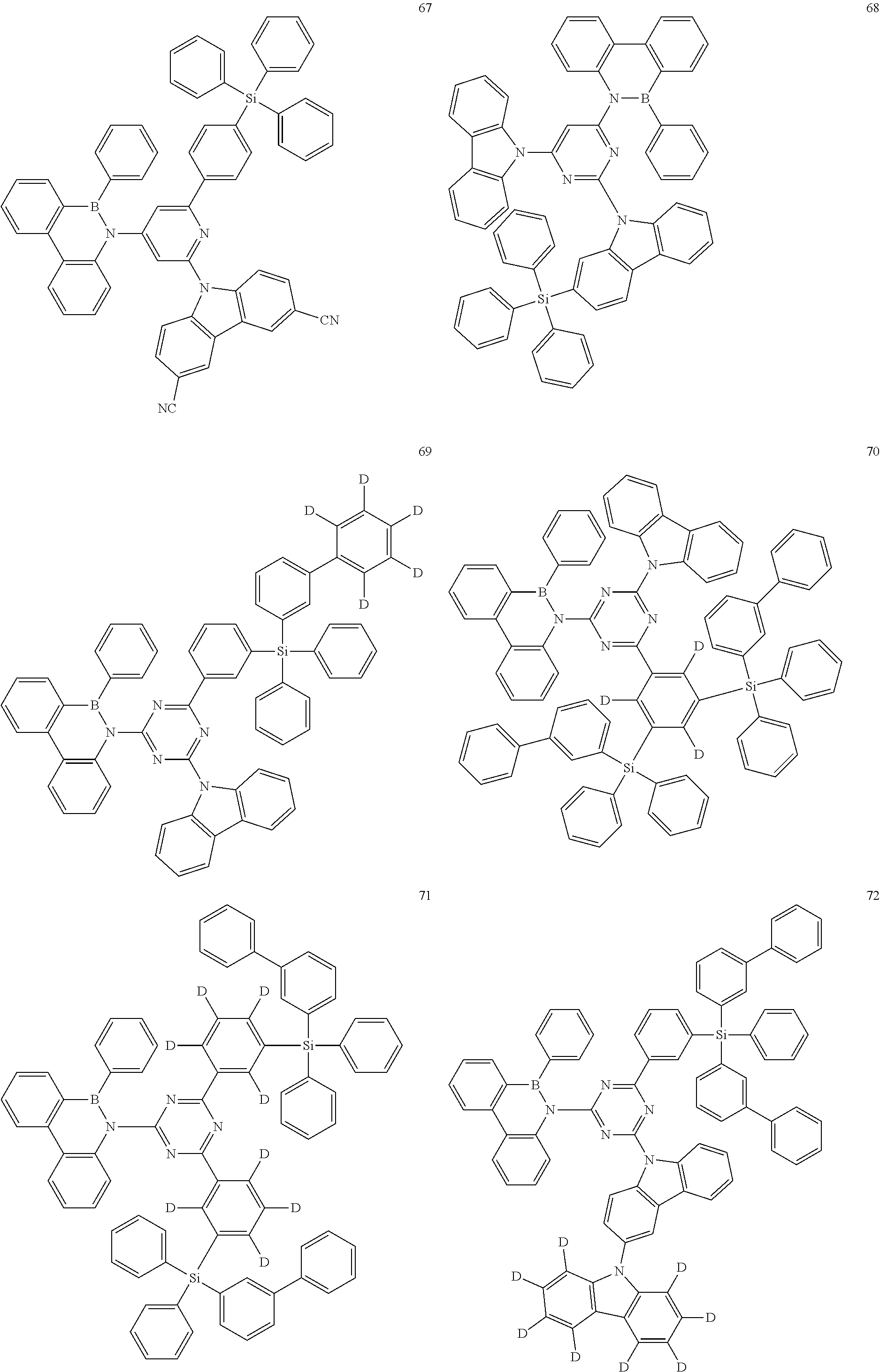 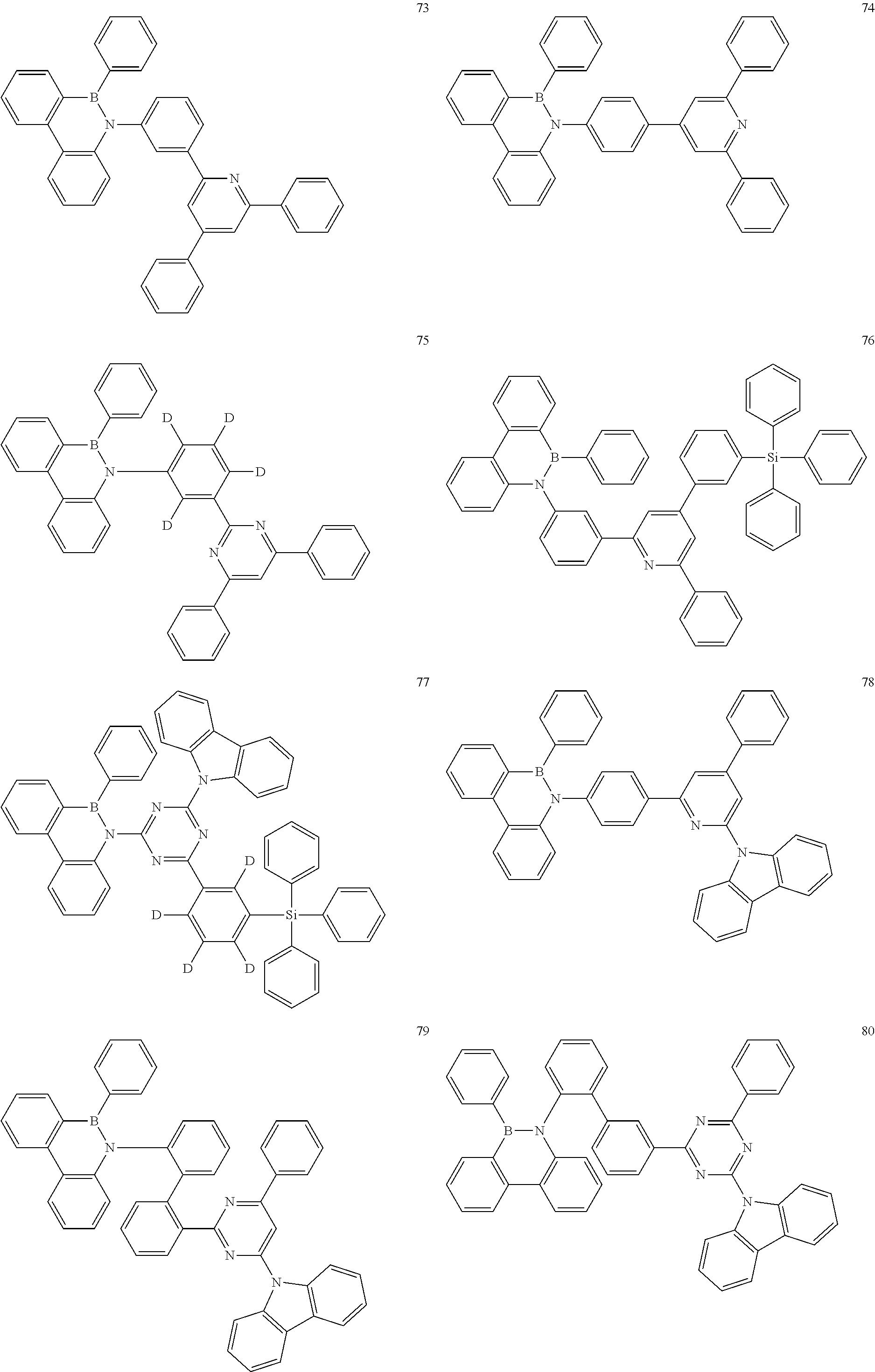 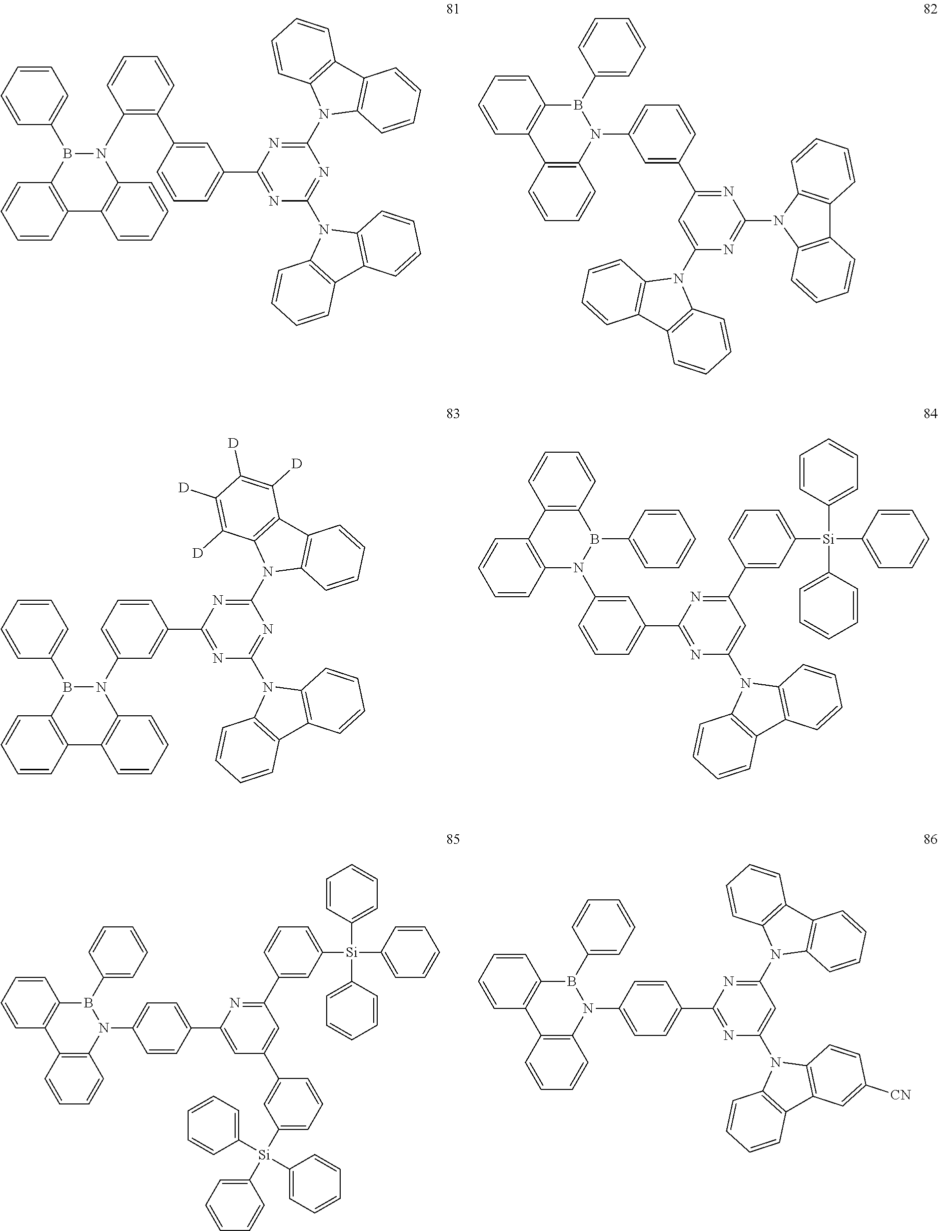 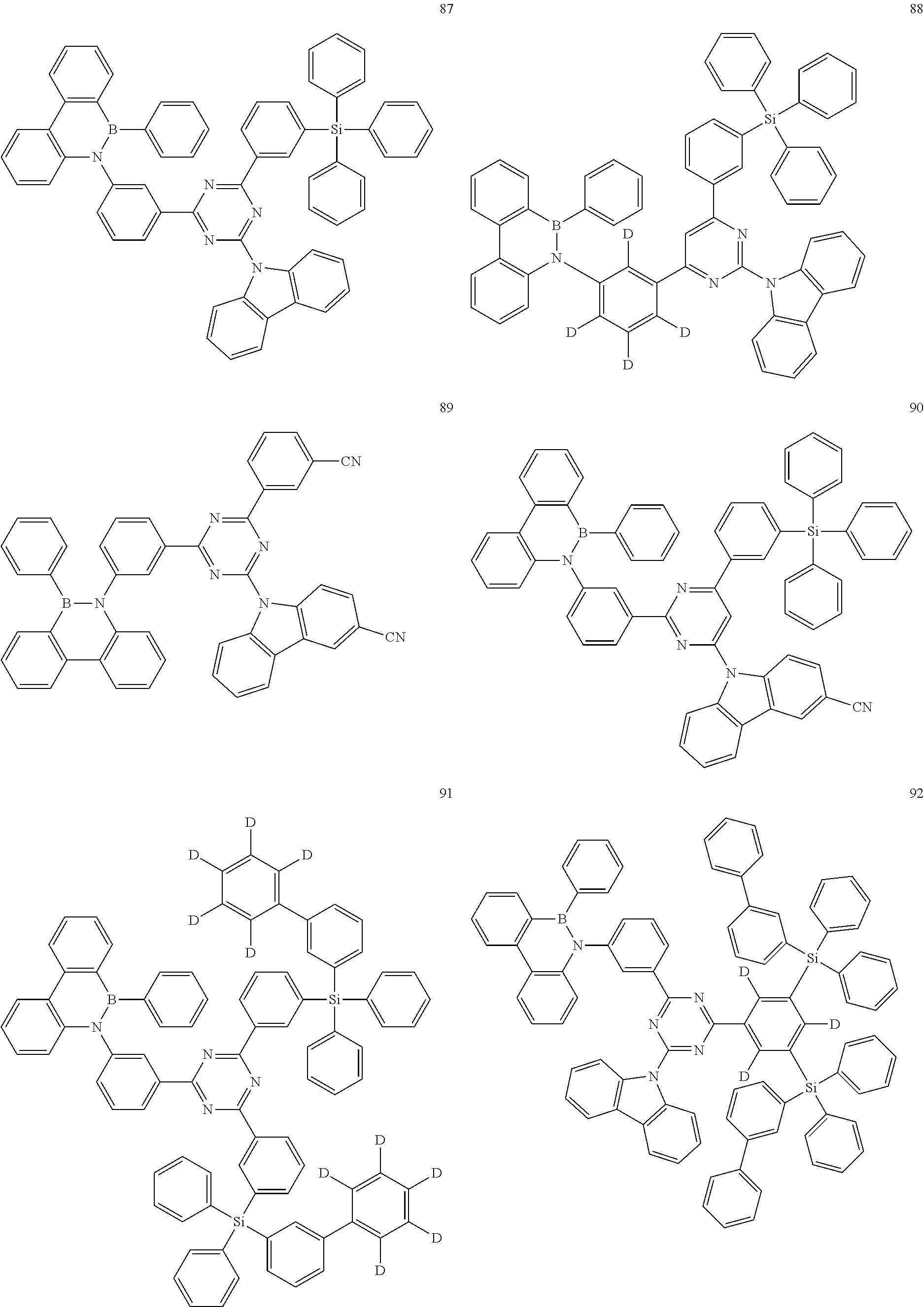 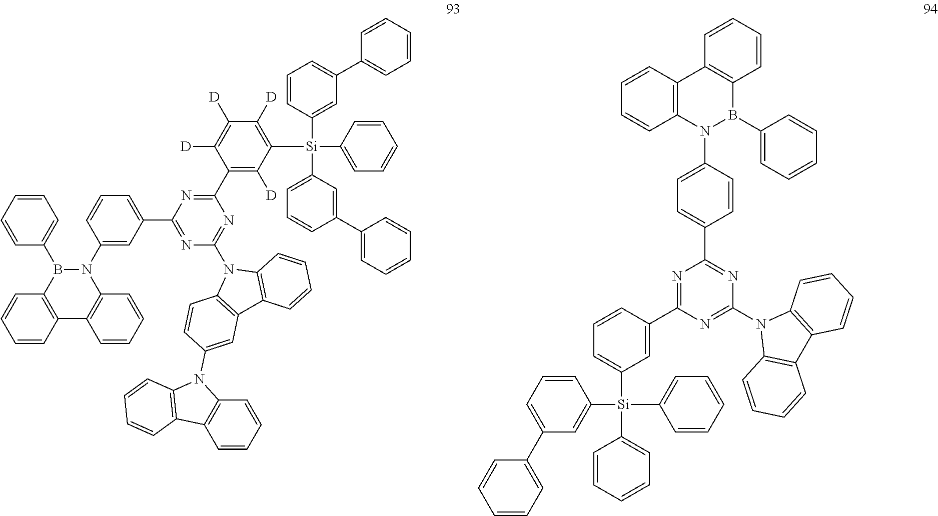
wherein in Compound Group 1, D is a deuterium atom.
